(19) United States
(12) Patent Application Publication
(10) Pub. No.: US 2022/0194969 A1
(43) Pub. Date: Jun. 23, 2022

(54) METAL HALIDE PEROVSKITE LIGHT EMITTING DEVICE AND METHOD FOR MANUFACTURING SAME

(71) Applicant: SEOUL NATIONAL UNIVERSITY R&DB FOUNDATION, Seoul (KR)

(72) Inventors: Tae-Woo LEE, Seoul (KR); Joo Sung KIM, Seoul (KR); Sung Joo KWON, Goyang-si, Gyeonggi-do (KR); So Yeong AHN, Seoul (KR); Ho Beom KIM, Goyang-si Gyeonggi-do (KR)

(21) Appl. No.: 17/415,718

(22) PCT Filed: Dec. 17, 2019
(86) PCT No.: PCT/KR2019/017914

§ 371 Date: Mar. 7, 2022

(30) Foreign Application Priority Data
Dec. 17, 2018 (KR) 10-2018-0163162
Dec. 17, 2018 (KR) 10-2018-0163461
Dec. 20, 2018 (KR) 10-2018-0166090
Dec. 16, 2019 (KR) 10-2019-0168360

(51) Int. Cl. C07F 7/24; C09K 11/06; C09K 11/66; C01G 21/16

(52) U.S. Cl. CPC C07F 7/24; C09K 11/06; B82Y 20/00; C01G 21/16; C09K 11/664

(57) ABSTRACT

Provided are metal halide perovskite light emitting device and method of manufacturing the same. The metal halide perovskite light emitting device uses perovskite film having a multi-dimensional crystal structure derived from a proton transfer reaction as light emitting layer. Due to self-assembled shell of the perovskite film, ion movement is suppressed and surface defects are removed. Thereby, photoluminescence intensity, luminescence efficiency and lifetime are improved. By injecting a fluorine-based material and a basic material into the PEDOT:PSS conductive polymer used as the conventional hole injection layer, the acidity is controlled and the work function of the interface is improved. Furthermore, chemically stable graphene barrier layer protects the electrode vulnerable to acid, so that a high-efficiency light emitting device can be manufactured.

### TECHNICAL FIELD

The present invention is related to metal halide light-emitting device and method of manufacturing the metal halide light-emitting device, more particularly to perovskite film having multi-dimensional crystal structure induced by proton transfer reaction, manufacturing method of the perovskite film and light-emitting device using the perovskite film as light emission layer.

### BACKGROUND ART

The current megatrend in the display market is moving to a high-efficiency, high-resolution display that aims to achieve high-purity and natural colors in addition to the existing high-efficiency, high-resolution displays. From this point of view, an organic light-emitting-diode (OLED) device based on an organic light emitter has made a leap forward, and an inorganic quantum dot LED with improved color purity is being actively researched and developed as another alternative. However, both the organic and the inorganic quantum dot light emitters have inherent limitations in terms of materials.

Existing organic light emitters have the advantage of high efficiency, but their color purity is poor due to a wide emission spectrum. In addition, inorganic quantum dot emitters have been known to have good color purity, but because they emit light by quantum confinement effect or quantum size effect, the luminous color changes according to the size of the nanocrystal which are mainly of diameters (or edge length in the case of a cube, or the thickness in the case of a plate) of 10 nm or less for spheres and wires, but there is a problem in that the color purity decreases because it is difficult to control the quantum dot size to be uniform as it goes toward the blue color. Moreover, since the inorganic quantum dots have a very deep valence band, there is a problem in that hole injection is difficult because the hole injection barrier at the interface with the organic hole injection layer is very large. In addition, the organic light emitters and the inorganic quantum dot light emitters have a disadvantage of being expensive. Accordingly, there is a need for a new type of organic-inorganic hybrid light emitters that compensates for the shortcomings of the organic light emitters and the inorganic quantum dot emitters and still maintains their advantages.

On the other hand, organic-inorganic hybrid materials have the advantages of low manufacturing costs, simple manufacturing and device fabrication processes, and the advantages of organic materials that are easy to control optical and electrical properties, and of inorganic materials having high charge mobility and mechanical and thermal stability. It is in the spotlight academically and industrially because you can have both advantages of organic and inorganic light emitters. Especially, the metal halide perovskite material not only has a high photoluminescence quantum efficiency, but also has very excellent properties as a light emitting material because it has high color purity and simple color control.

A material having a conventional perovskite structure (ABX3) is an inorganic metal oxide. These inorganic metal oxides are generally oxides, and cations of metals such as Ti, Sr, Ca, Cs, Ba, Y, Gd, La, Fe, and Mn having different sizes (alkali metals, alkaline earth metals, transition metals, and lanthanum groups) are located at the A and B sites, and oxygen anions are located at the X site, and the metal cations at the B site are 6-fold coordination with the oxygen anions at the X site. It is a material that is bound in the form of a corner-sharing octahedron. Examples thereof include SrFeO3, LaMnO3, and CaFeO3.

In contrast, metal halide perovskite has an organic ammonium (RNH3) cation or metal cation located at the A site in the ABX3 structure, and a halide anion (Cl⁻, Br⁻, I⁻) at the X site. As a result, a metal halide perovskite material is formed, so the composition is completely different from that of the inorganic metal oxide perovskite material.

In addition, the properties of the material are also changed according to the difference between these constituent materials. Inorganic metal oxide perovskite typically exhibits properties such as superconductivity, ferroelectricity, and colossal magnetoresistance, and therefore, research has been generally applied to sensors, fuel cells, and memory devices. As an example, yttrium barium copper oxide has superconducting or insulating properties depending on the oxygen contents.

On the other hand, metal halide perovskite is mainly used as a light-emitting body or photosensitive material because it has high light absorption, high photoluminescence quantum efficiency, and high color purity (less than 20 nm at full-width-at-half-maximum, FWHM) caused by the crystal structure itself.

Even among metal halide perovskite materials, organic-inorganic hybrid perovskite (i.e., organometal halide perovskite), if organic ammonium (A) contains a chromophore (mainly including a conjugated structure) which have a smaller band gap than the central metal-halogen crystal structure (BX3), light of high color purity cannot be emitted, and the full-width-at-half-maximum (FWHM) of the emission spectrum becomes wider than 50 nm, making it unsuitable as a light emission layer. Therefore, in this case, it is not very suitable for the high color purity emitters emphasized in this patent. Therefore, in order to make high-color-purity light emitters, it is important that organic ammonium does not contain a chromophore and that light emission occurs in an inorganic lattice composed of a central metal-halogen element. In other words, this patent focuses on the development of high color purity and high efficiency light emitters that emit light that originates from an inorganic lattice. For example, Korean Published Patent No. 10-2001-0015084 (Feb. 26, 2001) discloses an electroluminescent device using a dye-containing organic-inorganic hybrid material as a light emission layer by forming their thin film instead of particles. It does not emit light from the perovskite lattice structure.

However, until now, metal halide perovskite has a problem in that the stability of the material is greatly reduced because the crystal structure is maintained through weak ionic bonding, unlike the conventional organic light emitter or inorganic quantum dot emitter. For example, the external quantum efficiency of a green light-emitting diode based on FAPbBr₃ is reported to be 14.36% [Nature Communications, 2018, 9, 570] or higher, but the electric driving lifetime of the light-emitting diode is very short around 1 hour. Therefore, a method for improving the luminescence lifetime of metal halide perovskite materials should be studied. The emission lifetime of the metal halide perovskite material can be expanded by suppressing ion migration due to the weak ionic crystal structure and high defect density. In particular, in a light emitting diode, an electric field is formed inside the crystal when a voltage is applied, which causes ions of the perovskite crystal with low ion migration energy barrier (I⁻: 0.58 eV, MA⁺: 0.84 eV, Pb²⁺: 2.37). eV) [Energy Environmental Science, 2015, 8, 2118] to move easily through the defect or grain boundary, and the crystal structure collapses and the luminous efficiency decreases. In addition, electrochemical degradation occurs due to ions and charges accumulated at the interface, and there is a problem in that the efficiency of the perovskite light-emitting diode is rapidly decreased. Therefore, there is a need for a new method to improve the luminous efficiency and lifetime of the metal halide perovskite light emission layer or light emitting-diode, and a method development for improving light-emitting stability by suppressing ion migration in the metal halide perovskite is needed.

In particular, in order to improve the stability of the metal halide perovskite light emission layer, it is necessary to develop a technology for suppressing and stabilizing ion migration on the crystal surface. However, there have been few studies to improve the stability of the metal halide perovskite light emission layer by adjusting the defect location and surface to a desired shape or forming a core/shell structure.

Recently, a method for improving stability using a metal halide perovskite having a pseudo-two-dimensional structure has been reported [Adv. Funct. Mater. 2018, 1801193], but the pseudo-two-dimensional structure method has a problem in that the emission spectrum changes due to the quantum effect as the dimension changes, as like in the case of inorganic quantum dots, and it does not show a great effect on degradation due to the most important ion migration, so the improvement of the lifetime of the perovskite light-emitting diode is at a negligible level. Therefore, it is necessary to develop a new process for suppressing ion migration for driving stability of the metal halide perovskite light emission layer.

### DISCLOSURE

### Technical Problem

A first objective of the present invention is directed to providing a perovskite film with improved luminescence efficiency and lifetime expanded by preventing ion movement in the organic-inorganic hybrid perovskite.

A second objective of the present invention is directed to providing method of manufacturing the perovskite film.

A third objective of the present invention is directed to providing a light-emitting device in which the perovskite film is used as light emission layer.

A fourth objective of the present invention is directed to providing a light-emitting device further comprising a conductive polymer composition with controlled acidity.

A fifth objective of the present invention is directed to providing a light-emitting device further comprising a graphene barrier layer on a substrate.

### Technical Solution

To achieve the above-mentioned first objective, a perovskite film consisted of a perovskite crystal having 3D/2D core-shell crystal structure comprising: a core consisting of three-dimensional perovskite crystals of ABX₃ or A′₂BX₃ₙ₊₁ (n is an integer from 3 to 100); and a two-dimensional perovskite surrounding the core as self-assembled shell and having Y₂Aₘ₋₁BX₃ₘ₊₁ (m is an integer of 1 to 100) in which a phenylalkanamine compound (Y) of the following formula 27 is self-assembled through a proton transfer reaction,

wherein the A or the A′ is an alkali metal ion or a monovalent organic cation selected from group consisting of organic ammonium (RNH₃)⁺, organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺ or (CₙF₂ₙ₊₁NH₃)₂⁺ (x, and n is an integer greater than or equal to 1, R=hydrocarbon derivative, H, F, Cl, Br, or I) and combinations thereof,

wherein the B is a divalent transition metal, a rare earth metal, an alkaline earth metal, a monovalent metal, a trivalent metal, or a combination thereof,

wherein X is F⁻, Cl⁻, Br⁻, I⁻, At⁻ or a combination thereof.

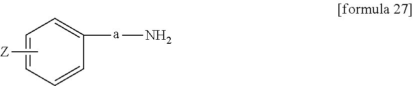

(In formula 27, “a” is unsubstituted linear alkyl or branched alkyl C1 to C10, or amine-substituted linear alkyl or branched alkyl of C1 to C10, “Z” is F or CF₃).

The formula 27 is selected from group consisting of phenylmethanamine, (4-fluorophenyl)methanamine, (4-(trifluoromethyl)phenyl)methanamine, 2-phenylethanamine, 1-phenylpropan-2-amine, 1-phenylpropan-1-amine, 1-phenylethane-1,2-diamine, 2-(4-fluorophenyl)ethanamine, 1-(4-fluorophenyl)propan-2-amine, 1-(4-fluorophenyl) propan-1-amine, 1-(4-fluorophenyl) ethane-1,2-diamine, 2-(4-(trifluoromethyl)phenyl)ethanamine, 1-(4-(trifluoromethyl)phenyl)propan-2-amine, 1-(4-(trifluoromethyl)phenyl)propan-1-amine, 3-phenylpropan-1-amine, 4-phenylbutan-2-amine, 1-phenylbutan-2-amine, 1-phenylbutan-1-amine, 3-phenylpropane-1,2-diamine, 3-(4-fluorophenyl)propan-1-amine, 4-(4-fluorophenyl)butan-2-amine, 1-(4-fluorophenyl)butan-1-amine, 4-phenylbutan-1-amine, 5-phenylpentan-2-amine, 1-phenylpentan-3-amine, 1-phenylpentan-1-amine, 4-(4-fluorophenyl)butan-1-amine, 1-(4-fluorophenyl) pentan-3-amine, 1-(4-fluorophenyl) pentan-1-amine, 5-phenylpentan-1-amine, 1-phenylhexan-1-amine, 1-phenylhexan-2-amine, 1-phenylhexan-3-amine, 6-phenylhexan-2-amine, 1-(4-fluorophenyl)hexan-1-amine, 1-(4-fluorophenyl)hexan-3-amine, 6-phenylhexan-1-amine and 1-phenylheptan-1-amine.

Also preferably, the organic ammonium is an organic ammonium cation or an amidinium group organic ion, and the amidinium group organic ion is formamidinium (CH(NH₂)₂), guanidinium (C(NH₂)₃, acetamidinium ((CH₃)C(NH₂)₂), (CₙF₂ₙ₊₁)(C(NH₂)₂), combinations or derivatives thereof, wherein the organic ammonium cation is CH₃NH₃, (CₙH₂ₙ₊₁)ₓNH₄₋ₓ, ((CₙH₂ₙ₊₁)_{y}NH_{3-y})(CH2)ₘNH₃, (CₙF₂ₙ₊₁)ₓNH₄₋ₓ, ((CₙF₂ₙ₊₁)_{y}NH_{3-y})(CH₂)ₘNH₃ (n is an integer from 1 to 100, x is an integer from 1 to 3, and y is an integer from 1 to 2), combinations or derivatives thereof.

Furthermore, the perovskite crystal having the 3D/2D core-shell crystal structure has a size of 10 nm to 1 um.

To achieve the above-mentioned second objective, present invention provides a method of manufacturing a perovskite film consisted of a perovskite crystal having 3D/2D core-shell crystal structure comprising: preparing a mixed solution by adding a phenylalkanamine compound of formula 27 to a perovskite bulk precursor solution (S100); and forming the perovskite film having the 3D/2D core-shell crystal structure by coating the mixed solution of the perovskite bulk precursor solution and the phenylalkanamine compound on a substrate.

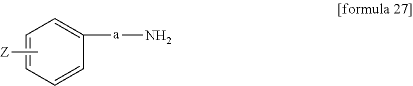

(In formula 27, “a” is unsubstituted linear alkyl or branched alkyl C1 to C10, or amine-substituted linear alkyl or branched alkyl of C1 to C10, “Z” is F or CF₃).

The formula 27 is selected from group consisting of phenylmethanamine, (4-fluorophenyl)methanamine, (4-(trifluoromethyl)phenyl)methanamine, 2-phenylethanamine, 1-phenylpropan-2-amine, 1-phenylpropan-1-amine, 1-phenylethane-1,2-diamine, 2-(4-fluorophenyl)ethanamine, 1-(4-fluorophenyl)propan-2-amine, 1-(4-fluorophenyl) propan-1-amine, 1-(4-fluorophenyl) ethane-1,2-diamine, 2-(4-(trifluoromethyl)phenyl)ethanamine, 1-(4-(trifluoromethyl)phenyl)propan-2-amine, 1-(4-(trifluoromethyl)phenyl)propan-1-amine, 3-phenylpropan-1-amine, 4-phenylbutan-2-amine, 1-phenylbutan-2-amine, 1-phenylbutan-1-amine, 3-phenylpropane-1,2-diamine, 3-(4-fluorophenyl)propan-1-amine, 4-(4-fluorophenyl)butan-2-amine, 1-(4-fluorophenyl)butan-1-amine, 4-phenylbutan-1-amine, 5-phenylpentan-2-amine, 1-phenylpentan-3-amine, 1-phenylpentan-1-amine, 4-(4-fluorophenyl)butan-1-amine, 1-(4-fluorophenyl) pentan-3-amine, 1-(4-fluorophenyl) pentan-1-amine, 5-phenylpentan-1-amine, 1-phenylhexan-1-amine, 1-phenylhexan-2-amine, 1-phenylhexan-3-amine, 6-phenylhexan-2-amine, 1-(4-fluorophenyl)hexan-1-amine, 1-(4-fluorophenyl)hexan-3-amine, 6-phenylhexan-1-amine and 1-phenylheptan-1-amine.

The solvent of the perovskite bulk precursor solution may be dimethylformamide, gamma butyrolactone (gamma), butyrolactone), N-methylpyrrolidone, dimethylsulfoxide or a combination thereof.

A concentration of the perovskite bulk precursor solution may have range of 0.01 M to 1.5 M.

Also preferably, in mixed solution of the perovskite bulk precursor solution and the phenylalkanamine compound with respect to the perovskite bulk precursor solution is 0.1, 0.2, 0.3, 0.4, 0.5, 0.6, 0.7, 0.8, 0.9, 1.0, 1.1, 1.2, 1.3, 1.4, 1.5, 1.6, 1.7, 1.71, 1.72, 1.73, 1.74, 1.75, 1.76, 1.77, 1.78, 1.79, 1.8, 1.81, 1.82, 1.83, 1.84, 1.85, 1.86, 1.87, 1.88, 1.89,1.9, 1.91, 1.92, 1.93, 1.94, 1.95, 1.96, 1.97, 1.98, 1.99, 2.0, 2.01, 2.02, 2.03, 2.04, 2.05, 2.06, 2.07, 2.08, 2.09, 2.1, 2.11, 2.12, 2.13, 2.14, 2.15, 2.16, 2.17, 2.18, 2.19, 2.2, 2.21, 2.22, 2.23, 2.24, 2.25, 2.26, 2.27, 2.28, 2.29, 2.3, 2.31, 2.32, 2.33, 2.34, 2.35, 2.36, 2.37, 2.38, 2.39, 2.4, 2.41, 2.42, 2.43, 2.44, 2.45,2.46, 2.47, 2.48, 2.49, 2.5, 2.51, 2.52, 2.53, 2.54, 2.55, 2.56, 2.57, 2.58, 2.59, 2.6, 2.61, 2.62, 2.63, 2.64, 2.65, 2.66, 2.67, 2.68, 2.69, 2.7, 2.71, 2.72, 2.73, 2.74, 2.75, 2.76, 2.77, 2.78, 2.79, 2.8, 2.81, 2.82, 2.83, 2.84, 2.85, 2.86, 2.87, 2.88, 2.89, 2.9, 2.91, 2.92,2.93, 2.94, 2.95, 2.96, 2.97, 2.98, 2.99, 3.0, 3.01, 3.02, 3.03, 3.04, 3.05, 3.06, 3.07, 3.08, 3.09, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0, 5.1, 5.2, 5.3, 5.4, 5.5, 5.6, 5.7, 5.8, 5.9, 6.0, 6.1, 6.2, 6.3, 6.4, 6.5, 6.6, 6.7, 6.8, 6.9, 7.0, 7.1, 7.2, 7.3, 7.4, 7.5, 7.6, 7.7, 7.8, 7.9, 8.0, 8.1, 8.2, 8.3, 8.4, 8.5, 8.6, 8.7, 8.8, 8.9, 9.0, 9.1, 9.2, 9.3, 9.4, 9.5, 9.6, 9.7, 9.8, 9.9, 10.0, 10.1, 10.2, 10.3, 10.4, 10.5, 10.6, 10.7, 10.8, 10.9, 11.0, 11.1, 11.2, 11.3, 11.4, 11.5, 11.6, 11.7, 11.8, 11.9, 12.0, 12.1, 12.2, 12.3, 12.4, 12.5, 12.6, 12.7, 12.8, 12.9, 13.0, 13.1, 13.2, 13.3, 13.4, 13.5, 13.6, 13.7, 13.8, 13.9, 14.0, 14.1, 14.2, 14.3, 14.4, 14.5, 14.6, 14.7, 14.8, 14.9, 15.0, 15.1, 15.2, 15.3, 15.4, 15.5, 15.6, 15.7, 15.8, 15.9, 16.0, 16.1, 16.2, 16.3, 16.4, 16.5, 16.6, 16.7, 16.8, 16.9, 17.0, 17.1, 17.2, 17.3, 17.4, 17.5, 17.6, 17.7, 17.8, 17.9, 18.0, 18.1, 18.2, 18.3, 18.4, 18.5, 18.6, 18.7, 18.8, 18.9, 19.0, 19.1, 19.2, 19.3, 19.4, 19.5, 19.6, 19.7, 19.8, 19.9, 20 mol. It may be mixed in proportions covering range where the lower value of the two numbers in the % is the lower limit and the higher value is the upper limit.

The phenylalkanamine compound forms a self-assembled shell by receiving a proton from an organic ammonium ion in the perovskite bulk precursor solution and being changed to a cation.

To achieve the above-mentioned third objective, present invention provides a perovskite light emitting device comprising: substrate; a first electrode formed on the substrate; a light emitting layer positioned on the first electrode; and a second electrode positioned on the light emitting layer, wherein the light emitting layer is perovskite film having 3D/2D core-shell crystal structure.

Preferably, the light emitting layer has thickness of 10 nm to 10 um.

Furthermore, the first electrode or the second electrode may have metal, conductive polymer, metallic carbon nanotubes, graphene, reduced graphene oxide, metal nanowires, carbon nanodots, metal nanodots, conductive oxides, or combination thereof.

Also preferably, the light emitting device may be selected from the group consisting of a light emitting diode, a light emitting transistor, a laser, and a polarized light emitting device.

In addition, in order to achieve the fourth object, the present invention provides a substrate, a first electrode positioned on the substrate, a hole injection layer positioned on the first electrode, a light emission layer positioned on the hole injection layer, and a second electrode positioned the light emission layer, and wherein the hole injection layer includes an acidity-controlled conductive polymer composite.

In addition, in order to achieve the fifth object, the present invention provides a substrate, a first electrode positioned on the substrate, a hole injection layer positioned on the first electrode, a light emission layer positioned on the hole injection layer, and a second electrode positioned on the light emission layer, and further comprising a graphene barrier layer between the first electrode and the hole injection layer.

### Advantageous Effects

According to the present invention, the perovskite film having a multi-dimensional crystal structure induced through a proton transfer reaction according to the present invention can improve photoluminescence intensity, luminescence efficiency and lifetime by suppressing ion movement and removing surface defects by the self-assembled shell.

In addition, the efficiency of the light-emitting device can be improved by injecting a fluorine-based material and a basic material into the PEDOT:PSS conductive polymer used as a conventional hole injection layer to control acidity and improve the work function of the interface.

In addition, in the light-emitting device comprising a PEDOT:PSS-based hole injection layer having acidity, a chemically stable graphene barrier layer protects the electrode vulnerable to acid, and the exciton dissociation characteristic of the electrode due to the PEDOT:PSS-based hole injection layer is prevented, so that a high-efficiency light-emitting device can be manufactured.

### DESCRIPTION OF DRAWINGS

FIG. 1 is a schematic diagram showing the difference between a metal halide perovskite bulk thin film and a metal halide perovskite nanocrystal according to an embodiment of the present invention.

FIG. 2 is a schematic diagram showing a metal halide perovskite nanocrystal according to an embodiment of the present invention.

FIG. 3 is a schematic diagram showing a method of manufacturing a metal halide perovskite nanocrystal according to an embodiment of the present invention.

FIG. 4 is a schematic diagram showing a core-shell structured metal halide perovskite nanocrystal and an energy band diagram thereof according to an embodiment of the present invention.

FIG. 5 is a schematic diagram showing a method of manufacturing a metal halide perovskite nanocrystal having a core-shell structure according to an embodiment of the present invention.

FIG. 6 is a schematic diagram showing a metal halide perovskite nanocrystal having a gradient composition structure according to an embodiment of the present invention.

FIG. 7 is a schematic diagram showing a metal halide perovskite nanocrystal having a structure having a gradient composition and an energy band diagram thereof according to an embodiment of the present invention.

FIG. 8 is a schematic diagram showing a doped metal halide perovskite nanocrystal and an energy band diagram thereof according to an embodiment of the present invention.

FIG. 9 is a schematic diagram illustrating the Ostwald Ripening phenomenon of a metal halide perovskite nanocrystal according to an embodiment of the present invention.

FIG. 10 is a schematic diagram showing a method of controlling the size distribution of perovskite nanocrystal according to an embodiment of the present invention.

FIG. 11 is a graph showing the photoluminescence characteristics of metal halide perovskite nanocrystal prepared in air according to a conventional method.

FIG. 12 is a graph showing the photoluminescence characteristics of metal halide perovskite nanocrystal prepared in a nitrogen atmosphere according to an embodiment of the present invention.

FIG. 13 is a schematic diagram of a process of removing a solvent remaining after a bar coating process through air injection according to an embodiment of the present invention.

FIG. 14 is a schematic diagram showing a light-emitting device according to an embodiment of the present invention.

FIG. 15 is a schematic diagram showing a light-emitting device according to another embodiment of the present invention.

FIG. 16 is a schematic diagram showing the structure of a metal halide perovskite light-emitting transistor according to an embodiment of the present invention.

FIG. 17 is a schematic diagram showing an organic nanowire lithography process sequence according to an embodiment of the present invention.

FIG. 18 is a schematic diagram of an electric field assisted robotic nozzle printer.

FIG. 19 is a schematic diagram showing the structure of a metal halide perovskite light-emitting transistor according to another embodiment of the present invention.

FIG. 20 is a schematic diagram illustrating a light-emitting transistor in which a semiconductor layer including a metal halide perovskite having a polycrystal structure is located according to an embodiment of the present invention.

FIG. 21 is a schematic diagram illustrating a light-emitting transistor in which a semiconductor layer including a metal halide perovskite having a single crystal structure is located according to another embodiment of the present invention.

FIG. 22 is a schematic diagram showing a metal halide perovskite light-emitting device according to an embodiment of the present invention.

FIG. 23 shows transient photoluminescence and normal light emission before and after coating a TBMM thin film as a passivation layer on a metal halide perovskite nanocrystal emission layer in a perovskite light-emitting device according to an embodiment of the present invention.

FIG. 24 is an X-ray photoelectron spectrum (XPS) before and after coating a TBMM thin film as a passivation layer on a metal halide perovskite nanocrystal emission layer in a perovskite light-emitting device according to an embodiment of the present invention.

FIG. 25 is a graph showing the hole current density and electron current density before and after coating the TBMM thin film as a passivation layer on the a metal halide perovskite nanocrystal emission layer in hole-only device and an electron-only device among perovskite light-emitting devices according to an embodiment of the present invention.

FIG. 26 is a graph showing capacitance-voltage characteristics before and after coating a TBMM thin film as a passivation layer on a metal halide perovskite nanocrystal emission layer in a perovskite light-emitting device according to an embodiment of the present invention.

FIG. 27 is a graph showing luminescence efficiency characteristics before and after coating a TBMM thin film as a passivation layer on a metal halide perovskite nanocrystal emission layer in a perovskite light-emitting device according to an embodiment of the present invention.

FIG. 28 is a schematic diagram showing a method of manufacturing a light-emitting device including an exciton buffer layer according to an embodiment of the present invention.

FIG. 29 is a schematic diagram showing the effect of an exciton buffer layer according to an embodiment of the present invention.

FIG. 30 is a graph showing the effect of acidity and work function when a basic additive is added to PEDOT:PSS:PFI, which is hole injection layer as a conductive polymer according to an embodiment of the present invention.

FIG. 31 is a graph showing a change in photoelectron intensity according to binding energy when PEDOT:PSS:PFI:aniline is deposited on the ITO electrode as the hole injection layer according to an embodiment of the present invention.

FIG. 32 is a graph showing the ion intensity at the interface between the hole injection layer and the metal halide perovskite light emission layer when PEDOT:PSS:PFI:aniline is deposited on the ITO electrode as the hole injection layer according to an embodiment of the present invention.

FIG. 33 shows the surface roughness of the formed thin film according to the amount of aniline added when aniline is added to PEDOT:PSS according to an embodiment of the present invention.

FIG. 34 shows the surface roughness of the formed thin film according to the amount of aniline added when aniline is added to PEDOT:PSS:PFI that is hole injection layer according to an embodiment of the present invention.

FIG. 35 is a graph showing photoluminescence intensity and photoluminescence lifetime of a polycrystal metal halide perovskite layer/PEDOT:PSS:PFI:aniline/ITO electrode according to an embodiment of the present invention.

FIG. 36 is a graph showing photoluminescence intensity and photoluminescence lifetime of metal halide perovskite nanoparticle layer/PEDOT:PSS:PFI:aniline/ITO electrode according to an embodiment of the present invention.

FIG. 37 is a graph showing device efficiency of a polycrystal metal halide perovskite device and a metal halide perovskite nanoparticle device using a PEDOT:PSS:PFI:aniline hole injection layer according to an embodiment of the present invention.

FIG. 38 is a schematic diagram showing an organic material-assisted nanocrystal pinning which is a method of coating by dropping a low-molecular organic material solution before the solvent of the light emission layer evaporates while the metal halide perovskite light emission layer according to an embodiment of the present invention is being coated.

FIG. 39 is a graph showing a point in time when a low molecular weight organic material solution is dropped while the metal halide perovskite emission layer is being coated when the metal halide perovskite light emission layer is manufactured according to an embodiment of the present invention.

FIG. 40 is a cross-sectional view illustrating a metal halide perovskite-organic small molecule host mixed light emission layer according to an embodiment of the present invention.

FIG. 41 shows energy levels of perovskite and organic small molecule hosts used in the perovskite-organic small molecule host mixed emission layer according to an embodiment of the present invention.

FIG. 42 shows energy levels of an organic small molecule host used in a metal halide perovskite-organic small molecule host mixed emission layer according to an embodiment of the present invention.

FIG. 43 is a schematic diagram showing the structure of a high vacuum evaporator for manufacturing a perovskite-organic small molecule host mixed light emission layer according to an embodiment of the present invention.

FIG. 44 shows energy levels of constituent layers in a light-emitting device (structure) including a metal halide perovskite-organic small molecule host mixed light emission layer according to an embodiment of the present invention.

FIG. 45 shows energy levels of constituent layers in a light-emitting device (inverse structure) including a metal halide perovskite-organic small molecule host mixed light emission layer according to another embodiment of the present invention.

FIG. 46 is an example of a structure of a light-emitting diode including a multi-dimensional metal halide perovskite hybrid light emission layer according to an embodiment of the present invention.

FIG. 47 is a schematic diagram showing examples of various methods of manufacturing a multi-dimensional perovskite hybrid light emission layer according to an embodiment of the present invention.

FIG. 48 shows a core/shell structure of a perovskite film according to an embodiment of the present invention.

FIG. 49 shows a mechanism for forming a core/shell structure of a metal halide perovskite film according to an embodiment of the present invention.

FIG. 50 shows a principle of forming each of the core and shell structures of a metal halide perovskite film according to an embodiment of the present invention.

FIG. 51 shows a proton nuclear magnetic resonance analysis spectrum of a perovskite film with or without a self-assembled shell according to an embodiment of the present invention.

FIG. 52 is a schematic diagram and a scanning electron microscope image of a crystal of a perovskite film with or without a self-assembled shell according to an embodiment of the present invention.

FIG. 53 is a graph showing photoluminescence characteristics of a perovskite film with or without a self-assembled shell according to an embodiment of the present invention.

FIG. 54 is a graph showing charge lifetime characteristics of a perovskite film with or without a self-assembled shell according to an embodiment of the present invention.

FIG. 55 is a schematic diagram of a self-assembled polymer-metal halide perovskite light emission layer according to an embodiment of the present invention.

FIG. 56 is a schematic diagram of a self-assembled polymer-perovskite light emission layer according to another embodiment of the present invention.

FIG. 57 is a flowchart illustrating a method of manufacturing a self-assembled polymer-perovskite light emission layer according to an embodiment of the present invention.

FIG. 58 is a schematic diagram showing a process of forming a self-assembled polymer pattern on a substrate according to an embodiment of the present invention.

FIG. 59 is a flowchart illustrating a method of manufacturing a self-assembled polymer-perovskite light emission layer according to another embodiment of the present invention.

FIG. 60 illustrates an organic material layer on a self-assembled polymer pattern formed on a substrate according to an embodiment of the present invention.

FIG. 61 is a schematic diagram showing a process of disposing perovskite nanocrystal in a self-assembled polymer pattern formed on a substrate according to an embodiment of the present invention.

FIG. 62 is a flowchart illustrating a method of manufacturing a self-assembled polymer-perovskite light emission layer according to another embodiment of the present invention.

FIG. 63 is a schematic diagram showing a method of manufacturing a quasi-two-dimensional perovskite film in which the structure of a nanocrystal is adjusted according to an embodiment of the present invention.

FIG. 64 is an image of a quasi-two-dimensional perovskite crystal in which the structure of a nanocrystal is adjusted according to an embodiment of the present invention.

FIG. 65 is a flowchart illustrating a method of manufacturing a metal halide perovskite nanocrystal light emitter in which an organic ligand is substituted according to an embodiment of the present invention.

FIG. 66 is a flowchart illustrating a method of manufacturing an organic-inorganic hybrid perovskite nanocrystal light emitter according to an embodiment of the present invention.

FIG. 67 is a schematic diagram showing a method of manufacturing an organic-inorganic hybrid perovskite nanocrystal light emitter according to an embodiment of the present invention.

FIG. 68 is a schematic diagram showing an organic-inorganic hybrid perovskite nanocrystal light emitter and an inorganic metal halide perovskite nanocrystal light emitter according to an embodiment of the present invention.

FIG. 69 is a schematic diagram showing a method of manufacturing an organic-inorganic hybrid perovskite nanocrystal light emitter substituted with an organic ligand according to an embodiment of the present invention.

FIG. 70 is a cross-sectional view illustrating a light emission layer having a tandem structure according to an embodiment of the present invention.

FIG. 71 illustrates energy levels of a light emission layer having a stacked structure in which first and second light-emitting material layers are alternately located according to an embodiment of the present invention.

FIG. 72 illustrates energy levels of materials used in a light emission layer having a stacked structure in which first and second light-emitting material layers are alternately located according to an embodiment of the present invention.

FIG. 73 illustrates energy levels of constituent layers in a light-emitting device (normal structure) including a light emission layer according to an embodiment of the present invention.

FIG. 74 illustrates energy levels of constituent layers in a light-emitting device (inverse structure) including a light emission layer according to another embodiment of the present invention.

FIG. 75 is a schematic structural diagram illustrating a structure of a stacked hybrid light-emitting diode according to an embodiment of the present invention.

FIG. 76 is a schematic diagram showing the structure of a light-emitting device according to an embodiment of the present invention (normal structure).

FIG. 77 is a schematic diagram showing the structure of a light-emitting device according to an embodiment of the present invention (inverted structure).

FIG. 78 shows energy levels of a light-emitting device in which a first charge transport layer (hole injection layer) of a light-emitting device is a metal halide perovskite thin film according to an embodiment of the present invention (normal structure).

FIG. 79 shows energy levels of a light-emitting device in which a first charge transport layer (hole injection layer) of a light-emitting device is a metal halide perovskite thin film according to an embodiment of the present invention (inverted structure).

FIG. 80 shows energy levels of a light-emitting device in which a second charge transport layer (electron injection layer) of the light-emitting device is a thin film of metal halide perovskite according to an embodiment of the present invention (normal structure).

FIG. 81 shows energy levels of a light-emitting device in which the second charge transport layer (electron injection layer) of the light-emitting device is a metal halide perovskite thin film according to an embodiment of the present invention (inverted structure).

FIG. 82 shows energy levels of a light-emitting device in which the first charge transport layer (hole injection layer) and the second charge transport layer (electron injection layer) of the light-emitting device are metal halide perovskite thin films according to an embodiment of the present invention (inverted structure).

FIG. 83 shows energy levels of a light-emitting device in which the first charge transport layer (hole injection layer) and the second charge transport layer (electron injection layer) of the light-emitting device are metal halide perovskite thin films according to an embodiment of the present invention (normal structure).

FIG. 84 shows energy levels of a light-emitting device in which the first charge transport layer (hole injection layer) and the second charge transport layer (electron injection layer) of the light-emitting device are metal halide perovskite thin films according to an embodiment of the present invention (inverted structure).

FIG. 85 shows energy levels of a light-emitting device in which the first charge transport layer (hole injection layer) and the second charge transport layer (electron injection layer) of the light-emitting device are metal halide perovskite thin films according to an embodiment of the present invention (normal structure).

FIG. 86 is a schematic diagram showing a metal halide perovskite-polymer composite film according to another embodiment of the present invention.

FIG. 87 are cross-sectional views illustrating a method of sealing a wavelength converting body according to an embodiment of the present invention.

FIG. 88 is a cross-sectional view of a light-emitting device including a wavelength converting layer according to an embodiment of the present invention.

FIG. 89 is a cross-sectional view of a light-emitting device including a wavelength converting body according to an embodiment of the present invention.

FIG. 90 is a cross-sectional view schematically illustrating a stretchable wavelength converting layer according to an embodiment of the present invention.

FIG. 91 is a cross-sectional view of a stretchable light-emitting device according to an embodiment of the present invention.

FIG. 92 is a schematic diagram illustrating a method of manufacturing a stretchable wavelength converting layer according to an embodiment of the present invention.

FIG. 93 is another schematic diagram illustrating a method of manufacturing a stretchable wavelength converting layer according to an embodiment of the present invention.

FIG. 94 is a schematic diagram illustrating a method of manufacturing a stretchable light-emitting device according to an embodiment of the present invention.

FIG. 95 shows a hybrid wavelength converting body according to an embodiment of the present invention.

FIG. 96 is a schematic diagram showing a hybrid wavelength converting body according to another embodiment of the present invention.

FIG. 97 is a schematic diagram showing a method of manufacturing a metal halide perovskite nanocrystal used as a wavelength converting particle in a hybrid wavelength converting body according to an embodiment of the present invention.

FIG. 98 is a cross-sectional view showing a method of manufacturing a hybrid wavelength converting body using a sealing method according to an embodiment of the present invention.

FIG. 99 is a cross-sectional view of a light-emitting device including a hybrid wavelength converting body according to an embodiment of the present invention.

FIG. 100 is a cross-sectional view of a light-emitting device including a hybrid wavelength converting body according to another embodiment of the present invention.

FIG. 101 is a cross-sectional view of an encapsulated metal halide perovskite wavelength converting film according to an embodiment of the present invention.

FIG. 102 is a schematic diagram showing a method of manufacturing a metal halide perovskite wavelength converting body having a structure in which encapsulated particles are dispersed according to an embodiment of the present invention.

FIG. 103 is a schematic diagram showing a method of manufacturing a metal halide perovskite wavelength converting body having a structure in which encapsulated particles are dispersed according to another embodiment of the present invention.

FIG. 104 is a schematic diagram showing a method of manufacturing a metal halide perovskite wavelength converting body having a structure in which encapsulated particles are dispersed according to another embodiment of the present invention.

FIG. 105 is a schematic diagram showing a method of manufacturing a metal halide perovskite wavelength converting body having a structure in which encapsulated particles are dispersed according to another embodiment of the present invention.

FIG. 106 is a schematic diagram of a metal halide perovskite light emitting particle to which a medium-sized organic cation is added according to an embodiment of the present invention.

FIG. 107 is a schematic diagram of a metal halide perovskite light emitting particle to which a medium-sized organic cation is added according to another embodiment of the present invention.

FIG. 108 is an XRD analysis result according to the content of a medium-sized organic cation (guanidinium) in the metal halide perovskite light emitting particle according to an embodiment of the present invention.

FIG. 109 is a photoluminescence analysis result according to the content of medium-sized organic cations (guanidinium) in the metal halide perovskite light emitting particles according to an embodiment of the present invention.

FIG. 110 is an analysis result of particle size according to the content of medium-sized organic cations (guanidinium) in the metal halide perovskite light emitting particles according to an embodiment of the present invention.

FIG. 111 is a graph of photoluminescence quantum efficiency according to the content of medium-sized organic cations (guanidinium) in the metal halide perovskite light emitting particles according to an embodiment of the present invention.

FIG. 112 is a graph of photoluminescence lifetime according to the content of medium-sized organic cations (guanidinium) in the metal halide perovskite light emitting particles according to an embodiment of the present invention.

FIG. 113 is a graph showing an exciton binding energy determined by temperature dependent photoluminescence according to the content of a medium-sized organic cation (guanidinium) in the metal halide perovskite light emitting particle according to an embodiment of the present invention.

FIG. 114 is a graph showing the stability against UV irradiation of a metal halide perovskite light emitting particle to which a medium organic cation is added according to an embodiment of the present invention.

FIG. 115 is a graph showing the stability against thermal decomposition with varying the content of medium-sized organic cations (guanidinium) in the metal halide perovskite light emitting particles according to an embodiment of the present invention.

FIG. 116 is a graph showing the luminescence efficiency of a light-emitting diode with varying the content of medium-sized organic cations (guanidinium) in the metal halide perovskite light emitting particles according to an embodiment of the present invention.

FIG. 117 is a graph showing changes in lattice constants in crystals with varying the content of medium-sized organic cations (guanidinium) in the metal halide perovskite light emitting particles having a mixed cation structure according to an embodiment of the present invention.

FIG. 118 is a graph showing the photoluminescence intensity of the perovskite light emitting particles with varying the content of medium-sized organic cations (guanidinium) in the metal halide perovskite light emitting particles having a mixed cationic structure according to an embodiment of the present invention.

FIG. 119 is a graph showing a photoluminescence intensity and photoluminescence lifetime of metal halide perovskite light emitting particles having a mixed cation structure depending on the content of medium-sized organic cations (guanidinium) according to an embodiment of the present invention.

FIG. 120 is a graph showing photoluminescence intensity of a polycrystal thin film including perovskite light emitting particles depending on the types of organic cations to be mixed in a metal halide perovskite light emitting particle having mixed cations according to an embodiment of the present invention.

FIG. 121 is a graph showing the luminance of a polycrystal thin film including perovskite light emitting particles depending on the types of organic cations to be mixed in the metal halide perovskite light emitting particles having a mixed cationic structure according to an embodiment of the present invention.

FIG. 122 is a graph showing current efficiency of a polycrystal thin film including perovskite light emitting particles depending on the types of organic cations to be mixed in metal halide perovskite light emitting particles having a mixed cationic structure according to an embodiment of the present invention.

FIG. 123 is a graph showing the operational lifetime of a polycrystal thin film including perovskite light emitting particles depending on the types of organic cations to be mixed in the metal halide perovskite light emitting particles having a mixed cationic structure according to an embodiment of the present invention.

FIG. 124 is a graph showing current efficiency of a light-emitting device including a perovskite film without or with a self-assembled shell according to an embodiment of the present invention.

FIG. 125 is a graph showing the operational lifetime of a light-emitting device including a perovskite film without or with a self-assembled shell according to an embodiment of the present invention.

FIG. 126 is a graph showing the mobility of ions with respect to acid according to the presence or absence of the graphene barrier layer stacked on the electrode dissociated to the acid according to an embodiment of the present invention.

FIG. 127 is a graph showing the results of TOF-SIMS analysis according to the presence or absence of the graphene barrier layer stacked on electrode dissociated to the acid according to an embodiment of the present invention.

FIG. 128 is a graph showing the results of X-ray photoelectric analysis according to the presence or absence of the graphene barrier layer stacked on electrode dissociated to the acid in a light-emitting diode according to an embodiment of the present invention.

FIG. 129 is a graph showing exciton lifetime of the perovskite light emitting body according to the presence or absence of the graphene barrier layer stacked on an electrode dissociated to the acid according to an embodiment of the present invention.

FIG. 130 shows light emitting characteristics according to the presence or absence of the graphene barrier layer stacked on an electrode dissociated to the acid in a light-emitting diode according to an embodiment of the present invention.

### MODES OF THE INVENTION

Hereinafter, embodiments of the present invention will be described in detail with reference to the accompanying drawings.

While the present invention is susceptible to various modifications and alternative forms, specific embodiments thereof are shown by way of example in the drawings and will herein be described in detail. However, it should be understood that there is no intent to limit the invention to the particular forms disclosed but rather the invention is to cover all modifications, equivalents, and alternatives falling within the spirit and scope of the invention defined by the appended claims.

When an element such as a layer, a region, and a substrate is referred to as being disposed “on” another element, it should be understood that the element may be directly formed on the other element or an intervening element may be interposed therebetween.

It should be understood that, although the terms “first,” “second,” etc. may be used herein to describe various elements, components, areas, layers, and/or regions, these elements, components, areas, layers, and/or regions are not limited by these terms.

<Metal Halide Perovskite Crystal>

The metal halide perovskite may be a material having a three-dimensional crystal structure, a two-dimensional crystal structure, a one-dimensional crystal structure, or a zero-dimensional crystal structure.

The metal halide perovskite is ABX₃(3D), A₄BX₆(0D), AB₂X₅(2D), A₂BX₄(2D), A₂BX₆(0D), A₂B⁺B³⁺X₆(3D), A₃B₂X₉(2D) or Aₙ₋₁BₙX₃ₙ₊₁ (quasi-2D) (n is an integer between 2 and 6). A is a monovalent cation, B is a metal material, and X may be a halogen element. The quasi-2D structure may be a Ruddlesden-Popper phase or a Dion-Jacobson phase.

The monovalent cation may be a monovalent organic cation or an alkali metal. For example, the monovalent organic cation is organic ammonium (RNH₃)⁺, organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺ or (CₙF₂ₙ₊₁NH₃)₂⁺ (x or n is an integer of 1 or more, R=hydrocarbon derivative, alkyl, alkyl fluoride derivatives, H, F, Cl, Br, I) or combinations thereof, but are not limited thereto. The alkali metal may be Li+, Na+, K+, Rb+, Cs+, Fr+, or combinations thereof, but is not limited thereto.

In addition, preferably, the organic cations are acetamidinium, azaspironanium, benzene diammonium, benzylammonium, butanediammonium, iso-butylammonium, n-butylammonium, t-butylammonium, cyclohexylammonium, cyclohexylmethylammonium, azobicyclooctanedinium, diethylammonium, N,N-diethylethane diammonium, N,N-diethylpropane diammonium, Dimethylammonium, N,N-dimethylethane diammonium, dimethylpropane diammonium, dodecylammonium, Ethanediammonium, ethylammoniuium, 4-fluoro-benzylammonium, 4-fluoro-phenylethylammonium, 4-fluoro-phenylammonium, formamidinium, guanidinium, hexanediammnium, hexylammonium, imidazolium, 2-methoxyethylammonium, 4-methoxy-phenlylethylammonium, 4-methoxy-phenylammonium, methylammonium, morpholinium, octylammonium, pentylammonium, piperazinediium, piperidinium, propanediammonium, iso-propylammonium, di-iso-propylammonium, n-propylammonium, pyridinium, 2-pyrrolidin-1-ium-1-yethylammonium, Pyrrolidinium, quinclidin-1-ium, 4-trifluoromethyl-benzylammonium, 4-trifluoromethyl ammonium, and quaternary ammonium cations such as benzalkonium chloride, dimethyldioctadecylammonium chloride, trimethylglycine, choline, or combinations thereof, but is not limited there to.

The B may be a divalent transition metal, a rare earth metal, an alkaline earth metal, a combination of a monovalent metal and a trivalent metal, an organic substance (a monovalent, divalent, trivalent cation), or a combination thereof. In addition, preferably, the divalent transition metal, rare earth metal or alkaline earth metal may be Be²⁺, Mg²⁺, Ca²⁺, Sr²⁺, Ba²⁺, Ra²⁺, Mn²⁺, Fe²⁺, Co²⁺, Ni²⁺, Cu²⁺, Zn²⁺, Ru²⁺, Bi²⁺, Pd²⁺, Cd²⁺, Pt²⁺, Hg²⁺, Ge²⁺, Sn²⁺, Pb²⁺, Se²⁺, Te²⁺, Po²⁺, Eu²⁺, No²⁺, or combinations thereof, but are not limited thereto. The monovalent metal may be Li⁺, Na⁺, K⁺, Rb⁺, Cs⁺, Fr⁺, Ag⁺, Hg⁺, Ti⁺, or combinations thereof, and the trivalent metal may be Cr³⁺, Fe³⁺, Co³⁺, Ru³⁺, Rh³⁺, Ir³⁺, Au³⁺, Al³⁺, Ga³⁺, In³⁺, Ti³⁺, As³⁺, Sb³⁺, Bi³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Am³⁺, Cm³⁺, Bk³⁺, Cf³⁺, Es³⁺, Fm³⁺, Md³⁺, Lr³⁺ or combinations thereof.

In addition, X may be F⁻, Cl⁻, Br⁻, I⁻, At⁻, or combinations thereof.

The metal halide perovskite is ABX₃(3D), A₄BX₆(0D), AB₂X₅(2D), A₂BX₄(2D), A₂BX₆(0D), A₂B⁺B³⁺X₆(3D), A₃B₂X₉(2D) or Aₙ₋₁BₙX₃ₙ₊₁ (quasi-2D) (n is an integer between 2 and 6), wherein A is a monovalent cation, B is a metal material, and X is a halogen.

Tolerance factor is defined as

$$t = \frac{{R}_{A} + {R}_{X}}{\sqrt{2} ( {R}_{B} + {R}_{X} )}$$

(R_{A}, R_{B}, R_{X} is the ionic radius of A, B, X respectively).

The metal halide perovskite may be in the form of a polycrystal metal halide perovskite bulk thin film, or a metal halide perovskite nanocrystal that can be easily dispersed in a colloidal state in a solution.

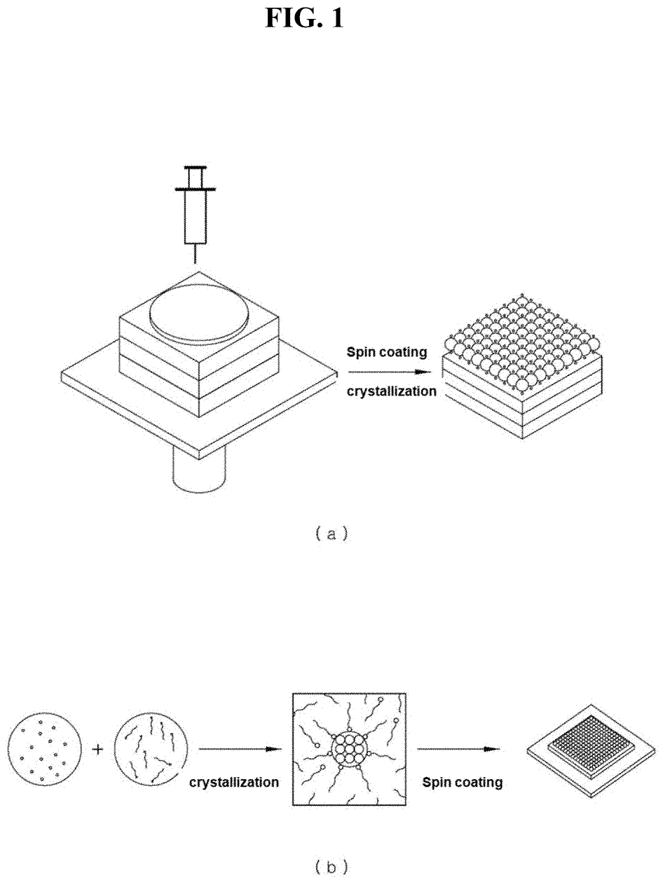

FIG. 1 is a schematic diagram showing the difference between a metal halide perovskite bulk thin film and a metal halide perovskite nanocrystal according to an embodiment of the present invention.

As shown in FIG. 1, crystallization and thin film formation processes occur at the same time to form the metal halide perovskite bulk thin film by evaporating the solvent in the spin coating process of the transparent ion-type metal halide perovskite precursor solution. Therefore, the bulk thin film forms a thin film by directly reacting two or more precursors, and it is greatly affected by thermodynamic parameters such as temperature and surface energy during the thin film formation process. A thin film composed of a large three-dimensional or two-dimensional polycrystal is formed.

However, as shown in FIG. 1, the perovskite nanocrystal are first crystallized into nanoparticles in a colloidal solution and then stably dispersed in the solution using a ligand. Because nanocrystals are in a state where crystallization is terminated in a solution, when forming a thin film through coating, there is no additional growth of crystals and is not affected by coating conditions, and the nanocrystal that are configured to have a size of several nanometers to several tens of nanometers can form a thin film that maintains high luminescence efficiency.

Colloidal solution refers to a dispersion in which solid particles having a size of about 10 μm or less do not aggregate with each other, form a stable mixed solution, and spread in a liquid. The solid particles constituting the colloid correspond to the dispersed phase, and the liquid in which the solid fine particles are dispersed is referred to as a dispersion medium. Similar concepts to colloid, there may be an aerosol and an emulsion. However, aerosol refers to a state in which liquid droplets or solid particles are dispersed in a gas, and emulsion is a uniformly dispersed state of liquid droplets that is immiscible in other types of liquid. Thus, the aerosol and emulsion have differences from colloids. There are various opinions on the limit of the size of the solid particles constituting the colloidal dispersion system. A dispersion of the corresponding fine particles having a size of 1 nm to 1 μm to be dispersed is referred to as a colloid, and for a size larger than that, it is sometimes referred to separately as a suspension. In this specification, the concept of defining a solid dispersion having a size of 10 μm or less as a colloid is followed, but the difference between dispersion and suspension is classified according to whether or not it precipitates well over time. For example, when precipitation occurs within several hours, it is a suspension, and dispersion is defined as a dispersion that can be dispersed without precipitation for several hours or longer, preferably for several days or longer. The colloidal dispersion may be dispersed in a dispersion medium such as a polymer or ceramic material to form a thin film or film.

### <Metal Halide Perovskite Nanocrystal>

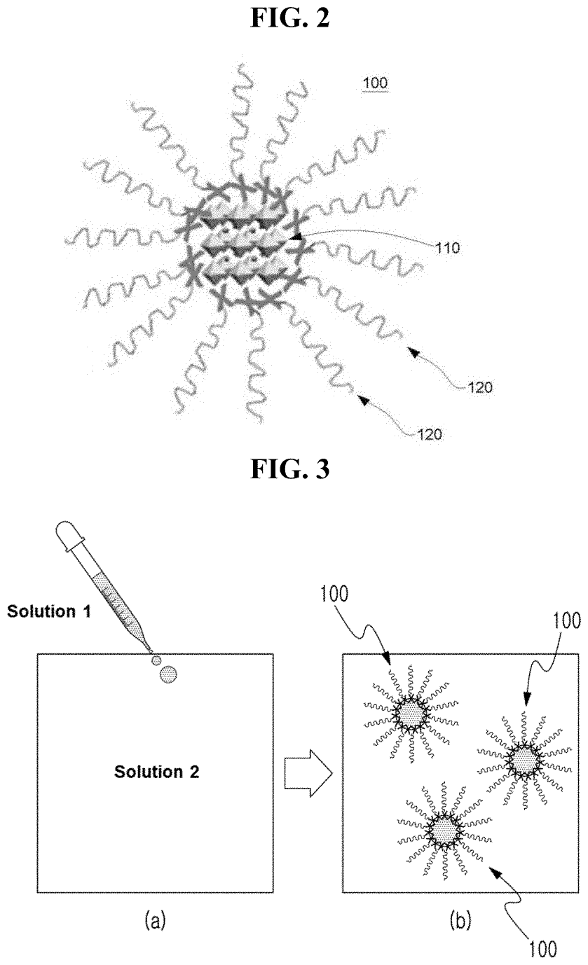

FIG. 2 is a schematic diagram showing a metal halide perovskite nanocrystal according to an embodiment of the present invention.

The metal halide perovskite nanocrystal may further include a plurality of organic ligands 20 surrounding the metal halide perovskite nanocrystal 10. The organic ligands 20 at this time are substances used as surfactants, so it may include alkyl halide, alkyl ammonium halide, amine ligand, carboxylic acid, or phosphonic acid.

Ligand refers to a generic term for an ion or molecule that can be bound to a central atom in a dative complex. The ligand binds to the surface of the nanoparticle and serves to precisely control the shape and size of the nanoparticle. For a detailed description of the ligand, refer to [Journal of the American Chemistry Society, 2013, 135, 49, pp 18536-18548]. The ligand binding to the surface of the nanoparticle may correspond to an L-type ligand, an X-type ligand, or a Z-type ligand according to the mode of binding with the surface of the nanoparticle. L-type ligand donate two electrons to form a coordination bond, an X-type ligand donates an electron to the cation site on the surface of a nanoparticle followed by formation of a covalent bond, and the acceptor of two electrons on the surface of a nanoparticle corresponds to the Z-type ligand.

Surfactants are amphiphilic substances that have opposite functional groups of hydrophilicity and hydrophobicity simultaneously in the same molecule, and are adsorbed at the interface between liquid and gas, liquid and liquid, or liquid and solid, so they can play a role in causing various physical phenomena to appear. The role of the surfactant can serve to lower surface tension, emulsify, improve wettability and foamability, or solubilize. Particularly, when the surfactant acts as a ligand by binding to the surface of the nanoparticle through a coordinate bond, the dispersibility of the nanoparticle can be improved. Examples of surfactants include anionic surfactants (e.g., sulfate (such as ammonium lauryl sulfate, sodium lauryl sulfate, sodium dodecyl sulfate, sodium laureth sulfate or sodium myreth sulfate), sulfonate (such as dioctyl sodium sulfosuccinate, perfluorooctanesulfonate, perfluorobutanesulfonate or linear alkylbenzene sulfates), phosphate esters, or carboxylates (such as sodium stearate, sodium lauroyl sarcosinate, perfluorononanoate or perfluorooctanoate)), cationic surfactants that include primary, secondary, tertiary, or quaternary ammonium cation, and quaternary ammonium cations such as benzalkonium chloride, dimethyldioctadecylammonium chloride, trimethylglycine or choline, or zwitterionic or amphoteric surfactant having both cations and anions in the same substance, or nonionic surfactants that include long chain alcohols such as fatty alcohols, cetyl alcohol, stearyl alcohol, cetostearyl alcohol (consisting predominantly of cetyl and stearyl alcohols), or oleyl alcohol.

The alkyl halide may be an alkyl-X structure. The halogen element corresponding to X may include Cl, Br, or I. In addition, the alkyl structure at this time includes a primary alcohol having a structure such as acyclic alkyl having a structure of CnH2n+1, a primary alcohol having a structure such as CnH2n+1OH, a secondary alcohol, a tertiary alcohol, alkylamine having a structure of alkyl-N (ex. hexadecyl amine, 9-octadecenylamine (1-Amino-9-octadecene, C18H37N), p-substituted aniline, phenyl ammonium or fluorine ammonium, but are not limited thereto.

The amine ligand can be N,N-diisopropylethylethylamine, ethylenediamine, hexamethylenetetraamine, methylamine, hexylamine, oleylamine, N,N,N,N-tetramethylenediamine, triethylamine, diethanolamine, or 2,2-(ethylenedioxyl)bis-(ethylamine), but is not limited thereto.

The alkyl ammonium halide (or alkylammonium salt) includes methylammonium chloride, dimethylammonium bromide, or octylammonium bromide, and in some cases, fluoride or acetate may be substituted as a salt in the place of a halide (e.g. ethyl dimethylammonium fluoride, tetrabenzylammonium acetate), but are not limited thereto.

The carboxylic acid include 4,4′-azobis(4-cyanovaleric acid), acetic acid, 5-aminosalicylic acid, acrylic acid, L-aspentic acid, 6-bromohexanoic acid, bromoacetic acid, dichloro acetic acid, ethylenediaminetetraacetic acid, isobutyric acid, itaconic acid, maleic acid, r-maleimidobutyric acid, L-malic acid, 4-nitrobenzoic acid, or 1-pyrenecarboxylic acid or oleic acid.

The phosphonic acid includes n-hexylphosphonic acid, n-octylphosphonic acid, n-decylphosphonic acid, n-dodecylphosphonic acid, n-tetradecylphosphonic acid, n-hexadecylphosphonic acid, or n-octadecylphonic acid, but is not limited thereto.

The organic ligand may be in a fluorinated form. For example, the organic ligands include 2-fluorophenylboronic acid, 3,5-diformyl-2-fluorophenylboronic acid, 3-chloro-4-fluorophenylboronic acid, 4-cyano-3-fluorobenzoic acid, L-Fmoc-3-fluorophenylalanine, L-Fmoc-4-fluorophenylalanine, Methyl 6-fluorochromone-2-carboxylic acid, 4-fluorobenzoic acid, 2-fluorobenzoic acid, 2-fluorobenzylamine, 2-2-fluorocinnamic acid, 2-fluorophenyl isothiocyanate, 4-fluorobenzenesulfonic acid, 4-fluorobenzylamine, 4-fluorophenyl isothiocyanate, 4-fluorophenylacetic acid, Fluorocinnamic acid, 3-Fluoro-4-methylphenyl)acetic acid, 3-fluoro-5-isopropoxyphenyl)boronic acid, 3-fluoro-5-methoxycarbonylphenyl)boronic acid, 3-fluoro-5-methylphenyl)boronic acid, 4-fluoro-2-methoxyphenyl)oxoacetic acid, 4-fluoro-3-methoxyphenyl)acetic acid, 4-fluoro-3-methoxyphenyl)boronic acid or a combination thereof, but are not limited thereto.

Also, preferably, the fluorinated organic compound may be in the form of a perfluorinated compound. The perfluorinated compounds include perfluorinated alkyl halides, perfluorinated aryl halide, fluorochloroalkene, perfluoroalcohol, perfluoroamine, and perfluorocarboxylic acid, perfluorosulfonic acid, or a derivative thereof, but is not limited thereto.

The perfluorinated alkyl halides and perfluorinated aryl halide are trifluoroiodomethane, pentafluoroethyl iodide, perfluorooctyl bromide (perflubron), dichlorodifluoromethane, or derivatives thereof, but are not limited thereto.

The fluorochloroalkene may be chlorotrifluoroethylene, dichlorodifluoroethylene, or a derivative thereof, but is not limited thereto.

The fluorochloroalkene may be chlorotrifluoroethylene, dichlorodifluoroethylene, or derivatives thereof, but is not limited thereto.

The perfluorocarboxylic acid may be trifluoroacetic acid, heptafluorobutryric acid, pentafluorobenzoic acid, perfluorooctanoic acid, perfluorononanoic acid, or derivatives thereof, but is not limited thereto.

The perfluorosulfonic acid is triflic acid, perfluorobutanesulfonic acid, perfluorobutane sulfonamide, perfluorooctanesulfonic acid, or a derivative thereof, but is not limited thereto.

The ligand may be trioctylphosphine oxide (TOPO), trioctylphosphine (TOP, trioctylphosphine), triethylphosphine oxide, tributylphosphine oxide or a derivative, thereof but is not limited thereto.

Therefore, as described above, the alkyl halide used as a surfactant to stabilize the surface of the metal halide perovskite, which may otherwise precipitate, becomes an organic ligand surrounding the surface of the metal halide perovskite nanocrystal. On the other hand, when the length of the alkyl halide surfactant is short, the size of the formed nanocrystal increases, so it can be formed in excess of 100 nm, further 300 nm or more, and even more than 1 μm, and in the large nanocrystals, there may be a fundamental problem in that due to thermal ionization and delocalization of charge carriers, excitons do not emit light and are separated into free charge carriers and disappear. Accordingly, the size of the metal halide perovskite nanocrystals formed by using an alkyl halide having a predetermined length or longer as a surfactant can be controlled to a predetermined size or less (i.e. 100 nm or less, preferably 30 nm or less).

In addition, as the size of the previously used inorganic quantum dots becomes smaller than the exciton Bohr diameter, it is difficult to adjust the size of the quantum dots, and the color purity and spectrum are affected by the size and size distribution, and there is a disadvantage in that the efficiency is rather reduced due to the defect on the crystal surface. In order to solve this problem, it is possible to provide nanocrystal having a size larger than the exciton Bohr diameter, which are not affected by the quantum confinement effect and exhibit maximum luminescence efficiency.

The method for deriving the exciton Bohr diameter is described in the [ACS Nano, 2017, 11 (7), pp 6586-6593, AIP Advances, 2018, 8, 025108] papers, their Supporting Information, and references described in this paper [in particular, Nature Physics, 2015, 11, 582; Energy & Environmental Science, 2016, 9, 962; J. Phys. Chem. Lett., 2017, 8, 1851]. As an example, in the case of MAPbBr3, the exciton Bohr diameter may be about 10 nm. It may be smaller than 10 nm or higher depending on the material. When obtaining physical parameters to be used in such a measurement, it should be obtained within a range that those skilled in the art agree. According to recent papers on dielectric constant according to frequency [Advanced Energy Materials, 2017, 7, 1700600; APL Materials, 2019, 7, 010901; Advanced Materials, 2019, 31, 1806671], the dielectric constant (εr) should not be used in the range of a dynamic dielectric constant higher than the high frequency (>1,000,000 Hz). It should be determined by considering the static dielectric constant (ε₀=static dielectric constant). A high frequency level of about 10¹⁵ Hz is the range in which the photophysical reaction takes place, and ε_{∞} can be defined in this range. The dielectric constant used to calculate the exciton Bohr diameter should be between ε_{∞} and ε₀. In general, considering that an organic semiconductor material has a dielectric constant of 3-5, the ionic metal halide perovskite material must have a static dielectric constant much larger than these values, and the ionic metal halide perovskite materials possess dielectric constant of 10 or more and 50 or less when measured at room temperature, more preferably 20 or more and 35 or less at room temperature, and may vary depending on the temperature in the range between 20 and 100. The CsPbBr₃ material has a dielectric constant that is almost independent of temperature, but the organic-inorganic hybrid metal halide perovskite has a dependence on temperature. And the measurement should be made with a pure metal halide perovskite thin film without ligands, and the value measured at normal room temperature should be put into the formula. In a typical metal halide perovskite semiconductor in the range of 1 eV to 3.5 eV, it is reasonable that the dielectric constant of the metal halide perovskite has a value that is more than twice the dielectric constant of an organic material. The dielectric constant can be measured through a conventional LCR meter or obtained by fitting with an equivalent circuit after measurement with an impedance spectroscopy equipment. See also papers reported in Nature Physics, 2015, 11, 582, Energy & Environmental Science, 2016, 9, 962 and J. Phys. Chem. Lett., 2017, 8, 1851. As shown in those papers, after obtaining the effective mass and exciton binding energy, dielectric constant can be obtained according to the equation R*=R₀μ/m₀εᵣ² (R*=exciton binding energy, R₀=atomic Rydberg constant, m₀=free electron mass, μ=reduced effective mass defined by 1/μ=1/mₕ+1/mₑ, mₕ=effective mass of hole, mₑ=effective mass of electron). The effective dielectric constant obtained in this way and reported in AIP Advances, 2018, 8, 025108 is 11.4. At this time, a value of μ=0.117m₀ was used. The calculated exciton Bohr radius is 5.16 nm and the exciton Bohr diameter is 10.32 nm (in the paper, it described that the exciton Bohr radius is 4.7 nm, so the exciton Bohr diameter is 9.4 nm, but it is judged as a calculation error.)

The exciton Bohr diameter can be obtained by the value of the effective mass of the metal halide perovskite and Equation 1 below.

$$r = {a}_{0} {ɛ}_{r} \frac{{m}_{0}}{μ} \qquad [ Equation 1 ]$$

Where r is the Bohr exciton radius, a₀ is the Bohr diameter of hydrogen (0.053 nm), εᵣ is the dielectric constant, μ=mₑ×mₕ/(mₑ+mₕ), mₑ is the effective electron mass and mₕ can be the effective hole mass. Here, the Bohr diameter represents twice the Bohr radius.

In addition, ITO/PEDOT:PSS/perovskite film/electron injection layer/cathode structure device was fabricated, and the capacitance (C) value of the perovskite thin film at 1000 Hz was measured through Impedance Spectroscopy. Afterwards C=εᵣε₀A/d (where A is the device area and d is the thickness), εᵣ is measured, and the reduced effective mass value (μ=0.117m₀) in the papers of Energy & Environmental Science, 2016, 9, 962 for MAPbBr₃ is used to determine the exciton Bohr diameter which was calculated as 12.4 nm.

Here, the dielectric constant should be measured at room temperature and measured using a pure metal halide perovskite thin film without a ligand, and it may vary depending on the material, but may generally have a value of 7-30, and more preferably between 7-20. However, when it has a value less than 7, it may be due to an error in measurement and thus should be measured with special care. In the case of MAPbBr₃, it may vary depending on the crystal size or the quality of the thin film, but a value between 7 and 20 is a reasonable range. In addition, if different values come out depending on the quality of the thin film, the measured value using the thin film of which the grain size is made as large as possible should be used.

Another way to experimentally determine the exciton Bohr diameter is that the size of the point at which the photoluminescence peak wavelength starts to change rapidly with a function of the size of the nanoparticles is very close to the exciton Bohr diameter, or it can be viewed as the particle size at the point where the full width at half maximum (FWHM) of the photoluminescence spectrum starts to increase. The quantum confinement effect begins at the size of the above exciton Bohr diameter, and particles below this point are called quantum dots. If the particle size becomes smaller in the quantum dot regime and the distribution of the particle size is present, the photoluminescence peak of a particle shifts toward blue color and the emission colors can be changed with the particle size, so the FWHM can be increased because photoluminescence spectrum is measured from ensembles of all the nanoparticles. It is most preferable to measure the size of the particles with a transmission electron microscope (TEM). When measured by the light scattering method, the particle size error is larger. When the particles are agglomerated, it is difficult to analyze the size of one particle, and the size of the aggregated particles is overestimated.

The quantum confinement effect refers to a phenomenon observed when the energy band is affected by a change in the atomic structure of a particle, and the exciton Bohr diameter is the point (the size of the semiconductor particle) at which the quantum confinement effect occurs. In other words, if a quantum dot is a particle of the semiconductor of which the size is an exciton Bohr diameter or less, as the particle size decreases the quantum confinement effect is applied, and accordingly, the “band gap” and the corresponding “emission wavelength (photoluminescence (PL) spectrum)” changes. Therefore, in order to obtain a practical value of the exciton Bohr diameter, it is necessary to find a region where the quantum confinement effect begins, that is, the “point at which the emission wavelength changes according to the size” of the semiconductor particle.

However, even when the particle size is larger than the exciton Bohr diameter, since electron-hole interaction in the semiconductor changes, the band gap and emission wavelength of the semiconductor particle may change. However, since the amount of change in this part is very small, it is commonly referred to as “Weak confinement regime”. On the other hand, the quantum confinement regime in which the band gap varies greatly depending on the size of the quantum dot particles is referred to as a “strong confinement regime”. Therefore, in order to obtain the exciton Bohr diameter, the boundary between the weak confinement regime and the strong confinement regime must be found. Therefore, when the particle size obtained through this experimentally the point at which the PL peak or FWHM rapidly changes (the point at which the straight line drawn along the slope meets when two sharply different slopes meet) matched the value obtained by the above equation within a slight error range (approximately 10%), the exciton Bohr diameter obtained by the formula can be said to be a physically meaningful value.

Referring to FIG. 2, a metal halide perovskite nanocrystal 100 according to the present invention may include a metal halide perovskite nanocrystal structure 110 that can be dispersed in an organic solvent. The organic solvent may be a polar solvent or a non-polar solvent.

For example, the polar solvent includes acetic acid, acetone, acetonitrile, dimethylformamide, gamma butyrolactone, N-methylpyrrolidone, ethanol or dimethylsulfoxide, and the non-polar solvent includes ethylene dichloride, trichloroethylene, chloroform, chlorobenzene, dichlorobenzene, styrene, dimethylformamide, dimethyl sulfoxide, xylene, toluene, cyclohexane, or isopropyl alcohol, but is not limited thereto.

In addition, the shape structures of the metal halide perovskite nanocrystals may be forms generally used in the art. The shape of the metal halide perovskite nanocrystal may be a 0-dimensional, 1-dimensional or 2-dimensional shape. As an example, it may be in the form of sphere, ellipsoid, cube, hollow cube, pyramid, cylinder, cone, elliptic column, hollow sphere, Janus particle, prism, multipod, polyhedron, nano tube, nano wire, nano fiber or nanoplatelet.

In addition, the size of the crystalline particles may be 1 nm to 10 μm or less. For example, the size of the crystalline particles may be 1 nm, 2 nm, 3 nm, 4 nm, 5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 μm. The size of the particle can be defined as a region that takes the lower value as the minimum value and the larger value as the maximum value out of the two numbers selected above. It is preferably 8 nm or more and 300 nm or less, and more preferably 10 nm or more and 30 nm or less. On the other hand, the size of the crystalline particles at this time means a size that does not take the length of a ligand to be described later into account, that is, the size of the remaining portions excluding the ligand. When the size of the crystalline particles is 1 μm or more, there may be a fundamental problem in that excitons do not undergo luminescence due to thermal ionization and delocalization of charge carriers in a large crystal, but are separated into free charge carriers and disappear. In addition, more preferably, as described above, the size of the crystalline particles may be greater than or equal to exciton Bohr diameter. The thermal ionization and delocalization of the charge carrier may gradually increase when the size of the nanocrystal exceeds 100 nm. If it is more than 300 nm, the phenomenon will occur more significantly, and if it is more than 1 μm, it is completely bulky and is subject to the above phenomenon.

For example, when the crystalline particles are spherical, the diameter of the crystalline particles may be 1 nm to 10 μm. For example, the diameter of the crystalline particles may be 1 nm, 2 nm, 3 nm, 4 nm, 5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm or 10 μm.

In addition, the band gap energy of the nanocrystal may be 1 eV to 5 eV. Preferably, the band gap energy of the nanocrystal may be included in 1 eV, 1.1 eV, 1.2 eV, 1.3 eV, 1.4 eV, 1.5 eV, 1.6 eV, 1.7 eV, 1.8 eV, 1.81 eV, 1.82 eV, 1.83 eV, 1.84 eV, 1.85 eV, 1.86 eV, 1.87 eV, 1.88 eV, 1.89 eV, 1.9 eV, 1.91 eV, 1.92 eV, 1.93 eV, 1.94 eV, 1.95 eV, 1.96 eV, 1.97 eV, 1.98 eV, 1.99 eV, 2 eV, 2.01 eV, 2.02 eV, 2.03 eV, 2.04 eV, 2.05 eV, 2.06 eV, 2.07 eV, 2.08 eV, 2.09 eV, 2.1 eV, 2.11 eV, 2.12 eV, 2.13 eV, 2.14 eV, 2.15 eV, 2.16 eV, 2.17 eV, 2.18 eV, 2.19 eV, 2.2 eV, 2.21 eV, 2.22 eV, 2.23 eV, 2.24 eV, 2.25 eV, 2.26 eV, 2.27 eV, 2.28 eV, 2.29 eV, 2.3 eV, 2.31 eV, 2.32 eV, 2.33 eV, 2.34 eV, 2.35 eV, 2.36 eV, 2.37 eV, 2.38 eV, 2.39 eV, 2.4 eV, 2.41 eV, 2.42 eV, 2.43 eV, 2.44 eV, 2.45 eV, 2.46 eV, 2.47 eV, 2.48 eV, 2.49 eV, 2.5 eV, 2.51 eV, 2.52 eV, 2.53 eV, 2.54 eV, 2.55 eV, 2.56 eV, 2.57 eV, 2.58 eV, 2.59 eV, 2.6 eV, 2.61 eV, 2.62 eV, 2.63 eV, 2.64 eV, 2.65 eV, 2.66 eV, 2.67 eV, 2.68 eV, 2.69 eV, 2.7 eV, 2.71 eV, 2.72 eV, 2.73 eV, 2.74 eV, 2.75 eV, 2.76 eV, 2.77 eV, 2.78 eV, 2.79 eV, 2.8 eV, 2.9 eV, 3 eV, 3.1 eV, 3.2 eV, 3.3 eV, 3.4 eV, 3.5 eV, 3.6 eV, 3.7 eV, 3.8 eV, 3.9 eV, 4 eV, 4.1 eV, 4.2 eV, 4.3 eV, 4.4 eV, 4.5 eV, 4.6 eV, 4.7 eV, 4.8 eV, 4.9 eV, or 5 eV.

Accordingly, since the energy band gap is determined according to the constituent material or crystal structure of the nanocrystal, light having a wavelength of, for example, 200 nm to 1300 nm may be emitted by controlling the constituent material of the nanocrystal. In addition, preferably, the nanocrystal may emit ultraviolet, blue, green, red, or infrared light.

The ultraviolet light includes ranges in which a lower value out of two numbers selected among 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, or 430 nm is a lower limit and a higher value out of the two numbers has an upper limit. The blue light includes ranges in which a lower value of two numbers among 440 nm, 450 nm, 451 nm, 452 nm, 453 nm, 454 nm, 455 nm, 456 nm, 457 nm, 458 nm, 459 nm, 460 nm, 461 nm, 462 nm, 463 nm, 464 nm, 465 nm, 466 nm, 467 nm, 468 nm, 469 nm, 470 nm, 471 nm, 472 nm, 473 nm, 474 nm, 475 nm, 476 nm, 477 nm, 478 nm, 479 nm, or 480 nm is a lower limit and a higher value of two is an upper limit. The green light is range in which a lower value of two numbers selected among 500 nm, 501 nm, 502 nm, 503 nm, 504 nm, 505 nm, 506 nm, 507 nm, 508 nm, 509 nm, 510 nm, 511 nm, 512 nm, 513 nm, 514 nm, 515 nm, 516 nm, 517 nm, 518 nm, 519 nm, 520 nm, 521 nm, 522 nm, 523 nm, 524 nm, 525 nm, 526 nm, 527 nm, 528 nm, 529 nm, 530 nm, 531 nm, 532 nm, 533 nm, 534 nm, 535 nm, 536 nm, 537 nm, 538 nm, 539 nm, 540 nm, 541 nm, 542 nm, 543 nm, 544 nm, 545 nm, 546 nm, 547 nm, 548 nm, 549 nm, 550 nm, 560 nm, 570 nm, or 580 nm is a lower limit and a higher value of the two has an upper limit. The red light include ranges in which a lower value of two numbers selected among 590 nm, 600 nm, 601 nm, 602 nm, 603 nm, 604 nm, 605 nm, 606 nm, 607 nm, 608 nm, 609 nm, 610 nm, 611 nm, 612 nm, 613 nm, 614 nm, 615 nm, 616 nm, 617 nm, 618 nm, 619 nm, 620 nm, 621 nm, 622 nm, 623 nm, 624 nm, 625 nm, 626 nm, 627 nm, 628 nm, 629 nm, 630 nm, 631 nm, 632 nm, 633 nm, 634 nm, 635 nm, 636 nm, 637 nm, 638 nm, 639 nm, 640 nm, 641 nm, 642 nm, 643 nm, 644 nm, 645 nm, 646 nm, 647 nm, 648 nm, 649 nm, 650 nm, 660 nm, 670 nm, 680 nm, 690 nm, or 700 nm is a lower limit and a higher value of the two is an upper limit. The infrared light includes ranges in which a lower value of two numbers selected among 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1000 nm, 1010 nm, 1020 nm, 1030 nm, 1040 nm, 1050 nm, 1060 nm, 1070 nm, 1080 nm, 1090 nm, 1100 nm, 1110 nm, 1120 nm, 1130 nm, 1140 nm, 1150 nm, 1160 nm, 1170 nm, 1180 nm, 1190 nm, 1200 nm, 1210 nm, 1220 nm, 1230 nm, 1240 nm, 1250 nm, 1260 nm, 1270 nm, 1280 nm, 1290 nm, 1300 nm, 1350 nm, 1400 nm, 1450 nm, or 1500 nm is a lower limit and a higher value of the two is an upper limit.

The metal halide perovskite nanocrystal according to the present invention may provide nanocrystal having various band gaps according to substitution of halogen elements.

For example, a nanocrystal including a CH₃NH₃PbCl₃ organic-inorganic metal halide perovskite nanocrystal structure may have a band gap energy of about 3.1 eV. In addition, the nanocrystal including the CH₃NH₃PbBr₃ organic-inorganic metal halide perovskite nanocrystal structure may have a band gap energy of about 2.3 eV. In addition, the nanocrystal including the CH₃NH₃PbI₃ organic-inorganic metal halide perovskite nanocrystal structure may have a band gap energy of about 1.5 eV.

In addition, the metal halide perovskite nanocrystal according to the present invention may provide nanocrystal having various band gaps according to substitution of organic elements.

For example, when n=4 in (CₙH₂ₙ₊₁NH₃)₂PbBr₄, nanocrystal having a band gap of about 3.5 eV may be provided. In addition, when n=5, nanocrystal having a band gap of about 3.33 eV may be provided. In addition, when n=7, nanocrystal having a band gap of about 3.34 eV may be provided. In addition, when n=12, nanocrystal having a band gap of about 3.52 eV may be provided.

In addition, the metal halide perovskite nanocrystal according to the present invention may provide nanocrystal having various band gaps according to the substitution of a central metal

For example, a nanocrystal including a CH₃NH₃PbI₃ organic-inorganic metal halide perovskite nanocrystal structure may have a band gap energy of about 1.5 eV. In addition, the nanocrystal including the CH₃NH₃Sn_{0.3}Pb_{0.7}I₃ organic-inorganic metal halide perovskite nanocrystal structure may have a band gap energy of about 1.31 eV. In addition, the nanocrystal including the CH₃NH₃Sn_{0.5}Pb_{0.5}I₃ organic-inorganic metal halide perovskite nanocrystal structure may have a band gap energy of about 1.28 eV. In addition, the nanocrystal including the CH₃NH₃Sn_{0.7}Pb_{0.3}I₃ organic-inorganic metal halide perovskite nanocrystal structure may have a band gap energy of about 1.23 eV. In addition, the nanocrystal including the CH₃NH₃Sn_{0.9}Pb_{0.1}I₃ organic-inorganic metal halide perovskite nanocrystal structure may have a band gap energy of about 1.18 eV. In addition, the nanocrystal including the CH₃NH₃SnI₃ organic-inorganic metal halide perovskite nanocrystal structure may have a band gap energy of about 1.1 eV. In addition, the nanocrystal including the CH₃NH₃PbₓSn₁₋ₓBr₃ organic-inorganic metal halide perovskite nanocrystal structure may have a band gap energy of 1.9 eV to 2.3 eV. In addition, the nanocrystal including the CH₃NH₃PbₓSn₁₋ₓCl₃ organic-inorganic metal halide perovskite nanocrystal structure may have a band gap energy of 2.7 eV to 3.1 eV.

FIG. 3 is showing a method of manufacturing a metal halide perovskite nanocrystal according to an embodiment of the present invention.

Referring to FIG. 3, in the method for preparing metal halide perovskite nanocrystal according to an embodiment of the present invention, a first solution in which a metal halide perovskite is dissolved in a polar solvent and a surfactant is dissolved in a non-polar solvent. Preparing a second solution and mixing the first solution with the second solution to form nanocrystal.

First, a first solution in which a metal halide perovskite is dissolved in a polar solvent and a second solution in which a surfactant is dissolved in a non-polar solvent are prepared.

The polar solvent include dimethylformamide, gamma butyrolactone, N-methylpyrrolidone, or dimethylsulfoxide, but is not limited thereto.

The metal halide perovskite may be a material having a three-dimensional crystal structure, a two-dimensional crystal structure, a one-dimensional crystal structure, or a zero-dimensional crystal structure.

The metal halide perovskite is ABX₃(3D), A₄BX₆(0D), AB₂X₅(2D), A₂BX₄(2D), A₂BX₆(0D), A₂B⁺B³⁺X₆(3D), A₃B₂X₉(2D) or Aₙ₋₁BₙX₃ₙ₊₁ (quasi-2D) (n is an integer between 2 and 6). A is a monovalent cation, B is a metal material, and X may be a halogen element. Specific examples of A, B, and X of the metal halide perovskite are as described in the previous section of <Metal Halide Perovskite Crystal>.

On the other hand, such a metal halide perovskite can be prepared by combining AX and BX₂ in a certain ratio. That is, the first solution may be formed by dissolving AX and BX₂ in a polar solvent at a predetermined ratio. For example, by dissolving AX and BX₂ in a polar solvent in a ratio of 2:1, a first solution in which a metal halide perovskite precursor is dissolved may be prepared.

In addition, the non-polar solvent may include dichloroethylene, trichloroethylene, chloroform, chlorobenzene, dichlorobenzene, styrene, dimethylformamide, dimethylsulfoxide, xylene, toluene, hexane, octadecene, cyclohexene or isopropyl alcohol.

In addition, the surfactant may include an alkyl halide, an amine ligand, a carboxylic acid or phosphonic acid.

The specific description of the alkyl halide, amine ligand, carboxylic acid, and phosphonic acid is as described in the previous section of <metal halide perovskite nanocrystal>.

Next, the first solution is mixed with the second solution to form nanocrystal.

In the step of forming nanocrystal by mixing the first solution with the second solution, it is preferable to mix the first solution by dropping the first solution into the second solution. At this time, it is preferable to mix by dropping into fine droplets, and to react by dropping several droplets finely from a spray or nozzle. In some cases, the first solution in the beaker may be poured as it is and dropped into the stirred second solution. In addition, the second solution at this time may be stirred. For example, a first solution in which an organic-inorganic metal halide perovskite (OIP) is dissolved is slowly added dropwise to a second solution in which an alkyl halide surfactant is dissolved and then nanocrystals are synthesized.

In this case, when the first solution is dropped into the second solution and mixed, organic-inorganic metal halide perovskite (OIP) is precipitated from the second solution due to a difference in solubility. The organic-inorganic metal halide perovskite (OIP) precipitated in the second solution is stabilized by an alkyl halide surfactant to form well-dispersed organic-inorganic metal halide perovskite nanocrystals (OIP-NC). Accordingly, it is possible to prepare metal halide perovskite nanocrystal including organic-inorganic metal halide perovskite nanocrystals and a plurality of alkyl halide organic ligands surrounding the organic/inorganic metal halide perovskite nanocrystals.

Meanwhile, the size of the crystalline particles of the organic/inorganic metal halide perovskite can be controlled by controlling the length or shape factor and amount of the alkyl halide surfactant. For example, the shape factor control can control the size through a linear, tapered, or inverted triangular surfactant.

In addition, the metal halide perovskite nanocrystal according to an embodiment of the present invention may have a core-shell structure.

Hereinafter, a core-shell structured metal halide perovskite nanocrystal according to an embodiment of the present invention will be described.

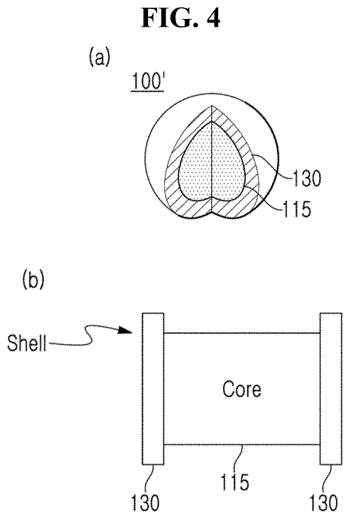

FIG. 4 is a schematic diagram showing a core-shell structured metal halide perovskite nanocrystal and an energy band diagram thereof according to an embodiment of the present invention.

Referring to FIG. 4(a), a core-shell structured metal halide perovskite nanocrystal 100′ according to the present invention includes a core 115 and a shell 130 surrounding the core 115. In this case, a material having a band gap larger than that of the core 115 may be used as the material of the shell 130.

Referring to FIG. 4(b), the energy band gap of the shell 130 is larger than the energy band gap of the core 115, so that excitons can be better constrained to the core metal halide perovskite.

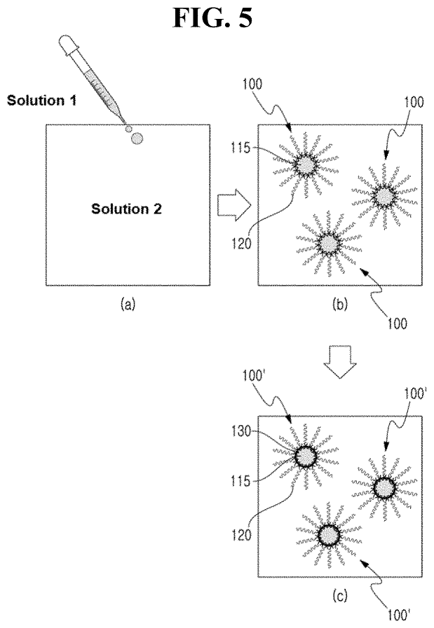

FIG. 5 is a schematic diagram showing a method for producing a metal halide perovskite nanocrystal having a core-shell structure according to an embodiment of the present invention.

A method for producing a core-shell structured metal halide perovskite nanocrystal according to an embodiment of the present invention comprises preparing a first solution in which a first metal halide perovskite is dissolved in a polar solvent and a second solution in which at least one surfactant selected from an alkyl halide, a carboxylic acid derivative, and an amine derivative is dissolved in a non-polar solvent, forming a core including a first metal halide perovskite nanocrystal structure by mixing the first solution with the second solution, and forming a shell surrounding the core and having a larger band gap than the core.

Referring to FIG. 5(a), a first solution in which a metal halide perovskite is dissolved in a polar solvent is added dropwise to a second solution in which an alkyl halide surfactant is dissolved in a non-polar solvent.

Referring to FIG. 5(b), when the first solution is added to the second solution, metal halide perovskite is precipitated in the second solution due to the difference in solubility, and the precipitated metal halide perovskite includes a well-dispersed metal halide perovskite nanocrystal core 115 while stabilizing the surface by being surrounded by at least one surfactant selected from an alkyl halide, a carboxylic acid derivative, and an amine derivative. Therefore, the metal halide perovskite nanocrystal 100 are formed. The nanocrystal core 115 is surrounded by the alkyl halide organic ligands 120.

When octadecene or hexane is used as a non-polar solvent to prepare the second solution, there is no miscibility with polar solvents such as dimethylsulfoxide, dimethylformamide, gamma butyrolactone, or N-methylpyrrolidone, so it is not mixed at all. Then, the phase separation occurs and thus the reaction does not occur, and the reaction still does not occur even after stirring. When vigorously stirred, an opaque emulsion solution is formed as cloudy as milky, and the color of the perovskite itself is not found. However, when acetone or alcohol such as tert-butanol is added into this solution, a reaction occurs and particles are formed. In this case, the ligands mix with the other solvent through acetone or tert-butanol, thereby causing a reaction surrounding the nanocrystal. This method is called the Inverse Nano Emulsion method. If instead of hexane and octadecene, you use a solvent (eg, toluene) that can mix with even a little bit of polar solvent, there is no need to inject additional solvent, and when the first solution is dropped into the second solution, perovskite particles are formed. This case is called the Ligand-Assisted Reprecipitation method. If the first solution is injected into the second solution and injected at a temperature of at least 50 degrees above room temperature, it is called a hot injection method. Typically, the high-temperature injection method is performed in an inert gas atmosphere.

Since the description on FIGS. 5(a) and 5(b) is the same as described above in FIG. 4, a detailed description thereof will be omitted.

Referring to FIG. 5(c), metal halide perovskite nanocrystal 100′ having a core-shell structure can be prepared by forming a shell 130 including a material having a larger band gap than the core 115 while surrounding the core 115. The following five methods can be used for the methods of forming such a shell.

As a first method, a shell may be formed using a second metal halide perovskite solution or an inorganic semiconductor material solution. That is, by adding a third solution, in which a second metal halide perovskite having a larger band gap than the first metal halide perovskite or an inorganic semiconductor material is dissolved, to the second solution, a shell may be formed. The shell surrounding the core may include a second metal perovskite nanocrystal, an inorganic semiconductor material or an organic polymer.

For example, while strongly stirring the solution of metal halide perovskites (MAPbBr₃) produced through the inverse nano-emulsion method, the ligand-assisted reprecipitation method, or the hot injection method as described above, a solution of metal halide perovskite (MAPbCl₃) with a larger band gap than MAPbBr₃, or a solution of inorganic semiconductor materials such as metal sulfide (e.g. PbS and ZnS) or metal oxide or a precursor solution thereof, or a solution of organic polymers such as polyethylene glycol, polyethylene oxide, polyvinylpyrrolidone, polyethyleneimine, polyvinyl alcohol (PVA), polysilazane, acrylate polymer, fluorinated polyvinylidene fluoride (PVDF) polymer, or acrylate-based low-molecular monomer, are slowly added dropwise or several drops into the metal halide perovskite solution. Then, a shell that includes a second metal halide perovskite nanocrystal (MAPbCl₃) or an inorganic semiconductor material may be formed. MA above stands for methyl ammonium.

The core-shell metal halide perovskite nanocrystals are synthesized because the core made of metal halide perovskite and the shell made of metal halide perovskite are mixed to form an alloy or adhere to each other.

Therefore, it is possible to form metal halide perovskite nanocrystal of MAPbBr₃/MAPbCl₃ core-shell structure.

In addition, after dispersing an organic polymer dot and an existing inorganic quantum dot (mainly III-V, II-IV semiconductor) in the second solution, the perovskite shell is formed by injecting the perovskite precursor.

As a second method, a shell can be formed using an organic ammonium halide solution. That is, after adding a large amount of the organic ammonium halide solution to the second solution and stirring, a shell having a larger band gap than the core surrounding the core may be formed.

For example, a metal halide perovskite (MAPbBr₃) solution is produced through the inverse nano-emulsion method, the ligand-assisted reprecipitation method, or the hot injection method as described above. A MACl solution is added to the MAPbBr₃ solution, stirred vigorously, and MAPbBr₃ on the surface is converted to MAPbBr₃₋ₓClₓ by the excess MACl to form a shell.

Accordingly, metal halide perovskite nanocrystal having a MAPbBr₃/MAPbBr₃₋ₓClₓ core-shell structure can be formed.

In addition, a metal halide perovskite (MAPbI₃) solution is produced through the inverse nano-emulsion method, ligand-assisted reprecipitation method, or hot injection method as described above. The MABr solution is added to the MAPbI₃ solution and vigorously stirred, and MAPbI₃ on the surface is converted into MAPbI₃₋ₓBrₓ by the excess MABr, thereby forming a shell.

Accordingly, metal halide perovskite nanocrystal having a MAPbI₃/MAPbI₃₋ₓBrₓ core-shell structure can be formed.

In addition, the MAI solution is added to a solution of metal halide perovskite (MAPbBr₃) produced through the inverse nano-emulsion method, ligand-assisted reprecipitation method, or hot injection method as described above, the solution is vigorously stirred, and thus MAPbBr₃ on the surface is converted into MAPbBr₃₋ₓIₓ by the excess MAI to form a shell.

Accordingly, metal halide perovskite nanocrystal having a MAPbBr₃/MAPbBr₃₋ₓIₓ core-shell structure can be formed. In this case, a red-emitting perovskite can be prepared.

As a third method, the shell can be formed using a pyrolysis/synthesis method. That is, after thermally decomposing the surface of the core by heat-treating the second solution, an organic ammonium halide solution is added to the heat-treated second solution to synthesize the surface again, so that the band gap of the shell is larger than that of the core while the shell surrounds the core.

For example, after heat-treating a solution of metal halide perovskite (MAPbBr₃) produced through the inverse nano-emulsion method as described above, thermally decomposing the surface of the perovskite particle to be converted to PbBr₂, and then adding the MACl solution to the heat-treated solution, the shell can be formed by reacting it again to have MAPbBr₂Cl at the surface. In this case, blue-emitting perovskite particles can be produced.

Accordingly, metal halide perovskite nanocrystal having a MAPbBr₃/MAPbBr₂Cl core-shell structure can be formed.

Therefore, the metal halide perovskite nanocrystal of the core-shell structure formed according to the present invention has a shell with a material having a larger band gap than the core, so that excitons are better confined to the core, and the metal halide perovskite nanocrystals are stable in air. It is possible to improve the durability of nanocrystals by using air-stable metal halide perovskite or inorganic semiconductor to prevent the core made of metal halide perovskite from being exposed to air.

As a fourth method, a shell can be formed using an organic semiconductor material solution. That is, in the second solution, an organic semiconductor material having a larger band gap than the metal halide perovskite is previously dissolved, and the first solution in which the above-described first metal halide perovskite is dissolved is added to the second solution. A core including a first metal halide perovskite nanocrystal and a shell including an organic semiconductor material surrounding the core may be formed.

Since the organic semiconductor material adheres to the surface of the core metal halide perovskite, it is possible to synthesize a metal halide perovskite having a core-shell structure.

Therefore, MAPbBr₃-organic semiconductor core-shell structure metal halide perovskite nanocrystal light emitters can be formed.

As a fifth method, a shell may be formed using a selective extraction method. That is, by adding a small amount of IPA solvent to the second solution in which the core containing the first metal halide perovskite nanocrystal is formed, MABr is selectively extracted from the surface of the nanocrystal and the surface is formed only with PbBr₂ to surround the core and finally a shell having a larger band gap than the core may be formed.

For example, by adding a small amount of IPA to the metal halide perovskite (MAPbBr₃) solution produced through the inverse nano-emulsion method as described above, only MABr on the nanocrystal surface is selectively dissolved. PbBr₂ shell can be formed by extracting so that only PbBr₂ remains on the surface.

That is, MABr on the surface of MAPbBr₃ may be removed through selective extraction.

Therefore, it is possible to form a metal halide perovskite nanocrystal light emitter having a MAPbBr₃—PbBr₂ core-shell structure.

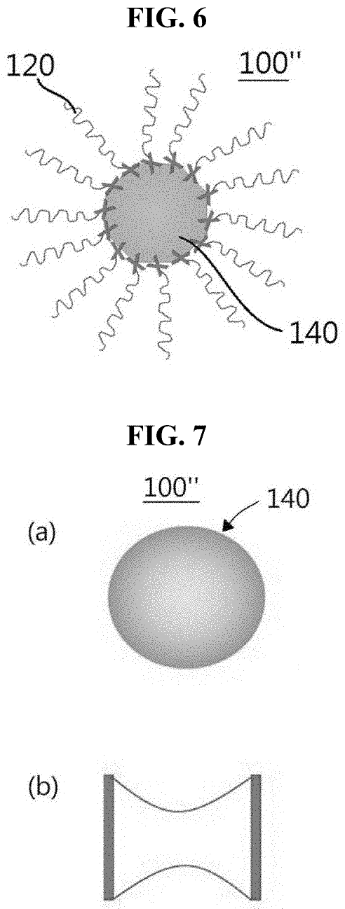

FIG. 6 is a schematic diagram showing a metal halide perovskite nanocrystal having a gradient composition structure according to an embodiment of the present invention.

FIG. 6, a metal halide perovskite nanocrystal 100″ having a structure having a gradient composition according to an embodiment of the present invention has a metal halide perovskite nanocrystal structure 140 that can be dispersed in an organic solvent and the nanocrystal structure 140 has a gradient composition structure whose composition changes from the center toward the outside, and the organic solvent at this time may be a polar solvent or a non-polar solvent.

The metal halide perovskite has a structure of ABX₃₋ₘX′ₘ, A₂BX₄₋ₗX′ₗ or ABX₄₋ₖX′ₖ, wherein A is a monovalent cation, B is a metal material, and X is Br, X′ may be Cl or X may be I, and X′ may be Br. In addition, the m, l, and k values are characterized by increasing from the center of the nanocrystal structure 140 toward the outside.

Accordingly, the energy band gap increases from the center of the nanocrystal structure 140 toward the outside.

For example, the monovalent cation may be a monovalent organic cation or an alkali metal. For example, the monovalent organic cation is organic ammonium (RNH₃⁺), organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)²⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺, (CₙF₂ₙ₊₁NH₃)₂⁺ (x, n is an integer of 1 or more, R=hydrocarbon derivative, alkyl, alkyl fluoride derivatives, H, F, Cl, Br, I), or combinations thereof, but are not limited thereto. The alkali metal may be Li⁺, Na⁺, K⁺, Rb⁺, Cs⁺, Fr⁺, or combinations thereof, but is not limited thereto.

Also preferably, the organic cations are acetamidinium, azaspironanium, benzene diammonium, benzylammonium, butanediammonium, isobutylammonium, n-butylammonium, t-butylammonium, cyclohexylammonium, cyclohexylmethylammonium, diazobicyclooctanedinium, diethylammonium, N,N-diethylethane diammonium, N,N-diethylpropane diammonium, dimethylammonium, N, N-dimethylethane diammonium, dimethylpropane diammonium, dodecylammonium, ethanediammonium, ethylammoniuium, 4-fluoro-benzyl ammonium, 4-fluoro-phenylethylammonium, 4-fluoro-phenylammonium, formamidinium, guanidinium, hexanediammnium, hexylammonium, imidazolium, 2-methoxyethylammonium, 4-methoxy-phenylethylammonium, 4-methoxy-phenylammonium, methylammonium, morpholinium, octylammonium, pentylammonium, piperidinium, propanediammonium, iso-propylammonium, di-iso-propylammonium, n-propylammonium, pyridinium, 2-pyrrolidin-1-ium-1-yethylammonium, pyrrolidinium, quinclidin-1-ium, 4-trifluoromethyl-benzylammonium, 4-trifluoromethyl ammonium, and benzalkonium chloride, dimethyldioctadecylammonium chloride, trimethylglycine, quaternary ammonium cation such as Choline, or combinations thereof.

The B may be a divalent transition metal, a rare earth metal, an alkaline earth metal, a monovalent metal, a combination of a trivalent metal, an organic substance (a monovalent, divalent, trivalent cation), or a combination thereof. In addition, preferably, the divalent transition metal, rare earth metal, and alkaline earth metal are Be²⁺, Mg²⁺, Ca²⁺, Sr²⁺, Ba²⁺, Ra²⁺, Mn²⁺, Fe²⁺, Co²⁺, Ni²⁺, Cu²⁺, Zn²⁺, Ru²⁺, Bi²⁺, Pd²⁺, Cd²⁺, Pt²⁺, Hg²⁺, Ge²⁺, Sn²⁺, Pb²⁺, Se²⁺, Te²⁺, Po²⁺, Eu²⁺, No²⁺, or combinations thereof, but are not limited thereto. The monovalent metal may be Li⁺, Na⁺, K⁺, Rb⁺, Cs⁺, Fr⁺, Ag⁺, Hg⁺, Ti⁺, or combinations thereof, and the trivalent metal is Cr³⁺, Fe³⁺, Co³⁺, Ru³⁺, Rh³⁺, Ir³⁺, Au³⁺, Al³⁺, Ga³⁺, In³⁺, Ti³⁺, As³⁺, Sb³⁺, Bi³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Am³⁺, Cm³⁺, Bk³⁺, Cf³⁺, Es³⁺, Fm³⁺, Md³⁺, Lr³⁺ or combinations thereof.

Meanwhile, the m, l, and k values may gradually increase from the center of the nanocrystal structure toward the outside. Therefore, the energy band gap may gradually increase according to the composition change.

As another example, the m, l, and k values may increase in a stepwise shape from the center of the nanocrystal structure toward the outside. Therefore, according to the composition change, the energy band gap may increase in the form of a step.

In addition, a plurality of organic ligands 120 surrounding the metal halide perovskite nanocrystal structure 140 may be further included. The organic ligand 120 may include an alkyl halide, an amine ligand, a carboxylic acid or phosphonic acid. Detailed descriptions of the alkyl halide, amine ligand, carboxylic acid, and phosphonic acid are as described in the section of <Metal Halide perovskite nanocrystals>.

Therefore, by making the nanocrystal structure into a gradient-alloy type, the contents of the metal halide perovskite present in a large amount outside the nanocrystal structure and the metal halide perovskite present in a large amount inside the nanocrystal structure can be gradually changed. This gradual change in the content in the nanocrystal structure uniformly adjusts the fraction in the nanocrystal structure, reduces surface oxidation, and improves exciton confinement in the metal halide perovskite present in a larger amount toward the center, thereby increasing luminescence efficiency. Not only that, it can also increase durability and stability.

A method of manufacturing a metal halide perovskite nanocrystal having a gradient composition structure according to an embodiment of the present invention will be described.

The method for preparing metal halide perovskite nanocrystals having a gradient composition structure according to an embodiment of the present invention includes preparing a metal halide perovskite nanocrystal having a core-shell structure, and forming the metal halide perovskite nanocrystals to have a gradient composition through interdiffusion by heat treatment.

First, a core-shell structure of metal halide perovskite nanocrystals is prepared. A method of manufacturing a metal halide perovskite nanocrystal having a related core-shell structure is the same as described above with reference to FIG. 5, and a detailed description thereof is omitted.

Thereafter, the core-shell structured metal halide perovskite nanocrystals may be heat-treated to form a gradient composition through interdiffusion.

For example, a metal halide perovskite having a core-shell structure is annealed at a high temperature to form a solid solution, and then heat treated to have a gradient composition through interdiffusion.

For example, the heat treatment temperature may be 100° C. to 150° C. Interdiffusion can be induced by annealing at this heat treatment temperature.

A method of manufacturing a metal halide perovskite nanocrystal having a gradient composition structure according to another embodiment of the present invention includes the steps of forming a first metal halide perovskite nanocrystal core and forming a second metal halide perovskite nanocrystal shell having a gradient composition and surrounding the core.

First, a first metal halide perovskite nanocrystal core is formed. This is the same as the method of forming the nanocrystal core described above, so a detailed description thereof will be omitted.

Then, a second metal halide perovskite nanocrystal shell having a gradient composition, surrounding the core, is formed.

The second metal halide perovskite has a structure of ABX₃₋ₘX′ₘ, A₂BX₄₋ₗX′ₗ or ABX₄₋ₖX′ₖ, wherein A is an organic cationic material, and B may be a metal material. The combination of X and X′ may be selected from F⁻, Cl⁻, Br⁻, I⁻, or At⁻, but the ionic radius of X′ may be smaller than X.

The monovalent cation may be a monovalent organic cation or an alkali metal. For example, the monovalent organic cation is organic ammonium (RNH₃⁺), organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺, (CₙF₂ₙ₊₁NH₃)₂⁺ (x, n is an integer of 1 or more, R=hydrocarbon derivative, alkyl, alkyl fluoride derivatives, H, F, Cl, Br, I), or combinations thereof, but are not limited thereto. The alkali metal may be Li⁺, Na⁺, K⁺, Rb⁺, Cs⁺, Fr⁺, or combinations thereof, but is not limited thereto.

Also preferably, the organic cations are acetamidinium, azaspironanium, benzene diammonium, benzylammonium, butanediammonium, isobutylammonium iso-butylammonium), n-butylammonium, t-butylammonium, cyclohexylammonium, cyclohexylmethylammonium, diazobicyclooctanedinium, diethylammonium, N,N-diethylethane diammonium, N,N-diethylpropane diammonium, dimethylammonium, N, N-dimethylethane diammonium, dimethylpropane diammonium, dodecylammonium, ethanediammonium, ethyl ammoniuium, 4-fluoro-benzylammonium, 4-fluoro-phenylethylammonium, 4-fluoro-phenylammonium, formamidinium, guanidinium, hexanediammnium, hexylammonium, imidazolium, 2-methoxyethylammonium, 4-methoxy-phenylethylammonium, 4-methoxy-phenylammonium, methylammonium, morpholinium, octylammonium, pentylammonium, piperazinediium, piperidinium, propanediammonium, Iso-propylammonium, di-iso-propyl ammonium, n-propyl ammonium, pyridinium, 2-pyrrolidin-1-ium-1-yethylammonium, pyrrolidinium, quinclidin-1-ium, 4-trifluoromethyl-benzylammonium, 4-trifluoromethyl ammonium, and benzalkonium chloride, dimethyldioctadecylammonium chloride, trimethylglycine, quaternary ammonium cation such as choline, or combinations thereof.

The B may be a divalent transition metal, a rare earth metal, an alkaline earth metal, a monovalent metal, a combination of a trivalent metal, an organic substance (a monovalent, divalent, trivalent cation), or a combination thereof. In addition, preferably, the divalent transition metal, rare earth metal, and alkaline earth metal are Be²⁺, Mg²⁺, Ca²⁺, Sr²⁺, Ba²⁺, Ra²⁺, Mn²⁺, Fe²⁺, Co²⁺, Ni²⁺, Cu²⁺, Zn²⁺, Ru²⁺, Bi²⁺, Pd²⁺, Cd²⁺, Pt²⁺, Hg²⁺, Ge²⁺, Sn²⁺, Pb²⁺, Se²⁺, Te²⁺, Po²⁺, Eu²⁺, No²⁺, or combinations thereof, but are not limited thereto. The monovalent metal may be Li⁺, Na⁺, K⁺, Rb⁺, Cs⁺, Fr⁺, Ag⁺, Hg⁺, Ti⁺, or combinations thereof, and the trivalent metal is Cr³⁺, Fe³⁺, Co³⁺, Ru³⁺, Rh³⁺, Ir³⁺, Au³⁺, Al³⁺, Ga³⁺, In³⁺, Ti³⁺, As³⁺, Sb³⁺, Bi³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Am³⁺, Cm³⁺, Bk³⁺, Cf³⁺, Es³⁺, Fm³⁺, Md³⁺, Lr³⁺ or combinations thereof.

Accordingly, a third solution in which the second metal halide perovskite is dissolved may be added to the second solution while increasing the m, l or k value.

That is, the solution in which the composition of ABX₃₋ₘX′ₘ, A₂BX₄₋ₗX′ₗ or ABX₄₋ₖX′ₖ is controlled is continuously dropped to form a shell whose composition is continuously changed.

FIG. 7 is a schematic diagram showing a metal halide perovskite nanocrystal particle having a structure having a gradient composition and an energy band diagram thereof according to an embodiment of the present invention.

Referring to FIG. 7(a), it can be seen that the nanocrystal particle 100″ according to the present invention is a metal halide perovskite nanocrystal structure 140 having a gradient composition of varying content. In this case, FIG. 7(b), by changing the composition of the material from the center of the metal halide perovskite nanocrystal structure 140 toward the outside, the energy band gap may be increased from the center to the outside.

Meanwhile, the metal halide perovskite nanocrystal particles according to the present invention may be nanocrystal particle of doped metal halide perovskites.

The doped metal halide perovskite contains a structure of ABX₃, A₂BX₄, ABX₄ or Aₙ₋₁BₙX₃ₙ₊₁ (n is an integer between 2 and 6), and a part of A is substituted with A′, or a part of B is substituted with B′, or a part of X is substituted with X′, wherein A and A′ are monovalent cationic materials, and B and B′ are metal materials, and the X and X′ may be halogen elements.

The monovalent cation may be a monovalent organic cation or an alkali metal. For example, the monovalent organic cation is organic ammonium (RNH₃⁺), organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺ or (CₙF₂ₙ₊₁NH₃)₂⁺ (x, n is an integer of 1 or more, R=hydrocarbon derivative, alkyl, alkyl fluoride derivatives, H, F, Cl, Br, I), or combinations thereof, but are not limited thereto. The alkali metal may be Li⁺, Na⁺, K⁺, Rb⁺, Cs⁺, Fr⁺, or combinations thereof, but is not limited thereto.

In addition, preferably, the organic cations are acetamidinium, azaspironanium, benzene diammonium, benzylammonium, butanediammonium, iso-butylammonium, n-butylammonium, t-butylammonium, cyclohexylammonium, cyclohexylmethylammonium, diazobicyclooctanedinium, diethylammonium, N,N, diethylpropane diammonium, dimethylammonium, N,N-dimethylethane diammonium, dimethylpropane diammonium, dodecylammonium, ethanediammonium, ethylammoniuium, 4-fluoro-benzylammonium, 4-fluoro-phenylethylammonium, 4-fluoro-phenylammonium, formamidinium, guanidinium, 2 hexanediammonium -methoxyethylammonium, 4-methoxy-phenlylethylammonium, 4-methoxy-phenylammonium, methylammonium, morpholinium, oxtylammonium, pentylammonium, piperazinediium, piperidinium, propanediammonium, iso-propylammonium, di-iso-propylammonium, n-propylammonium, pyridin-1pyridinium, 2-pyrrolidinium, 2-pyrrolidinium-ium-1-yethylammonium, pyrrolidinium, quinclidin-1-ium, 4-trifluoromethyl-benzylammonium, 4-trifluoromethyl ammonium, and quaternary ammonium cation such as benzalkonium chloride, dimethyldioctadecylammonium chloride, trimethylglycine, choline, or combinations thereof, but are not limited thereto.

B and B′ are divalent metals (e.g., transition metal, rare earth metal, alkaline earth metal, post-transition metal, lanthanum group), monovalent metal, trivalent metal, organic material (monovalent, divalent, trivalent cation) or combinations thereof. In addition, preferably, the divalent metal (e.g., transition metal, rare earth metal, alkaline earth metal, post-transition metal, lanthanum group) is Be²⁺, Mg²⁺, Ca²⁺, Sr²⁺, Ba²⁺, Ra²⁺, Mn²⁺, Fe²⁺, Co²⁺, Ni²⁺, Cu²⁺, Zn²⁺, Ru²⁺, Bi²⁺, Pd²⁺, Cd²⁺, Pt²⁺, Hg²⁺, Ge²⁺, Sn²⁺, Pb²⁺, Se²⁺, Te²⁺, Po²⁺, Eu²⁺, No²⁺, or combinations thereof, but are not limited thereto. The monovalent metal may be Li⁺, Na⁺, K⁺, Rb⁺, Cs⁺, Fr⁺, Ag⁺, Hg⁺, Ti⁺, or combinations thereof, and the trivalent metal is Cr³⁺, Fe³⁺, Co³⁺, Ru³⁺, Rh³⁺, Ir³⁺, Au³⁺, Al³⁺, Ga³⁺, In³⁺, Ti³⁺, As³⁺, Sb³⁺, Bi³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Am³⁺, Cm³⁺, Bk³⁺, Cf³⁺, Es³⁺, Fm³⁺, Md³⁺, Lr³⁺ or combinations thereof. Also, Eu metals can be additionally doped.

In addition, X and X′ may be F⁻, Cl⁻, Br⁻, I⁻, or At⁻, or combinations thereof.

In addition, a portion of A is substituted with A′, a portion of B is substituted with B′, or a portion of X is substituted with X′ is characterized in that 0.1% to 5%.

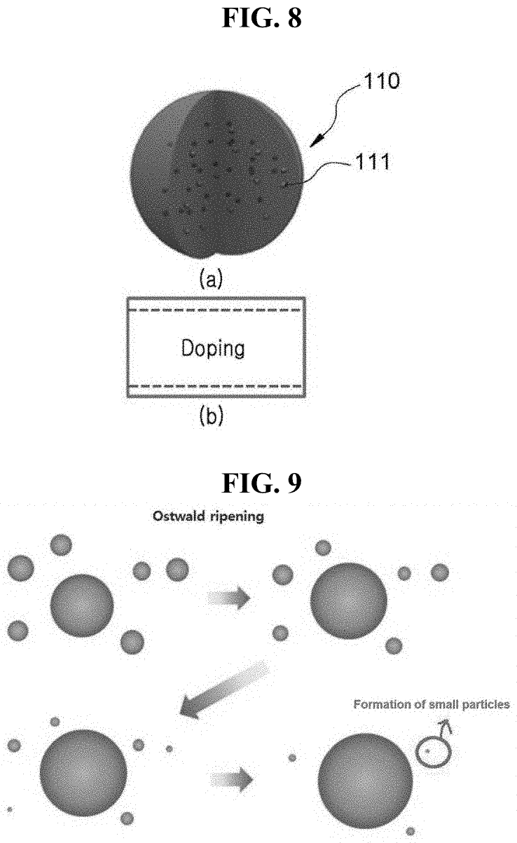

FIG. 8 is a schematic diagram showing a doped metal halide perovskite nanocrystal particle and an energy band diagram thereof according to an embodiment of the present invention.

FIG. 8(a) is a partially cut-away schematic diagram of a metal halide perovskite nanocrystal structure 110 doped with a doping element 111. FIG. 8(b) is a band diagram of such a doped metal halide perovskite nanocrystal structure 110.

Referring to FIGS. 8A and 8B, a semiconductor type may be changed to an n-type or a p-type through doped a metal halide perovskite. For example, when a metal halide perovskite nanocrystal of MAPbI₃ is partially doped with Cl, it can be changed to n-type to control electro-optical properties, wherein MA is methyl ammonium.

A doped metal halide perovskite nanocrystal particle according to an embodiment of the present invention will be described. A method of manufacturing through an inverse nano-emulsion method or a ligand-assisted reprecipitation method will be described as an example.

First, a first solution in which a metal halide perovskite doped in a polar solvent is dissolved in is added in the form of drops to a second solution in which at least one surfactant selected from alkyl halides, carboxylic acids and derivatives thereof, or alkylamines and derivatives thereof is dissolved in a non-polar solvent.

The polar solvent may include dimethylformamide, gamma butyrolactone or N-methylpyrrolidone, or dimethylsulfoxide, but is limited thereto.

The doped metal halide perovskite contains a structure of ABX₃, A₂BX₄, ABX₄ or Aₙ₋₁BₙX₃ₙ₊₁ (n is an integer between 2 and 6), and a part of A is substituted with A′, or a part of B is substituted with B′, or a part of X′ is substituted with X′, wherein A and A′ are monovalent cationic materials, and B and B′ are metal materials, and the X and X′ may be halogen elements

For example, the monovalent cation may be a monovalent organic cation is organic ammonium (RNH₃⁺), organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺, (CₙF₂ₙ₊₁NH₃)₂⁺ (x, n is an integer of 1 or more, R=hydrocarbon derivative, fluorocarbon derivatives, alkyl, alkyl fluoride (fluoroalkyl), H, F, Cl, Br, I), or combinations thereof, but are not limited thereto. The alkali metal may be Li⁺, Na⁺, K⁺, Rb⁺, Cs⁺, Fr⁺, or combinations thereof, but is not limited thereto.

Also preferably, the organic cation is acetamidinium, azaspironanium, benzene diammonium, benzylammonium, butanediammonium, iso-butylammonium, n-butylammonium, t-butylammonium, cyclohexylammonium, cyclohexylmethylammonium, diazobicyclooctanedinium, diethylammonium, N-diethylpropane diammonium, dimethylammonium, N,N-dimethylethane diammonium, dimethylpropane diammonium, dodecylammonium, ethanediammonium, ethylammoniuium, 4-fluoro-benzylammonium, 4-fluoro-phenylethylammonium, 4-fluoro-phenylamidamonium, formamidinium, guanidinium, hexylammonium 2-methoxyethylammonium, 4-methoxy-phenlylethylammonium, 4-methoxy-phenylammonium, methylammonium, morpholinium, oxtylammonium, pentylammonium, piperazinediium, piperidinium, propanediammonium, iso-propylammonium, di-iso-propylammonium, n-propylammonium, pyridinium, 2-pyrrolidinium, 2-pyrrolidinium 1-ium-1-yethylammonium, pyrrolidinium, quinclidin-1-ium, 4-trifluoromethyl-benzylammonium, 4-trifluoromethyl ammonium, derivatives thereof, or a combination thereof, but is not limited thereto.

B may be a divalent transition metal, a rare earth metal, an alkaline earth metal, a monovalent metal, a combination of a trivalent metal, or a combination thereof. Also preferably, the divalent transition metal, rare earth metal, or alkaline earth metal is Be²⁺, Mg²⁺, Ca²⁺, Sr²⁺, Ba²⁺, Ra²⁺, Mn²⁺, Fe²⁺, Co²⁺, Ni²⁺, Cu²⁺, Zn²⁺, Ru²⁺, Bi²⁺, Pd²⁺, Cd²⁺, Pt²⁺, Hg²⁺, Ge²⁺, Sn²⁺, Pb²⁺, Se²⁺, Te²⁺, Po²⁺, Eu²⁺, No²⁺, or combinations thereof, but are not limited thereto. The monovalent metal may be Li⁺, Na⁺, K⁺, Rb⁺, Cs⁺, Fr⁺, Ag⁺, Hg⁺, Ti⁺, or combinations thereof, and the trivalent metal is Cr³⁺, Fe³⁺, Co³⁺, Ru³⁺, Rh³⁺, Ir³⁺, Au³⁺, Al³⁺, Ga³⁺, In³⁺, Ti³⁺, As³⁺, Sb³⁺, Bi³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Am³⁺, Cm³⁺, Bk³⁺, Cf³⁺, Es³⁺, Fm³⁺, Md³⁺, Lr³⁺ or combinations thereof.

In addition, X and X′ may be Cl, Br or I.

A and A′ are different organic substances, B and B′ are different metals, and X and X′ are different halogen elements. Furthermore, it is preferable to use an element that does not form an alloy with X as the doped X′.

For example, a first solution may be formed by adding CH₃NH₃I, PbI₂, and PbCl₂ to a DMF solvent. In this case, the molar ratio of CH₃NH₃I:PbI₂ and PbCl₂ may be 1:1, and the molar ratio of PbI₂:PbCl₂ may be set to 97:3.

Meanwhile, as an example of the synthesis of AX, when A is CH₃NH₃ and X is Br, CH₃NH₂ (methylamine) and HBr (hydroiodic acid) are dissolved in a nitrogen atmosphere to obtain CH₃NH₃Br through solvent evaporation.

Then, when the first solution is added to the second solution, the doped metal halide perovskite is precipitated from the second solution due to the difference in solubility, and the precipitated doped metal halide perovskite is converted into a well-dispersed doped metal halide perovskite nanocrystal 100 structure while stabilizing the surface while surrounding a large number of at least one type of surfactant selected from an alkyl halide, carboxylic acid and its derivatives (e.g. oleic acid) and amine derivatives (e.g. oleylamine) The surface of the doped metal halide perovskite nanocrystal particles is surrounded by a plurality of organic ligands (the surfactant also serves as a ligand).

Thereafter, a polar solvent including doped metal halide perovskite nanocrystal particles dispersed in a non-polar solvent in which a surfactant is dissolved is selectively evaporated by heating, or a co-solvent capable of dissolving both a polar solvent and a non-polar solvent (co-solvent) is added to selectively extract a polar solvent including nanocrystal particle from a non-polar solvent to obtain doped metal halide perovskite nanocrystal particles.

On the other hand, when the metal halide perovskite nanoparticles are synthesized in the air (ambient condition), grain boundary creep and defects are formed by moisture in the air, and Ostwald ripening occurs to produce random small-sized nanocrystal particles, which causes a problem of lowering the color purity.

Thus, for the synthesis of metal halide perovskite nanocrystal particles exhibiting better color purity, a first solution in which metal halide perovskite is dissolved in an aprotic solvent, and a second solution in which a surfactant is dissolved in a protic or aprotic solvent are prepared. And mixing the first solution with the second solution in an inert gas atmosphere to form metal halide perovskite nanocrystal particles is performed. When metal halide nanocrystal particle is formed in the inert gas atmosphere, the occurrence of Ostwald ripening between the nanocrystal particles is suppressed and the size distribution of the crystal particles is controlled, so it is possible to control the size distribution of metal halide perovskite crystal particles.

Referring to FIG. 3, the conventional method for preparing metal halide perovskite nanocrystal particles is a method of manufacturing through the inverse nano-emulsion method or the ligand-assisted reprecipitation method. A first solution in which metal halide perovskite precursors are dissolved in a protic solvent and a second solution in which a surfactant is dissolved in a protic solvent or an aprotic solvent are prepared, and the first solution is mixed with the second solution to form nanocrystal particles in the air (ambient condition). In the inverse nano-emulsion method, an emulsion is formed in two solvents that are not completely miscible, and a particle-forming reaction is not formed unless acetone or alcohol is additionally added. In the ligand-assisted reprecipitation method, since the two solvents are partially miscible, the particle formation reaction proceeds immediately without an additional solvent. However, depending on the process, a surfactant may be added to the first solution, and some or all of the perovskite precursors may be added to the second solution.

However, in the case of synthesizing metal halide perovskite nanoparticles in the air (ambient condition), grain boundary creep and defects are formed by moisture in the air, and as shown in FIG. 9, Ostwald ripening takes place.

The Ostwald ripening is a theory explaining the principle of the growth of particles dissolved in the form of an emulsion. It means “When the particle size of the emulsion is varied, the relatively small particles continue to decrease, and the large particles gradually increase.”

Conventionally, in the case of synthesis in air, nanocrystal particle having a size of 5 nm or less were generated due to the Ostwald ripening, and the size distribution range of the prepared crystalline particles was too wide, which is the cause of lowering the color purity.

If the nanocrystal particle has a size of less than the exciton Bohr diameter, that is, less than 10 nm, for example, the band gap is changed by the particle size. The Bohr diameter may vary depending on the structure of the material, but since it is generally more than 10 nm, in the case of less than 10 nm, the emission wavelength may be changed even if it has the same metal halide perovskite structure. Therefore, in order to increase the color purity of the metal halide perovskite nanoparticles, it is preferable that the size of the particles is uniform, and it is required to control the size distribution range of the crystal particles generated therefrom.

When the synthesis atmosphere is adjusted to form nanocrystal particle by mixing the first solution with the second solution under an inert atmosphere, Ostwald ripening does not occur because of suppressing the generation of fine nanocrystal particle, and thus, the nanocrystal particle with a size distribution of 10-30 nm larger than the Bohr diameter can be prepared.

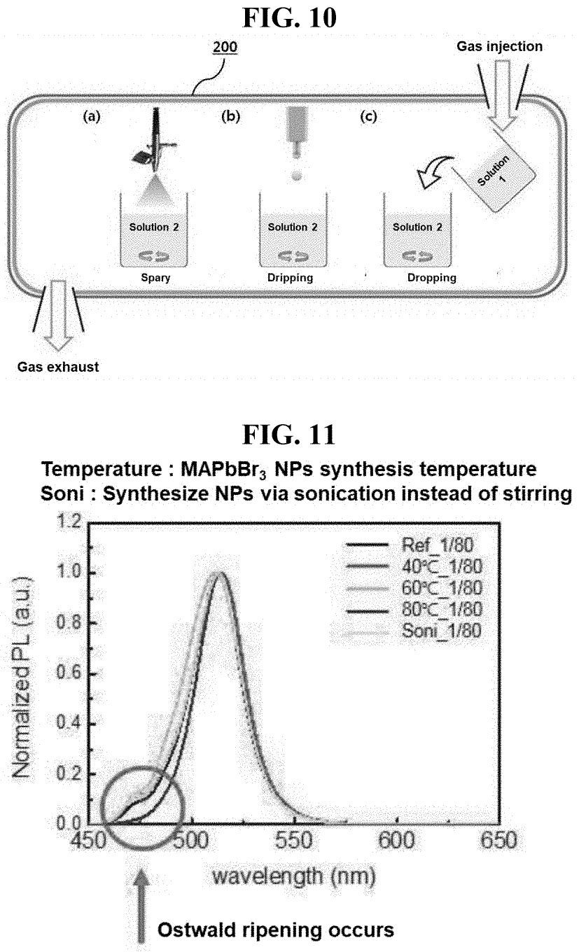

Hereinafter, the present invention will be described in more detail with reference to FIG. 10.

As shown in FIG. 10, the method for controlling the size distribution of the metal halide perovskite crystalline particles according to the present invention includes preparing a first solution in which metal halide perovskite precursors are dissolved in a polar solvent (including a protic solvent or an aprotic solvent), and a second solution in which a surfactant is dissolved in a at least one solvent selected from a protic solvent, an aprotic solvent, or a non-polar solvent (however, it must be different from the solvent of the first solution), and mixing the first solution with the second solution in an inert gas atmosphere to form metal halide perovskite nanocrystal particles. In the case of forming an inverse nano-emulsion, an additional process of demulsifying the emulsion is required. For demulsifying, acetone or alcohols such as tert-butanol can be used.

First, a first solution and a second solution are prepared. The first solution has metal halide perovskite precursors dissolved in an aprotic solvent, and the second solution has surfactants dissolved in at least one type of solvent selected from a protic solvent, aprotic, and non-polar solvent.

The protic solvent may be selected from methanol, ethanol, isopropyl alcohol, tert-butanol, carboxylic acid, water and formic acid, and the aprotic solvent may be selected from dimethylformamide, dimethyl sulfoxide, gamma butyrolactone, N-methylpyrrolidone, acetonitrile, THF (tetrahydrofuran), acetone, and HMPA (hexamethylphosphoramide), but it is not limited thereto. The non-polar solvent may be selected from xylene, octadecene, toluene, hexane, cyclohexene, dichloroethylene, trichloroethylene, chloroform, chlorobenzene, and dichlorobenzene, but it is not limited thereto.

The metal halide perovskite may be a material having a three-dimensional crystal structure, a two-dimensional crystal structure, an one-dimensional crystal structure, or a zero-dimensional crystal structure.

The metal halide perovskite is ABX₃(3D), A₄BX₆(0D), AB₂X₅(2D), A₂BX₄(2D), A₂BX₆(0D), A₂B⁺B³⁺X₆(3D), A₃B₂X₉(2D) or Aₙ₋₁BₙX₃ₙ₊₁ (quasi-2D) (n is an integer between 2 and 6). A is a monovalent cation, B is a metal material, and X may be a halogen element. Specific examples of A, B, and X of the metal halide perovskite are as described in the section of <Metal Halide Perovskite Crystal>.

On the other hand, such a metal halide perovskite can be prepared by combining AX and BX₂ in a certain ratio. That is, the first solution may be formed by dissolving AX and BX₂ in an aprotic solvent at a predetermined ratio. For example, by dissolving AX and BX₂ in a 1:1 ratio in an aprotic solvent, a first solution, in which ABX₃ metal halide perovskite is dissolved, may be prepared.

In addition, the surfactant may include an alkyl halide, an amine ligand, a carboxylic acid, phosphonic acid, or derivatives thereof. Detailed descriptions of the alkyl halide, amine ligand, carboxylic acid, and phosphonic acid are as described in the section of <Metal Halide perovskite nanocrystal particles>.

Next, the first solution is mixed with the second solution in an inert gas atmosphere to form metal halide perovskite nanocrystal particles.

At this time, the inert gas may be nitrogen (N₂), argon (Ar), or a mixed gas thereof, and any inert gas flow is possibly made if an oxygen concentration is 20 ppm or less. Mixing the first solution with the second solution under the inert gas atmosphere may be performed in a closed space such as a glove box.

In the step of forming nanocrystal particle by mixing the first solution with the second solution, it is preferable that the first solution is added dropwise into the second solution and mixed. In addition, the second solution may be stirred. For example, a first solution in which an organic-inorganic metal halide perovskite (OIP) is dissolved slowly added drop by drop or in several drops to a second solution in which an amine ligand, a carboxylic acid or phosphonic acid surfactant are dissolved and then nanocrystal particle can be synthesized.

When the first solution is dropped into the second solution and mixed, organic-inorganic metal halide perovskite (OIP) is precipitated from the second solution due to a difference in solubility. The amine-based ligand previously mixed in the second solution adheres to the crystal structure of the metal halide perovskite, thereby reducing the difference in solubility to prevent rapid precipitation of the metal halide perovskite. And carboxylic acid surfactants or phosphonic acid surfactants are adhered to the surface of ionic crystals of organic-inorganic metal halide perovskite (OIP) precipitated from the second solution and stabilizes nanocrystals, and then well-dispersed organic-inorganic metal halide perovskite nanocrystals (OIP-NCs) are produced. Therefore, it is possible to prepare a metal halide perovskite nanocrystal including an organic-inorganic metal halide perovskite nanocrystals and a plurality of organic ligands surrounding the organic-inorganic metal halide perovskite nanocrystals.

However, when the first solution and the second solution have very low or no miscibility, recrystallization may not occur, and in this case, a demulsifier may be additionally added.

Tert-butanol or acetone may be used as the demulsifier, but the present invention is not limited thereto.

The size distribution of the thus prepared metal halide perovskite crystal particles can be controlled in the range of 10 nm to 30 nm.

The colloidal solution containing the thus prepared metal halide perovskite nanocrystal particles may then be coated to form a thin film.

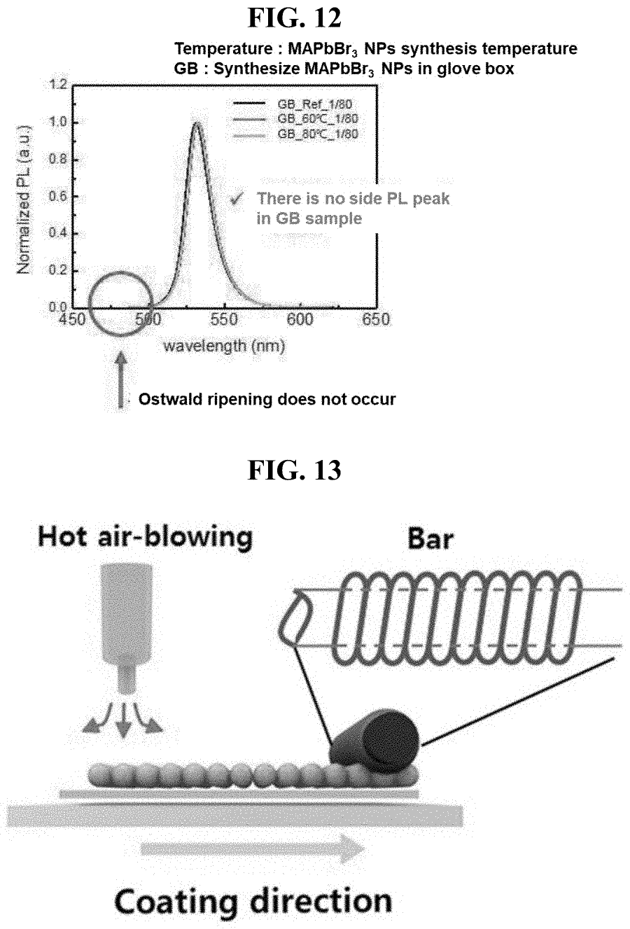

By spin coating a colloidal solution containing metal halide perovskite nanocrystal particles prepared in an inert gas atmosphere according to the method of the present invention and a colloidal solution containing metal halide perovskite nanocrystal particles prepared in air according to a conventional manufacturing method, thin films are formed and used to measure the photoluminescence properties. As shown in FIG. 11, in the case of the metal halide perovskite nanocrystal particle thin film produced in air according to the conventional manufacturing method, very small nanoparticles are also generated due to occurrence of Oswald ripening and the band of the emission wavelength is splitted. However, in the case of the metal halide perovskite nanocrystal particle thin film prepared in an inert gas atmosphere according to the present invention, as shown in FIG. 12, Oswald ripening does not occur and the single emission band appears, thereby realizing higher color purity.

Therefore, metal halide perovskite nanocrystal particles (organic metal halide perovskite nanocrystal particles or inorganic metal halide perovskite nanocrystal particles) prepared according to the method according to an embodiment of the present invention can be applied to various optoelectronics devices.

### <Metal Halide Perovskite Nanocrystal Thin Film Production>

In order to apply the metal halide perovskite nanocrystal particles to various optoelectronic devices, it is important to form a uniform thin film. For example, process of preparing a metal halide perovskite nanocrystal particle dispersed in an organic solvent may be performed to form a uniform metal halide perovskite nanocrystal particle thin film. Thin films are formed with a randomly selected one among various known methods such as spin coating method, spray method, dip coating method, bar coating method, nozzle printing method, slot-die coating method, gravure printing method, casting method, and Langmuir-Blodgett film method (LB).

When performing the spin coating process, the spin coating speed may be 1000 rpm to 5000 rpm, and the spin coating time may be 15 seconds to 150 seconds. If the spin coating speed falls below 1000 rpm or the spin coating time is shortened within 15 seconds, the thin film may become non-uniform or the solvent may not evaporate.

When forming a thin film through a printing method other than spin coating, the metal halide perovskite nanocrystal particles form a thin film in an already-crystallized state and thus are not affected by the coating speed, the coating environment, and the crystallinity of the underlying substrate layer, compared to polycrystal bulk metal halide perovskite thin film in which crystallization proceeds during coating. However, when a thin film is manufactured using such a printing method, the evaporation rate of the solvent is slow, so the nanocrystal particles are agglomerated and thus large crystals can be formed through recrystallization.

Accordingly, a uniform metal halide perovskite nanocrystal thin film can be manufactured through a printing process combined with an additional method of rapidly drying the printed nanocrystal thin film. It is possible to prevent recrystallization between the metal halide perovskite nanocrystal particles by additionally performing a step of rapidly drying the thin film after the printing process.

Preferably, the solvent remaining after the printing process can be removed through air injection.

FIG. 13 is a schematic diagram of a process of removing a solvent remaining after a bar coating process through air injection according to an embodiment of the present invention.

In addition, preferably, referring to FIG. 13, the drying step may be characterized in that high-temperature air is sprayed. It is preferable that the temperature of the sprayed air be 70° C. to 100° C. If the temperature of the air sprayed is less than 70° C., evaporation of the solvent from the bottom may be delayed and recrystallization between the nanocrystal particles may occur. If the temperature of the sprayed air exceeds 100° C., the metal halide perovskite crystal structure vulnerable to heat may be decomposed. In order to promote evaporation of the solvent at a drying temperature of 100°° C. or less, it is more preferable to perform rapid drying using air spray.

In the case of drying by applying only a temperature of 70° C. to 100° C. without blowing air in the drying step, since the drying temperature is lower than the boiling point (e.g., toluene: 110.6° C., dimethylformamide: 153° C.) of the organic solvent used for dispersion of the metal halide perovskite nanocrystal particles, the drying speed is slow, so that recrystallization of the nanocrystal particles can be achieved. Hence, it is more preferable to perform rapid drying by adding air injection.

According to another embodiment of the present invention, in order to form a uniform metal halide perovskite nanocrystal particle thin film, step of the forming of the perovskite nanocrystal particle thin film includes preparing of an anchoring solution and the solution of organic-inorganic metal halide perovskite nanoparticles containing perovskite nanocrystals, forming an anchoring agent layer by spin coating the anchoring solution on the substrate or the gate insulating film, and forming an anchoring semiconductor layer by spin coating the organic-inorganic metal halide perovskite nanoparticle solution on the agent layer.

Specifically, first, an anchoring solution and an organic-inorganic metal halide perovskite nanoparticle solution including the organic-inorganic metal halide perovskite nanocrystal may be prepared.

The anchoring solution may be a solution containing a resin that imparts adhesiveness exhibiting an anchoring effect. The anchoring solution may be, for example, a 3-mercaptopropionic acid ethanolic solution. The anchoring solution may have a concentration of 7 wt % to 12 wt %.

Thereafter, the anchoring agent layer may be formed by spin coating the anchoring solution on the substrate on which the metal halide perovskite nanocrystal particle thin film is to be formed. When performing the spin coating process, the spin coating speed may be 1000 rpm to 5000 rpm, and the spin coating time may be 15 seconds to 150 seconds. If the spin coating speed falls below 1000 rpm or the spin coating time is shortened within 15 seconds, the thin film may become non-uniform or the solvent may not evaporate.

Thereafter, an organic-inorganic metal halide perovskite nanoparticle solution may be spin-coated on the anchoring agent layer to form a thin film of anchoring metal halide perovskite nanocrystal particles. When the anchoring metal halide perovskite nanocrystal particle thin film is formed using the anchoring solution, a denser nanocrystal layer may be formed.

Thereafter, a crosslinking agent layer may be formed on the anchoring metal halide perovskite nanocrystal particle thin film. When the crosslinking agent layer is formed, a denser metal halide perovskite nanocrystal layer can be formed, and the length of the ligand is shortened to facilitate the injection of charges into the nanocrystals, thereby increasing the luminescence efficiency and luminance of the light-emitting device.

The crosslinking agent above is preferably a crosslinking agent having an X—R—X structure, and as an example, 1,2-ethanedithiol may be used. After preparing a solution by mixing the crosslinking agent in a soluble solvent, it may be spin-coated.

The steps of spin-coating the organic-inorganic metal halide perovskite nanoparticle solution and forming a crosslinking agent layer on the spin-coated layer of the organic-inorganic metal halide perovskite nanoparticle solution are alternately repeated. Thus, the thickness of the light emission layer can be adjusted.

The spin coating speed is preferably 1000 rpm to 5000 rpm, and the spin coating time may be 15 seconds to 150 seconds. If the spin coating speed decreases down to 1000 rpm or less, or if the spin coating time is shortened to 15 seconds or less, the thin film may become non-uniform or the solvent may not evaporate.

### <Metal Halide Perovskite Light-Emitting Device>

According to an embodiment of the present invention, the metal halide perovskite described above may be used in a light-emitting device.

In the present specification, the “light-emitting device” may include all devices that emit light such as a light-emitting diode, a light-emitting transistor, a laser, and a polarized light-emitting device.

The light-emitting device according to an embodiment of the present invention is characterized in that light is emitted from the above-described metal halide perovskite.

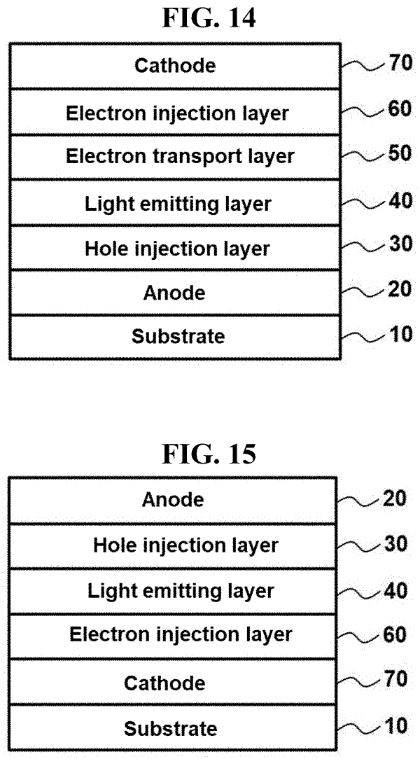

FIGS. 14 and 15 are schematic diagrams showing a light-emitting device according to an embodiment of the present invention.

FIGS. 14 and 15, the light-emitting device according to the present invention may include an anode 20 and a cathode 70 and a light emission layer 40 located between the two electrodes. In addition, preferably, a hole injection layer 30 may be provided between the anode 20 and the light emission layer 40 to facilitate injection of holes. In addition, an electron transport layer 50 for transporting electrons and an electron injection layer 60 for facilitating injection of electrons may be provided between the light emission layer 40 and the cathode 70.

In addition, the light-emitting device according to the present invention may further include a hole transport layer for transporting holes between the hole injection layer 30 and the light emission layer 40.

In addition, a hole blocking layer (not shown) may be located between the light emission layer 40 and the electron transport layer 50. In addition, an electron blocking layer (not shown) may be located between the light emission layer 40 and the hole transport layer. However, the present invention is not limited thereto, and the electron transport layer 50 may serve as a hole blocking layer, or the hole transport layer may serve as an electron blocking layer.

The anode 20 may be a conductive metal oxide, a metal, a metal alloy, or a carbon material. Conductive metal oxides include ITO, AZO(Al-doped ZnO), GZO(Ga-doped ZnO), IGZO(In,Ga-doped ZnO), MZO(Mg-doped ZnO), Mo-doped ZnO, Al-doped MgO, Ga-doped MgO, F-doped SnO₂, Nb-doped TiO₂, CuAlO₂, or a combination thereof. Metals or metal alloys suitable as the anode 20 may be Au or CuI. The carbon material may be graphite, graphene, or carbon nanotubes.

The negative electrode 70 is a conductive film having a lower work function than the positive electrode 20, for example, metals such as aluminum, magnesium, calcium, sodium, potassium, indium, yttrium, lithium, silver, lead, cesium, or combination of at least two metals thereof.

The anode 20 and the cathode 70 may be formed using a sputtering method, a vapor deposition method, or an ion beam deposition method. The hole injection layer 30, the hole transport layer, the light emission layer 40, the hole blocking layer, the electron transport layer 50, and the electron injection layer 60 are independent of each other by a vapor deposition method or a coating method such as spraying and spin coating, dipping, printing, doctor blading, or electrophoresis.

The hole injection layer 30 and/or the hole transport layer is layer having a HOMO level between the work function level of the anode 20 and the HOMO level of the light emission layer 40, and holes are injected or transported from the anode 20 to the light emission layer 40. Therefore, it functions to increase the efficiency of injection or transport.

The hole injection layer 30 or the hole transport layer may include a material commonly used as a hole transport material, and one layer may include different hole transport materials or layers. Hole transport materials include, for example, mCP (N,Ndicarbazolyl-3,5-benzene), PEDOT:PSS (poly(3,4-ethylenedioxythiophene):polystyrenesulfonate), NPD (N,N′-di(1-naphthyl)-N,N′-diphenylbenzidine), N,N′-Bis(3-methylphenyl)-N,N′-diphenylbenzidine (TPD), DNTPD (N4,N4′-Bis[4-[bis(3-methylphenyl)amino]phenyl]-N4,N4′-diphenyl-[1,1′-biphenyl]-4,4′-diamine), N,N′-diphenyl-N,N′-dinaphthyl-4,4′-diaminobiphenyl, N,N,N′N′-tetra-p-tolyl-4,4′-diaminobiphenyl, N,N,N′N′-tetraphenyl-4,4′-diaminobiphenyl, porphyrin compound derivatives such as copper(II)1,10,15,20-tetraphenyl-21H,23H-porphyrin; TAPC (1,1-Bis[4-[N,N′-Di(p-tolyl)Amino]Phenyl]Cyclohexane), Triarylamine derivatives such as N,N,N-tri(p-tolyl)amine, 4,4′,4′-tris[N-(3-methylphenyl)-N-phenylamino]triphenylamine, Carbazole derivatives such as N-phenylcarbazole or polyvinylcarbazole, phthalocyanine derivatives such as metal-free phthalocyanine or copper phthalocyanine, starburst amine derivatives, enaminestilbene derivatives, derivatives of aromatic tertiary amines or styryl amine compounds, or polysilane. Such a hole transport material may serve as an electron blocking layer.

The hole injection layer 30 may also include a hole injection material. For example, the hole injection layer may include at least one of a metal oxide and a hole injection organic material.

When the hole injection layer 30 includes a metal oxide, the metal oxide is at least one selected from the group consisting of MoO₃, WO₃, V₂O₅, nickel oxide (NiO), copper oxide (Copper(II) Oxide: CuO), copper aluminum oxide (copper aluminum oxide: CAO, CuAlO₂), zinc rhodium oxide (ZRO), ZnRh₂O₄, GaSnO, and GaSnO doped with metal-sulfide (FeS, ZnS or CuS).

When the hole injection layer 30 contains a hole injection organic material, the hole injection layer 30 may be formed according to a method arbitrarily selected from a variety of known methods such as a vacuum deposition method, a spin coating method, a casting method, a Langmuir-Blodgett (LB) method, a spray coating method, a dip coating method, a gravure coating method, a reverse offset coating method, a screen printing method, a slot-die coating method, and a nozzle printing method.

The hole-injecting organic material is may include at least one selected from the group consisting of Fullerene (C₆₀), HAT-CN, F₁₆CuPC, CuPC, m-MTDATA [4,4′,4″-tris (3-methylphenylphenylamino) triphenylamine] (see formula below), NPB [N,N′-Di(1-naphthyl)-N,N′-diphenyl-(1,1′-biphenyl)-4,4′-diamine)], TDATA (see formula below), 2T-NATA (see formula below), Pani/DBSA (Polyaniline/Dodecylbenzenesulfonic acid: Polyaniline/Dodecylbenzenesulfonic acid), PEDOT/PSS (Poly(3,4-ethylenedioxythiophene)/Poly(4-styrenesulfonate): Poly(3,4-ethylenedioxythiophene)/Poly(4-styrenesulfonate)), Pani/CSA (Polyaniline/Camphor sulfonic acid: polyaniline/camphor sulfonic acid) and PANI/PSS (Polyaniline)/Poly(4-styrenesulfonate).

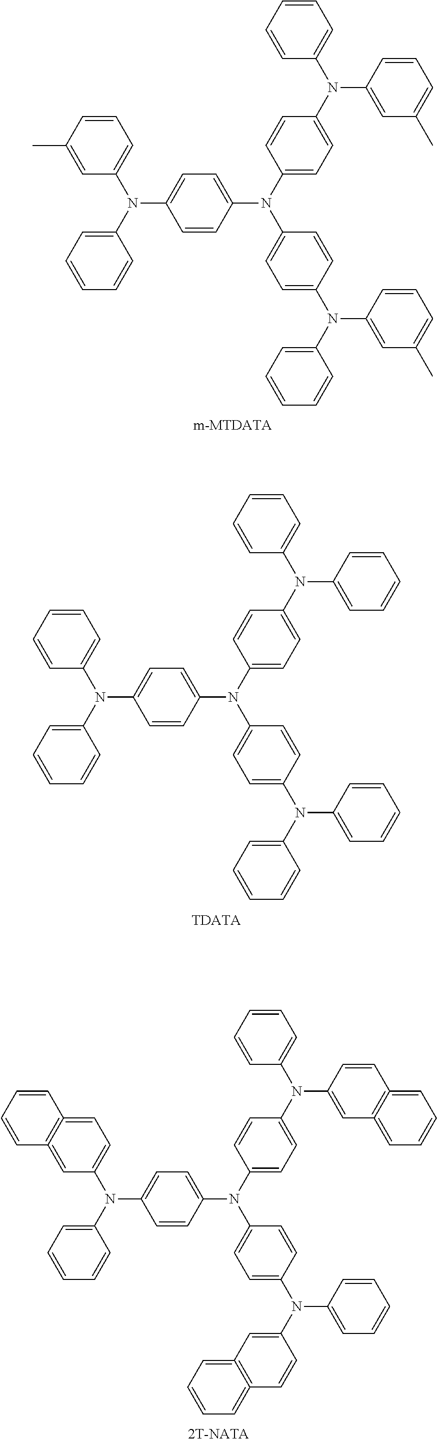

For example, the hole injection layer may be a layer in which the metal oxide is doped into the hole injecting organic material matrix. In this case, the doping concentration is preferably 0.1 wt % to 80 wt % based on the total weight of the hole injection layer.

The hole injection layer may have a thickness of 1 nm to 1000 nm. For example, the thickness of the hole injection layer is 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 59 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm, 101 nm, 102 nm, 103 nm, 104 nm, 105 nm, 106 nm, 107 nm, 108 nm, 109 nm, 110 nm, 111 nm, 112 nm, 113 nm, 114 nm, 115 nm, 116 nm, 117 nm, 118 nm, 119 nm, 120 nm, 125 nm, 130 nm, 135 nm, 140 nm, 145 nm, 150 nm, 155 nm, 160 nm, 165 nm, 170 nm, 175 nm, 180 nm, 185 nm, 190 nm, 195 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 450 nm, 500 nm, 550 nm, 600 nm, 650 nm, 700 nm, 750 nm, 800 nm, 850 nm, 900 nm, 950 nm or 1000 nm. The thickness of the hole injection layer can be defined as a range that takes the lower value as the minimum value and the larger value as the maximum value out of the two numbers selected above. Also, preferably, the thickness of the hole injection layer may be 10 nm to 200 nm. When the thickness of the hole injection layer satisfies the above-described range, the driving voltage is not increased, so that a high-quality organic device can be implemented.

In addition, a hole transport layer may be further formed between the light emission layer and the hole injection layer.

The hole transport layer may include a known hole transport material. For example, the hole transport material may include at least one selected from the group consisting of (1,3-bis(carbazol-9-yl)benzene (MCP), 1,3,5-tris(carbazol-9-yl)benzene (TCP), 4,4′,4″-tris(carbazol-9-yl)triphenylamine (TCTA), 4,4′-bis(carbazol-9-yl)biphenyl (CBP), N,N′-bis(naphthalen-1-yl)-N,N′-bis(phenyl)-benzidine (NPB), N,N′-bis(naphthalen-2-yl)-N,N′-bis(phenyl)-benzidine (β-NPB), N,N′-bis(naphthalen-1-yl)-N,N′-bis(phenyl)-2,2′-dimethylbenzidine (α-NPD), Di-[4-(N,N-ditolyl-amino)-phenyl]cyclohexane (TAPC), N,N,N′,N′-tetra-naphthalen-2-yl-benzidine (β-TNB) and N4,N4,N4′,N4′-tetra(biphenyl-4-yl)biphenyl-4,4′-diamine (TPD15), poly(9,9-dioctylfluorene-co-bis-N,N′-(4-butylphenyl)-bis-N,N′-phenyl-1,4-phenylenediamine) (PFB), poly(9,9′-dioctylfluorene-co-N-(4-butylphenyl)diphenylamine) (TFB), poly(9,9′-dioctylfluorene-co-bis-N,N′-(4-butylphenyl)-bis-N,N′-phenylbenzidine) (BFB), and poly(9,9-dioctylfluorene-co-bis-N,N′-(4-methoxyphenyl)-bis-N,N′-phenyl-1,4-phenylenediamine)(PFMO), but it is not limited thereto.

The formula of the hole transport material is summarized in Table 1 below.

TABLE 1

| Name | Formula |
|---|---|
| NPH | 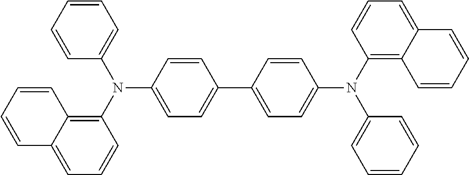 [SMILES: c1ccc(N(c2ccc(-c3ccc(N(c4ccccc4)c4cccc5ccccc45)cc3)cc2)c2cccc3ccccc23)cc1] |
| MCP | 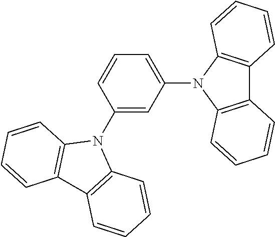 [SMILES: c1cc(-n2c3ccccc3c3ccccc32)cc(-n2c3ccccc3c3ccccc32)c1] |
| TCP | 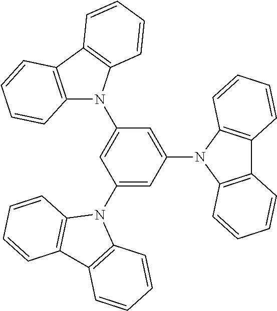 [SMILES: c1ccc2c(c1)c1ccccc1n2-c1cc(-n2c3ccccc3c3ccccc32)cc(-n2c3ccccc3c3ccccc32)c1] |
| TCTA | 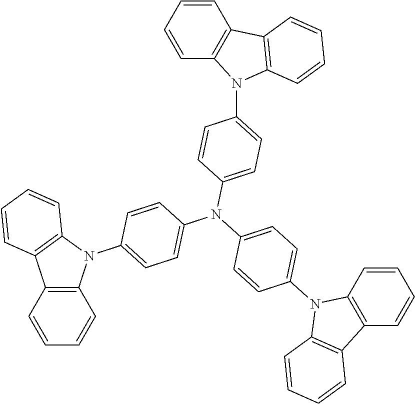 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1] |
| CBP | 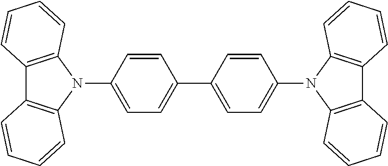 [SMILES: c1ccc2c(c1)c1ccccc1n2-c1ccc(-c2ccc(-n3c4ccccc4c4ccccc43)cc2)cc1] |
| β-NPB | 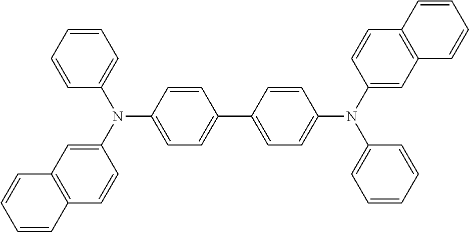 [SMILES: c1ccc(N(c2ccc(-c3ccc(N(c4ccccc4)c4ccc5ccccc5c4)cc3)cc2)c2ccc3ccccc3c2)cc1] |
| α-NPD | 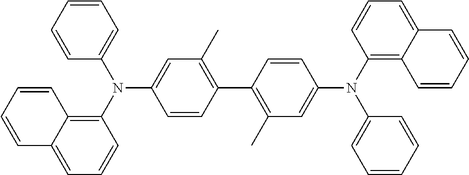 [SMILES: Cc1cc(N(c2ccccc2)c2cccc3ccccc23)ccc1-c1ccc(N(c2ccccc2)c2cccc3ccccc23)cc1C] |
| TAPC | 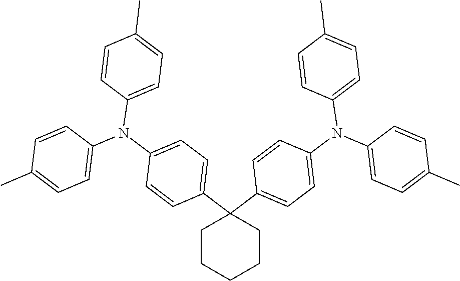 |
| β-TNB | 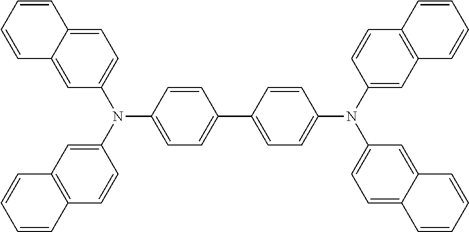 [SMILES: c1ccc2cc(N(c3ccc(-c4ccc(N(c5ccc6ccccc6c5)c5ccc6ccccc6c5)cc4)cc3)c3ccc4ccccc4c3)ccc2c1] |
| TPD15 | 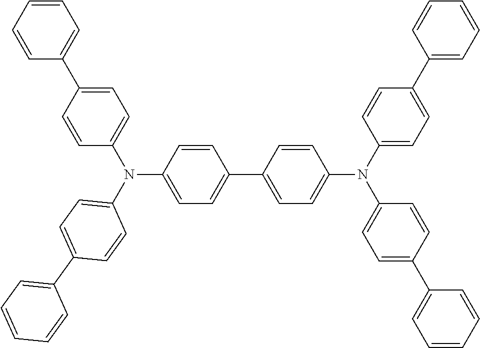 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1] |

Among the hole transport layers, for example, in the case of TCTA, in addition to the hole transport role, it may play a role of preventing diffusion of excitons from the emission layer.

The thickness of the hole transport layer may be 1 nm to 100 nm. For example, the thickness of the hole transport layer is 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, or 100 nm. The thickness of the hole transport layer can be defined as a range that takes the lower value as the minimum value and the larger value as the maximum value out of the two numbers selected above. In addition, preferably, the thickness of the hole transport layer may be 10 nm to 60 nm. When the thickness of the hole transport layer satisfies the above-described range, light efficiency of the organic light-emitting diode may be improved and luminance may be increased.

The electron injection layer 60 and/or the electron transport layer 50 are layers having an LUMO level between the work function level of the cathode 70 and the LUMO level of the emission layer 40, and increase the efficiency of injection or transport of electrons from the cathode 70 to the emission layer 40.

The electron injection layer 60 may be, for example, LiF, NaCl, NaF, CsF, Li₂O, BaO, BaF₂, MgF₂, or Liq (lithium quinolate). In addition, if the electron transport layer and the electron injection layer material are co-deposited to form a doped electron transport layer, the electron injection layer may be replaced.

The electron transport layer 50 may include quinoline derivative, especially tris(8-hydroxyquinoline)aluminum (Alq₃), Bis(2-methyl-8-quinolinolate)-4-(phenylphenolato)aluminium (Balq), bis(10-hydroxybenzo [h] quinolinato)-beryllium (Bebq₂), 2,9-dimethyl-4,7-diphenyl-1,10-phenanthroline (BCP), 4,7-diphenyl-1,10-phenanthroline (Bphen), 2,2′,2″-(benzene-1,3,5-triyl)-tris(1-phenyl-1H-benzimidazole (TPBI), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2)-yl)-4,7-diphenyl-1,10-phenanthroline (NBphen), Tris(2,4,6-trimethyl-3-(pyridin-3-yl)phenyl)borane (3TPYMB), phenyl-dipyrenylphosphine oxide (POPy₂), 3,3′,5,5′-tetra[(m-pyridyl)-phen-3-yl]biphenyl (BP4mPy), 1,3,5-tri[(3-pyridyl)-phen-3-yl]benzene (TmPyPB), 1,3-bis[3,5-di(pyridin-3-yl) phenyl]benzene (BmPyPhB), Bis(10-hydroxybenzo[h]quinolinato)beryllium (Bepq₂), Diphenylbis(4-(pyridin-3-yl)phenyl)silane (DPPS) and 1,3,5-tri(p-pyrid-3-yl-phenyl)benzene (TpPyPB), 1,3-bis[2-(2,2′-bipyridine-6-yl)-1,3,4-oxadiazo-5-yl]benzene (Bpy-OXD), 6,6′-bis[5-(biphenyl-4-yl)-1,3,4-oxadiazo-2-yl]-2,2′-bipyridyl (BP-OXD-Bpy), TSPO1(diphenylphosphine oxide-4-(triphenylsilyl)phenyl), TPBi(1,3,5-tris (N-phenylbenzimidazol-2-yl)benzene), tris(8-quinolinorate) aluminum (Alq3), 2,5-diaryl silol derivative (PyPySPyPy), perfluorinated compound (PF-6P), or COTs (Octasubstituted cyclooctatetraene).

The formula of the electron transport material is summarized in Table 2 below.

TABLE 2

| Name | Formula |
|---|---|
| Alq [symbol] | 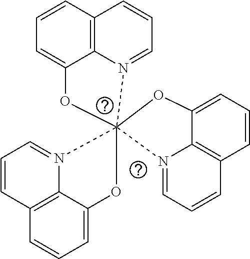 |
| TPB [symbol] | 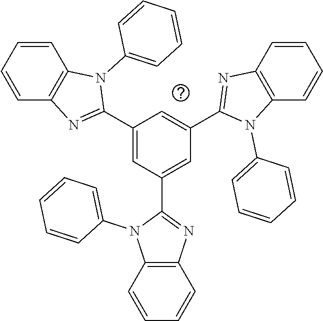 [SMILES: c1ccc(-n2c(-c3cc(-c4nc5ccccc5n4-c4ccccc4)cc(-c4nc5ccccc5n4-c4ccccc4)c3)nc3ccccc32)cc1] |
| PBD | 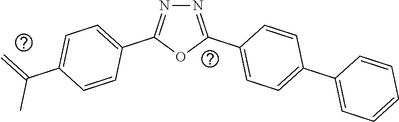 [SMILES: C=C(C)c1ccc(-c2nnc(-c3ccc(-c4ccccc4)cc3)o2)cc1] |
| BCP | 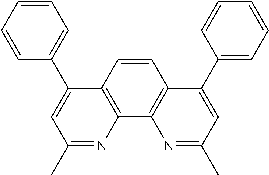 [SMILES: Cc1cc(-c2ccccc2)c2ccc3c(-c4ccccc4)cc(C)nc3c2n1] |
| Bo [symbol] | 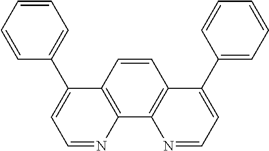 [SMILES: c1ccc(-c2ccnc3c2ccc2c(-c4ccccc4)ccnc23)cc1] |
| Balq | 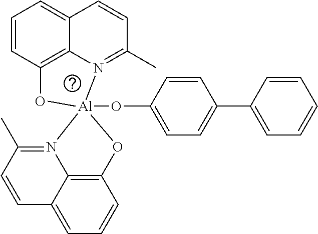 |
| B [symbol] y-GX [symbol] | 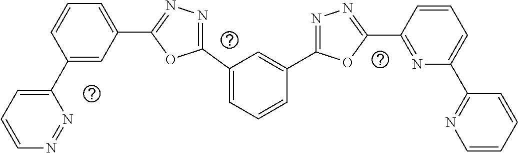 [SMILES: c1ccc(-c2cccc(-c3nnc(-c4cccc(-c5nnc(-c6cccc(-c7cccnn7)c6)o5)c4)o3)n2)nc1] |
| BP-OXD- Bpy | 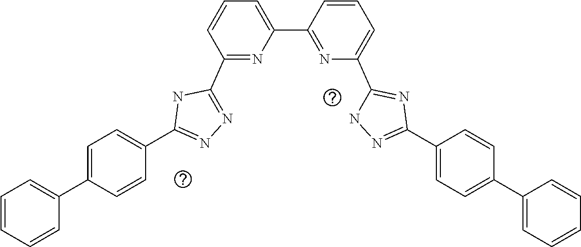 [SMILES: c1ccc(-c2ccc(-c3n[nH]c(-c4cccc(-c5cccc(-c6nnc(-c7ccc(-c8ccccc8)cc7)[nH]6)n5)n4)n3)cc2)cc1] |
| TAZ | 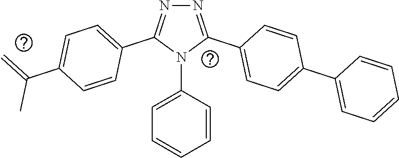 [SMILES: C=C(C)c1ccc(-c2nnc(-c3ccc(-c4ccccc4)cc3)n2-c2ccccc2)cc1] |
| NTAZ | 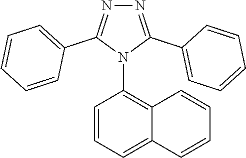 [SMILES: c1ccc(-c2nnc(-c3ccccc3)n2-c2cccc3ccccc23)cc1] |
| NBphen | 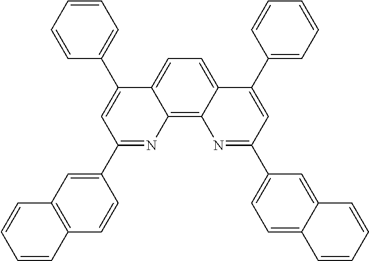 [SMILES: c1ccc(-c2cc(-c3ccc4ccccc4c3)nc3c2ccc2c(-c4ccccc4)cc(-c4ccc5ccccc5c4)nc23)cc1] |
| 3TPYMB | 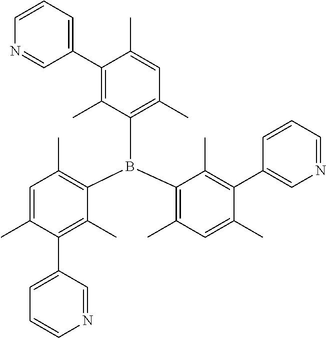 [SMILES: Cc1cc(C)c(-c2cccnc2)c(C)c1B(c1c(C)cc(C)c(-c2cccnc2)c1C)c1c(C)cc(C)c(-c2cccnc2)c1C] |
| POPy2 | 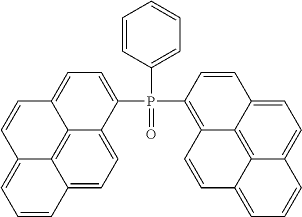 [SMILES: O=P(c1ccccc1)(c1ccc2ccc3cccc4ccc1c2c34)c1ccc2ccc3cccc4ccc1c2c34] |
| BP4mPy | 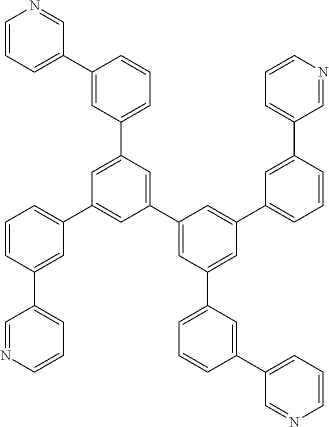 [SMILES: c1cncc(-c2cccc(-c3cc(-c4cccc(-c5cccnc5)c4)cc(-c4cc(-c5cccc(-c6cccnc6)c5)cc(-c5cccc(-c6cccnc6)c5)c4)c3)c2)c1] |
| TmPyPB | 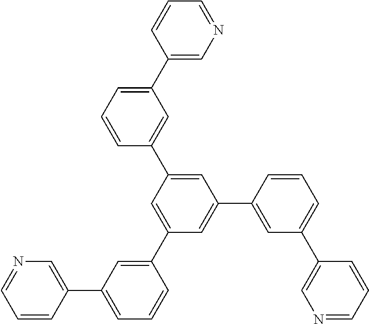 [SMILES: c1cncc(-c2cccc(-c3cc(-c4cccc(-c5cccnc5)c4)cc(-c4cccc(-c5cccnc5)c4)c3)c2)c1] |
| BmPyPhB | 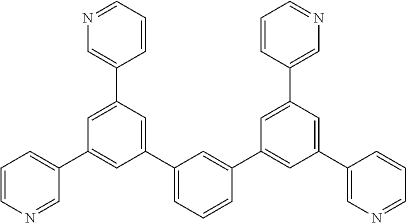 [SMILES: c1cncc(-c2cc(-c3cccnc3)cc(-c3cccc(-c4cc(-c5cccnc5)cc(-c5cccnc5)c4)c3)c2)c1] |
| Bebq2 | 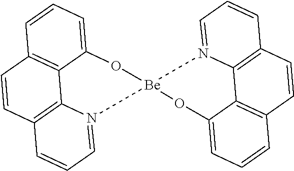 |
| DPPS | 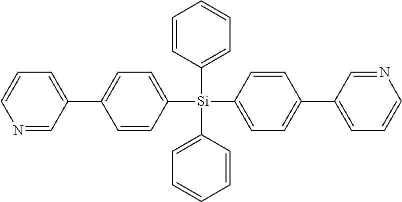 [SMILES: c1ccc([Si](c2ccccc2)(c2ccc(-c3cccnc3)cc2)c2ccc(-c3cccnc3)cc2)cc1] |
| TpPyPB | 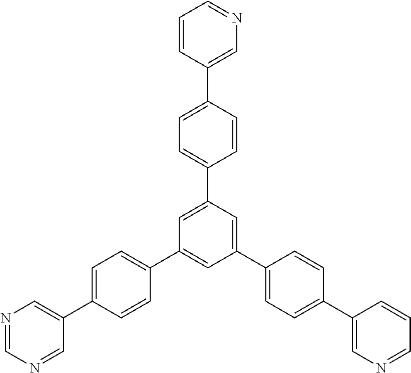 [SMILES: c1cncc(-c2ccc(-c3cc(-c4ccc(-c5cccnc5)cc4)cc(-c4ccc(-c5cncnc5)cc4)c3)cc2)c1] |

[symbol]

indicates data missing or illegible when filed

The thickness of the electron transport layer may be about 5 nm to 100 nm. For example, the thickness of the electron transport layer is 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm. The thickness of the hole injection layer can be defined as a region that takes the lower value as the minimum value and the larger value as the maximum value out of the two numbers selected above. In addition, preferably, the thickness of the electron transport layer may be 15 nm to 60 nm. When the thickness of the electron transport layer satisfies the above-described range, excellent electron transport characteristics can be obtained without an increase in driving voltage.

The electron injection layer 60 may include a metal oxide. Since the metal oxide has n-type semiconductor properties, it has excellent electron transport capability, and further, it is a material that is not reactive to air or moisture, and may be selected from semiconductor materials having excellent transparency in a visible light region.

The electron injection layer 60 may include at least one metal oxide selected from among, for example, aluminum doped zinc oxide (AZO), alkali metal (Li, Na, K, Rb, Cs or Fr) doped AZO, TiOₓ (x is a real number of 1 to 3), indium oxide (In₂O₃), tin oxide (SnO₂), zinc oxide (ZnO), zinc tin oxide, gallium oxide (Ga₂O₃), tungsten oxide (WO₃), aluminum oxide, titanium oxide, vanadium oxide (V₂O₅, vanadium(IV) oxide(VO₂), V₄O₇, V₅O₉, or V₂O₃), molybdenum oxide (MoO₃ or MoOₓ), copper oxide (Copper(II) Oxide: CuO), nickel oxide (NiO), copper aluminum oxide (Copper Aluminum Oxide: CAO, CuAlO₂), Zinc Rhodium Oxide: ZRO, ZnRh₂O₄, iron oxide, chromium oxide, bismuth oxide, IGZO (indium-Gallium Zinc Oxide), and ZrO₂, but is not limited thereto. As an example, the electron injection layer 60 may be a metal oxide thin film layer, a metal oxide nanoparticle layer, or a layer including metal oxide nanoparticles in the metal oxide thin film.

The electron injection layer 60 may be formed using a wet process or a vapor deposition method.

As an example of a wet process, when the electron injection layer 60 is formed by a solution method (ex. a sol-gel method), mixture solution for electron injection layer, which includes at least one of a sol-gel precursor of a metal oxide, and solvent and a metal oxide in the form of nanoparticles is applied on the substrate 10 and then the electron injection layer is formed by heat treatment. In this case, the solvent may be removed by heat treatment or the electron injection layer 60 may be crystallized. The method of providing the mixture for the electron injection layer on the substrate 10 may be selected from a known coating method, for example, a spin coating method, a cast method, a Langmuir-Blodgett (LB) method, a spray coating method, a dip coating method, gravure coating method, a reverse offset coating method, a screen printing method, a slot-die coating method, a nozzle printing method, and a dry transfer printing method, but the present invention is not limited thereto.

The sol-gel precursor of the metal oxide may include at least one selected from the group consisting of a metal salt (e.g, metal halide, metal sulfate, metal nitrate, metal perchlorate, metal acetate, metal carbonate, etc.), metal salt hydrate, metal hydroxide, metal alkyl, metal alkoxide, metal carbide, metal acetylacetonate, metal acid, metal acid salt, metal acid hydrate, metal sulfide, metal acetate, metal alkanoate, metal phthalocyanine, metal nitride, and metal carbonate.

When the metal oxide is ZnO, the ZnO sol-gel precursor may include at least one selected from the group consisting of zinc sulfate, zinc fluoride, zinc chloride, zinc bromide, zinc iodide, zinc perchlorate, zinc hydroxide (Zn(OH)₂), zinc acetate (Zn(CH₃COO)₂), zinc acetate hydrate (Zn(CH₃(COO)₂.nH₂O), diethyl zinc (Zn(CH₃CH₂)₂), zinc nitrate (Zn(NO₃)₂), zinc nitrate hydrate (Zn(NO₃)₂.nH₂O), zinc carbonate (Zn(CO₃)), zinc acetylacetonate (Zn(CH₃COCHCOCH₃)₂), and zinc acetylacetonate hydrate (Zn(CH₃COCHCOCH₃)₂.nH₂O), but it is not limited thereto.

When the metal oxide is indium oxide (In₂O₃), the In₂O₃ sol-gel precursor may include at least one selected from the group consisting of nitric acid (nH₂O), indium acetate (In(CH₃COO)₂), indium acetate hydrate (In(CH₃(COO)₂.nH₂O), indium chloride (InCl, InCl₂, InCl₃), indium nitrate (In(NO₃)₃), indium nitrate hydrate (In(NO₃)₃.nH₂O), indium acetylacetonate (In(CH₃COCHCOCH₃)₂), and indium acetylacetonate hydrate (In(CH₃COCHCOCH₃)₂.nH₂O).

When the metal oxide is tin oxide (SnO₂), the SnO₂ sol-gel precursor may include at least one selected from the group consisting of tin acetate (Sn(CH₃COO)₂), tin acetate hydrate (Sn(CH₃(COO)₂nH₂O), tin chloride (SnCl₂, SnCl₄), tin chloride hydrate (SnClₙ.nH₂O), tin acetylacetonate (Sn(CH₃COCHCOCH₃)₂), and tin acetylacetonate hydrate (Sn(CH₃COCHCOCH₃)₂.nH₂O).

When the metal oxide is gallium oxide (Ga₂O₃), the Ga₂O₃ sol-gel precursor may include at least one selected from the group consisting of gallium nitrate (Ga(NO₃)₃), gallium nitrate hydrate (Ga(NO₃)₃nH₂O), gallium acetylacetonate (Ga(CH₃COCHCOCH₃)₃)), gallium acetylacetonate hydrate (Ga(CH₃COCHCOCH₃)₃.nH₂O), and gallium chloride (Ga₂Cl₄, GaCl₃).

When the metal oxide is tungsten oxide (WO₃), the WO₃ sol-gel precursor may include at least one selected from the group consisting of tungsten carbide (WC), tungstic acid powder (H₂WO₄), tungsten chloride (WCl₄, WCl₆), tungsten isopropoxide (W(OCH(CH₃)₂)₆), sodium tungstate (Na₂WO₄), sodium tungstate hydrate (Na₂WO₄.H₂O), ammonium tungstate ((NH₄)₆H₂W₁₂O₄₀), ammonium tungstate hydrate ((NH₄)₆H₂W₁₂O₄₀.nH₂O), and tungsten ethoxide (W(OC₂H₅)₆).

When the metal oxide is aluminum oxide, the aluminum oxide sol-gel precursor may include at least one selected from the group consisting of aluminum chloride (AlCl₃), aluminum nitrate (Al(NO₃)₃), aluminum nitrate hydrate (Al(NO₃)₃.nH₂O), and aluminum butoxide (Al(C₂H₅CH(CH₃)O)).

When the metal oxide is titanium oxide, the titanium oxide sol-gel precursor may include at least one selected from the group consisting of titanium isopropoxide (Ti(OCH(CH₃)₂)₄), titanium chloride (TiCl₄), titanium ethoxide (Ti(OC₂H₅)₄)), and titanium butoxide (Ti(OC₄H₉)₄).

When the metal oxide is vanadium oxide, the sol-gel precursor of vanadium oxide may include at least one selected from the group consisting of vanadium isopropoxide (VO(OC₃H₇)₃), ammonium vanadate (NH₄VO₃), vanadium acetylacetonate (V(CH₃COCHCOCH₃),), and vanadium acetylacetonate hydrate (V(CH₃COCHCOCH₃)₃.nH₂O).

When the metal oxide is molybdenum oxide, the molybdenum oxide sol-gel precursor may include at least one selected from the group consisting of molybdenum isopropoxide (Mo(OC₃H₇)₅), molybdenum chloride isopropoxide (MoCl₃(OC₃H₇)₂)), ammonium molybdenate ((NH₄)₂MoO₄), and ammonium molybdenate hydrate ((NH₄)₂MoO₄.nH₂O).

When the metal oxide is copper oxide, the copper oxide sol-gel precursor may include at least one selected from the group consisting of copper chloride (CuCl, CuCl₂), copper chloride hydrate (CuCl₂.nH₂O), copper acetate (Cu(CO₂CH₃), Cu(CO₂CH₃)₂), copper acetate hydrate (Cu(CO₂CH₃)₂.nH₂O), copper acetylacetonate (Cu(C₅H₇O₂)₂), copper nitrate (Cu(NO₃)₂), copper nitrate hydrate (Cu(NO₃)₂.nH₂O), copper bromide (CuBr, CuBr₂), copper carbonate (CuCO₃ Cu(OH)₂), copper sulfide (Cu₂S, CuS), copper phthalocyanine (C₃₂H₁₆N₈Cu), copper trifluoroacetate (Cu(CO₂CF₃)₂), copper isobutyrate (C,H₁₄CuO₄), copper ethylacetoacetate (C₁₂H₁₈CuO₆)), copper 2-ethylhexanoate ([CH₃(CH₂)₃CH(C₂H,)CO₂]₂Cu), copper fluoride (CuF₂), copper formate hydrate ((HCO₂)₂CuH₂O), copper gluconate (C₁₂H₂₂CuO₁₄), copper hexafluoroacetylacetonate (Cu(C₅HF₆O₂)₂), copper hexafluoroacetylacetonate hydrate (Cu(C₅HF₆O₂)₂.nH₂O), copper methoxide (Cu(OCH₃)₂), copper neodecanoate (C₁₀H₁₉O₂Cu), copper perchlorate hydrate (Cu(ClO₄)₂.6H₂O), copper sulfate (CuSO₄), copper sulfate hydrate (CuSO₄.nH₂O), copper tartrate hydrate ([—CH(OH)CO₂]₂Cu.nH₂O), copper trifluoroacetylacetonate (Cu(C₅H₄F₃O₂)₂), copper trifluoromethanesulfonate ((CF₃SO₃)₂Cu), and tetraamine copper sulfate hydrate (Cu(NH₃)₄SO₄.H₂O).

When the metal oxide is iron oxide, the sol-gel precursor of iron oxide may include at least one selected from the group consisting of iron acetate (Fe(CO₂CH₃)₂), iron chloride (FeCl₂, FeCl₃), iron chloride hydrate (FeCl₃.nH₂O), iron acetylacetonate (Fe(C₅H₇O₂)₃), iron nitrate hydrate (Fe(NO₃)₃.9H₂O), iron phthalocyanine (C₃₂H₁₆FeN₈), iron oxalate hydrate (Fe(C₂O₄).nH₂O, and Iron(III) oxalate hexahydrate (Fe₂(C₂O₄)₃.6H₂O).

When the metal oxide is chromium oxide, the chromium oxide sol-gel precursor may include at least one selected from the group consisting of chromium chloride (CrCl₂, CrCl₃), chromium chloride hydrate (CrCl₃.nH₂O), chromium carbide (Cr₃C₂), chromium acetylacetonate (Cr(C₅H₇O₂)₃), chromium nitrate hydrate (Cr(NO₃)₃.nH₂O), chromium hydroxide (CH₃CO₂)₇Cr₃(OH)₂, and chromium acetate hydrate ([(CH₃CO₂)₂CrH₂O]₂).

When the metal oxide is bismuth oxide, the bismuth oxide sol-gel precursor may include at least one selected from the group consisting of bismuth chloride (BiCl₃), bismuth nitrate hydrate (Bi(NO₃)₃.nH₂O), bismuth acetic acid ((CH₃CO₂)₃Bi), and bismuth carbonate ((BiO)₂CO₃).

When the metal oxide nanoparticles are contained in the mixed solution for the electron injection layer, the average particle diameter of the metal oxide nanoparticles may be 10 nm to 100 nm.

The solvent may be a polar solvent or a non-polar solvent. For example, examples of the polar solvent include alcohols or ketones, and examples of the nonpolar solvent include aromatic hydrocarbons, alicyclic hydrocarbons, or aliphatic hydrocarbon-based organic solvents. As an example, the solvent may include at least one selected from the group consisting of ethanol, dimethylformamide, ethanol, methanol, propanol, butanol, isopropanol, methyl ethyl ketone, propylene glycol (mono) methyl ether (PGM), isopropyl cellulose (IPC), ethylene carbonate (EC), methyl cellosolve (MC), ethyl cellosolve, 2-methoxy ethanol and ethanol amine. But it is not limited thereto.

For example, when forming the electron injection layer 60 made of ZnO, the mixture for the electron injection layer may include zinc acetate dehydrate as a precursor of ZnO, and combination of 2-methoxy ethanol and ethanolamine as solvents, but it is not limited thereto.

The heat treatment conditions will vary depending on the type and content of the selected solvent, but it is generally preferably performed within the range of 100° C. to 350° C., and 0.1 hour to 1 hour. When the heat treatment temperature and time satisfy this range, the solvent removal effect is good and the device may not be deformed.

When the electron injection layer 60 is formed using a vapor deposition method, it can be deposited by a variety of known methods such as electron beam deposition, thermal evaporation, sputter deposition, atomic layer deposition, chemical vapor deposition. The deposition conditions vary depending on the target compound, the structure of the target layer, and thermal properties, but for example, the deposition temperature range of 25° C. to 1500° C., specifically 100° C. to 500° C., and the vacuum degree range of 10⁻¹⁰ to 10⁻³ torr is preferred, and the deposition rate is performed within the range of 0.01 to 100 Å/sec.

The electron injection layer 60 may have a thickness of 1 nm to 100 nm. For example, the thickness of the electron injection layer is 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, or 100 nm. The thickness of the hole injection layer can be defined as a range that takes the lower value as the minimum value and the larger value as the maximum value out of the two numbers selected above. In addition, preferably, the thickness of the electron injection layer may be 15 nm to 60 nm.

The hole injection layer 30, the hole transport layer, the electron injection layer 60, or the electron transport layer 50 may include materials used in conventional organic light-emitting diodes.

The hole injection layer 30, the hole transport layer, the electron injection layer 60 or the electron transport layer 50 may be formed by performing a method arbitrarily selected from a variety of known methods such as a vacuum deposition method, a spin coating method, a spray method, a dip coating method, a bar coating method, a nozzle printing method, a slot-die coating method, a gravure printing method, a cast method, or a Langmuir-Blodgett (LB) method. The conditions and coating conditions for forming the thin film may vary depending on the target compound, the structure and thermal properties of the target layer.

The substrate 10 serves as a support for the light-emitting device and may be a transparent material. In addition, the substrate 10 may be a flexible material or a hard material, and preferably may be a flexible material.

The material of the substrate 10 may include glass, sapphire, quartz, silicon, polyethylene terephthalate (PET), polystyrene (PS), and polyimide (PI), polyvinyl chloride (PVC), polyvinylpyrrolidone (PVP), or polyethylene (PE), but it is not limited thereto.

The substrate 10 may be located under the anode 20 or may be located above the cathode 70. In other words, the anode 20 may be formed before the cathode deposition 70 on the substrate, or the cathode 70 may be formed before the anode deposition 20. Accordingly, the light-emitting device may have both the normal structure of FIG. 14 and the inverse structure of FIG. 15.

The light emission layer 40 is formed between the hole injection layer 30 and the electron injection layer 60, and the holes (h) introduced from the anode 20 and the electrons (e) introduced from the cathode 70 are combined. As a result, excitons are formed, and light is emitted while the excitons transit to a ground state.

In the light-emitting device according to the present invention, the light emission layer 40 is characterized in that it includes the metal halide perovskite described above.

The metal halide perovskite may be a material having a three-dimensional crystal structure, a two-dimensional crystal structure, a one-dimensional crystal structure, or a zero-dimensional crystal structure.

The metal halide perovskite is ABX₃(3D), A₄BX₆(0D), AB₂X₅(2D), A₂BX₄(2D), A₂BX₆(0D), A₂B⁺B³⁺X₆(3D), A₃B₂X₉(2D) or Aₙ₋₁BₙX₃ₙ₊₁ (quasi-2D) (n is an integer between 2 and 6). A is a monovalent cation, B is a metal material, and X may be a halogen element. Specific examples of A, B, and X of the metal halide perovskite are as described in the section of <Metal Halide Perovskite Crystal>.

### <Metal Halide Perovskite Light-Emitting Transistor>

In particular, when the light-emitting device is a light-emitting transistor, it may have a higher color purity than a conventional organic semiconductor-based light-emitting transistor, and field-effect mobility and on/off ratio are increased, so that switching properties can be improved, and manufacturing costs can be reduced.

The metal halide perovskite light-emitting transistor includes a gate electrode, a semiconductor layer, a gate insulating film located between the semiconductor layer and the gate electrode, and a light-emitting transistor including a source electrode and a drain electrode electrically connected to the semiconductor layer. In this case, it may be characterized in that it has a semiconductor layer including a metal halide perovskite.

The substrate may be used as a support for an electrode, a semiconductor layer, or the like formed on the substrate, and any substrate used in a known organic light-emitting transistor may be used. The substrate, for example, may be a metal substrate such as carbon (C), iron (Fe), chromium (Cr), manganese (Mn), nickel (Ni), titanium (Ti), molybdenum (Mo), stainless steel (SUS), a plastic substrate such as polyethylene naphthalate (PEN), polyethylene terephthalate (PET), polyphenylene sulfide (PPS), polyallylate, polyimide, polyester, polyetherimide (PEI), polyacrylate (PAR), or polycarbonate, or a glass substrate, but it is not limited thereto.

The source electrode, the drain electrode, and the gate electrode may include at least one selected from the group consisting of a metal, a conductive polymer, a carbon material-doped semiconductor, and a combination thereof. For example, gold (Au), platinum (Pt), chromium (Cr), molybdenum (Mo), nickel (Ni), aluminum (Al), graphene, an alloy thereof, or inorganic oxide materials such as indium zinc oxide (IZO) or indium tin oxide (ITO) may be used.

The gate insulating layer is formed between the gate electrode and the semiconductor layer for stability of the light emitting transistor, and may include self-assembled molecules selected from the group consisting of a carboxyl group (—COOH), a hydroxyl group (—OH), a thiol group (—SH), and a trichlorosilane group (—SiCl₃), and may be made of any one selected from the group consisting of metals, insulating polymers, inorganic oxides, polymer electrolytes, and combinations thereof.

The metal halide perovskite used in the semiconductor layer may be a material having a three-dimensional crystal structure, a two-dimensional crystal structure, a one-dimensional crystal structure, or a zero-dimensional crystal structure.

The metal halide perovskite is ABX₃(3D), A₄BX₆(0D), AB₂X₅(2D), A₂BX₄(2D), A₂BX₆(0D), A₂B⁺B³⁺X₆(3D), A₃B₂X₉(2D) or Aₙ₋₁BₙX₃ₙ₊₁ (quasi-2D) (n is an integer between 2 and 6) may be included. A is a monovalent cation, B is a metal material, and X may be a halogen element. Specific examples of A, B, and X of the metal halide perovskite are as described in <Metal Halide Perovskite Crystal>.

The metal halide perovskite light-emitting transistor may have a bottom-gate/top-contact, a bottom-gate/bottom-contact, a top-gate/top-contact, or a top-gate/bottom-contact structure.

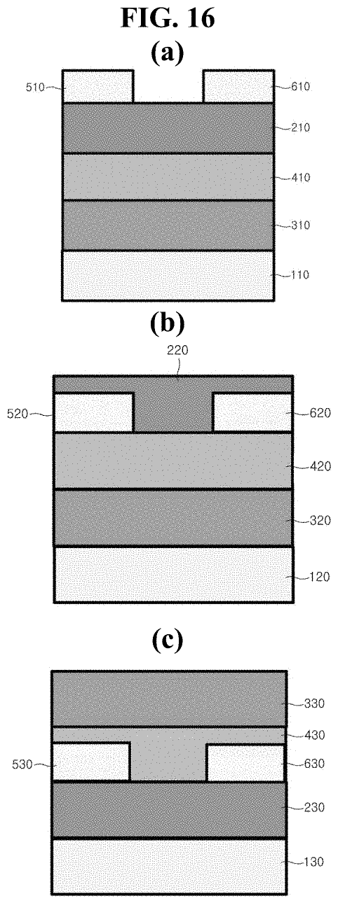

Referring to FIG. 16(a), in an embodiment of the present invention, the metal halide perovskite light-emitting transistor may have a bottom gate/top-contact structure. Specifically, the gate electrode 310 and the gate insulating layer 410 may be sequentially located on the substrate 110, and the semiconductor layer 210 including a metal halide perovskite may be located on the gate insulating layer 410. Also, a source electrode 510 and a drain electrode 610 may be located on the semiconductor layer 210 to be electrically connected to the semiconductor layer 210

Referring to FIG. 16(b), in another embodiment of the present invention, the metal halide perovskite light-emitting transistor may have a bottom-gate/bottom-contact structure. Specifically, the gate electrode 320 and the gate insulating layer 420 may be sequentially located on the substrate 120, and the source electrode 520 and the drain electrode 620 may be located on the gate insulating layer 420. So as to be electrically connected to the source electrode 520 and the drain electrode 620, the semiconductor layer 220 including a metal halide perovskite may be located as covering the source electrode 520 and the drain electrode 620 form on the gate insulating layer 420.

Referring to FIG. 16(c), in another embodiment of the present invention, the metal halide perovskite light-emitting transistor may have a top-gate/top-contact structure. Specifically, a semiconductor layer 230 including a metal halide perovskite may be located on the substrate 130, and the source electrode 530 and the drain electrode 630 can be located on the semiconductor layer 230 to be electrically connected to the semiconductor layer 230. A gate insulating layer 430 may be located to cover the source electrode 530 and the drain electrode 630, and the gate electrode 330 may be located on the gate insulating layer 430.

Referring to FIG. 16(d), in another embodiment of the present invention, the metal halide perovskite light-emitting transistor may have a top gate/bottom-contact structure. Specifically, the source electrode 540 and the drain electrode 630 may be located on the substrate 140, and the source electrode 540 may be electrically connected to the drain electrode 630. A semiconductor layer 240 including a metal halide perovskite may be located to cover the 540 and the drain electrode 630. A gate insulating layer 440 may be located on the semiconductor layer 240, and a gate electrode 340 may be located on the gate insulating layer 440.

As described above, in the metal halide perovskite light-emitting transistor of the present invention, a semiconductor layer including a metal halide perovskite can be applied to various structures.

It may further include at least one of an electron transport layer and a hole transport layer located above or below the semiconductor layer.

FIG. 19(a) to 19(d) are schematic diagrams showing the structure of a metal halide perovskite light-emitting transistor according to another embodiment of the present invention.

Specifically, FIG. 19(a) to 19(d) show an upper or lower part of the semiconductor layer in the light-emitting transistor in the case of a metal halide perovskite light-emitting transistor having a bottom-gate/top-contact structure of the present invention. It may further include at least one of the electron transport layer and the hole transport layer.

Referring to FIG. 19(a), in an embodiment of the present invention, an electron transport layer 750 may be further located under the semiconductor layer 250. Specifically, the gate electrode 350 and the gate insulating layer 450 are sequentially located on the substrate 150, the electron transport layer 750 may be located first before the semiconductor layer 250 is located on the gate insulating layer 450, and a semiconductor layer 250 including the metal halide perovskite may be located on the electron transport layer 750. Thereafter, a source electrode 550 and a drain electrode 650 may be located on one end and the other end of the semiconductor layer 250 so that they are electrically connected to the semiconductor layer 250 on the semiconductor layer 250.

Referring to FIG. 19(b) in another embodiment of the present invention, a hole transport layer 860 may be further located under the semiconductor layer 260. Specifically, the gate electrode 360 and the gate insulating layer 460 are sequentially located on the substrate 160, the hole transport layer 860 is located on the gate insulating layer 460 before the semiconductor layer 260 is located on the gate insulating layer 260, and a semiconductor layer 260 including metal halide perovskite may be located on the hole transport layer 860. Thereafter, a source electrode 560 and a drain electrode 660 may be located on one end and the other end of the semiconductor layer 260 so that they are electrically connected to the semiconductor layer 260 on the semiconductor layer 260.

Referring to FIG. 19(c), in another embodiment of the present invention, an electron transport layer 770 may be located under the semiconductor layer 270, and a hole transport layer 870 may be further located on the semiconductor layer 270. Specifically, the gate electrode 370 and the gate insulating layer 470 are sequentially located on the substrate 170, and the electron transport layer 770 is first located on the gate insulating layer 470 and, and the semiconductor layer 270 including a metal halide perovskite may be located on the electron transport layer 770. Thereafter, a hole transport layer 870 may be located on the semiconductor layer 270, and a source electrode 570 and a drain electrode 670 may be located at one end and the other end of the hole transport layer 870.

Referring to FIG. 19(d), in another embodiment of the present invention, a hole transport layer 880 is located under the semiconductor layer 280, and an electron transport layer 780 is further located on the semiconductor layer 280. Specifically, a gate electrode 380 and a gate insulating layer 480 are sequentially located on the substrate 180, a hole transport layer 880 is first located on the gate insulating layer 480, and the semiconductor layer 280 including a metal halide perovskite may be located on the hole transport layer 880. Thereafter, an electron transport layer 780 may be located on the semiconductor layer 280, and a source electrode 580 and a drain electrode 680 may be located at one end and the other end of the electron transport layer 780.

According to an embodiment, even when the metal halide perovskite light-emitting transistor has a bottom-gate/bottom-contact, top-gate/top-contact, or top-gate/bottom-contact structure in addition to the above-described bottom-gate/top-contact structure, as shown in FIGS. 19(a) and 19(d), at least one of an electron transport layer and a hole transport layer may be located above or below the semiconductor layer.

The metal halide perovskite may have a polycrystal or single crystal structure.

FIGS. 20(a) and 20(b) are schematic diagrams illustrating a light-emitting transistor in which a semiconductor layer including a metal halide perovskite having a polycrystal structure is located according to an embodiment of the present invention.

Referring to FIG. 20(a), a semiconductor layer including a metal halide perovskite having a polycrystal structure according to an embodiment of the present invention may be located in a bottom-gate/bottom-contact structure. Specifically, the gate electrode 301 and the gate insulating film 401 are sequentially located on the substrate 101, and the source electrode 501 and the drain electrode 601 may be located at one end and the other end of the gate insulating film 401. A semiconductor layer 201 including a metal halide perovskite having the polycrystal structure may be located to cover the source electrode 501 and the drain electrode 601 so that it is electrically connected to the source electrode 501 and the drain electrode 601.

Referring to FIG. 20(b), a semiconductor layer including a metal halide perovskite having a polycrystal structure according to another embodiment of the present invention may be located in a bottom-gate/top-contact structure. Specifically, a gate electrode 302 and a gate insulating film 402 are sequentially located on a substrate 102, and a semiconductor layer 202 including a metal halide perovskite having the polycrystal structure on the gate insulating film 402 can be positioned. Thereafter, a source electrode 502 and a drain electrode 602 are formed at one end and the other end of the semiconductor layer 202 so that the semiconductor layer 202 is electrically connected to the source electrode 502 and the drain electrode 602 can be placed.

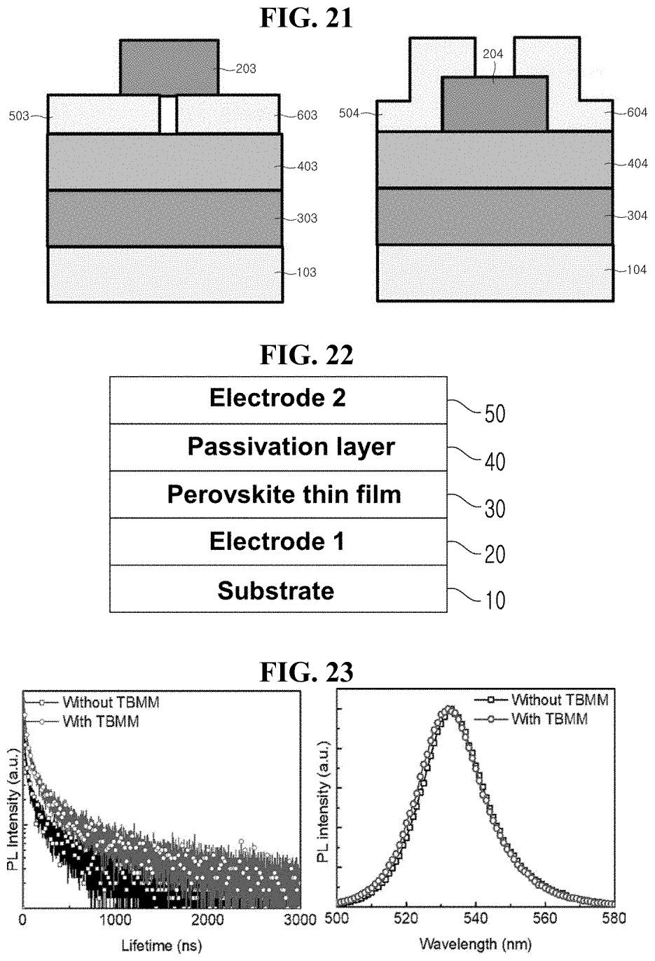

FIG. 21(a) to 21(b) are schematic diagrams showing a light-emitting transistor in which a semiconductor layer including a metal halide perovskite having a single crystal structure is located according to another embodiment of the present invention.

Referring to FIG. 21(a), a semiconductor layer including a metal halide perovskite having a single crystal structure according to another embodiment of the present invention may be located in a bottom-gate/bottom-contact structure. Specifically, the gate electrode 302 and the gate insulating film 403 are sequentially located on the substrate 103, and the source 503 electrode and the drain electrode 603 are located at one end and the other end of the gate insulating film 403. A semiconductor layer 203 including metal halide perovskite having polycrystal structure can be located on the source electrode 503 and the drain electrode 603 to be electrically connected to the source electrode 503 and the drain electrode 603.

Referring to FIG. 21(b), a semiconductor layer including a metal halide perovskite having a single crystal structure according to another embodiment of the present invention may be located in a bottom-gate/top-contact structure. Specifically, a semiconductor layer 204 including a metal halide perovskite having the single crystal structure in the upper center of the gate electrode 304 and the gate insulating film 404 are sequentially located on the substrate 104 may be located. Thereafter, the source electrode 504 and a drain electrode 604 may be positioned in a form in which a portion of one end and the other end region of the semiconductor layer 204 is electrically connected to the source electrode 504 and the drain electrode 604.

As described above, when a semiconductor layer including a metal halide perovskite having a single crystal structure is located in a bottom-gate/top-contact structure, the channel length may be 1 μm or less.

Hereinafter, a method of manufacturing a metal halide perovskite light-emitting transistor according to an embodiment of the present invention will be described.

The method of manufacturing the metal halide perovskite light-emitting transistor includes a step of forming a semiconductor layer made of a nanocrystal thin film in which a metal halide perovskite nanocrystal is formed on a substrate or the gate insulating layer by coating a solution containing perovskite nanoparticles based on a method of manufacturing a transistor commonly used in the art.

The solution containing the organic-inorganic metal halide perovskite nanoparticles in which the metal halide perovskite nanocrystals are formed is a first solution in which a metal halide perovskite is dissolved in a protic solvent. A second solution in which an alkyl halide surfactant is dissolved in an aprotic solvent may be prepared, and the first solution may be mixed with the second solution to form nanoparticles.

The protic solvent may include dimethylformamide, gamma butyrolactone or N-methylpyrrolidone, or dimethylsulfoxide, but is limited thereto.

The metal halide perovskite may be a material having a polycrystal or single crystal structure.

On the other hand, such a metal halide perovskite can be prepared by combining AX and BX₂ in a certain ratio. That is, the first solution may be formed by dissolving AX and BX₂ in a protic solvent at a predetermined ratio. For example, a first solution in which A₂BX₃ metal halide perovskite is dissolved may be prepared by dissolving AX and BX₂ in a ratio of 2:1 in a protic solvent.

In addition, the aprotic solvent may be dichloroethylene, trichloroethylene, chloroform, chlorobenzene, dichlorobenzene, styrene, dimethylformamide, dimethylsulfoxide, xylene, toluene, cyclohexene or isopropyl alcohol, but is not limited thereto.

The surfactant may include the aforementioned alkyl halide, amine ligand, carboxylic acid or phosphonic acid.

Then, the first solution may be mixed with the second solution to form nanoparticles. Mixing the first solution with the second solution to form nanoparticles may be mixing the first solution drop by drop into the second solution. In addition, the second solution at this time may be stirred. For example, nanoparticles may be synthesized by slowly adding a second solution in which organic-inorganic metal halide perovskite (OIP) is dissolved in a second solution in which a surfactant being strongly stirred is dissolved.

In this case, when the first solution is dropped into the second solution and mixed, organic-inorganic metal halide perovskite (OIP) is precipitated in the second solution due to a difference in solubility. The organic-inorganic metal halide perovskite (OIP) precipitated in the second solution is stabilized by an alkyl halide surfactant to form well-dispersed organic-inorganic metal halide perovskite nanocrystals (OIP-NC). Accordingly, it is possible to prepare an organic-inorganic hybrid metal halide perovskite nanoparticle including an organic-inorganic metal halide perovskite nanocrystal and a plurality of alkyl halide organic ligands surrounding the organic-inorganic metal halide perovskite nanocrystal.

Meanwhile, the size of the organic-inorganic metal halide perovskite nanocrystal particles can be controlled by controlling the length or shape factor and amount of the alkyl halide surfactant. For example, the shape factor control can control the size through a linear, tapered, or inverted triangular surfactant.

That is, the metal halide perovskite nanoparticles according to the present invention can be prepared through an inverse nano-emulsion method.

Meanwhile, as an example of the synthesis of AX, when A is CH₃NH₃ and X is Br, CH₃NH₂ (methylamine) and HBr (hydroiodic acid) are dissolved in a nitrogen atmosphere to obtain CH₃NH₃Br through solvent evaporation. When the first solution is added to the second solution, a metal halide perovskite is precipitated in the second solution due to a difference in solubility, and the precipitated metal halide perovskite is surrounded by an alkyl halide surfactant while stabilizing the surface, it may be to generate metal halide perovskite nanoparticles including well-dispersed metal halide perovskite nanocrystals. The surface of the metal halide perovskite nanocrystal may be surrounded by organic ligands that are alkyl halide.

Thereafter, metal halide perovskite nanoparticles can be obtained by selectively evaporating by applying heat to a protic solvent including the metal halide perovskite nanoparticles, or selectively extracting protic solvent by adding a co-solvent that can dissolve both a protic solvent and aprotic solvent.

In another embodiment of the present invention, the forming of the semiconductor layer may include mixing an organic semiconductor with a solution containing the organic-inorganic metal halide perovskite nanoparticles to form an organic-inorganic metal halide perovskite-organic semiconductor solution. And a semiconductor layer is formed by spin coating the organic-inorganic metal halide perovskite-organic semiconductor solution on the substrate or the gate insulating layer.

Specifically, in the process of forming a semiconductor layer by spin coating the organic-inorganic metal halide perovskite-organic semiconductor solution, the semiconductor layer may be self-assembled layer in which an organic semiconductor layer and the organic-inorganic metal halide perovskite nanoparticles are sequentially stacked.

Specifically, first, the organic-inorganic metal halide perovskite-organic semiconductor solution may be prepared by mixing an organic semiconductor with a solution containing the organic-inorganic metal halide perovskite nanoparticles. The organic semiconductor is tris (8-quinolinorate) aluminum (Alq₃), TAZ, TPQ1, TPQ2, Bphen (4,7-diphenyl-1,10-phenanthroline (4,7-diphenyl-1,10-phenanthroline)), BCP, BeBq₂, BAlq, CBP (4,4′-N,N′-dicarbazole-biphenyl), 9,10-di(naphthalen-2-yl) anthracene (ADN), TCTA (4,4′,4″-tris(N-carbazolyl)triphenylamine), TPBI (1,3,5-tris(N-phenylbenzimidazol-2-yl)benzene(1,3,5-tris(Nphenylbenzimidazol) e-2-yl)benzene)), TBADN (3-tert-butyl-9,10-di (naphth-2-yl) anthracene), or E3, but is not limited thereto.

Thereafter, the organic-inorganic metal halide perovskite-organic semiconductor solution may be spin-coated to form a semiconductor layer. In this case, the spin coating speed is preferably 1000 rpm to 5000 rpm, and the spin coating time may be 15 seconds to 150 seconds. If the spin coating speed drops to 1000 rpm or less, or if the spin coating time is shortened to 15 seconds or less, the thin film may become non-uniform or the solvent may not evaporate.

Accordingly, the semiconductor layer of the present invention may form a nanocrystal thin film of organic-inorganic metal halide perovskite nanoparticles including organic-inorganic metal halide perovskite nanocrystals on the substrate or the gate insulating layer.

As described above, when the semiconductor layer is formed, exciton-exciton annihilation, which may occur because the nanocrystals are closely located in the existing metal halide perovskite nanocrystal layer, can be prevented. In addition, by using an organic host or co-host having a bipolar characteristic, the electron-hole recombination zone can be widened, thereby preventing exciton-exciton annihilation. Accordingly, roll-off that occurs when the metal halide perovskite light-emitting transistor operates at high luminance can be reduced.

In another embodiment of the present invention, the forming of the semiconductor layer includes forming a self-assembled monolayer on a member for depositing a semiconductor layer, and forming as organic-inorganic metal halide perovskite nanoparticles layer on the self-assembled monolayer by spin coating a solution containing organic-inorganic metal halide perovskite nanoparticles, and forming the organic-inorganic metal halide perovskite nanoparticle layer on the substrate or the gate insulating layer using a stamp process.

Specifically, the self-assembled monolayer may be formed on the semiconductor layer deposition member. In this case, a member made of silicon may be used as the member for depositing the semiconductor layer. In more detail, an octadecyltrichlorosilane (ODTS) treated wafer obtained by dipping a silicon native wafer in an ODTS solution may be used.

Thereafter, a solution including the organic-inorganic metal halide perovskite nanoparticles may be spin-coated on the self-assembled monolayer to form an organic-inorganic metal halide perovskite nanoparticle layer. Then, the organic-inorganic metal halide perovskite nanoparticle layer may be formed on the second semiconductor layer deposition member using a stamp. The stamp may be prepared by curing polydimethylsiloxane (PDMS) on a silicon wafer.

In the case of forming the semiconductor layer as described above, the problems related to substrate sensitivity, and stacking processes of large-area assembly and layer-by-layer in the existing wet processes can be solved by forming the organic-inorganic metal halide perovskite nanoparticle layer through the stamping process. In the metal halide perovskite light emitting transistor, the order of performing the steps of forming each of the substrate, the gate electrode, the gate insulating layer, the source electrode, and the drain electrode may be changed according to the structure of the transistor to be manufactured. Specifically, the structure of the metal halide perovskite light-emitting transistor implemented in the embodiment of the present invention is a bottom-gate/top-contact structure, a bottom-gate/bottom-contact structure, a top-gate/top-contact structure, or it may be a top-gate/bottom-contact structure.

Specifically, in an embodiment of the method of manufacturing the metal halide perovskite light-emitting transistor, prior to the forming of the semiconductor layer, the step of sequentially forming the gate electrode and the gate insulating layer on a substrate may be further performed. And after the step of forming the semiconductor layer, forming a source electrode and a drain electrode electrically connected to the semiconductor layer at one end and the other end of the semiconductor layer may be further performed. Specifically, this may be a method of manufacturing a metal halide perovskite light-emitting transistor having a bottom-gate/top-contact structure as shown in FIG. 16(a).

In another embodiment of the method of manufacturing the metal halide perovskite light emitting transistor, before the step of forming the semiconductor layer, the steps of sequentially forming the gate electrode, the gate insulating film, and a source electrode and a drain electrode electrically connected to one end and the other end of the semiconductor layer are further included. Specifically, this may be a method of manufacturing a metal halide perovskite light-emitting transistor having a bottom-gate/bottom-contact structure as shown in FIG. 16(b).

In another embodiment of the method of manufacturing the metal halide perovskite light emitting transistor, before the step of forming the semiconductor layer, the steps of forming a source electrode and a drain electrode electrically connected to the semiconductor layer at one end and the other end of the semiconductor layer on a substrate is further included, and after forming the semiconductor layer, the steps of sequentially forming the gate insulating layer and the gate electrode on the semiconductor layer is further included. Specifically, this may be a method of manufacturing an organic-inorganic hybrid metal halide perovskite light-emitting transistor having a top-gate/bottom-contact structure, as shown in FIG. 16(d).

In each of the above-described embodiments, forming the gate electrode, the gate insulating film, and the source electrode and the drain electrode may be performed using at least one method selected from organic nanowire lithography, drop casting, spin coating, dip coating, e-beam evaporation, thermal evaporation, printing, soft lithography, and sputtering.

In an embodiment of the present invention, the forming of the gate electrode, the gate insulating layer, the source electrode and the drain electrode may be performed using the organic nanowire lithography method. Specifically, in the organic nanowire lithography, the steps include forming an organic wire or organic-inorganic hybrid wire mask pattern having a circular or elliptical cross section on a pattern forming member, forming a target material layer on the mask pattern and removing the mask pattern to leave the target material layer in a region where the mask pattern is not formed. Here, the target material layer may be a material layer for forming a gate electrode that is a target to be formed.

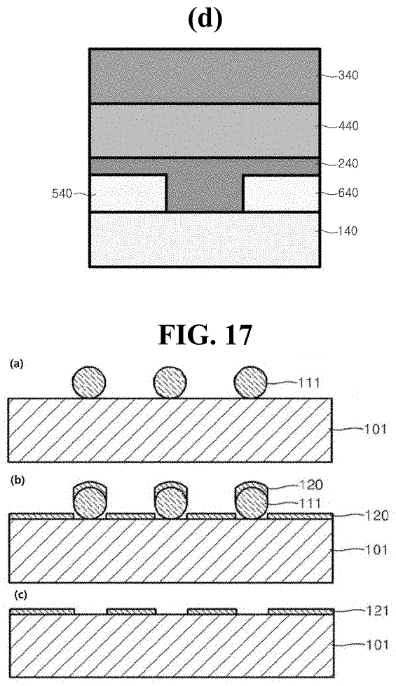

FIG. 17(a) to 17(c) are schematic diagrams showing an organic nanowire lithography process sequence according to an embodiment of the present invention.

First, as shown in FIG. 17A, an organic wire or organic-inorganic hybrid wire mask pattern 111 having a circular or elliptical cross section may be formed on the pattern forming member 101

Thereafter, referring to FIG. 17B, a target material layer 120 may be formed on the mask pattern 111. The target material layer may be formed on the mask pattern 111 and on the pattern forming member 101 as shown in FIG. 17B.

Then, when the mask pattern 111 is removed, the target material layer 121 may remain in a region where the mask pattern is not formed, as shown in FIG. 17C. Using this method, the gate electrode, the gate insulating film, the source electrode, and the drain electrode included in the metal halide perovskite light-emitting transistor of the present invention may be formed.

The organic wire or organic-inorganic hybrid wire mask pattern having a circular or elliptical cross section may be formed using electric field assisted robotic nozzle printing, direct tip drawing, and meniscus-guided direct writing, melt spinning, wet spinning, dry spinning, gel spinning, or electrospinning

Specifically, this may be performed using an electric field assisted robotic nozzle printer device as disclosed in Korean Patent Registration No. 10-1407209.

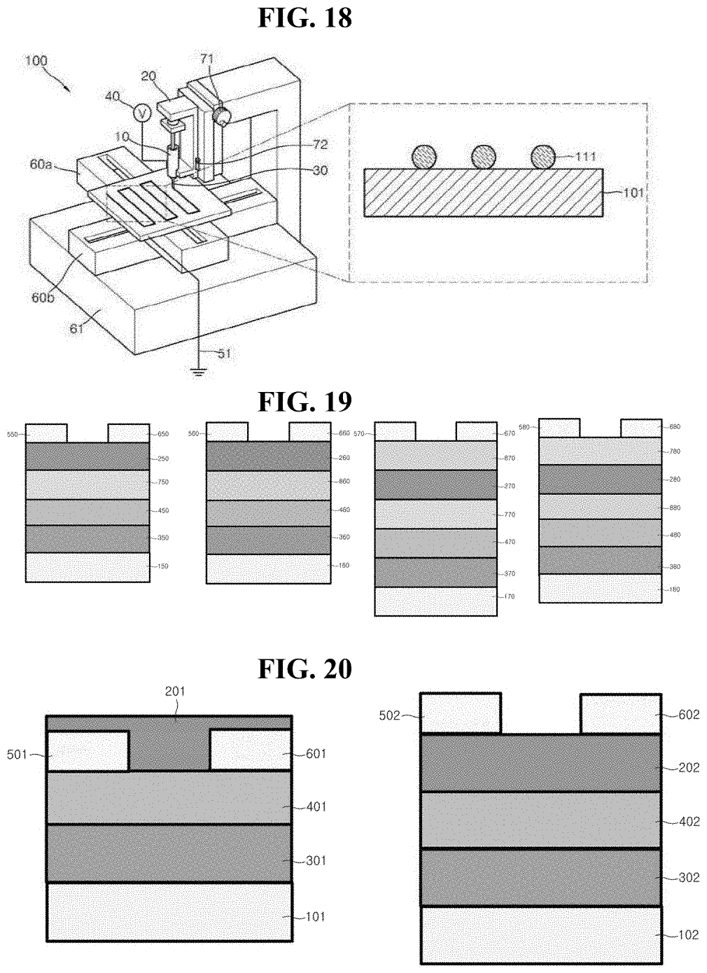

FIG. 18 is a schematic diagram of an electric field assisted robotic nozzle printer.

Referring to FIG. 18, the electric field assisted robotic nozzle printing device 100 includes a solution storage device 10 for supplying a solution for discharging, and a nozzle 30 for discharging a solution supplied from the solution storage device 10. A voltage application device 40 for applying a high voltage to the nozzle 30, a flat and movable collector 50 in which an organic wire or an organic-inorganic hybrid wire formed by being discharged from the nozzle 30 is aligned, the collector 50 a robot stage 60 installed below and capable of moving the collector 50 in the x-y direction (horizontal direction), the nozzle 30 and the collector 50 in the z direction (vertical direction) a micro-distance adjuster that adjusts the distance between the micro-distance adjusters, and a stone table 61 located under the robot stage 60 to maintain a plan view of the collector 50 and suppress vibrations generated during the operation of the robot stage 60. It may be to use the included electric field assisted robotic nozzle printer 100.

The above-described organic nanowire lithography may be performed using the electric field assisted robotic nozzle printer. Specifically, as shown in FIG. 17, an organic wire or an organic-inorganic hybrid wire mask pattern 111 may be formed on the substrate 101.

Meanwhile, according to an embodiment, before or after the step of forming the semiconductor layer, the step of forming at least one of an electron transport layer and a hole transport layer above or below the semiconductor layer may be further included.

Specifically, in an embodiment of the present invention, in the case of a metal halide perovskite light-emitting transistor having a bottom-gate/top-contact structure, as shown in FIG. 19(a), it may further include forming the electron transport layer under the semiconductor layer. Alternatively, as shown in FIG. 19(b), the step of forming a hole transport layer under the semiconductor layer may be further included. Alternatively, the step of forming an electron transport layer under the semiconductor layer and forming a hole transport layer over the semiconductor layer as shown in FIG. 19(c) may be further included. Alternatively, as shown in FIG. 19(d), forming a hole transport layer under the semiconductor layer and forming an electron transport layer over the semiconductor layer may be further included.

In detail, the electron transport layer may be formed according to a method arbitrarily selected from a variety of known methods such as a vacuum deposition method, a spin coating method, a casting method, or an LB method.

As the electron transport layer material, a known electron transport material may be used. For example, the electron transport layer is a quinoline derivative, in particular tris (8-hydroxyquinoline) aluminum (Alq₃), Bis(2-methyl-8-quinolinolate)-4-(phenylphenolato)aluminium (Balq), bis(10-hydroxybenzo[h] quinolinato)-beryllium (Bebq₂), 2,9-dimethyl-4,7-diphenyl-1,10-phenanthroline (BCP), 4,7-diphenyl-1,10-phenanthroline: Bphen, 2,2,2 (benzene-1,3,5-triyl)-Tris(1-phenyl-1H-benzimidazole) (TPBI), 3-(4-Biphenyl)-4-(phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-diphenyl-1,10-phenanthroline (NBphen), tris(2,4,6-trimethyl-3-(pyridin-3-yl)phenyl)borane (3TPYMB), phenyl-dipyrenylphosphine oxide: POPy₂, 3,3,5,5 Tetra[(m-pyridyl)-phen-3-yl]biphenyl (BP4mPy), 1,3,5-tri[(3-pyridyl)-phen-3-yl]benzene (TmPyPB), 1,3-Bis[3,5-di(pyridin-3-yl)phenyl]benzene (BmPyPhB), bis(10-hydroxybenzo) [h]quinolinato)beryllium (Bepq₂), diphenylbis(4-(pyridin-3-yl)phenyl)silane (DPPS), 1,3,5-tri(p-pyrid-3-yl-phenyl)benzene (TpPyPB), 1,3-bis[2-(2,2bipyridin-6-yl)-1,3,4-oxadiazo-5-yl]benzene (Bpy-OXD), or 6,6 bis[5-(biphenyl-4-yl)-1,3,4-oxadiazo-2-yl]-2,2bipyridyl (BP-OXD-Bpy), but is not limited thereto.

In addition, the hole transport layer may be formed according to a method arbitrarily selected from among various known methods such as a vacuum deposition method, a spin coating method, a cast method, or an LB method. In the case of selecting the vacuum deposition method, the deposition conditions vary depending on the target compound, the structure of the target layer, and thermal properties, but for example, the deposition temperature range of 100° C. to 500° C., the vacuum degree range of 10⁻¹⁰ to 10⁻³ torr, and a range of a deposition rate of 0.01 Å/sec to 100 Å/sec may be selected. On the other hand, in the case of selecting the spin coating method, the coating conditions are different depending on the target compound, the structure of the target layer, and thermal properties, but the coating speed range of 2000 rpm to 5000 rpm, the heat treatment temperature of 80 to 200° C. (after coating heat treatment temperature for solvent removal) may be selected within the range.

The hole transport layer material may be selected from materials capable of better transporting holes than hole injection. The hole transport layer may be formed using a known hole transport material. For example, the hole transport layer may be an amine-based material having an aromatic condensed ring or a triphenyl amine-based material.

More specifically, the hole transporting material is, 1,3-bis(carbazol-9-yl)benzene (MCP), 1,3,5-tris(carbazol-9-yl)benzene (TCP), 4,4′,4″-tris(carbazol-9-yl)triphenylamine (TCTA), 4,4′-bis(carbazol-9-yl)biphenyl (CBP), N,N′-bis(naphthalen-1-yl)-N,N′-bis(phenyl)benzidine (NPB), N,N′-bis(naphthalen-2-yl))-N,N′-bis(phenyl)-benzidine (β-NPB), N,N′-bis(naphthalen-1-yl)-N,N′-bis(phenyl)-2,2′-dimethylbenzidine (αNPD), (Di-[4-(N,N-ditolyl-amino)-phenyl]cyclohexane (TAPC), N,N,N′,N′-tetra-naphthalen-2-yl-benzidine (β-TNB) and N4,N4,N4′,N4′-tetra(biphenyl-4-yl)biphenyl-4,4′-diamine (TPD15), poly(9,9-dioctylfluorene-co-bis-N,N′-(4-butylphenyl)-bis-N,N′-phenyl-1,4-phenylenediamine) (PFB), poly(9,9′-dioctylfluorene-co-N-(4-butylphenyl)diphenylamine) (TFB), poly(9,9′-dioctylfluorene-co-bis-N,N′-(4-butylphenyl)-bis-N,N′-phenylbenzidine) (BFB), or poly(9,9-dioctylfluorene-co-bis-N,N′-(4-methoxyphenyl)-bis-N,N′-phenyl-1,4-phenylenediamine) (PFMO), but is not limited thereto.

The thickness of the hole transport layer may be 5 nm to 100 nm, for example, 10 nm to 60 nm. When the thickness of the hole transport layer satisfies the above-described range, excellent hole transport characteristics can be obtained without an increase in driving voltage.

### <Metal Halide Perovskite Light-Emitting Device Including Passivation Layer>

According to still another embodiment of the present invention, the light-emitting device may include a passivation layer capable of reducing defects in the metal halide perovskite thin film and eliminating charge imbalance.

Metal halide perovskite nanocrystal particles having improved properties that can be applied to various electronic devices exhibit improved luminescence efficiency by confining excitons to a very small size. In addition, even a bulk polycrystal film having a very small grain size may exhibit improved luminescence efficiency through exciton confinement. However, the metal halide perovskite light emission layer shows relatively low luminescence efficiency because surface defects still exist, and it causes charge carrier imbalance in the light-emitting device to show low luminescence efficiency. Accordingly, defects of the metal halide perovskite thin film may be reduced and charge imbalance may be eliminated by further including a passivation layer in the light-emitting device.

A metal halide perovskite light-emitting device comprising a passivation layer according to the present invention includes a metal halide perovskite thin film as a light emission layer, and a passivation layer is formed on the metal halide perovskite thin film.

FIG. 22 is a schematic diagram showing a metal halide perovskite light-emitting device according to an embodiment of the present invention.

Referring to FIG. 22, the metal halide perovskite light-emitting device according to the present invention includes a substrate 10, a first electrode 20, a metal halide perovskite thin film 30, a passivation layer 40, and a second electrode 50.

The form of the metal halide perovskite nanocrystal may be a form commonly used in the art. The shape of the metal halide perovskite nanocrystal may be a 0-dimensional, 1-dimensional or 2-dimensional shape. As an example, it may be in the form of a sphere, an ellipsoid, a hollow cube, a pyramid, a cylinder, a cone, an elliptic column, hollow sphere, Janus particle, prism, multipod, polyhedron, nano tube, nano wire, nano fiber or nanoplatelet.

In addition, the size of the metal halide perovskite crystalline particles may be 1 nm to 10 μm or less. For example, 1 nm, 2 nm, 3 nm, 4 nm, 5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 μm. The size of the particle can be defined as a region with the lower value as the minimum value and the larger value as the maximum value among the two numbers selected above. It is preferably 8 nm or more and 300 nm or less, and more preferably 10 nm or more and 30 nm or less. On the other hand, the size of the crystal particles means a size that does not take into account the length of a ligand to be described later, that is, the size of the remaining portions excluding the ligand. When the size of the crystal particles is 1 μm or more, there is a fundamental problem in that excitons do not emit light due to thermal ionization and delocalization of charge carriers in a large crystal, but are separated into free charges and disappeared. In addition, more preferably, as described above, the size of the crystal particles may be greater than or equal to an exciton Bohr diameter. The thermal ionization and delocalization of the charge carrier may gradually appear when the size of the nanocrystal exceeds 100 nm. If it is more than 300 nm, the phenomenon will appear more, and if it is more than 1 μm, it is completely bulky and is subject to the above phenomenon.

For example, when the nanocrystal particle are spherical, the diameter of the nanocrystal particle may be 1 nm to 10 μm. Preferably diameter may be 1 nm, 3 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm or 10 μm.

In addition, the band gap energy of the nanocrystal particle may be 1 eV to 5 eV. Preferably, the band gap energy of the nanocrystal particle is 1 eV, 1.1 eV, 1.2 eV, 1.3 eV, 1.4 eV, 1.5 eV, 1.6 eV, 1.7 eV, 1.8 eV, 1.81 eV, 1.82 eV, 1.83 eV, 1.84 eV, 1.85 eV, 1.86 eV, 1.87 eV, 1.88 eV, 1.89 eV, 1.9 eV, 1.91 eV, 1.92 eV, 1.93 eV, 1.94 eV, 1.95 eV, 1.96 eV, 1.97 eV, 1.98 eV, 1.99 eV, 2 eV, 2.01 eV, 2.02 eV, 2.03 eV, 2.04 eV, 2.05 eV, 2.06 eV, 2.07 eV, 2.08 eV, 2.09 eV, 2.1 eV, 2.11 eV, 2.12 eV, 2.13 eV, 2.14 eV, 2.15 eV, 2.16 eV, 2.17 eV, 2.18 eV, 2.19 eV, 2.2 eV, 2.21 eV, 2.22 eV, 2.23 eV, 2.24 eV, 2.25 eV, 2.26 eV, 2.27 eV, 2.28 eV, 2.29 eV, 2.3 eV, 2.31 eV, 2.32 eV, 2.33 eV, 2.34 eV, 2.35 eV, 2.36 eV, 2.37 eV, 2.38 eV, 2.39 eV, 2.4 eV, 2.41 eV, 2.42 eV, 2.43 eV, 2.44 eV, 2.45 eV, 2.46 eV, 2.47 eV, 2.48 eV, 2.49 eV, 2.5 eV, 2.51 eV, 2.52 eV, 2.53 eV, 2.54 eV, 2.55 eV, 2.56 eV, 2.57 eV, 2.58 eV, 2.59 eV, 2.6 eV, 2.61 eV, 2.62 eV, 2.63 eV, 2.64 eV, 2.65 eV, 2.66 eV, 2.67 eV, 2.68 eV, 2.69 eV, 2.7 eV, 2.71 eV, 2.72 eV, 2.73 eV, 2.74 eV, 2.75 eV, 2.76 eV, 2.77 eV, 2.78 eV, 2.79 eV, 2.8 eV, 2.9 eV, 3 eV, 3.1 eV, 3.2 eV, 3.3 eV, 3.4 eV, 3.5 eV, 3.6 eV, 3.7 eV, 3.8 eV, 3.9 eV, 4 eV, 4.1 eV, 4.2 eV, 4.3 eV, 4.4 eV, 4.5 eV, 4.6 eV, 4.7 eV, 4.8 eV, 4.9 eV, or 5 eV. Band gap energy of the nanocrystal particle can be defined as a range that takes the lower value as the minimum value and the larger value as the maximum value out of the two numbers selected above.

Accordingly, since the energy band gap is determined according to the constituent material or crystal structure of the nanocrystal particle, light having a wavelength of, for example, 200 nm to 1300 nm may be emitted by controlling the constituent material of the nanocrystal particle. In addition, preferably, the nanocrystal particle may emit ultraviolet, blue, green, red, or infrared light.

The ultraviolet light can be defined as a range that takes the lower value as the minimum value and the larger value as the maximum value out of the two numbers selected among 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, and 430 nm. The blue light can be defined as a range that takes the lower value as the minimum value and the larger value as the maximum value out of the two numbers selected among 440 nm, 450 nm, 451 nm, 452 nm, 453 nm, 454 nm, 455 nm, 456 nm, 457 nm, 458 nm, 459 nm, 460 nm, 461 nm, 462 nm, 463 nm, 464 nm, 465 nm, 466 nm, 467 nm, 468 nm, 469 nm, 470 nm, 471 nm, 472 nm, 473 nm, 474 nm, 475 nm, 476 nm, 477 nm, 478 nm, 479 nm, 480 nm, 490 nm. The green light can be defined as a range that takes the lower value as the minimum value and the larger value as the maximum value out of the two numbers selected among 500 nm, 501 nm, 502 nm, 503 nm, 504 nm, 505 nm, 506 nm, 507 nm, 508 nm, 509 nm, 510 nm, 511 nm, 512 nm, 513 nm, 514 nm, 515 nm, 516 nm, 517 nm, 518 nm, 519 nm, 520 nm, 521 nm, 522 nm, 523 nm, 524 nm, 525 nm, 526 nm, 527 nm, 528 nm, 529 nm, 84 530 nm, 531 nm, 532 nm, 533 nm, 534 nm, 535 nm, 536 nm, 537 nm, 538 nm, 539 nm, 540 nm, 541 nm, 542 nm, 543 nm, 544 nm, 545 nm, 546 nm, 547 nm, 548 nm, 549 nm, 550 nm, 560 nm, 570 nm, and 580 nm. The red light can be defined as a range that takes the lower value as the minimum value and the larger value as the maximum value out of the two numbers selected among 590 nm, 600 nm, 601 nm, 602 nm, 603 nm, 604 nm, 605 nm, 606 nm, 607 nm, 608 nm, 609 nm, 610 nm, 611 nm, 612 nm, 613 nm, 614 nm, 615 nm, 616 nm, 617 nm, 618 nm, 619 nm, 620 nm, 621 nm, 622 nm, 623 nm, 624 nm, 625 nm, 626 nm, 627 nm, 628 nm, 629 nm, 630 nm, 631 nm, 632 nm, 633 nm, 634 nm, 635 nm, 636 nm, 637 nm, 638 nm, 639 nm, 640 nm, 641 nm, 642 nm, 643 nm, 644 nm, 645 nm, 646 nm, 647 nm, 648 nm, 649 nm, 650 nm, 660 nm, 670 nm, 680 nm, 690 nm, 700 nm. The infrared light can be defined as a range that takes the lower value as the minimum value and the larger value as the maximum value out of the two numbers selected among 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1000 nm, 1010 nm, 1020 nm, 1030 nm, 1040 nm, 1050 nm, 1060 nm, 1070 nm, 1080 nm, 1090 nm, 1100 nm, 1110 nm, 1120 nm, 1130 nm, 1140 nm, 1150 nm, 1160 nm, 1170 nm, 1180 nm, 1190 nm, 1200 nm, 1210 nm, 1220 nm, 1230 nm, 1240 nm, 1250 nm, 1260 nm, 1270 nm, 1280 nm, 1290 nm, 1300 nm.

A passivation layer 40 is formed on the metal halide perovskite thin film 30.

The metal halide perovskite thin film 30 exhibits relatively low luminescence efficiency due to the presence of surface defects, and low luminescence efficiency due to charge carrier imbalance in the light-emitting device. Accordingly, there is a need for a method capable of eliminating defects in a metal halide perovskite thin film and eliminating charge imbalance in a light-emitting device.

Accordingly, in a light-emitting device including a metal halide perovskite thin film as a light emission layer, the present invention is characterized in that a passivation layer is formed on the metal halide perovskite thin film.

In the metal halide perovskite light-emitting device according to the present invention, the passivation layer may include one or more compounds of Formulas 1 to 4 below.

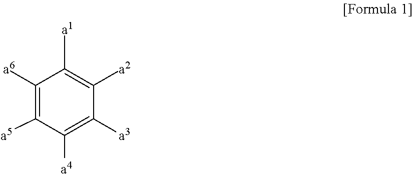

In Formula 1, a₁ to a₆ are H, CH₃ or CH₂X, wherein at least three of al to a6 are CH₂X, and X is a halogen element.

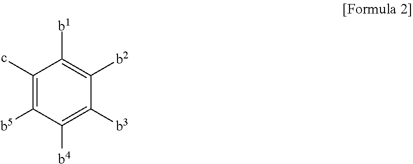

(In the above chemical formula 2, b1 to b5 are halogen elements, and

c is

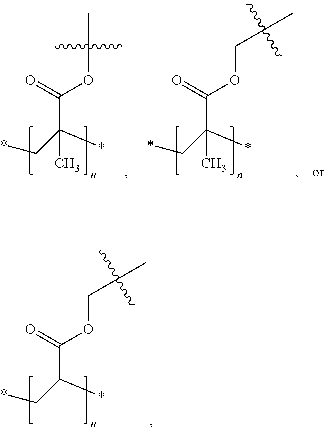

n is an integer from 1 to 100)

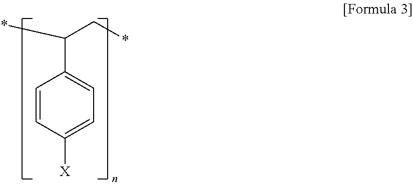

(In the above chemical formula 3, X is a halogen element

n is an integer from 1 to 100)

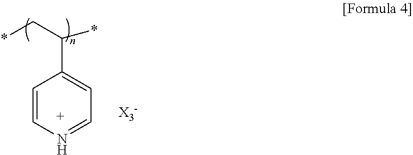

The compounds of chemical formulas 1 to 4 are organic compounds containing halogen, and defects in the emission layer can be stabilized by compensating for the deficiency of halogen in the metal halide perovskite crystal.

Preferably, the compounds forming the passivation layer can be selected from the group consisting of poly (4-vinylpyridinium tribromide), (1,3,5-tris (bromomethyl) benzene), 2,4,6-tris (bromomethyl) mesitylene (TBMM), 1,2,4,5-tetrakis. (Bromomethyl) benzene, hexakis (bromomethyl) benzene, poly (pentabromophenylmethacrylate), poly (pentabromobenzylmethacrylate), poly (pentabromobenzyl acrylate) and poly (4-bromostyrene), and more preferably 2,4,6-tris(bromomethyl)mesitylene (TBMM) can be used.

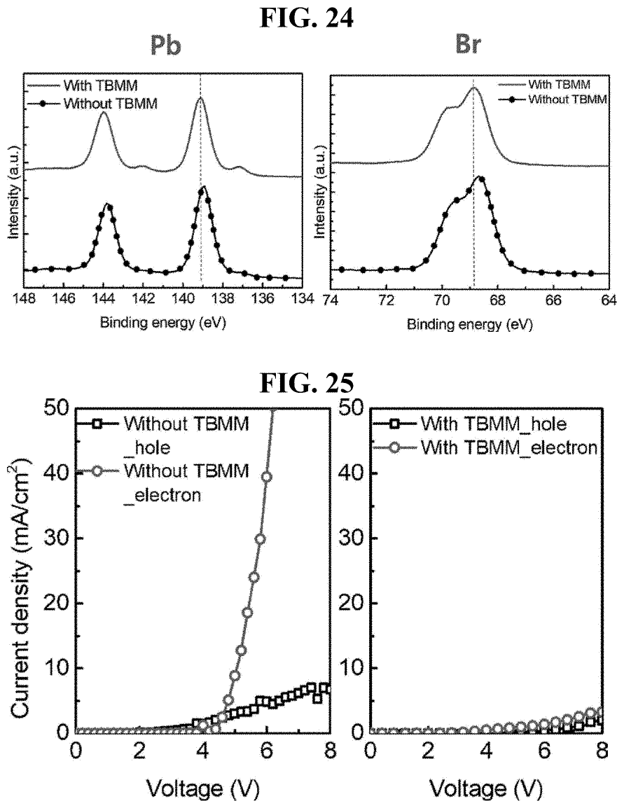

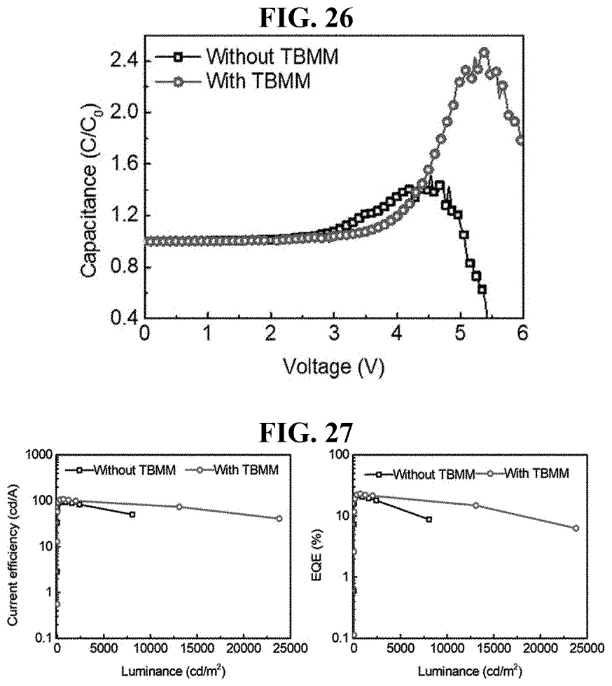

In one embodiment of the present invention, as a result of measuring the light emission characteristics before and after coating the TBMM thin film which is one of the compounds of the chemical formula 1, on the metal halide perovskite nanocrystal particle emission layer, the photoluminescence (PL) lifetime becomes longer (see FIG. 23), the binding energy of elements in the metal halide perovskites increases (see FIG. 24), and the current densities of holes and electrons become similar after the TBMM thin film is coated. It is confirmed that the charge imbalance in the device is eliminated (see FIG. 25), the maximum capacitance is increased (see FIG. 26), and the luminescence efficiency and maximum brightness are improved (see FIG. 27).

Therefore, when the passivation layer is formed on the metal halide perovskite thin film, the luminescence efficiency and the photoluminescence (PL) lifetime can be improved.

The thickness of the passivation layer 40 is preferably 1 to 100 nm, but if the thickness of the passivation layer exceeds 100 nm, charge injection is reduced due to insulation characteristics.

The passivation layer may be coated by performing spin coating, bar coating, spray coating, slot die coating, gravure coating, blade coating, screen printing, nozzle printing, inkjet printing, electrohydrodynamic jet printing, electrospray or electrospinning.

On the other hand, in one embodiment of the present invention, if the first electrode 20 is used as an anode, the second electrode 50 is used as a cathode, and if the first electrode 20 is used as a cathode, the second electrode 50 can be used as an anode.

The first electrode 20 or second electrode 50 can be formed by physical vapor deposition (PVD), chemical vapor deposition (CVD), sputtering, pulsed laser deposition (PLD), evaporation method, electron beam evaporation, atomic layer deposition (ALD) or molecular beam epitaxy vapor deposition (MBE).

On the other hand, in the light-emitting diodes according to the embodiment of the present invention, when the first electrode 20 is the anode, and the second electrode 50 is the cathode, as shown in FIG. 22, a hole injection layer 23 and hole transport for facilitating hole injection between the first electrode 20 and the metal halide perovskite thin film (emissive layer) 30 can be provided as a hole transport layer. Further, an electron transport layer 43 for transporting electrons and an electron injection layer for facilitating electron injection may be provided between the passivation layer 40 and the second electrode 50.

In addition, a hole blocking layer (not shown) can be placed between the metal halide perovskite thin film (emission layer) 30 and the electron transport layer 43. Further, an electron blocking layer (not shown) can be arranged between the metal halide perovskite thin film (emission layer) 30 and the hole transport layer. However, the present invention is not limited to thereto, and the electron transport layer 43 can perform the role of the hole blocking layer, or the hole transport layer can also perform the role of the electron blocking layer.

The hole injection layer 23 and/or the hole transport layer have a HOMO level between the work function level of the first electrode (anode) 20 and the HOMO level of the metal halide perovskite thin film (emission layer) 30, and functions to improve the injection or transport efficiency of holes into the metal halide perovskite thin film (emission layer) 30 from the first electrode (anode) 20.

The hole injection layer 23 or the hole transport layer can include materials commonly used as hole transport materials, and one layer can comprise different hole transport layer. The hole transport material is, for example, mCP (N,N′-dicarbazolyl-3,5-benzene), PEDOT:PSS (poly(3,4-ethylenedioxythiophene):polystyrenesulfonate), NPD (N,N′-di(1-naphthyl))-N,N′-diphenylbenzidine), N,N′-diphenyl-N,N′-di(3-methylphenyl)-4,4′-diaminobiphenyl (TPD), DNTPD (N4,N4′-Bis [4-[bis(3-methylphenyl)amino]phenyl]-N4,N4′-diphenyl-[1,1′-biphenyl]-4,4′-diamine), N,N′-diphenyl-N,N′-dinaphthyl-4,4′-diaminobiphenyl, N,N,N′N′-tetra-p-tolyl-4,4′-diaminobiphenyl, N,N,N′N′-tetraphenyl-4,4′-Diaminobiphenyl, derivatives of porphyrin compounds such as copper (II) 1,10,15,20-tetraphenyl-21H, 23H-porphyrin, TAPC (1,1-Bis [4-[N,N′-Di) (P-tolyl)amino]phenyl]cyclohexane), triallylamine derivatives such as N,N,N-tri (p-tolyl) amine, 4,4′,4′-tris [N-(3-methylphenyl)-N-phenylamino]triphenylamine, carbazole derivatives such as N-phenylcarbazole and polyvinylcarbazole, phthalocyanine derivatives such as metal-free phthalocyanine and copper phthalocyanine, starburstamine derivatives, enamine stilbene derivatives, derivatives of tertiary aromatic amine, styrylamine compounds, or polysilanes. These hole transport material can also perform the role of an electron blocking layer.

The hole blocking layer serves to prevent triplet excitons or holes from diffusing in the direction of the second electrode (cathode) 50 and can be selected randomly among the known hole blocking material. For example, an oxadiazole derivative, a triazole derivative, a phenanthroline derivative, TSPO1 (diphenylphosphine oxide-4-(triphenylsilyl) phenyl) or the like can be used.

The electron injecting layer and/or the electron transport layer 43 have a LUMO level between the work function level of the second electrode (cathode) 50 and the LUMO level of the metal halogen perovskite thin film (emission layer) 30, and functions to increase the efficiency of electron injection or transport into the metal halide perovskite thin film (emission layer) 30 from the second electrode (cathode) 50.

The electron injection layer can be, for example, LiF, NaCl, CsF, Li₂O, BaO, BaF₂, or Liq (lithium quinolate).

The electron transport layer 43 includes TSPO1 (diphenylphosphine oxide-4-(triphenylsilyl) phenyl), TPBi (1,3,5-tris (N-phenylbenzimidazol-2-yl) benzene), tris(8-hydroxyquinolate)aluminum (Alq₃), 2,5-diarylsilol derivative (PyPySPyPy), perfluorinated compound (PF-6P), COTs (Octasubstituted cyclooctatetraene), TAZ (see chemical formula below), Bphen (4,7- It can be diphenyl-1,10-phenanthroline (4,7-diphenyl-1,10-phenanthroline), BCP (see chemical formula below), or BAlq (see chemical formula below).

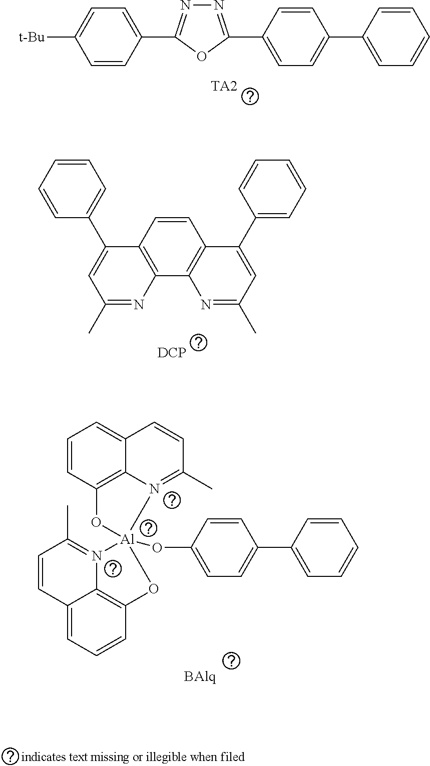

The present invention also comprises a method for manufacturing a metal halide perovskite light-emitting diode containing a passivation layer.

The method to producing a metal halide perovskite light-emitting diodes according to the present invention includes a step of forming a first electrode on a substrate, a step of forming a metal halide perovskite thin film on the first electrode, a step of forming a passivation layer containing one or more compounds of the chemical formulas 1 to 4 on the metal halide perovskite thin film, and a step of forming a second electrode on the passivation layer.

Hereinafter, a method for manufacturing a metal halide perovskite light-emitting diodes including a passivation layer according to an embodiment of the present invention will be described with reference to the structure of FIG. 22.

First, the substrate 10 is prepared.

Next, a first electrode 20 may be formed on the substrate 10. The first electrode may be formed using a vapor deposition method or a sputtering method.

Next, a metal halide perovskite thin film 30 can be formed on the first electrode 20. The metal halide perovskite has a structure of ABX₃, A₂BX₄, A₃BX₅, A₄BX₆, ABX₄ or Aₙ₋₁BₙX₃ₙ₊₁ (n is an integer between 2 and 6), where A is an organic ammonium ion, organic amidinium ion, organic phosphonium ion, alkali metal ion or derivatives thereof, the above B contains transition metals, rare earth metals, alkaline earth metals, organic materials, inorganic materials, ammonium, derivatives thereof or combinations thereof, the above X is a halogen ion or a combination of different halogen ions.

The metal halide perovskite thin film 30 can be a thin film composed of a bulk polycrystal thin film or nanocrystal particle, and the nanocrystal particle has a core-shell structure or a structure having a gradation composition.

These metal halide perovskite thin films 30 are can be formed by using bar-coating, spray coating, slot-die coating, gravure coating, blade coating, screen printing, nozzle printing, inkjet printing, electrohydrodynamic-jet printing, electrospray, or electrospinning

Next, a passivation layer 40 may be formed on the metal halide perovskite thin film 30. The passivation layer preferably includes at least one compound of formulas 1 to 4, and specifically, the compound constituting the passivation layer may be (1,3,5-tris(bromomethyl)benzene), 2,4,6-tris(bromomethyl)mesitylene (TBMM), 1,2,4,5-tetrakis(bromomethyl)benzene, hexakis(bromomethyl)benzene, poly(pentabromophenyl methacrylate), poly(pentabromobenzyl methacrylate), poly(pentabromobenzyl acrylate), poly(4-bromostyrene) or poly(4-vinylpyridinium tribromide).

It is preferable that the thickness of the passivation layer 40 is 1 to 100 nm, and if the thickness of the passivation layer exceeds 100 nm, there is a problem that charge injection decreases due to insulating properties.

The passivation layer 40 is formed using spin coating, bar coating, spray coating, slot die coating, gravure coating, blade coating, screen printing, nozzle printing, inkjet printing, electrohydrodynamic jet printing, electrospray or electrospinning

A second electrode 50 can be formed on the passivation layer 40. These two electrodes 50 can be formed by using a vapor deposition method or a sputtering method.

Further, in one embodiment of the present invention, the method for producing the metal halide perovskite light-emitting diodes can include a step of forming a first electrode on a substrate, a step of forming a hole injection layer on the first electrode, a step of forming a metal halide perovskite thin film as an emission layer on the hole injection layer, a step of forming a passivation layer containing one or more compounds of the chemical formulas 1 to 4 on the metal halide perovskite thin film, a step of forming an electron transport layer on the passivation layer, and a step of forming a second electrode on the electron transport layer.

Hole injection layers or electron transport layers can be formed by conducting spin coating, dip coating, thermal or spray deposition.

In the metal halide perovskite light-emitting diodes prepared as described above, a passivation layer composed of one or more compounds of formulas 1 to 4 is formed on the metal halide perovskite thin film. By removing defects and resolving charge imbalance in the device, the maximum efficiency and maximum luminance of the light-emitting diodes including the metal halide perovskite thin film are improved.

### <Metal Halide Perovskite Light-Emitting Device Including Exciton Buffer Layer>

According to an embodiment of the present invention, the metal halide perovskite light-emitting device can include an exciton buffer layer.

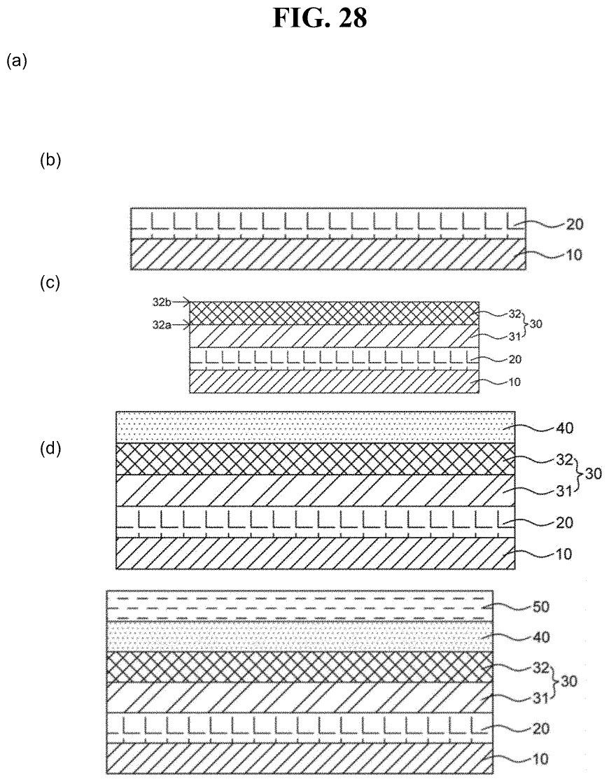

FIG. 28(a) to 28(d) are a schematic diagrams showing a method of manufacturing light-emitting device including an exciton buffer layer according to an embodiment of the present invention. In FIG. 28(a) to 28(d), a metal halide perovskite is described, but an inorganic metal halide perovskite may be applied in the same manner as the description of the metal halide perovskite.

Referring to FIG. 28(a), the first electrode 20 is formed on the substrate 10.

The description of the substrate and the first electrode will be omitted because they are as described above.

Referring to FIG. 28(b), an exciton buffer layer 30 containing a conductive material and a fluorine-based material having a surface energy lower than that of the conductive material is formed on the first electrode 20 described above.

In this case, the above-described exciton buffer layer 30 is a form in which the conductive layer 31 including the conductive material described above and the surface buffer layer 32 including the fluorine-based material described above are sequentially stacked as shown in FIG. 28(b).

The conductive material described above can contain at least one of a group consisting of conductive polymers, metal carbon nanotubes, graphene, reduced graphene oxide, metal nanowires, semiconductor nanowires, metal grids, metal quantum dots and conductive oxides.

The conductive polymers described above include polythiophene, polyaniline, polypyrrole, polystyrene, sulfonated polystyrene, poly(3,4-ethylenedioxythiophene), self-doped conductive polymers, derivatives thereof, or combinations thereof. The above-described derivative may mean that it may further include various sulfonic acids and the like.

For example, the conductive polymer described above can contain at least one of a group consisting of Pani:DBSA (Polyaniline/Dodecylbenzenesulfonic acid, see the following formula), PEDOT:PSS (Poly(3,4-ethylenedioxythiophene)/Poly(4-styrenesulfonate), see the following formula), Pani:CSA (polyaniline/camphorsulfonic acid) and PANI:PSS (Polyaniline/Poly(4-styrenesulfonate), but is not limited thereto.

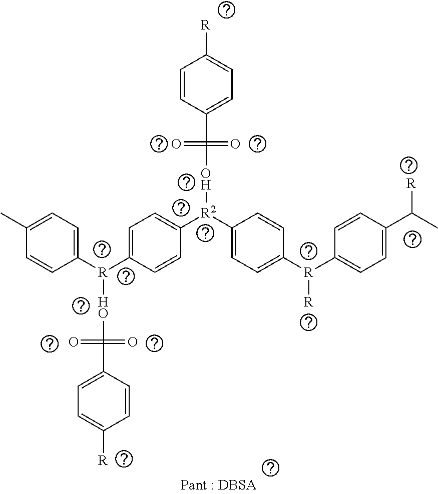

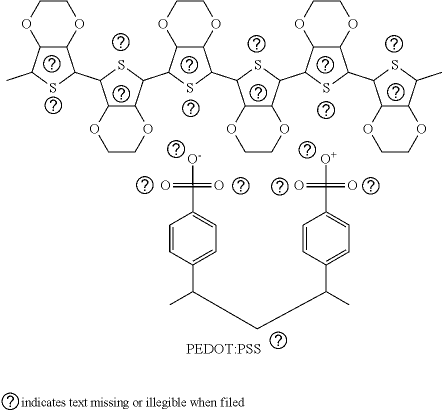

The R can be an H or C₁-C₁₀ alkyl group.

The self-doping conductive polymer can have a degree of polymerization of 10 to 10,000,000 and can have repeating units represented by chemical formula 5 below:

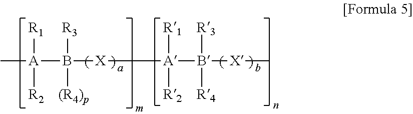

In formula 5, 0<m<10,000,000, 0<n<10,000,000, 0≤a≤20, ≤b≤20;

At least one of R₁, R₂, R₃, R′₁, R′₂, R′₃ and R′₄ contains an ionic group, and A, B, A′ and B′ are independently selected from C, Si, Ge, Sn, or Pb.

R₁, R₂, R_{3,} R′₁, R′₂, R′₃ and R′₄ are independently selected from the group consisting of hydrogen, halogen, nitro group, substituted or unsubstituted amino group, cyano group, substituted or unsubstituted C₁-C₃₀ alkyl groups, substituted or unsubstituted C₁-C₃₀ alkoxy groups, substituted or unsubstituted C₆-C₃₀ aryl groups, substituted or unsubstituted C₆-C₃₀ arylalkyl groups, substituted or unsubstituted C₆-C₃₀ aryloxy groups, substituted or unsubstituted C₂-C₃₀ heteroaryl groups, substituted or unsubstituted C₂-C₃₀ heteroarylalkyl groups, substituted or unsubstituted C₂-C₃₀ heteroaryloxy group, substituted or unsubstituted C₅-C₃₀ cycloalkyl group, substituted or unsubstituted C₅-C₃₀ heterocycloalkyl group, substituted or unsubstituted C₁-C₃₀ alkyl ester group, and substituted or substituted C₆-C₃₀ allyl ester groups, and hydrogen or halogen elements of R₁, R₂, R₃, R′₁, R′₂, R′₃ or R′₄ is selectively bonded to the carbon in the above chemical formula.

R₄ is composed of a conjugated conductive polymer chain, X and X′ are each independently selected from the a simple bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, and a substituted or unsubstituted C₅-C₃₀ heterocycloalkylene group or aryl ester group, and hydrogen or a halogen element of X and X′ may be optionally bonded to carbon in the above formula.

For example, the ionic group is an anionic group selected from the group consisting of PO₃, SO₃, COO, I and CH₃COO, a metal ion selected from Na, K, Li, Mg, Zn and Al, or organic ions selected from the group of H, NH₄ and CH₃(—CH₂—)ₙO (n is a natural number of 1 to 50), may include a cationic group paired with the anionic group.

For example, in the self-doped conductive polymer of Formula 5, at least one of each of R₁, R₂, R₃, R′₁, R′₂, R′₃ and R′₄ may be fluorine, or a group substituted with fluorine, but is not limited thereto.

Specific examples of the conductive polymer are as follows but are not limited thereto.

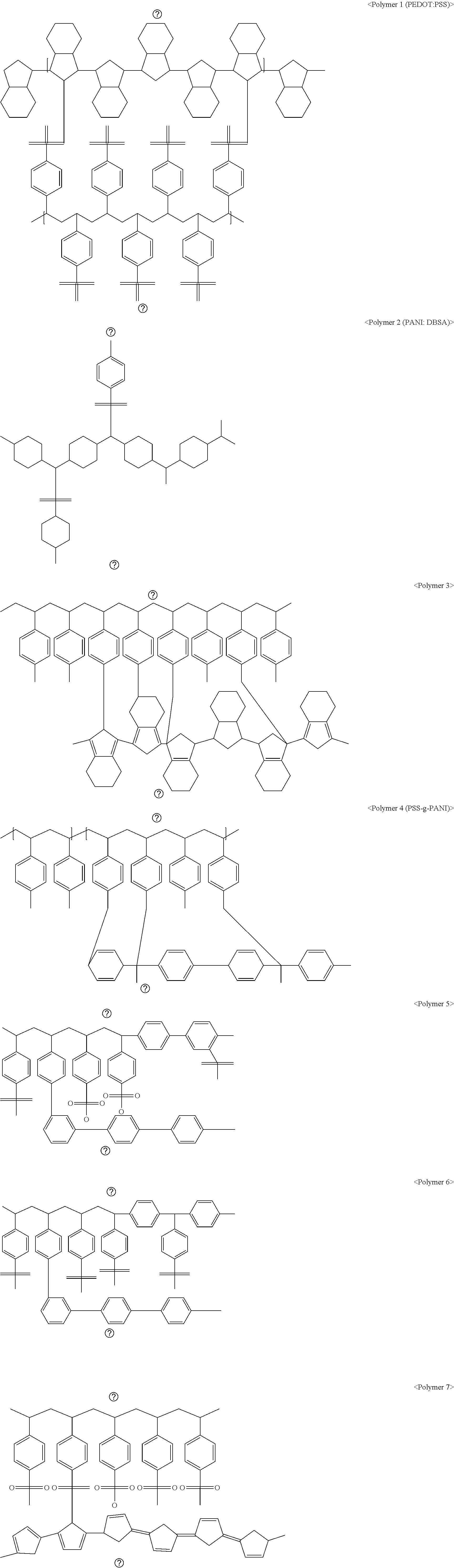

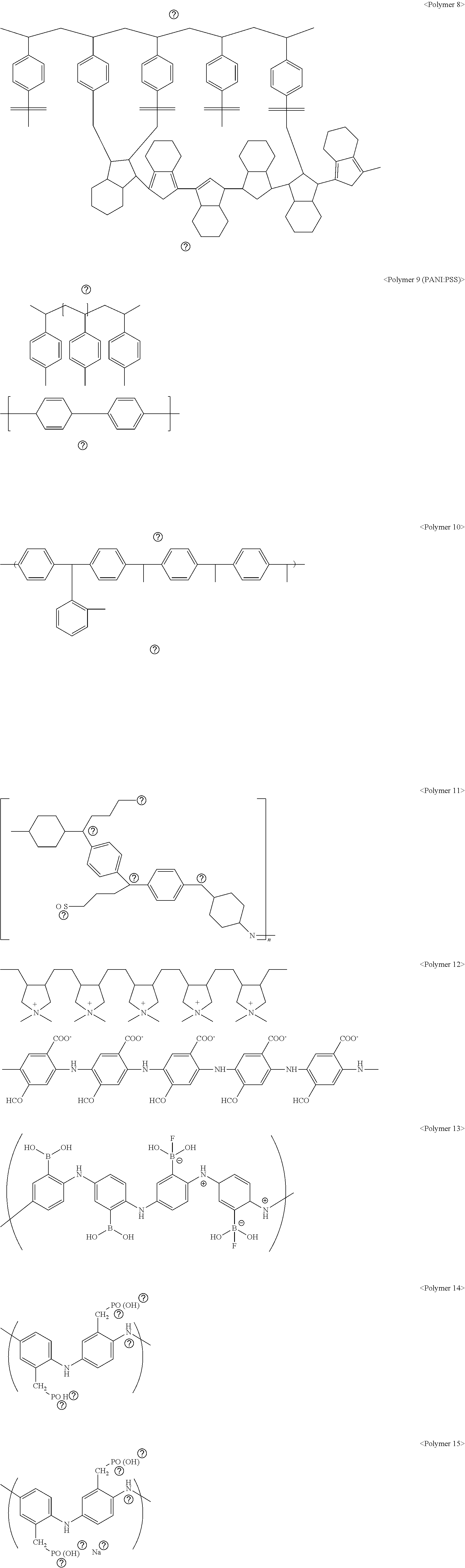

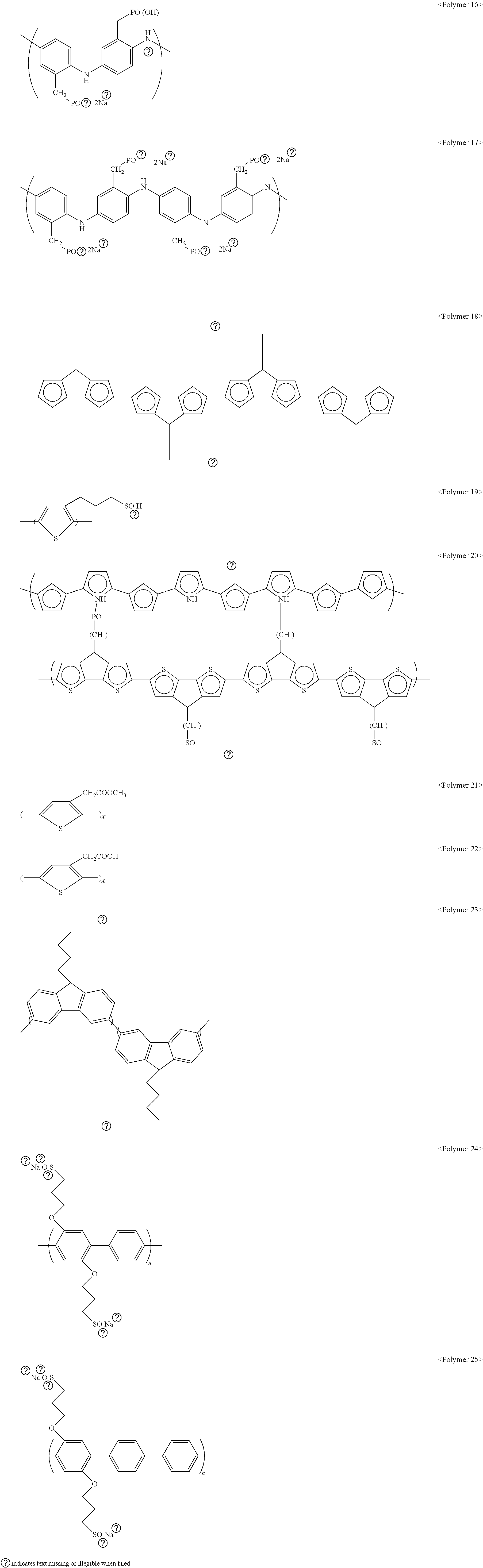

Specific examples of unsubstituted alkyl in present specification may include methyl, ethyl, profile, isobutyl, sec-butyl, tert-butyl, pentyl, iso-amyl, or hexyl as straight-chain or branched, and one or more of the hydrogen atoms contained in the aforementioned alkyl can be substituted to halogen atoms, hydroxyl, nitro group, cyano group (—NH₂, —NH(R), —N(R′)(R″), R′ and R″ are each independently an alkyl group having 1 to 10 carbon atoms), amidino, hydrazine, hydrazone, carboxyl, sulfonic acid, phosphoric acid alkyl of C₁-C₂₀, halogenated alkyl of C₁-C₂₀, alkenyl of C₁-C₂₀, alkynyl of C₁-C₂₀, heteroalkyl of C₁-C₂₀ arylliche of C₁-C₂₀, a heteroalkyl of C₆-C₂₀, a heteroalkyl of C₆-C₂₀, or a heteroarylalkyl of C₆-C₂₀.

The heteroalkyl group of the present specification means that at least one of the carbon atoms in the main chain of the above-described alkyl group, preferably 1 to 5 carbon atoms, is substituted with a hetero atom such as an oxygen atom, a sulfur atom, a nitrogen atom, or a number of atoms.

Aryl groups herein refer to a carbocycle aromatic system that includes multiple aromatic rings, and the rings described above can be attached or fused together in a pendant method. Specific examples of the aryl group include aromatic groups such as phenyl, naphthyl, and tetrahydronaphthyl, and one or more hydrogen atoms of the above-mentioned aryl group can be substituted with the same substituents as in the case of the above-mentioned alkyl group.

The heteroaryl groups herein contain one, two or three heteroatoms selected from N, O, P and S, means a ring aromatic system having 5 to 30 ring atoms in which the remaining ring atoms are C, and the rings described above can be attached or fused together in a pendant manner Then, one or more hydrogen atoms of the heteroaryl group described above can be substituted with the same substituents as in the case of the alkyl group described above.

Alkoxy group in this specification indicates radical-O-alkyl herein, and the alkyl is as defined above. Specific examples include methoxy, ethoxy, propoxy, isobutyloxy, sec-butyloxy, pentyloxy, iso-amyloxy, hexyloxy or the like, and one or more hydrogen atoms of the above-mentioned alkoxy group mentioned above can be substituted to above-mentioned substituents similar to those for alkyl groups.

The substituent heteroalkoxy group used in the present invention is essentially a heteroalkoxy group, except that one or more heteroatoms, such as oxygen, sulfur or nitrogen, can be present in the alkyl chain, it has the above-mentioned meaning of alkoxy, for example, CH₃CH₂OCH₂CH₂O—, C₄H₉OCH₂CH₂OCH₂CH₂O— or CH₃O(CH₂CH₂O)ₙH.

Arylalkyl groups herein are aryl groups as defined above, meaning that some of the hydrogen atoms have been substituted with lower alkyl radicals such as methyl, ethyl, propyl or the like. For example, there are benzyl, phenylethyl or the like. One or more hydrogen atoms of the allyl alkyl group described above can be substituted with the same substituents as in the case of the alkyl group described above.

The heteroarylalkyl group of the present specification means that some of the hydrogen atoms of the heteroaryl group are substituted with a lower alkyl group, and the definition of heteroaryl among the heteroarylalkyl groups is as described above. At least one hydrogen atom in the aforementioned heteroarylalkyl group may be substituted with the same substituent as in the case of the aforementioned alkyl group. The aryloxy in this specification refers to radical-O-aryl, where the aryl is defined above. Specific examples include phenoxy, naphtoxy, antracenyloxy, phenantrenyloxy, fluoreneyloxy, or indenyloxy, and one or more of the aryloxy's hydrogen atoms can be replaced by a replacement as in the case of the aforementioned alkyl group.

The heteroaryloxy group herein refers to a radical-O-heteroaryl, heteroaryl is as defined above.

Specific examples of the heteroaryloxy group in the present specification include a benzyloxy, a phenylethyloxy group, or the like, and one or more hydrogen atoms of the heteroaryloxy group can be substituted with a substituent same as in the case of the above-mentioned alkyl group.

The cycloalkyl group herein means a monocyclic system in which 1 of 5 to 30 carbon atoms is used. At least one or more hydrogen atoms of the above-mentioned cycloalkyl groups can be substituted with the same substituents as in the case of the above-mentioned alkyl groups.

The heterocycloalkyl groups herein contain one, two or three heteroatoms selected from N, O, P or S, with the remaining ring atoms being C from 5 to 5 ring atoms. 1 of 30 means a monocyclic system. One or more hydrogen atoms of the cycloalkyl group described above can be substituted with the same substituents as in the case of the alkyl group described above.

The alkyl ester group herein means a functional group that is ester-bonded to an alkyl group, where the alkyl group is as defined above.

The heteroalkyl ester group of the present specification means a functional group in which an ester group is bonded to the heteroalkyl group, and the heteroalkyl group described above is as defined above.

Aryl ester group herein means a functional group to which an allyl group and an ester group are attached, where the aryl group is as defined above.

The heteroaryl ester group herein means a functional group to which a heteroaryl group and an ester group are bonded, where the heteroaryl group is as defined above.

The amino group used in the present specification means —NH₂, —NH(R) or —N(R′)(R″), where R′ and R″ are independent of each other and have a carbon number of from 1 to 10.

The halogens herein are fluorine, chlorine, bromine, iodine, or astatine, of which fluorine is particularly preferred.

The aforementioned metallic carbon nanotubes may be either refined metallic carbon nanotubes themselves or carbon nanotubes with metal particles (e.g., Ag, Au, Cu, Pt particles, etc.) attached to the inner and/or outer walls of carbon nanotubes.

The above-mentioned graphene is possible to have a graphene single layer having a thickness of about 0.34 nm, a few layers graphene having a structure in which 2 to 10 graphene single layers are laminated, or a graphene multilayer structure having a structure in which a larger number of graphene single layers are stacked than the above-described a few layers graphene.

The metal nanowires and semiconductor nanowires described above include, for example, Ag, Au, Cu, Pt, NiSix (NickelSilicide) nanowires or nanowire with two or more composites of these (e.g. alloys or core-shell composites), but are not limited thereto.

Alternatively, the semiconductor nanowires described above are Si, Ge, B, N-doped Si nanowires, B, or N-doped Ge nanowires or composites of two or more of these (e.g. Alloy or core-shell structures, etc.), but are not limited to thereto.

The aforementioned metal nanowires or semiconductor nanowires can be between 5 nm and 100 nm in diameter and can be between 500 nm and 100 um in length, depending on the manufacturing method of the aforementioned metal nanowires and semiconductor nanowires.

The above-described metal grid is formed by using Ag, Au, Cu, Al, Pt or their alloys to form a mesh-shaped metal line crossing each other, and can have a line width of 100 nm to 100 μm, and the length is not limited. The above-described metal grid may be formed to protrude on the first electrode or may be inserted into the first electrode to form a recessed shape.

The metal quantum dots mentioned above can be selected from Ag, Au, Cu, Pt or two or more composites quantum dots of these (e.g. alloys or core-shell structures), but it is not limited to this.

On the surface of the metal nanowires, semiconductor nanowires, or metal nanodots described above, at least one moiety labeled as —S(Z₁₀₀) and —Si(Z₁₀₁)(Z₁₀₂)(Z₁₀₃) (here, Z₁₀₀, Z₁₀₁, Z₁₀₂, or Z₁₀₃ is hydrogen, halogen atoms, substituted or unsubstituted C₁-C₂₀ alkyl groups, or substituted or unsubstituted C₁-C₂₀ alkoxy group) may be boned. At least one moiety represented by —S(Z₁₀₀) and —Si(Z₁₀₁)(Z₁₀₂)(Z₁₀₃) described above is a self-assembled moiety, and through the moiety described above, the bonding among metal nanodots, or metal nanowires and semiconductor nanowires is enhanced, and the bonding force between the semiconductor nanowire or the metal nanodots, and the first electrode 210 may be strengthened, thereby electrical properties and mechanical strength can be improved.

The conductive oxide described above can be any of ITO (indium tin oxide), IZO (indium zinc oxide), SnO₂ and InO₂.

The steps of forming the above-mentioned conductive layer 31 on the above-mentioned first electrode 20 are spin coating method, casting method, quantity Langmuir-blog jet method, inkjet printing, nozzle printing method, slot die coating method, doctor blade coating method, screen printing method, dip coating method, gravure printing method, physical transfer method, spray coating method), chemical vapor deposition method or thermal evaporation method

Further, the above-mentioned conductive material is mixed with a solvent to produce a mixed solution, which is then applied onto the above-mentioned first electrode 10, and then heat-treated is conducted by removing the above-mentioned solvent. The above-mentioned solvent can be polar solvent, and, for example, may include at least one selected from the group consisting of water, alcohol (methanol, ethanol, n-propanol, 2-propanol, n-butanol, etc.), formic acid, nitromethane, Acetic acid, ethylene glycol, glycerol, n-Methyl-2-Pyrrolidone (NMP), N-dimethylacetamide, dimethylformamide (DMF), dimethyl sulfoxide (DMSO), tetrahydrofuran (THF), ethyl acetate (EtOAc), acetone, and acetonitrile (MeCN).

When the above-mentioned conductive layer 31 contains metal carbon nanotubes, the metal carbon nanotubes may be grown on the above-mentioned first electrode 20, or the carbon nanotubes dispersed in a solvent may be printed by a solution-based printing method (e.g. spray coating method, spin coating method, dip coating method, gravure coating method, reverse offset coating method, screen printing method, or slot-die coating method)

When the above-mentioned conductive layer 31 contains a metal grid, metal is vacuum-deposited on the above-mentioned first electrode 20 to form a metal film, and then various mesh shapes are formed by a photolithography, or printing method (eg, spray coating method, spin coating method, dip coating method, gravure coating method, reverse offset coating method, screen printing method, or slot die coating method) by patterning the metal precursor or metal particles in a solvent.

The above-mentioned conductive layer 31 mainly plays a role of improving the conductivity in the above-mentioned exciton buffer layer 30, and additionally adjusts scattering, reflection, and absorption to improve optical extraction, and improves mechanical strength by imparting flexibility.

The surface buffer layer 32 described above contains a fluorinated material. The fluorine-based material is preferably a fluorine-based material having a lower surface energy than the above-mentioned conductive material, and can have a surface energy of 30 mN/m or less.

Further, the fluorine-based material can have a hydrophobicity larger than that of the above-mentioned conductive polymer.

The concentration of the above-described fluorine-based material on the second surface 32b opposite to the above-described first surface 32a can be lower than the concentration of the above-described fluorine-based material on the first surface 32a close to the above-described conductive layer 31 in the above-described surface buffer layer 32.

This means that the work function of the second surface 32b of the surface buffer layer 32 described above can be 5.0 eV or higher. As an example, of the surface buffer layer 32 described above, the work function measured on the second surface 32b can be 5.0 to 6.5 eV, but is not limited to this.

The fluorinated material described above can be a fluorinated ionomer or a fluorinated ionomer containing at least one F. In particular, when the above-mentioned fluorine-based material is a fluorinated ionomer, the thickness of the buffer layer can be formed to be thick, preventing phase separation between the conductive layer 31 and the surface buffer layer 32 and making it more uniform and allows the formation of an extensive exciton buffer layer. 30.

The above-mentioned fluorinated material can contain at least one ionomer selected from the group consisting of ionomers having the structures of the following chemical formulas 6 to 17.

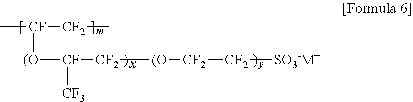

In the formula 6, m is a number from 1 to 10,000,000, x and y are independently numbers from 0 to 10, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—, n is an integer from 0 to 50).

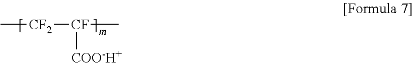

In the formula 7, m is a number from 1 to 10,000,000.

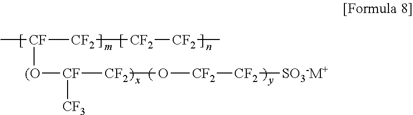

In the formula 8, m and n are 0<m≤10,000,000, 0≤n<10,000,000, x and y are independently numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂))ₙ— (n is an integer from 0 to 50).

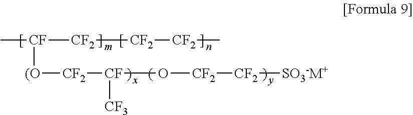

In the formula 9, m and n are 0<m≤10,000,000, 0≤n<10,000,000, x and y are independently numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂))ₙ— (n is an integer from 0 to 50).

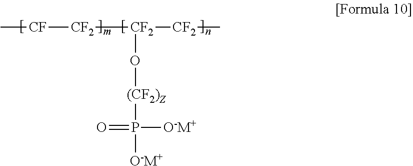

In the formula 10, m and n are 0<m≤10,000,000, 0≤n<10,000,000, x and y are independently numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂))ₙ— (n is an integer from 0 to 50).

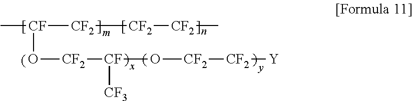

In the formula 11, m and n are 0<m≤10,000,000, 0≤n≤10,000,000, x and y are independently numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ— (n is an integer from 0 to 50).

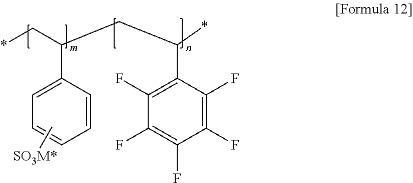

In the formula 12, m and n are 0<m≤10,000,000, 0≤n<10,000,000, x and y are independently numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ— (n is an integer from 0 to 50).

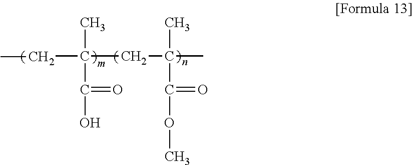

In the formula 13, m and n are 0<m≤10,000,000 and 0≤n<10,000,000.

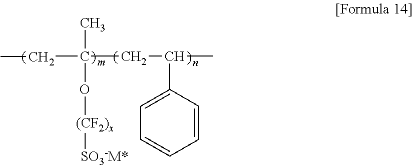

In the formula 14, m and n are 0<m≤10,000,000, 0≤n<10,000,000, x and y are independently numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ— (n is an integer from 0 to 50).

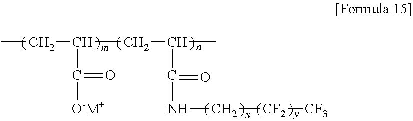

In the formula 15, m and n are 0<m≤10,000,000, 0≤n<10,000,000, x and y are independent numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ— (n is an integer from 0 to 50).

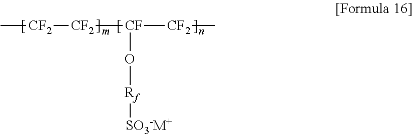

In the formula 16, m and n are 0<m≤10,000,000, 0≤n<10,000,000, x and y are independently numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ— (n is an integer from 0 to 50).

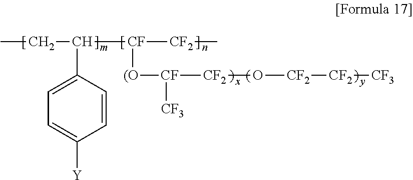

In the formula 17, m and n are 0<m≤10,000,000, 0≤n<10,000,000, x and y are independently numbers from 0 to 20, and M is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is CH₃ (R is CH₃(R)CH₂)ₙ— (n is an integer from 0 to 50).

Further, the above-mentioned fluorine-based material can contain at least one ionomer or low fluoride molecule selected from the group consisting of the structures of the following chemical formulas 18 to 22.

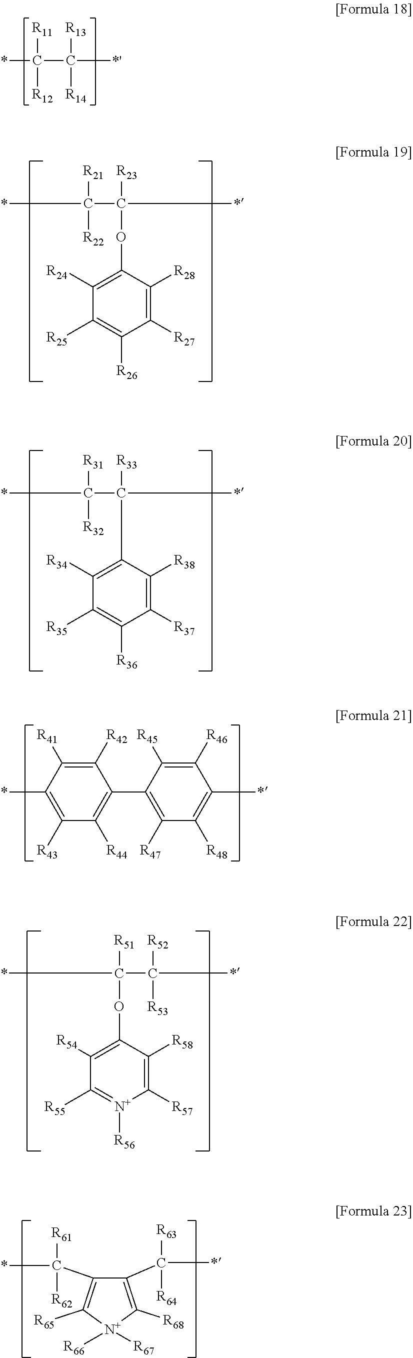

R₁₁ to R₁₄, R₂₁ to R₂₈, R₃₁ to R₃₈, R₄₁ to R₄₈, R₅₁ to R₅₈, and R₆₁ to R₆₈ are independently be chosen among hydrogen, —F, C₁-C₂₀ alkyl groups, C₁-C₂₀ alkoxy groups, at least one —F substituted C₁-C₂₀ alkyl groups, at least one —F substituted C₁-C₂₀ alkoxy groups, Q₁, and —O—(CF₂CF(CF₃)—O)ₙ—(CF₂)ₘ-Q₂ (where n and m are independent of each other and are integers from 0 to 20, n+m is greater than or equal to 1) and —(OCF₂CF₂)ₓ-Q₃ (where x is an integer from 1 to 20)).

The aforementioned Q₁ to Q₃ are ionic groups, and the ionic groups include anionic groups and cationic groups. The anionic groups are selected from PO₃²⁻, SO₃⁻, COO⁻, I⁻, CH₃COO⁻ and the cations include at least one of metal ions and organic ions. The metal ion is selected from Na⁺, K⁺, Li⁺, Mg²⁺, Zn²⁺, and Al³⁺ and the organic ion is H⁺, CH₃(CH₂)ₙNH₃⁺ (n is an integer of 0 to 50), NH₄⁺, NH₂⁺, NHSO₂CF₃⁺, CHO⁺, or C₂H₅OH⁺.

One of R₁₁ to R₁₄, at least one of R₂₁ to R₂₈, at least one of R₃₁ to R₃₈, and at least one of R₄₁ to R₄₈, at least one of R₅₁ to R₅₈ and at least one of R₆₁ to R₆₈ are selected from -F, at least one —F substituted C₁-C₂₀ alkyl group, at least one —F substituted C₁-C₂₀ alkoxy groups —O—(CF₂CF(CF₃)—O)ₙ—(CF₂)ₘ-Q₂ and —(OCF₂CF₂)ₓ-Q₃).

X-M^{f}ₙ-M^{h}ₘ-M^{a}ᵣ-G [Formula 24]

(in the chemical formula 24,

X is the end group.

M^{f}ₙ represents unit derived from fluorinated monomers obtained from perfluoropolyether alcohol, polyisocyanate or isocyanate reactive-non-fluorinated monomer.

M^{h}ₘ represents a unit derived from a non-fluorinated monomer.

M^{a}ᵣ represents the unit having a silyl group represented by —Si(Y₄)(Y₅)(Y₆);

Y₄, Y₅ and Y₆ described above represent substituted or unsubstituted C₁-C₂₀ alkyl groups, substituted or unsubstituted C₆-C₃₀ aryl groups or hydrolyzable substituents independently of each other, as described above. At least one of Y₄, Y₅ and Y₆ is the hydrolyzable substituents mentioned above.

G is an organic group of 1 containing residues of the chain transfer agent, n is a number from 1 to 100, m is a number between 0 and 100, r is a number between 0 and 100, and n+m+r is at least 2.

The thickness of the surface buffer layer 32 described above can be 1 nm to 500 nm. For example, the thickness of the surface buffer layer mentioned above may include a range in which a lower value of two numbers, has a lower limit value and a higher value of two numbers has an upper limit value among 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm, 101 nm, 102 nm, 103 nm, 104 nm, 105 nm, 106 nm, 107 nm, 108 nm, 109 nm, 110 nm, 111 nm, 112 nm, 113 nm, 114 nm, 115 nm, 116 nm, 117 nm, 118 nm, 119 nm, 120 nm, 125 nm, 130 nm, 135 nm, 140 nm, 145 nm, 150 nm, 155 nm, 160 nm, 165 nm, 170 nm, 175 nm, 180 nm, 185 nm, 190 nm, 195 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 450 nm, 500 nm. Also, preferably, the thickness of the surface buffer layer described above can be 10 nm to 200 nm. If the thickness of the surface buffer layer 32 described above satisfies the above range, excellent work function characteristics, transparency and flexibility characteristics can be provided.

The above-mentioned surface buffer layer 32 can be formed by producing a mixed solution containing the above-mentioned fluorine-based material and solvent on the above-mentioned conductive layer 31, and then heat-treating the mixed solution.

The exciton buffer layer 30 thus formed can have a thickness of 1 nm to 500 nm. Among 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm, 101 nm, 102 nm, 103 nm, 104 nm, 105 nm, 106 nm, 107 nm, 108 nm, 109 nm, 110 nm, 111 nm, 112 nm, 113 nm, 114 nm, 115 nm, 116 nm, 117 nm, 118 nm, 119 nm, 120 nm, 125 nm, 130 nm, 135 nm, 140 nm, 145 nm, 150 nm, 155 nm, 160 nm, 165 nm, 170 nm, 175 nm, 180 nm, 185 nm, 190 nm, 195 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 450 nm, 500 nm, a range in which a lower value of the two numbers is a lower limit value and a higher value is an upper limit value may be included. Also, preferably, the thickness of the surface buffer layer described above can be 10 nm to 100 nm. If the thickness of the exciton buffer layer described above satisfies the above range, excellent work function characteristics, transparency and flexibility characteristics can be provided.

The conductivity can be improved as the conductive layer 31 described above is formed, and at the same time, the surface energy can be lowered as the surface buffer layer 32 described above is formed. Thereby, the light emission performance can be maximized

The above-described surface buffer layer 32 may further include at least one additive selected from the group consisting of carbon nanotubes, graphene, reduced graphene oxide, metal nanowires, metal carbon nanodots, semiconductor quantum dots, semiconductor nanowires, and metal nanodots. When the above-described additive is further included, it is possible to maximize the conductivity of the exciton buffer layer 30 described above.

Further, the surface buffer layer 32 described above may further contain a cross-linking agent containing a bis(phenyl azide) material. When the above-mentioned cross-linking agent is further contained in the above-mentioned surface buffer layer 32, composition separation due to time and device drive can be prevented. This can improve the stability and reproducibility of the light-emitting diodes, which reduces the resistance and work function of the exciton buffer layer 30 described above.

The above-mentioned bisphenyl azide-based material can be a bisphenyl azide-based material having the following chemical formula 25.

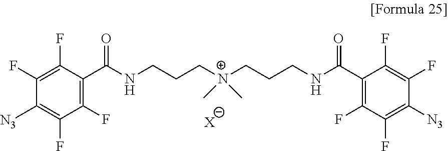

The steps of forming the above-mentioned surface buffer layer 32 on the above-mentioned conductive layer 31 can use spin coating method, casting method, Langmuir-Blodgett method, inkjet printing method, nozzle printing method, slot die coating method, doctor blade coating method, screen printing method, dip coating method, gravure printing method, reverse-offset printing method, spray coating method, chemical vapor deposition method or thermal evaporation method process.

However, in the step of forming the exciton buffer layer 30 described above, the conductive layer 31 and the surface buffer layer 32 may be sequentially deposited as described above, but after preparing a mixed solution by mixing the above-described conductive material and the above-described fluorine-based material in a solvent, it can be formed through a process of heat treatment by applying the mixed solution to the above-described first electrode.

In this case, by heat-treating the above-mentioned mixed solution, the conductive layer 31 and the surface buffer layer 32 are sequentially assembled and formed on the above-mentioned first electrode 20. This has the advantage that the process can be simplified.

The above-mentioned fluorine-based material can be a material having a solubility of 90% or more, for example, 95% or more in a polar solvent. Examples of the aprotic solvents mentioned above include water, alcohols (methanol, ethanol, n-propanol, 2-propanol, n-butanol, etc.), ethylene glycol, glycerol, dimethylformamide (DMF), dimethyl sulfoxide (DMSO), or acetone, but is not limited thereto.

The exciton buffer layer 30 described above may further contain a cross-linking agent.

By adding a cross-linking agent to the exciton buffer layer 30 described above, it is possible to prevent phase separation of constituent materials from occurring depending on the time and drive of the device. Further, it is possible to prevent the efficiency of the exciton buffer layer 30 from being lowered due to the use of a solvent or the like during the formation of the surface buffer layer 32 described above. Therefore, the stability and reproducibility of the device can be improved.

The cross-linking agent described above can include at least one functional group selected from the group consisting of amine groups (—NH₂), thiol groups (—SH), and carboxyl groups (—COO—).

The above-mentioned cross-linking agents can include at least one selected from the group consisting of bisphenyl azide-based materials, diaminoalkane-based materials, dithiol-based materials, dicarboxylate, ethylene glycol, ethylene glycol dimethacrylate derivatives, methylenebisacrylamide derivatives, and divinylbenzene (DVB).

A hole transport layer (not shown) can be formed on the exciton buffer layer 30 described above. The hole transport layer described above can be formed based on a method arbitrarily selected from various known methods such as a vacuum deposition method, a spin coating method, a casting method, and an LB method. When the vacuum vapor deposition method is selected, the vapor deposition conditions differ depending on the target compound, the structure and thermal properties of the target layer, and the like, for example, the vapor deposition temperature range of 100° C. to 500° C., vacuum range from 10⁻¹⁰ to 10⁻³ torr, the deposition rate range of 100 Å/sec can be selected. On the other hand, when the spin coating method is selected, the coating conditions vary depending on the target compound, the structure and thermal properties of the target layer, but the coating rate range from 2000 rpm to 5000 rpm and annealing temperature (heat treatment temperature for removing solvent after coating) from 80° C. to 200° C. can be selected.

Y₁, which is the value of the work function of the first surface 32a of the surface buffer layer 32 of the exciton buffer layer 30, can be in the range of 4.6 to 5.2, for example, 4.7 to 4.9. Y₂, which is the value of the work function of the second surface 32b of the surface buffer layer 32 of the exciton buffer layer 30, can be equal to or smaller than the work function of fluorine-based material contained in the surface buffer layer 32 described above. For example, the aforementioned Y₂ can be in the range of 5.0 to 6.5, for example 5.3 to 6.2, but is not limited thereto.

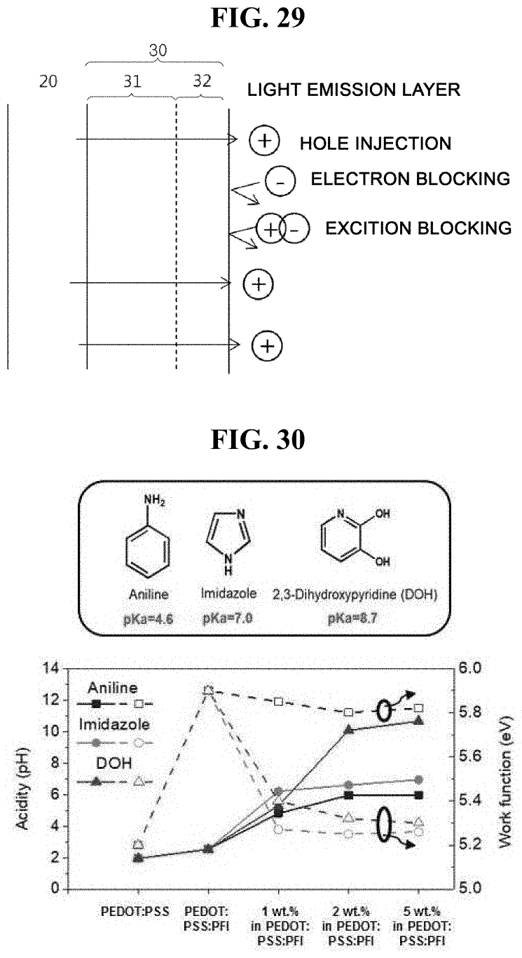

FIG. 29 shows the effect of the exciton buffer layer 30 according to the embodiment of the present invention.

Referring to FIG. 29, it can be seen that the exciton buffer layer 30 according to an embodiment of the present invention improves hole injection efficiency performs an electron blocking role and suppresses quenching of excitons.

### <Metal Halide Perovskite Light-Emitting Diodes Containing an Acidity-Controlled Conductive Polymer>

According to an embodiment of the present invention, the metal halide perovskite light-emitting diodes can include a conductive polymer composition containing a fluorine-based material and a basic material.

Also, preferably, the conductive polymer composition is comprised of a fluorinated material or basic materials that can be neutralized at pH 4.0 to 10.0 with a work function of 5.8 eV or higher.

Also, preferably, the conductive polymer composition is added by the addition of a basic material. The surface roughness of the thin film may have decreased below 2 nm.

In addition, preferably, the conductive polymer includes polythiophene, polyaniline, polypyrrole, polystyrene, polyethylenedioxythiophene, polyacetylene, polyphenylene, polyphenylvinylene, polycarbazole, and copolymers which contains at least two different repeating units of these, their derivatives, or blends of two or more of them.

Further, preferably, the above-mentioned fluorine-based material can be an ionomer represented by the following chemical formula 26.

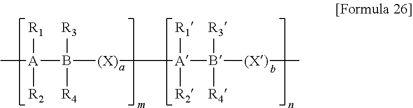

(in the above chemical formula 26,

0<m≤10,000,000, 0≤n<10,000,000, 0≤a≤20, 0≤b≤20,

A, B, A′ and B′ are independently selected from the group consisting of C, Si, Ge, Sn, and Pb,

R₁, R₂, R₃, R₄, R₁′, R₂′, R₃′ and R₄′ can be independently selected from the group consisting of hydrogen, halogen, nitro groups, substituted or unsubstituted amino groups, cyano groups, substituted or non-substituted, substituted C₁-C₃₀ alkyl groups, substituted or unsubstituted C₁-C₃₀ heteroalkyl groups, substituted or unsubstituted C₁-C₃₀ alkoxy groups, substituted or unsubstituted C₁-C₃₀ heteroalkryl groups, substituted or unsubstituted, substituted C₆-C₃₀ aryl groups, substituted or substituted C₆-C₃₀ arylalkyl groups, substituted or unsubstituted C₆-C₃₀ aryloxy groups, substituted or unsubstituted C₂-C₃₀ heteroaryl groups, substituted or unsubstituted C₂-C₃₀ heteroarylalkyl groups, substituted or substituted C₂-C₃₀ heteroaryloxy groups, substituted or unsubstituted C₅-C₂₀ cycloalkyl groups, substituted or unsubstituted C₂-C₃₀ heterocycloalkyl groups, substituted or unsubstituted C₁-C₃₀ alkyl ester groups, substituted or unsubstituted C₁-C₃₀ heteroalkyl ester groups, substituted or unsubstituted C₆-C₃₀ aryl ester groups, and substituted or unsubstituted C₂-C₃₀ heteroaryl ester groups, and at least one or more of R₁, R₂, R₃, and R₄ are ionic groups or contain ionic groups.

X and X′ are independently selected from the group consisting of simple bond, O, S, substituted or unsubstituted C₁-C30 alkylene group, substituted or unsubstituted C₁-C₃₀ heteroalkylene group, substituted or unsubstituted C₆-C₃₀ arylene group, substituted or unsubstituted C₆-C₃₀ arylalkylene group, substituted or unsubstituted C₂-C₃₀ heteroarylene groups, substituted or unsubstituted C₂-C₃₀ heteroarylalkylene groups, substituted or unsubstituted C₅-C₂₀ cycloalkylene groups, substituted or unsubstituted C₅-C₃₀ heterocycloalkylene groups, substituted or unsubstituted C₆-C₃₀ aryl ester group and a substituted or unsubstituted C₂-C₃₀ heteroaryl ester group.

However, when n is 0, at least one or more of R₁, R₂, R₃, and R₄ are hydrophobic functional groups containing halogen elements or containing hydrophobic functional groups.

The basic material can be an amine compound or a pyridine compound having a pKa of 4 to 6, and specifically, the amine compound may be one or more selected from the group consisting of naphthylamine, n-allylaniline, aminobiphenyl (4-aminobiphenyl), toluidine (o-Toluidine), aniline, quinoline, dimethylaniline (N,N,-diethyl aniline), and pyridine.

FIG. 30 is a graph showing the effects of acidity and work function when a basic additive is added to PEDOT:PSS:PFI, which is a conductive polymer and a hole injection layer.

As shown in FIG. 30, when aniline is added to PEDOT:PSS:PFI, the acidity decreases (pH increases), and it can be confirmed that an influence of work function is small compared to other basic additives.

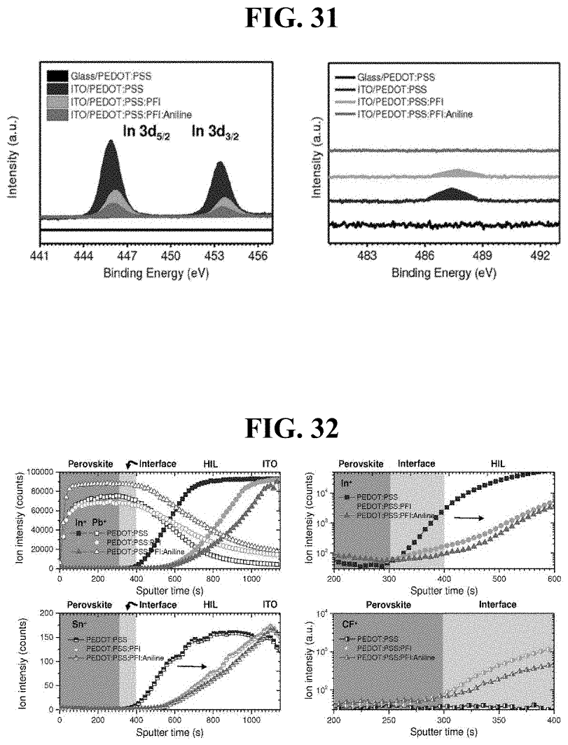

FIG. 31 is a graph of the change in intensity with a function of binding energy when PEDOT:PSS:PFI mixed with aniline is spin-coated on the ITO electrode as a conductive polymer hole injection layer according to an embodiment of the present invention.

As shown in FIG. 31, when PEDOT:PSS:PFI:aniline was formed on ITO, the amount of In⁺ and Sn⁺ ions detected on the surface was confirmed to be significantly lower than those of PEDOT:PSS.

FIG. 32 shows a graph which shows the ion intensity at the interface of a hole injection layer and a metal halide perovskite emission layer, when PEDOT:PSS:PFI with aniline is formed on an ITO electrode.

As shown in FIG. 32, it is confirmed that when PEDOT:PSS:PFI:aniline is deposited on ITO, the amount of In⁺ and Sn⁺ ions detected on the surface decreased and the diffusion is delayed.

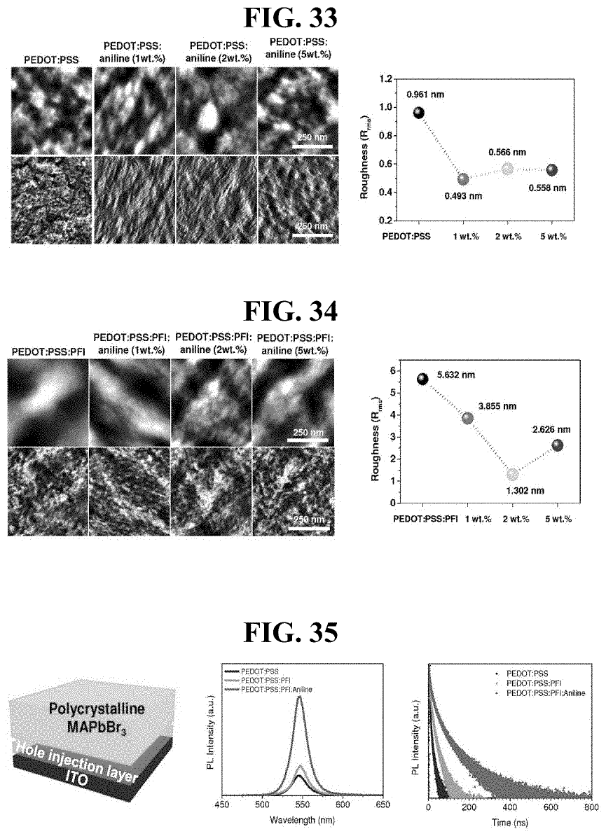

FIG. 33 shows the surface roughness of the formed thin film according to the amount of aniline added when aniline is added to PEDOT:PSS, in the conductive polymer hole injection layer according to an embodiment of the present invention.

FIG. 34 shows the surface roughness of the formed thin film according to the amount of aniline added when aniline is added to PEDOT:PSS:PFI.

As shown in FIGS. 33 and 34, it is confirmed that the surface roughness of the thin film is reduced when aniline is added to PEDOT:PSS or PEDOT:PSS:PFI.

FIG. 35 is a graph showing photoluminescence (PL) intensity and PL lifetime of metal halide perovskite in a polycrystal metal halide perovskite layer/PEDOT:PSS:PFI:aniline/ITO electrode according to an embodiment of the present invention.

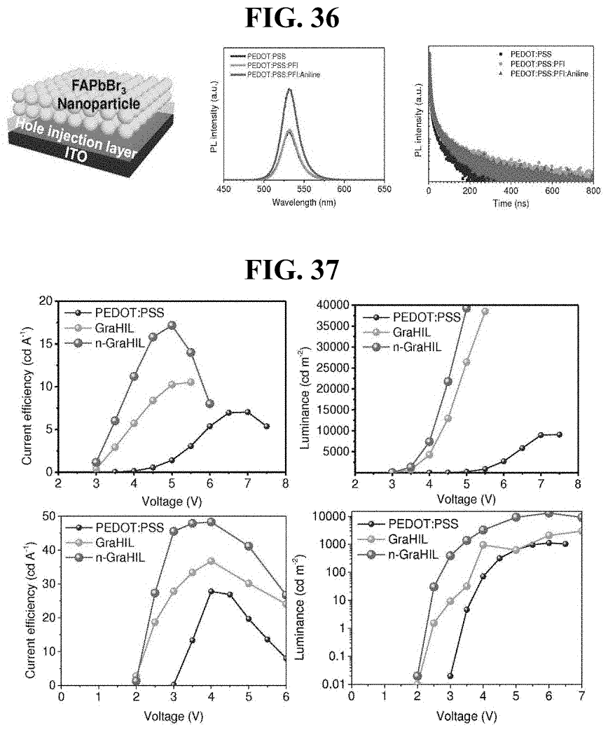

FIG. 36 is a graph showing the photoluminescence (PL) intensity and PL lifetime of the metal halide perovskite nanoparticle layer/PEDOT:PSS:PFI:aniline/ITO electrode according to the embodiment of the present invention.

As shown in FIGS. 35 and 36, the photoluminescence (PL) of the polycrystal metal halide perovskite thin film and the metal halide perovskite nanoparticle thin film on PEDOT:PSS:PFI:aniline is increased, and the PL lifetime is increased.

FIG. 37 is a graph showing the efficiency of a polycrystal metal halide perovskite device and a metal halide perovskite nanoparticle device using a PEDOT:PSS:PFI:aniline hole injection layer according to an embodiment of the present invention.

As shown in FIG. 37, the higher efficiency of a polycrystal metal halide perovskite device and a metal halide perovskite nanoparticle device using PEDOT:PSS:PFI:aniline as a hole injection layer is obtained compared to the device using PEDOT:PSS as a hole injection layer.

Therefore, the PEDOT:PSS:PFI:aniline hole injection layer according to the present invention can reduce the acidity and improve the stability of the lower electrode and the upper metal halide perovskite thin film, and therefore the efficiency and stability of the metal halide perovskite light-emitting diodes can be improved.

### <Light-Emitting Diodes Including Graphene Barrier>

According to another embodiment of the present invention, when an electrode dissociated by an acid is used for the light-emitting diodes, a graphene barrier layer can be further included. The electrode material including indium-tin oxide (ITO), which is mainly used as an oxide transparent electrode material for light-emitting diodes, has a property of being dissociated by acid. Generally, a PEDOT:PSS conductive polymer is mainly used as a hole injection layer on the upper part of the indium-tin oxide electrode. However, PEDOT:PSS has a high pH (˜ pH 2) and dissolves ITO which is vulnerable to acid, and when the dissolved indium and tin ions are diffused into the upper emissive layer, exciton quenching can occur and reduce the efficiency of the light-emitting diodes. In particular, when the emissive layer of the light-emitting diodes is a metal halide perovskite, the efficiency of the metal halide perovskite light-emitting diodes can be significantly reduced due to the long exciton diffusion length. In order to improve the characteristic that these light emission characteristics are lowered, the optoelectronic device can include a graphene barrier layer.

Further, preferably, the light-emitting diodes containing the graphene barrier has a first electrode and a second electrode facing each other, an emission layer formed between the first electrode and the second electrode, and a PEDOT:PSS hole transport layer formed between the first electrode and the emission layer. The first electrode is an electrode dissociated by acid, and graphene barrier layer may be formed between the first electrode and the PEDOT:PSS hole transport layer.

The first electrode 20 is made of a material having a conductive property as an electrode (anode) into which holes are injected. The material constituting the first electrode 20 can be a conductive metal oxide, a metal, a metal alloy, or a carbon material. Conductive metal oxides include indium tin oxide (ITO), fluorine tin oxide (FTO), antimony tin oxide (ATO), fluorine-doped tin oxide (FTO), SnO₂, ZnO, or a combination thereof. Suitable metals or metal alloys as anodes can be Au or CuI. For carbon material, it can be graphite, graphene, or carbon nanotubes.

The graphene barrier layer is located on the first electrode.

The graphene barrier layer 12 is a carbon allotrope forming a two-dimensional plane in the shape of a hexagonal lattice of carbon atoms. The graphene not only exhibits excellent electrical and optical properties, but also has a very dense carbon lattice structure and is attracting much attention as a sealing material.

Graphene can prevent acid dissociation as a barrier layer for electrodes such as ITO that are vulnerable to acid by preventing the movement of ions in the acid.

The thickness of the graphene barrier layer can be 0.1 nm to 100 nm, but is not limited thereto.

Further, the graphene barrier layer laminated on the electrode that can be dissociated by an acid can be composed of a single layer or a plurality of layers of two or more layers.

Hereinafter, the present invention provides a method for manufacturing an optoelectronic device including a graphene barrier layer laminated on an electrode which dissociates from acid.

The method for producing an optoelectronic device includes a step of forming a graphene barrier layer on an electrode dissociated by an acid. For example, when the optoelectronic device is a light-emitting diode including a PEDOT:PSS hole transport layer, method of manufacturing the optoelectronic device may have a step of forming a graphene barrier layer on the first electrode that can be dissociated by acid, a step of forming a PEDOT:PSS hole transport layer on the graphene barrier layer, a step of forming the emission layer, and a step of forming the second electrode on the emission layer, but the present invention is not limited to these, and depending on the type of the optoelectronic device, after a step of forming the graphene barrier layer on top of the electrode that can be dissociated by an acid, methods known in the art can be used.

Therefore, in the present invention, the steps of forming a graphene barrier layer on the electrodes dissociated by an acid will be mainly described.

The step of forming the graphene barrier layer on the electrode dissociated by an acid include forming the graphene layer on the catalytic metal layer, forming the polymer layer on the above graphene layer, forming a polymer layer/graphene layer thin film by removing the catalytic metal layer, and transferring the polymer layer/graphene layer thin film onto an electrode dissociated by an acid and removing the polymer layer.

Hereinafter, the details will be described step by step.

First, a graphene layer is formed on the catalyst metal layer.

The catalyst metal layer includes any one or a combination of two or more selected from the group consisting of copper (Cu), nickel (Ni), germanium (Ge), cobalt (Co), iron (Fe), gold (Au), palladium (Pd), aluminum (Al), Chromium (Cr), Magnesium (Mg), Molybdenum (Mo), Ruthenium (Rh), Silicon (Si), Tantalum (Ta), Titanium (Ti), Tungsten (W), Uranium, Vanadium (V) and Zirconium (Zr).

The catalyst metal layer can be vacuum-deposited on a substrate with a thickness of 100 nm to 50 μm.

When the graphene layer is formed on the catalyst metal layer, a carbon precursor is deposited on the catalyst metal layer for 1 second to 5 days in the range from 200° C. to 2000° C. in an inert atmosphere or a vacuum atmosphere by using a chemical vapor deposition method.

The carbon precursor can be a carbon-containing hydrocarbon in the form of a gas or solid.

Next, a polymer layer is formed on the graphene layer.

The polymer used in the art may be used for the polymer layer, and for example, polymethyl methacrylate (PMMA) may be used, but it is not limited thereto.

The polymer layer can be formed by coating a polymer solution dissolved in a solvent on the graphene layer. A polymer layer/graphene layer/catalyst metal layer thin film is formed.

Next, the catalytic metal layer is removed to form a polymer layer/graphene layer thin film.

The removal of the catalyst metal layer can be performed by immersing the polymer layer/graphene layer/catalyst metal layer thin film in a metal etching solution.

Next, the above polymer layer/graphene layer thin film is transferred on the electrodes that can be dissociated by the acid, and after removing the polymer layer, the graphene barrier layer can be formed on the electrodes that can be dissociated by the acid.

Specifically, the polymer layer/graphene layer thin film formed in the metal etching solution is scooped out by electrode substrate which is dissociated by acid, and form polymer layer/graphene layer/electrode, and immersing it in a polymer-layer-removing solution such as acetone to remove the polymer layer, a graphene barrier layer can be formed on the electrode that can be dissociated by the acid.

The thickness of the graphene barrier layer can be 0.1 nm to 100 nm.

The graphene barrier layer can be formed as a single layer, and by repeating the graphene barrier layer formation step, a plurality of layers having two or more layers can be formed.

It is desirable that the graphene barrier layer is within the 10 layers, but if the graphene barrier layer exceeds the 10 layers, the operating voltage of light-emitting diodes can increase, and the efficiency of light-emitting diodes can decrease, which is attributed to the insulating characteristics of the graphene barrier layer.

In an optoelectronic device manufactured in this manner, the chemically stable graphene barrier layer protects the electrode vulnerable to the acid, so that the stability and durability of the electrode are improved even in an acidic environment.

In an optoelectronic device containing an acid-containing PEDOT:PSS-based hole injection layer, wherein the chemically stable graphene barrier layer protects the vulnerable electrode, the exciton quenching by the PEDOT:PSS-based hole injection layer can be prevented and a highly efficient light-emitting diodes can be manufactured.

### <Organic-Assisted Nanocrystal Pinning Process for Producing High-Efficiency Metal Halide Perovskite Light-Emitting Devices>

When the above-described metal halide perovskite is a polycrystal bulk metal halide perovskite, and a polycrystal bulk metal halide perovskite is formed as the emission layer, an emission layer can be formed using a two-step process by additionally applying an organic solution in which a small amount of organic small molecule is dissolved in organic solvent before the solvent of the emission layer is removed.

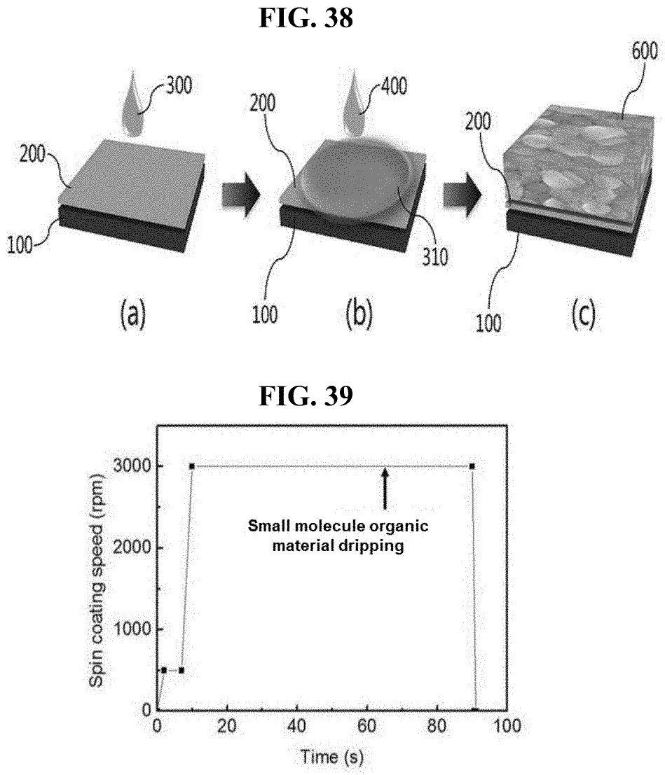

FIG. 38 a schematic diagram which shows the organic material-assisted nanocrystal pinning process, which is a method of dropping and coating an organic small molecule solution before the solvent of the emission layer evaporates while the metal halide perovskite emission layer is being coated.

Referring to FIG. 38, metal halide perovskite light-emitting diode includes the metal halide perovskite emission layer coated by the method of dropping the organic small molecule material solution while coating the metal halide perovskite emission layer according to the embodiment of the present invention (i.e. organic-material-assisted nanocrystal pinning process).

In the present specification, the above-mentioned “organic-assisted nanocrystal pinning process” is as follows. After starting to apply a metal halide perovskite solution on a substrate and before the solvent is completely evaporated, that is, before the color of the thin film changes due to crystallization, preferably, a process of dropping a small-molecular organic molecule solution within 1 to 200 seconds or applying jet printing in the form of drop-on-demand is performed after the start of metal halide perovskite coating, so the effect of reducing the size of the metal halide nanocrystals during coating exhibits. The metal halide perovskite light emission layer 600 can be formed by dropping the small molecular organic solution during coating process of the emission layer before it dries out.

First, a metal halide perovskite solution 300 and an organic small molecule solution 400 can be prepared. Next, the metal halide perovskite solution 300 can be applied and coated on the substrate. The coating methods including spin-coating, dip coating, shear coating, bar coating, slot-die coating, and inkjet printing, nozzle printing, electrohydrodynamic jet printing or spray coating can be used.

Then, during the coating, the organic small molecule solution is dropped into a small number of droplets (dripping) or droplets are sprayed through a printer device (jetting or spraying), and then a thin film with controlled size of lead halide perovskite crystal is formed. when the metal halide perovskite film in which the organic small molecule material is generally distributed is formed and crystallized, metal halide perovskite emission layer 600 in which the organic small molecule material is located at the grain boundary or on the surface can be formed [see FIG. 39(c)].

The applying small-molecular organic material solution 400 is preferably performed after coating the metal halide perovskite solution on a substrate, and before the solvent is completely evaporated (that is, before the color of the thin film is changed due to crystallization). For example, the organic small molecule solution 400 can be dropped within 1 to 200 seconds after the start of the metal halide perovskite coating.

Preferably, after the start of metal halide perovskite coating, the time to drop the small molecular organic material solution 400 include a range where the two numbers of 1 second, 2 seconds, 3 seconds, 4 seconds, 5 seconds, 6 seconds, 7 seconds, 8 seconds, 9 seconds, 10 seconds, 11 seconds, 12 seconds, 13 seconds, 14 seconds, 15 seconds, 16 seconds after the start of coating, 17 seconds, 18 seconds, 19 seconds, 20 seconds, 21 seconds, 22 seconds, 23 seconds, 24 seconds, 25 seconds, 26 seconds, 27 seconds, 28 seconds, 29 seconds, 30 seconds, 31 seconds, 32 seconds, 33 seconds. Seconds, 34 seconds, 35 seconds, 36 seconds, 37 seconds, 38 seconds, 39 seconds, 40 seconds, 41 seconds, 42 seconds, 43 seconds, 44 seconds, 45 seconds, 46 seconds, 47 seconds, 48 seconds, 49 seconds, 50 seconds, 51 seconds, 52 seconds, 53 seconds, 54 seconds, 55 seconds, 56 seconds, 57 seconds, 58 seconds, 59 seconds, 60 seconds, 61 seconds, 62 seconds, 63 seconds, 64 seconds, 65 seconds, 66 seconds, 67 seconds, 68 seconds, 69 seconds, 70 seconds, 71 seconds, 72 seconds, 73 seconds, 74 seconds, 75 seconds, 76 seconds, 77 seconds, 78 seconds, 79 seconds, 80 seconds, 85 seconds, 90 seconds, 95 seconds 100 seconds, 110 seconds, 120 seconds, 130 seconds, 140 seconds, 150 seconds, 160 seconds, 170 seconds, 180 seconds, 190 seconds, and 200 seconds, has the lower number is the lower limit and the higher value has the upper limit. The metal halide perovskite is as described above, and thus detailed description thereof will be omitted.

For example, the metal halide perovskite solution 300 can be prepared by mixing AX and BX₂ and dissolving them in a polar organic solvent. The polar organic solvent can be dimethyl sulfoxide or dimethyl formamide For example, CH₃NH₃Br and PbBr₂ can be mixed at a ratio of 1.05:1 and dissolved in dimethyl sulfoxide (DMSO) at 40 wt % to produce the above metal halide perovskite solution 300 of CH₃NH₃PbBr₃.

The above organic small molecule can be n-type organic small molecule when the metal halide perovskite material of the above metal halide perovskite emissive layer 600 has a p-type characteristic. It is not limited to thereto.

The organic small molecule matter can be n-type organic materials capable of playing a role in electron transport. For example, an n-type organic small molecule can be added to the metal halide perovskite emission layer 600 of p-type CH₃NH₃PbBr₃. The small organic material can include pyridines, —CN, —F or oxadiazole. For example, the organic small molecule includes TPBI (2,4,6-tris (2-N-phenylbenzimidazolyl) benzene), TmPyPB (2,4,6-Tri (m-pyrid-3-yl-phenyl) benzene), BmPyPB (1,3-bis (3,5-dipyrid-3-yl-phenyl) benzene), BCP (2,9-dimethyl-4,7-diphenyl-1,10-phenanthroline), PBD (2-(4)-biphenylyl)-5-phenyl-1,3,4-oxadiazole), Alq₃ (Tris-(8-hydroxyquinoline) aluminum), BAlq (aluminum (III) bis (2-methyl-8-quinolinato)-4-phenylphenolate), Bebq₂ (bis (10 hydroxybenzo [h] quinolinato) beryllium), or OXD-7 (bis [2-(4-tert-butylphenyl)-1,3,4-oxadiazo-5-yl] benzene).

The organic small molecule can have a molecular weight of 10 to 1000.

The organic small molecule can be a material such as the electron transport layer (not shown) described above.

The “organic small molecule” coated on the metal halide perovskite emission layer 600 is located at the grain boundaries of the metal halide perovskite crystal structure, reduce the interaction between crystals, and prevents growth of crystals into large grains. In addition, the n-type organic small molecular material is located at the metal halide perovskite crystal grain boundary so that the p-type metal halide perovskite emission layer 600 has intrinsic properties, improve the electrical properties, and helps to balance electrons and holes well. Therefore, by adding the organic small molecule to the grain boundary of the metal halide perovskite emission layer 600, the crystal grain size of the metal halide perovskite is reduced, and the metal halide perovskite defect is eliminated. Furthermore, the electron-hole imbalance can be eliminated by bipolar transporting electrical properties and the application limits of the metal halide perovskite light-emitting diodes can get solved.

The organic small molecule can be a p-type organic small molecule when the metal halide perovskite material of the metal halide perovskite emission layer 600 has the n-type characteristics. But it is not limited to thereto. The above p-type organic small molecule materials are TAPC (di-[4-(N,N-ditolyl-amino)-phenyl] cyclohexane) or TCTA (4,4′4″-tri (N-carbazolyl) triphenylamine). But it is not limited to thereto.

The above small molecular organic materials solution 400 may be prepared by dissolving small molecular organic materials in a non-polar organic solvent. The above non-polar organic solvents may be limited to chloroform, chlorobenzene, toluene, dichloroethane, dichloromethane, ethyl acetate or xylene, but may not be limited to thereto.

The concentration of the organic small molecule solution 400 can be 0.001 wt % to 5 wt %. For example, the concentrations of the organic small molecule solution 400 are 0.001 wt %, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 1.1 wt %, 1.2 wt %, 1.3 wt %, 1.4 wt %, 1.5 wt %, 1.6 wt %, 1.7 wt %, 1.8 wt %, 1.9 wt %, 2 wt %, 2.05 wt %, 2.1 wt %, 2.15 wt %, 2.2 wt %, 2.25 wt %, 2.3 wt %, 2.35 wt %, 2.4 wt %, 2.45 wt %, 2.5 wt %, 2.55 wt %, 2.6 wt %, 2.65 wt %, 2.7 wt %, 2.75 wt %, 2.8 wt %, 2.85 wt %, 2.9 wt %, 2.95 wt %, 3 wt %, 3.1 wt %, 3.2 wt %, 3.3 wt %, 3.4 wt %, 3.5 wt %, 3.6 wt % %, 3.7 wt %, 3.8 wt %, 3.9 wt %, 4 wt %, 4.1 wt %, 4.2 wt %, 4.3 wt %, 4.4 wt %, 4.5 wt %, 4.6 wt %, 4.7 wt %, 4.8 wt %, 4.9 wt % and 5 wt %. The range in which the lower value of two of the above is the lower limit, and the higher value is the upper limit can be included.

If the concentration of the above organic small molecule solution exceeds the above range and is less than 0.001 wt %, the effect of trap passivation by the organic small molecule material and the balance of electrons and holes may not be exhibited. When the above concentration is 5 wt % or more, organic small molecule materials that have not entered the metal halide perovskite grain boundaries are thickly accumulated on the surface (>20 nm), and the efficiency of the device can be reduced. Preferably, the device may be efficient if the organic small molecule material must have a thickness of 10 nm or less.

The thickness of the metal halide perovskite emission layer 600 can be 10 nm to 900 nm.

Referring to FIG. 38, in the process of coating the metal halide perovskite solution, the organic small molecule solution can be dropped.

FIG. 39 is a graph showing a point in time when a organic small molecule solution is dropped while the metal halide perovskite emission layer is coated.

For example, the organic small molecule solution can be dropped within 1 to 200 seconds after the start of the metal halide perovskite coating, preferably after the start of the metal halide perovskite coating, 1 second, 2 seconds, 3 seconds, 4 seconds, 5 seconds, 6 seconds, 7 seconds, 8 seconds, 9 seconds, 10 seconds, 11 seconds, 12 seconds, 13 seconds, 14 seconds, 15 seconds, 16 seconds, 17 seconds, 18 seconds, 19 seconds, 20 seconds, 21 seconds, 22 seconds, 23 seconds, 24 seconds, 25 seconds, 26 seconds, 27 seconds, 28 seconds, 29 seconds, 30 seconds, 31 seconds, 32 seconds, 33 seconds, 34 seconds, 35 seconds, 36 seconds, 37 seconds, 38 seconds, 39 seconds, 40 seconds, 41 seconds, 42 seconds, 43 seconds, 44 seconds, 45 seconds, 46 seconds, 47 seconds, 48 seconds, 49 seconds, 50 seconds, 51 seconds, 52 seconds, 53 seconds, 54 seconds, 55 seconds, 56 seconds, 57 seconds, 58 seconds, 59 seconds, 60 seconds, 61 seconds, 62 seconds, 63 seconds, 64 seconds, 65 seconds, 66 seconds, 67 seconds, 68 seconds, 69 seconds, 70 seconds, 71 seconds, 72 seconds, 73 seconds, 74 seconds, 75 seconds, 76 seconds, 77 seconds, 78 seconds, 79 seconds, 80 seconds, 85 seconds, 90 seconds, 95 seconds, 100 seconds, 110 seconds, 120 seconds, 130 seconds, 140 seconds, 150 seconds, 160 seconds, 170 seconds, 180 seconds, 190 seconds, or 200 seconds, and it can include the range in which the lower value of the two numbers above is the lower limit and the higher value is the upper limit.

For example, the organic small molecule solution can be dropped between 60 and 70 seconds after the metal halide perovskite solution is applied onto the substrate and spin coating begins.

The following chemical formula shows the structural formula of the organic small molecule material according to the present invention.

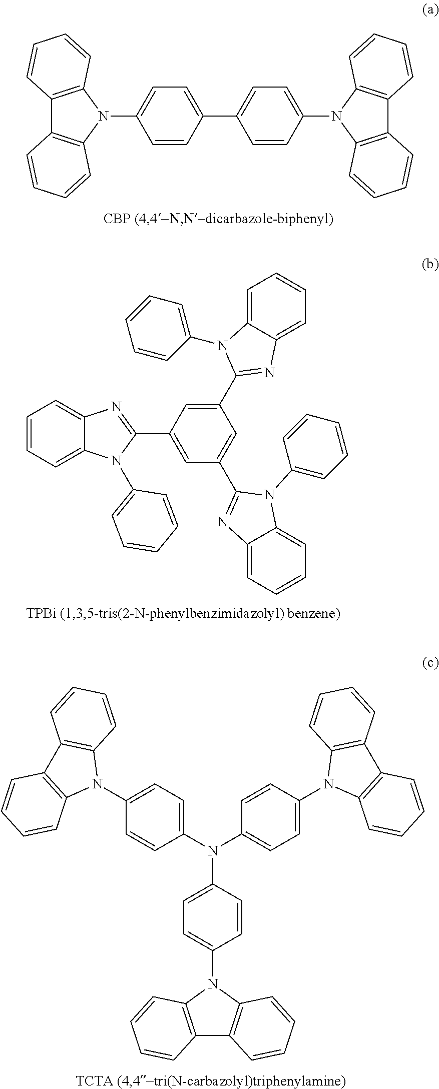 [SMILES: c1ccc2c(c1)c1ccccc1n2-c1ccc(-c2ccc(-n3c4ccccc4c4ccccc43)cc2)cc1 ; c1ccc(-n2c(-c3cc(-c4nc5ccccc5n4-c4ccccc4)cc(-c4nc5ccccc5n4-c4ccccc4)c3)nc3ccccc32)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

With reference to the formulas described above, the organic small molecule matter can be n-type organic materials capable of playing a role in electron transport. For example, an n-type organic small molecule can be added to the metal halide perovskite emission layer of p-type CH₃NH₃PbBr₃. The organic small molecule can include pyridines, —CN, —F or oxadiazole. For example, the organic small molecule includes TPBI (2,4,6-tris (2-N-phenylbenzimidazolyl) benzene), TmPyPB (2,4,6-tri(m-pyrid-3-yl-phenyl)benzene), BmPyPB (1,3-bis (3,5-dipyrid-3-yl-phenyl) benzene), BCP (2,9-dimethyl-4,7-diphenyl-1,10-phenanthroline), PBD (2-(4)-biphenylyl)-5-phenyl-1,3,4-oxadiazole), Alq₃ (tris-(8-hydroxyquinoline) aluminum), BAlq (aluminum (III) bis(2-methyl-8-quinolinato)-4-phenylphenolate), Bebq₂ (bis(10-hydroxybenzo[h]quinolinato) beryllium), or OXD-7 (bis [2-(4-tert-butylphenyl)-1,3,4-oxadiazo-5-yl] benzene)

The organic small molecule can have a molecular weight of 10 to 1000.

On the other hand, when the metal halide perovskite material of the metal halide perovskite emission layer has an n-type property, a p-type organic small molecule can be used, but is not limited thereto. For example, the organic small molecule can be TAPC (di-[4-(N,N-ditolyl-amino)-phenyl] cyclohexane) or TCTA (4,4′4″-tri (Ncarbazolyl) triphenylamine).

On the other hand, the organic small molecule can be a bipolar organic small molecule. The bipolar organic small molecule can be CBP (4,4′-N,N′-dicarbazole-biphenyl).

On the other hand, the organic small molecule has a molecular weight of 10-1000, may be compound having a thiol group (—SH), a benzene derivative containing an N atom or S atom, or benzene derivatives containing two or more atoms selected from N, S and O atoms.

The compound containing a thiol group (—SH) may be characterized in that it is represented by R—SH or HS—R—SH (R is an alkyl group, an aryl group, or a mixture of an alkyl group and an aryl group).

Benzene derivatives containing the N atom are pyridine, quinoline, isoquinoline, pyrazine, quinoxaline, acridine, pyrimidine, quinazoline, pyridazine, cinnoline, phthalazine, 1,2,3-triazine, 1,2,4-triazine, 1,3,5-triazine, pyrrole, pyrazole, indole, isoindole, imidazole, benzimidazol, purine, adenine, or indazole, but are not limited thereto.

The benzene derivative containing the S atom can include thiophene, benzothiophene or benzo[c]thiophene, but is not limited thereto.

The benzene derivative containing an O atom can include furan, benzofuran or isobenzofuran, but is not limited thereto.

The group of benzene derivatives having a plurality of atoms selected from the above N, S, and O atom includes oxazole, benzoxazole, benzisoxazole, isoxazole, thiazole, guanine, hypoxanthine, xanthine, theobromine, caffeine, uric acid, isoguanine, cytosine. thymine, uracil or benzothiazole, but is not limited to thereto.

Further, the organic small molecule additive can further include benzene derivative. The benzene derivative can include benzene, naphthalene or anthracene.

When the metal halide perovskite emission layer contains an organic small molecule additive, the organic small molecule additive locates at the crystal grain boundary in the process of growing metal halide perovskite crystal particles in the emission layer. By being located at the boundary, it is possible to prevent the quenching of the exciton occurring at the grain boundary and confine the exciton. Further, the organic small molecule additive prevents the growth of metal halide perovskite crystal particles during the formation of the metal halide perovskite thin film, thereby it is possible to induce the growth of crystal particles having a relatively smaller size compared with the crystal particles of the metal halide perovskite thin film containing no organic small molecule additive, which can increase the confinement of the exciton existing inside the metal halide perovskite crystal particles.

<Metal Halide Perovskite Light-Emitting Device Using Metal Halide Perovskite-Organic Small Molecule Host Mixed Emission Layer>

Also preferably, in the metal halide perovskite light-emitting device according to the present invention, the emission layer is a metal halide perovskite-organic small molecular host mixed emission layer in which a metal halide perovskite and an organic small molecule host are co-deposited.

The metal halide perovskite emission layer used in the metal halide perovskite light-emitting device is mainly manufactured through a solution process. However, the solution process has the disadvantages that the uniformity of the thin film formed is low, the thickness cannot be easily adjusted, and the materials that can be mixed are limited by the characteristics of the solvent.

For metal halide perovskite light-emitting devices, the most serious disincentive to performance is uneven thin films. For thin film devices consisting of laminated thin films, the unevenness of the thin film is one of the factors that significantly degrade the performance of the element by breaking the charge balance and generating leakage current. In particular, the uniformity of the thin film is crucial for the performance of metal halide perovskite light-emitting device, as metal halide perovskite varies greatly in the morphology of the thin film depending on the thin film formation conditions and surrounding environment. An example of forming uneven thin films is a common spin-coating process that forms CH₃NH₃PbBr₃, the problem is that without additional nanocrystal pinning process, the thin films are formed in a form of isolated crystals due to spontaneous crystallization. [Science 2015, 350, 1222].

However, when using the nanocrystal pinning process, the film quality of the thin film can be highly dependent on the experimental environment, so even if the same process is used, the deviation of the film quality is large. In addition, since the film quality of the thin film is improved only in the region where the nanocrystal is formed, there can be a limit in realizing a large area device.

The location of the electron-hole recombination zone in the device, i.e. the emission spectrum of the device, can be influenced by the thickness of the emission layer and the energy level of the material used.

However, by co-depositing the metal halide perovskite and the organic small molecule host, a uniform thin film can be formed, the thickness of the thin film can be easily adjusted, and the metal halide perovskite crystal to be formed can have small grains. Due to the smaller size, excitons or charge carriers can be spatially constrained to improve luminescence efficiency. Further, by adjusting the mixing ratio of the metal halide perovskite and the organic small molecule host to adjust the energy level, the degree of energy transfer can be adjusted, and the emission wavelength can be adjusted. The electron-hole recombination zone can be adjusted to improve the efficiency of electroluminescence.

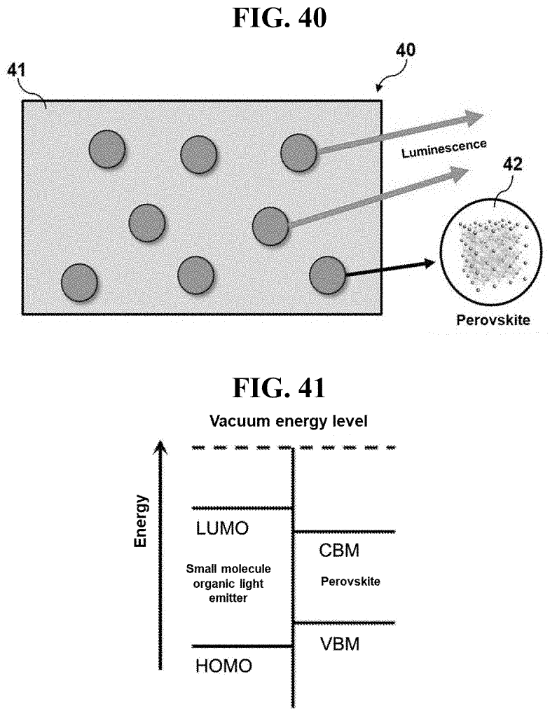

FIG. 40 is a sectional drawing showing metal halide perovskite-organic small molecule host mixed emission layer according to an embodiment of the present invention.

Referring to FIG. 40, the metal halide perovskite-organic small molecule host mixed emission layer has the metal halide perovskite 42 as a guest in the organic small molecule host 41.

In the case of a light emission layer co-deposited with a metal halide perovskite 42 and an organic small molecule host 41, the energy transfer behavior changes based on the energy level of the material. That is, the energy transfer may take place from the metal halide perovskite to the organic small molecule host(small organic molecules act as guests), or vice versa, and the emission may occur in the metal halide perovskite (the metal halide perovskite acts as a guest).

Therefore, the energy level of the material used to control the position of luminescence is very important.

In the present specification, the energy level means the magnitude of energy. Therefore, even when the energy level is displayed in the negative (−) direction from the vacuum level, the energy level is interpreted to mean the absolute value of the energy value. For example, the highest occupied molecular orbital (HOMO) energy level of an organic small molecule host means the distance between the HOMO energy level and vacuum level. The energy level of the lowest unoccupied molecular orbital (LUMO) also means the distance between the LUMO energy level and vacuum level.

In the present specification, the CBM (conduction band minimum) of the metal halide perovskite refers to the lowest level of the conduction band of the material, and the VBM (valence band maximum) of the metal halide perovskite refers to the uppermost level of the valence band of the material. The difference between the CBM and the VBM is called the bandgap.

In the present specification, the measurement of the HOMO energy level of the organic small molecule host and the VBM of the metal halide perovskite can be measured by UPS (UV photoelectron spectroscopy) which measures the ionization potential by irradiating the surface of the thin film with an ultraviolet (UV) light to emit electrons from the surface. Alternatively, the HOMO energy level is measured by using CV (cyclic voltammetry), which measures the oxidation potential via voltage sweep after dissolving the material to be measured in a solvent together with the electrolytic solution. In addition, a PYSA (Photoemission Yield Spectrometer in Air) method for measuring the ionization potential in the atmosphere can be used using an AC-3 (RKI) equipment. In the present specification, the LUMO energy level of the organic small molecule host and the CBM of the metal halide perovskite can be obtained by measuring inverse photoelectron spectroscopy (IPES) or electrochemical reduction potential. IPES is a method of determining the LUMO energy level by irradiating an electron beam onto a thin film and measuring the light emitted at the same time. In addition, in the measurement of the electrochemical reduction potential, a reduction potential may be measured through a voltage sweep after dissolving a material to be measured in a solvent together with an electrolyte. Alternatively, the LUMO energy level can be calculated using the HOMO energy level and the singlet energy level obtained by measuring the UV absorption level of the target material.

Specifically, the HOMO energy level of the present specification is measured via an AC-3 (RKI) equipment after vacuum-depositing the target material on an ITO substrate with a thickness of 50 nm or more. For the LUMO energy level, after measuring the absorption spectrum (abs.) and the photoluminescence (PL) of the prepared sample, the edge energy of absorption spectrum (or peak energy of PL) are calculated, which is the band gap (E_{g}). Then, the LUMO energy level is calculated by subtracting the band gap from the HOMO energy level measured by AC-3.

It is an objective of the present invention that light emission occurs in the metal halide perovskite 42. Therefore, the mixed emission layer of metal halide perovskite-organic small molecule host is characterized by using an organic small molecule host 41 as a host and a metal halide perovskite 42 as a guest. It is desirable to use a bandgap of energy levels of the organic small molecule host 41 used as a host that is larger than the bandgap of the metal halide perovskite used as a guest.

That is, as shown in FIG. 41, it is desirable to use an organic small molecule host of which the HOMO energy level is lower than the VBM of the metal halide perovskite, and the LUMO energy level is higher than the CBM of the metal halide perovskite.

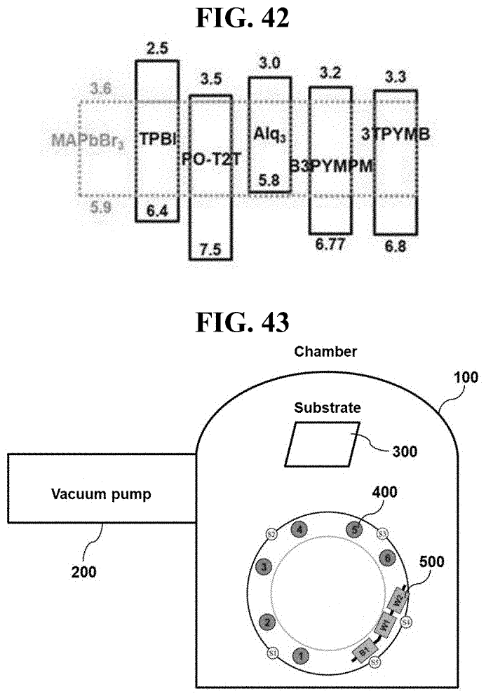

An example of such an organic small molecule host is shown in FIG. 42.

FIG. 42 shows the energy levels of the metal halide perovskite-organic small molecule host mixed emission layer according to one embodiment of the present invention.

Referring to FIG. 42, when the metal halide perovskite according to the embodiment of the present invention is used as MAPbBr₃, the VBM of the above MAPbBr₃ is (−) 5.9 eV and the CBM is (−) 3.6 eV. TBPI has a HOMO energy level of (−) 6.4 eV, which is lower than the VBM of the metal halide perovskite (MAPbBr₃), and a LUMO energy level of (−) 2.5 eV, which is higher than the CBM of the metal halide perovskite (MAPbBr₃). It can be used in the metal halide perovskite-organic small molecule host mixed emission layer according to the present invention.

As shown in FIG. 42, the organic small molecule host used in the metal halide perovskite-organic small molecule host mixed light emission layer can be 1,3,5-Tris(1-phenyl-1H-benzimidazol-2-yl)benzene (TPBI), 2,4,6-Tris[3-(diphenylphosphinyl)phenyl]-1,3,5-triazine (PO-T2T), Tris(8-hydroxyquinolinato)aluminium (Alq₃), 4,6-Bis(3,5-di(pyridin-3-yl)phenyl)-2-methylpyrimidine (B3PYMPM), Tris(2,4,6-triMethyl-3-(pyridin-3-yl)phenyl)borane (3TPYMB), 4,4′-Bis(N-carbazolyl)-1,1′-biphenyl (CBP), 9,10-di(2-naphthyl)anthracene (ADN), (Tris(4-carbazolyl-9-ylphenyl)amine) TCTA, (1,1-Bis[(di-4-tolylamino)phenyl]cyclohexane) TAPC, (2-tert-butyl-9,10-di(2-naphthyl)anthracene) (TBADN), E3, or (Bis(10-hydroxybenzo[h]quinolinato)beryllium) (BeBq₂), but is not limited thereto.

The mixing ratio of the metal halide perovskite and the organic small molecule host may be 0.01 wt % to 49.99 wt % based on the mass ratio of the metal halide perovskite to the sum of the weights of the metal halide perovskite and the organic small molecule host, but is not limited thereto. The mass ratio may include a range in which a lower value of two numbers among 0.01 wt %, 0.2 wt %, 0.4 wt %, 0.6 wt %, 0.8 wt %, 1 wt %, 1.2 wt %, 1.4 wt %, 1.6 wt %, 1.8 wt %, 2 wt %, 2.2 wt %, 2.4 wt %, 2.6 wt %, 2.8 wt %, 3 wt %, 3.1 wt %, 3.2 wt %, 3.3 wt %, 3.4 wt %, 3.5 wt %, 3.6 wt %, 3.7 wt %, 3.8 wt %, 3.9 wt %, 4 wt %, 4.1 wt %, 4.2 wt %, 4.3 wt %, 4.4 wt %, 4.5 wt %, 4.6 wt %, 4.7 wt %, 4.8 wt %, 4.9 wt %, 5 wt %, 5.2 wt %, 5.4 wt %, 5.6 wt %, 5.8 wt %, 6 wt %, 6.2 wt %, 6.4 wt %, 6.6 wt %, 6.8 wt %, 7 wt %, 7.2 wt %, 7.4 wt %, 7.6 wt %, 7.8 wt %, 8 wt %, 8.2 wt %, 8.4 wt %, 8.6 wt %, 8.8 wt %, 9 wt %, 9.2 wt %, 9.4 wt %, 9.6 wt %, 9.8 wt %, 10 wt %, 10.5 wt %, 11 wt %, 11.5 wt %, 12 wt %, 12.5 wt %, 13 wt %, 13.5 wt %, 14 wt %, 14.5 wt %, 15 wt %, 15.5 wt %, 16 wt %, 16.5 wt %, 17 wt %, 17.5 wt %, 18 wt %, 18.5 wt %, 19 wt %, 19.5 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43.127 wt %, 44 wt %, 45 wt %, 46 wt %, 47 wt %, 48 wt %, 49 wt %, and 49.99 wt % is a lower limit and a higher value is an upper limit.

If the mass ratio of the metal halide perovskite to the sum of the weights of the metal halide perovskite and the organic small molecule host outside the above range is less than 0.01 wt %, the energy transfer from organic small molecule to the metal halide perovskite is not effectively performed in the organic small molecule host, so that the organic small molecule host may still emit their own light.

It is preferable that the metal halide perovskite-organic small molecule host mixed light emission layer according to the present invention is formed by a vapor deposition method. The deposition method may include vacuum deposition, thermal deposition, flash deposition, laser deposition, chemical vapor deposition, atomic layer deposition, physical vapor deposition, physical-chemical co-evaporation deposition, sequential vapor deposition, or solution process-assisted thermal deposition.

Vacuum evaporation may be preferably used as the deposition method, and in this case, the vacuum evaporation may be performed in high vacuum and low vacuum. In an embodiment of the present invention, a light emission layer is formed using the vacuum evaporator shown in FIG. 43.

Referring to FIG. 43 in detail, the vacuum evaporator includes a chamber 100 and a vacuum pump 200, and in the chamber 100, a substrate 300 on which a sample substrate to be deposited is placed, a crucible containing the perovskite precursor material 400 and the organic small molecule host material 500, and a heat source for heating the crucible under the crucible. In the vacuum evaporation method, after placing the substrate 300 on the upper side in the chamber 100 of the vacuum evaporator and loading the metal halide perovskite precursor material 400 and the organic small molecule host material 500 at the lower side, when each material is evaporated by heating or an electron beam or the like in a vacuum state, the vaporized materials are synthesized while being deposited on the substrate to form a metal halide perovskite-organic small molecule host mixed light emission layer.

The metal halide perovskite-organic small molecule host mixed light emission layer according to the present invention can form a uniform thin film by co-depositing the metal halide perovskite and an organic small molecule host, and electroluminescence efficiency can be improved by controlling an energy level and an electron-hole recombination zone.

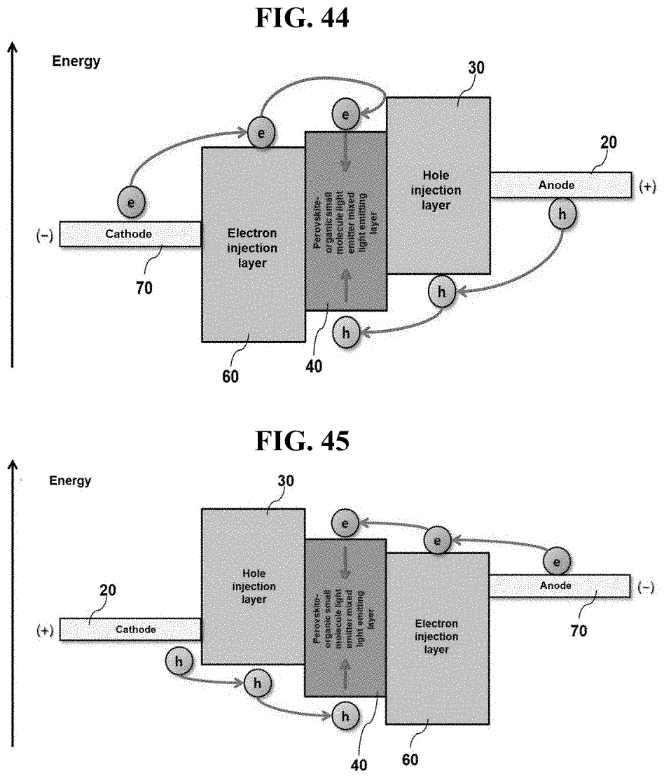

FIG. 44 shows energy levels of layers in a light-emitting device (normal structure) including a metal halide perovskite-organic small molecule host mixed light emission layer according to an embodiment of the present invention.

FIG. 45 shows energy levels of layers in a light-emitting device (inverted structure) including a metal halide perovskite-organic small molecule host mixed light emission layer according to an embodiment of the present invention.

FIGS. 44 and 45, it is desirable that the energy level of VBM of the light emission layer 40 is lower than that of the HOMO of the hole injection layer, and higher than the energy level of the HOMO of the electron transport layer in the light-emitting device according to the present invention. When having such an energy level, if a forward bias is applied to the light-emitting device, it becomes easy for holes (h) from the anode 20 to flow into the light emission layer 40 through the hole injection layer 30.

In addition, it is desirable that the energy level of CBM of the light emission layer is lower than the energy level of LUMO of the hole injection layer, and is preferably higher than the energy level of LUMO of the electron transport layer in the light-emitting device according to the present invention. When a forward bias is applied to the light-emitting device, it becomes easy for electrons (e) from the cathode 70 to flow into the light emission layer 40 through the electron injection layer 60.

The metal halide perovskite is as described above, and a detailed description thereof will be omitted.

### <Metal Halide Perovskite Light-Emitting Device Including Multi-Dimensional Hybrid Light Emission Layer>

According to another embodiment of the present invention, the emission layer may include a multi-dimensional metal halide perovskite hybrid emission layer.

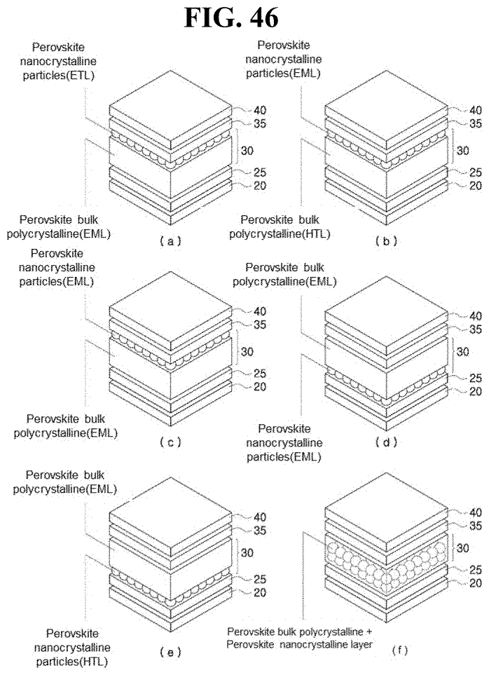

FIG. 46 is an example of a structure of a light-emitting diode including a multi-dimensional metal halide perovskite hybrid light emission layer according to an embodiment of the present invention.

As shown in FIG. 46, the above multi-dimensional metal halide perovskite hybrid light emission layer may be formed by sequential deposition or simultaneous deposition of metal halide perovskite bulk polycrystal films and metal halide perovskite nanocrystal particles films.

The multi-dimensional metal halide perovskite hybrid light emission layer can induce surface passivation of nanocrystal particle through a metal halide perovskite bulk polycrystal, and improve device luminescence efficiency by confining excitons in the nanocrystal particle by coexisting metal halide perovskite nanocrystal particles and metal halide perovskite bulk polycrystals in the light emission layer.

In addition, a light emission layer composed of two layers can be produced by forming a metal halide perovskite nanocrystal particle layer on the metal halide perovskite bulk polycrystals in the multi-dimensional metal halide perovskite hybrid light emission layer according to the present invention, and it is possible to implement a multicolor light-emitting device that is difficult to implement in a single-layered light-emitting device.

The multi-dimensional metal halide perovskite hybrid light emission layer 30 may partially serve as the hole injection layer 25. Metal halide perovskite is a promising material as a light emitter, but basically, it has a high potential as a charge transport layer due to high carrier mobility and long carrier diffusion length, so its role can be extended not only to light emission but also to charge transport. In addition, since the energy level can be easily adjusted through a method such as halide ion exchange in a unit lattice of a metal halide perovskite, it can be used for injecting charge carriers into various light emission layers.

Accordingly, in the multi-dimensional metal halide perovskite hybrid light emission layer of the present invention, the metal halide perovskite bulk polycrystals having high charge mobility and long exciton diffusion length functions as a charge transport layer. Also, since the metal halide perovskite nanocrystal can also serve as a charge transport layer, it is possible to improve device efficiency by promoting hole injection or electron injection into the light emission layer.

The method of forming the multi-dimensional metal halide perovskite hybrid light emission layer may be formed by various methods, and a specific method will be described in detail in the following manufacturing method section.

(a) Dripping Method (FIG. 47(a))

The steps of forming the multi-dimensional metal halide perovskite hybrid light emission layer 30 include preparing a metal halide perovskite bulk polycrystal precursor 1 solution and a metal halide perovskite nanocrystal 2 solution, applying the metal halide perovskite bulk polycrystal precursor 1 solution onto the first electrode 20 or the hole injection layer, and coating the bulk polycrystal material 1 and the metal halide perovskite nanocrystal 2 together by dropping the metal halide perovskite nanocrystal particle 2 solution before the coating of the metal halide perovskite bulk polycrystal precursor 1 solution is completed.

First, a metal halide perovskite bulk polycrystal precursor 1 solution and a metal halide perovskite nanocrystal particle 2 solution are prepared.

The metal halide perovskite bulk polycrystal 1 and the metal halide perovskite nanocrystal particles 2 may use a material having the same chemical structure or a material having a different chemical structure.

The metal halide perovskite bulk polycrystal precursor 1 solution can be prepared by dissolving the metal halide perovskite in a polar solvent (first solution).

In this case, the polar solvent may be selected from dimethylformamide, dimethyl sulfoxide, γ-butyrolactone, N-methylpyrrolidone, and isopropyl alcohol, but is not limited thereto.

Since the metal halide perovskite is the same as described above, a detailed description will be omitted.

On the other hand, such a metal halide perovskite can be prepared by combining AX and BX₂ in a certain ratio. That is, the first solution may be formed by dissolving AX and BX₂ in a polar solvent at a predetermined ratio. For example, a first solution in which ABX₃ metal halide perovskite is dissolved may be prepared by dissolving AX and BX₂ in a 1:1 ratio in a polar solvent.

The forming metal halide perovskite nanocrystal 2 solution above include preparing a first solution in which a metal halide perovskite is dissolved in a polar solvent and a second solution in which a surfactant is dissolved in a non-polar solvent or a polar solvent, and mixing the first solution with the second solution to form metal halide perovskite nanocrystal particles.

First, since the method of preparing the first solution is the same as the method of preparing the metal halide perovskite bulk polycrystal precursor solution described above, a detailed description will be omitted.

The second solution is prepared by dissolving a surfactant in a non-polar solvent or a polar solvent.

The non-polar solvent may be selected from methanol, ethanol, tert-butanol, xylene, toluene, hexane, cyclohexene, dichloroethylene, trichloroethylene, chloroform, chlorobenzene, xylene, toluene, hexane, cyclohexene and dichlorobenzene In addition, the polar solvent may be selected from dimethylformamide, dimethyl sulfoxide, γ-butyrolactone, N-methylpyrrolidone, and isopropyl alcohol, but is not limited thereto.

The surfactant may include an amine ligand, an organic acid, an organic ammonium ligand, or an inorganic ligand.

The amine ligand may be selected from N,N-diisopropylethylethylamine, ethylenediamine, hexamethylenetetraamine, methylamine, hexylamine, oleylamine, N,N,N,N-tetramethylenediamine, triethylamine, diethanolamine, and 2,2-(ethylenedioxyl) bis-(ethylamine), but is not limited thereto.

The organic acid includes carboxylic acid or phosphonic acid, and the carboxylic acid can be selected from 4,4′-Azobis(4-cyanovaleric acid), acetic acid, 5-aminosalicylic acid, acrylic acid, L-aspentic acid, 6-bromohexanoic acid, bromoacetic acid, dichloroacetic acid, ethylenediaminetetraacetic acid, isobutyric acid, itaconic acid, maleic acid, r-maleimidobutyric acid, L-malic acid, 4-nitrobenzoic acid, 1-pyrenecarboxylic acid, hexanoic acid, octanoic acid, decanoic acid, undecanoic acid, dodecanoic acid, hexadecenoic acid, octadecanoic acid and oleic acid.

Phosphonic acid can be selected from n-hexylphosphonic acid, n-octylphosphonic acid, n-decylphosphonic acid, n-dodecylphosphonic acid, n-tetradecylphosphonic acid, n-hexadecylphosphonic acid, and n-octadecylphonic acid.

The organic ammonium ligand is a ligand of the structure of alkyl-X, and the alkyl can be selected from the group consisting of an acyl alkyl (CₙH₂ₙ₊₁), a polyhydric alcohol (CₙH₂ₙ₊₁OH) including a primary alcohol, a secondary alcohol, or a tertiary alcohol, alkylamine (alkyl-N) including hexadecyl amine, 9-octadecenylamine, or 1-amino-9-octadecene (C₁₉H₃₇N), p-substituted aniline, phenyl ammonium and fluorine ammonium, and X may be Cl, Br or I.

In the step of forming nanocrystals by mixing the first solution with the second solution, the above first solution can be mixed with the above second solution to form nanocrystal particles, using methods such as spraying, dripping finely drop by drop, or dropping at one time. In addition, the second solution may be stirred. For example, a first solution containing an organic-inorganic metal halide perovskite (OIP) can be slowly added dropwise to a second solution containing amine ligands, organic acids (carboxylic acid or phosphonic acid), organic ammonium ligands, or inorganic ligand surfactants with vigorous stirring.

When the first solution is dropped into the second solution and mixed, organic-inorganic metal halide perovskite (OIP) is precipitated from the second solution due to a difference in solubility. The ligand (amine-based ligand) premixed in the second solution adheres to the crystal structure of the metal halide perovskite, thereby reducing the difference in solubility to prevent rapid precipitation of the metal halide perovskite. In addition, a carboxylic acid surfactant or phosphonic acid surfactant attaches to the surface of OIP precipitated from the second solution, stabilizing the nanocrystals, creating well-dispersed organic-inorganic metal halide perovskite nanocrystals (OIP-NCs). Accordingly, it is possible to prepare a metal halide perovskite nanocrystal particle that includes an organic-inorganic metal halide perovskite nanocrystal and a plurality of inorganic or the organic ligands surrounding the nanocrystal.

However, when the compatibility between the first solution and the second solution is low, recrystallization may not occur, and in this case, a demulsifier may be additionally added.

Tert-butanol may be used as the demulsifier, but is not limited thereto.

The prepared metal halide perovskite nanocrystal solution is a colloidal solution in which metal halide perovskite nanocrystal particles are dispersed in a solvent.

At this time, since the metal halide perovskite nanocrystal solution contains unreacted materials and can be re-dissolved by a polar solvent containing the generated nanocrystal particle, in order to maintain the shape of the nanocrystal particle, the step of separating only the nanocrystal particle by centrifugation or the like and redispersing them in a non-polar solvent may be additionally performed.

In addition, the form of the metal halide perovskite nanocrystal may be a form generally used in the related art. The shape of the metal halide perovskite nanocrystal may be a 0-dimensional, 1-dimensional or 2-dimensional shape. As an example, it may be in the form of a sphere, an ellipsoid, a hollow cube, a pyramid, a cylinder, a cone, an elliptic column, hollow sphere, Janus particle, prism, multipod, polyhedron, nano tube, nano wire, nano fiber or nanoplatelet.

In addition, the size of the crystalline particles may be 1 nm to 10 μm or less. For example, it can be 1 nm, 2nm, 3 nm, 4 nm, 5 nm, 6 nm, 7 nm, 7.5 nm, 8 nm, 8.5 nm, 9 nm, 9.5 nm, 10 nm, 10.5nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 μm. The size of the particle can be defined as a range in which the lower value among the two numbers selected from the above is taken as the minimum value and the larger value as the maximum value. It is preferably 8 nm or more and 300 nm or less, and more preferably 10 nm or more and 30 nm or less. On the other hand, the size of the crystalline particles means a size that does not take into account the length of a ligand to be described later, that is, the size of the remaining portions excluding the ligand. When the size of the crystalline particles is 1 μm or more, there is a fundamental problem in that excitons do not emit light due to thermal ionization and delocalization of charge carriers in a large crystal, but are separated into free charge carriers and disappear. In addition, more preferably, as described above, the size of the crystal particles may be greater than or equal to a Bohr diameter. The thermal ionization and delocalization of the charge carrier may gradually appear when the size of the nanocrystal exceeds 100 nm. If it is more than 300 nm, the phenomenon will appear more, and if it is more than 1 μm, it is in completely bulk regime and is subject to the above phenomenon. For example, when the nanocrystal particles are spherical, the diameter of the nanocrystal may be 1 nm to 10 μm. It may preferably be 1 nm, 3 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 um.

In addition, the band gap energy of the nanocrystal particle may be 1 eV to 5 eV. Preferably, the band gap energy of the nanocrystal may include a range in which the lower value of two numbers of 1 eV, 1.1 eV, 1.2 eV, 1.3 eV, 1.4 eV, 1.5 eV, 1.6 eV, 1.7 eV, 1.8 eV, 1.81 eV, 1.82 eV, 1.83 eV, 1.84 eV, 1.85 eV, 1.86 eV, 1.87 eV, 1.88 eV, 1.89 eV, 1.9 eV, 1.91 eV, 1.92 eV, 1.93 eV, 1.94 eV, 1.95 eV, 1.96 eV, 1.97 eV, 1.98 eV, 1.99 eV, 2 eV, 2.01 eV, 2.02 eV, 2.03 eV, 2.04 eV, 2.05 eV, 2.06 eV, 2.07 eV, 2.08 eV, 2.09 eV, 2.1 eV, 2.11 eV, 2.12 eV, 2.13 eV, 2.14 eV, 2.15 eV, 2.16 eV, 2.17 eV, 2.18 eV, 2.19 eV, 2.2 eV, 2.21 eV, 2.22 eV, 2.23 eV, 2.24 eV, 2.25 eV, 2.26 eV, 2.27 eV, 2.28 eV, 2.29 has a lower limit and a higher value has an upper limit.

Accordingly, since the energy band gap is determined according to the constituent material or crystal structure of the nanocrystal, light having a wavelength of, for example, 200 nm to 1300 nm may be emitted by controlling the constituent material of the nanocrystal particle. In addition, preferably, the nanocrystal may emit ultraviolet, blue, green, red, and infrared light.

The ultraviolet light may include a range in which a low value of two numbers of 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, 430 nm has a lower limit and a high value has an upper limit. The blue light may include a range in which a low value of two numbers of 440 nm, 450 nm, 451 nm, 452 nm, 453 nm, 454 nm, 455 nm, 456 nm, 457 nm, 458 nm, 459 nm, 460 nm, 461 nm, 462 nm, 463 nm, 464 nm, 465 nm, 466 nm, 467 nm, 468 nm, 469 nm, 470 nm, 471 nm, 472 nm, 473 nm, 474 nm, 475 nm, 476 nm, 477 nm, 478 nm, 479 nm, 480 nm, 490 nm has a lower limit and a high value has an upper limit. The green light may include a range in which a low value of two numbers of 500 nm, 501 nm, 502 nm, 503 nm, 504 nm, 505 nm, 506 nm, 507 nm, 508 nm, 509 nm, 510 nm, 511 nm, 512 nm, 513 nm, 514 nm, 515 nm, 516 nm, 517 nm, 518 nm, 519 nm, 520 nm, 521 nm, 522 nm, 523 nm, 524 nm, 525 nm, 526 nm, 527 nm, 528 nm, 529 nm, 530 nm, 531 nm, 532 nm, 533 nm, 534 nm, 535 nm, 536 nm, 537 nm, 538 nm, 539 nm, 540 nm, 541 nm, 542 nm, 543 nm, 544 nm, 545 nm, 546 nm, 547 nm, 548 nm, 549 nm, 550 nm, 560 nm, 570 nm, 580 nm has a lower limit and a high value has an upper limit. The red light may include a range in which a low value of two numbers of 590 nm, 600 nm, 601 nm, 602 nm, 603 nm, 604 nm, 605 nm, 606 nm, 607 nm, 608 nm, 609 nm, 610 nm, 611 nm, 612 nm, 613 nm, 614 nm, 615 nm, 616 nm, 617 nm, 618 nm, 619 nm, 620 nm, 621 nm, 622 nm, 623 nm, 624 nm, 625 nm, 626 nm, 627 nm, 628 nm, 629 nm, 630 nm, 631 nm, 632 nm, 633 nm, 634 nm, 635 nm, 636 nm, 637 nm, 638 nm, 639 nm, 640 nm, 641 nm, 642 nm, 643 nm, 644 nm, 645 nm, 646 nm, 647 nm, 648 nm, 649 nm, 650 nm, 660 nm, 670 nm, 680 nm, 690 nm, 700 nm has a lower limit and a high value has an upper limit. The infrared light may include a range in which a low value of two numbers of 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1000 nm, 1010 nm, 1020 nm, 1030 nm, 1040 nm, 1050 nm, 1060 nm, 1070 nm, 1080 nm, 1090 nm, 1100 nm, 1110 nm, 1120 nm, 1130 nm, 1140 nm, 1150 nm, 1160 nm, 1170 nm, 1180 nm, 1190 nm, 1200 nm, 1210 nm, 1220 nm, 1230 nm, 1240 nm, 1250 nm, 1260 nm, 1270 nm, 1280 nm, has a lower limit and a high value has an upper limit.

Next, the precursor solution of the metal halide perovskite bulk polycrystal 1 is coated on the first electrode.

In this case, the first electrode may be rotated so that the precursor solution of the metal halide perovskite bulk polycrystal 1 is evenly applied on the first electrode.

The rotation speed is preferably 1000 rpm to 8000 rpm, if it is less than 1000 rpm, there is a problem in forming a uniform thin film, and if it exceeds 8000 rpm, there is a problem in uniform crystal growth as evaporation of the solvent is remarkably accelerated, and there is a problem in forming a multidimensional metal halide perovskite light emission layer because it is difficult to incorporate the metal halide perovskite nanocrystals into the layer.

In one embodiment of the present invention, while rotating the first electrode at 3000 rpm, the precursor solution of the metal halide perovskite bulk polycrystal 1 is coated.

The coating may consist of spin coating, bar coating, nozzle printing, spray printing, slot die coating, gravure printing, inkjet printing, screen printing, electrohydrodynamic jet printing, or electrospray.

Next, before the coating of the precursor solution of the precursor solution of the metal halide perovskite bulk polycrystal 1 is completed, by dripping the metal halide perovskite nanocrystal 2 solution, the metal halide perovskite bulk polycrystal and metal halide perovskite nanocrystal particles are coated together.

The time when the coating of the precursor solution of the metal halide perovskite bulk polycrystal 1 is completed is the time when solvent of the precursor solution of the metal halide perovskite bulk polycrystal 1 is evaporated and crystallization is completed, and it is different for each material but it takes about 80 seconds. Therefore, it is preferable to drop the metal halide perovskite nanocrystal 2 solution within 1 second to 200 seconds after the coating of the metal halide perovskite bulk polycrystal precursor solution.

In an embodiment of the present invention, the metal halide perovskite nanocrystal 2 solution is dropped and coated together 20 seconds after applying the precursor solution of the metal halide perovskite bulk polycrystal 1.

After coating, heat treatment may be performed to increase the density of the thin film.

The heat treatment may be performed at 80° C. to 120° C.

In an embodiment of the present invention, the hybrid thin film was heat-treated at 90° C. for 10 minutes.

In this hybrid thin film coated with a metal halide perovskite bulk polycrystal 1 precursor solution and a metal halide perovskite nanocrystal 2 solution, metal halide perovskite nanocrystals act as a crystallization seed, providing many crystallization sites, which induces the granular structure of the thin film, as shown in FIG. 5. Accordingly, compared to the conventional single-dimensional light emission layer made of a perovskite material with only single dimension of the crystal structure, it is possible to exhibit remarkably improved photoluminescence intensity.

The thickness of the formed multi-dimensional metal halide perovskite hybrid light emission layer may be 10 nm to 10 μm.

In addition, the emission wavelength of the multi-dimensional metal halide perovskite hybrid emission layer may be 200 nm to 1300 nm.

In addition, the band gap energy of the multi-dimensional metal halide perovskite hybrid light emission layer may be 1 eV to 5 eV.

(b) Over-Coating Method (FIG. 47(b))

In addition, the steps of forming the multidimensional metal halide perovskite hybrid light emission layer 30 include preparing a metal halide perovskite bulk polycrystal 1 precursor solution and a metal halide perovskite nanocrystal solution, forming a metal halide perovskite bulk polycrystal thin film by coating the precursor solution of the metal halide perovskite bulk polycrystal 1 on a first electrode or a hole injection layer, and coating the metal halide perovskite nanocrystal 2 solution on the formed metal halide perovskite bulk polycrystal 1 thin film.

In the case of metal halide perovskite nanocrystal 2, since the crystals are dispersed in an anti-solvent that does not dissolve and are used to make a thin film, it is possible to coat on the previously formed metal halide perovskite bulk polycrystal film 1.

Since the steps of preparing the precursor solution of the metal halide perovskite bulk polycrystal 1 and the metal halide perovskite nanocrystal particle 2 solution are the same as described above, a detailed description will be omitted.

Next, a metal halide perovskite bulk polycrystal 1 precursor solution is coated on the hole injection layer.

The difference between the overcoating method and the above-described dripping method is that the dripping method is to make a thin film by coating a solution of low-dimensional metal halide perovskite nanocrystal 2 before the high-dimensional metal halide perovskite bulk polycrystal 1 thin film is formed, however, the overcoating method is to coat metal halide perovskite nanocrystal 2 after forming a metal halide perovskite bulk polycrystal film 1.

In order to evenly apply the metal halide perovskite bulk polycrystal 1 precursor solution onto the first electrode 20 or the hole injection layer 25, the first electrode 20 or the hole injection layer 25 can be rotated. Likewise, even when applying the metal halide perovskite nanocrystal 2 solution, the object to be coated may be rotated in order to apply evenly.

The rotational speed is preferably 1000 to 8000 rpm. If it is less than 1000 rpm, there is a problem in forming a uniform thin film, and if it exceeds 8000 rpm, evaporation of the solvent is remarkably accelerated, resulting in a difficulty in uniform crystal growth.

The coating can be performed by spin coating, bar coating, nozzle printing, spray printing, slot die coating, gravure printing, inkjet printing, screen printing, electrohydrodynamic jet printing, or electrospray.

In addition, after coating the nanocrystal 2, a purification process for removing impurities from the nanocrystal 2 solution may be additionally performed, and the purification process may be performed by applying a non-polar solvent.

In an embodiment of the present invention, impurities were removed by applying the non-polar solvent while rotating at a speed of 3000 rpm for 20 seconds.

After coating, heat treatment may be performed to increase the density of the thin film.

The heat treatment may be performed at 80° C. to 120° C.

In an embodiment of the present invention, the prepared metal halide perovskite bulk polycrystal 1 thin film and the metal halide perovskite nanocrystal 2 layer are heat-treated at 90° C. for 10 minutes.

The multi-dimensional metal halide perovskite hybrid light emission layer manufactured by the overcoating method according to an embodiment of the present invention exhibits remarkably improved light emission intensity compared to the conventional single-dimensional light emission layer made of perovskite material with only single dimension of the crystal structure. When a light-emitting device is fabricated using metal halide perovskite bulk polycrystals and nanocrystal having different emission wavelength as a light emission layer, electroluminescence can be generated in both wavelength.

(c) Polycrystal Vacuum Deposition Method (FIG. 47(c))

In addition, the steps of forming the multidimensional metal halide perovskite hybrid light emission layer 30 include preparing a solution of a metal halide perovskite bulk polycrystal 1 precursor and a metal halide perovskite nanocrystal particle 2, forming a metal halide perovskite nanocrystal 2 layer by coating the metal halide perovskite nanocrystal 2 solution on the first electrode 20 or the hole injection layer 25, and vacuum deposition of the metal halide perovskite bulk polycrystal 1 precursor on the formed metal halide perovskite nanocrystalline 2 layer.

(d) Simultaneous Deposition Method (FIG. 47(d))

In addition, the step of forming the multidimensional metal halide perovskite hybrid light emission layer 30 can be performed by simultaneous vacuum deposition of metal halide perovskite bulk polycrystal 1 precursors and metal halide perovskite nanocrystal 2.

For the polycrystal vacuum deposition method or simultaneous deposition method, the deposition method can be selected from co-deposition, thermal deposition, flash deposition, laser deposition, chemical vapor deposition, atomic layer deposition, physical vapor deposition, physical-chemical co-evaporation deposition, sequential vapor deposition, solution process solution process-assisted thermal deposition and spray deposition.

### <Metal Halide Perovskite Light-Emitting Device Including a Metal Halide Perovskite Light Emission Layer Having a 3D/2D Core-Shell Crystal Structure>

According to another embodiment of the present invention, the emission layer may be a metal halide perovskite film having a 3D/2D core-shell crystal structure.

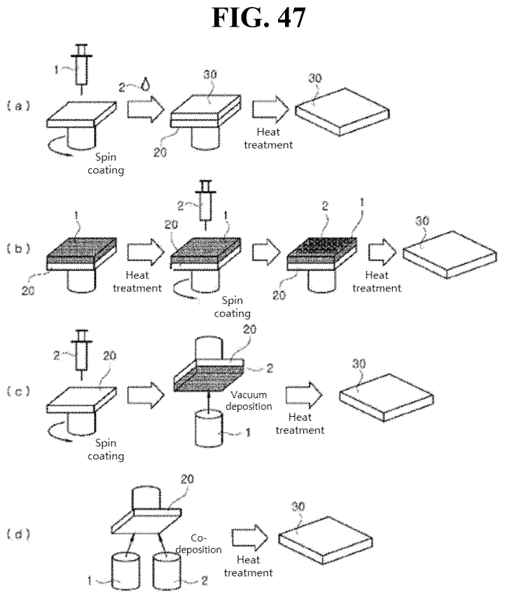

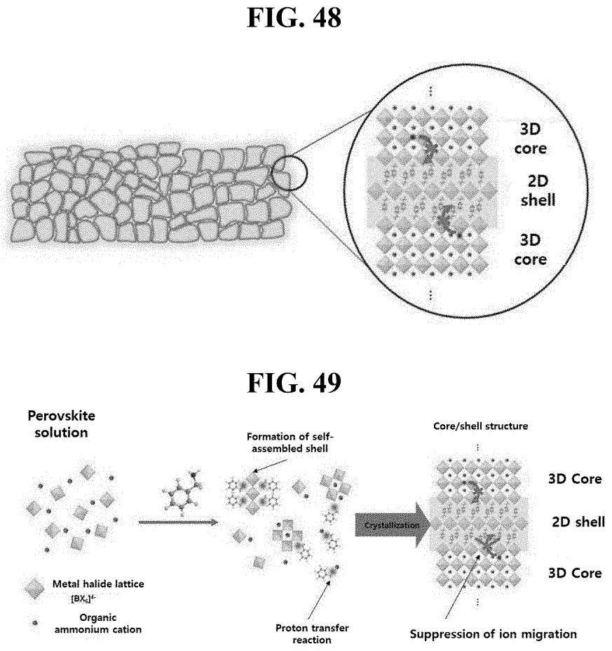

FIG. 48 shows a core/shell structure of a metal halide perovskite film according to an embodiment of the present invention.

Referring to FIG. 48, the metal halide perovskite film according to the present invention is composed of a core made of a three-dimensional metal halide perovskite crystal, and a shell made of a two-dimensional metal halide perovskite surrounding the core.

The core is composed of a three-dimensional metal halide perovskite crystal of ABX₃ or A′₂Aₙ₋₁BX₃ₙ₊₁ (n is an integer of 2 to 100), and the shell surrounding the core consists of a two-dimensional metal halide perovskite of Y₂Aₘ₋₁BX₃ₘ₊₁ (m is an integer of 1 to 100) including phenylalkanamine compound (Y) of Chemical Formula 1.

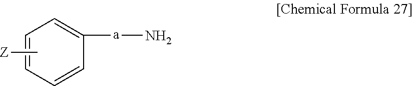

(In Chemical Formula 27, ‘a’ is a unsubstituted or amine-substituted linear or branched alkyl of C₁ to C₁₀, and Z is F or CF₃.)

A and A′ may be monovalent cations, B may be a metal material, and X may be a halogen element.

The monovalent cation may be a monovalent organic cation or an alkali metal. For example, the monovalent organic cation may be organic ammonium (RNH₃)⁺, organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺, (CₙF₂ₙ₊₁NH₃)₂⁺ (x, n is an integer greater than or equal to 1, R=hydrocarbon derivative, H, F, Cl, Br, or I) or combinations thereof, but is not limited thereto. The alkali metal may be Li⁺, Na⁺, K⁺, Rb⁺, Cs⁺, Fr⁺, or combinations thereof, but is not limited thereto.

In addition, preferably, the organic cations may be acetamidinium, azaspironanium, benzene diammonium, benzylammonium, butanediammonium, iso-butylammonium, n-butylammonium, t-butylammonium, cyclohexylammonium, cyclohexylmethylammonium, diazobicyclooctanedinium, diethylammonium, N,N-diethylethane diammonium, dimethylammonium, dodecylammonium, ethanediammonium, ethylammoniuium, 4-fluoro-benzylammonium, 4-fluoro-phenylethylammonium 4-fluoro-phenylammonium, formamidinium, guanidinium, hexanediammnium, hexylammonium, imidazolium, 2-methoxyethylammonium, 4-methoxy-phenylethylammonium, 4-methoxy-phenylammonium, methylammonium, morpholinium, octylammonium, pentylammonium, piperazinediium, piperidinium, propanediammonium, iso-propylammonium, di-isopropylammonium, n-propylammonium, pyridinium, 2-pyrrolidin-1-ium-1-yethylammonium, pyrrolidinium, quinclidin-1-ium, 4-trifluoromethyl-benzylammonium, 4-trifluoromethyl ammonium, quaternary ammonium cations such as benzalkonium chloride, dimethyldioctadecylammonium chloride, trimethylglycine, choline or combinations thereof, but are not limited thereto.

The B may be a divalent transition metal, a rare earth metal, an alkaline earth metal, a monovalent metal, a combination of a trivalent metal, an organic substance (a monovalent, divalent, trivalent cation), or a combination thereof. In addition, preferably, the divalent transition metal, rare earth metal, and alkaline earth metal may be Be²⁺, Mg²⁺, Ca²⁺, Sr²⁺, Ba²⁺, Ra²⁺, Mn²⁺, Fe²⁺, Co²⁺, Ni²⁺, Cu²⁺, Zn²⁺, Ru²⁺, Pd²⁺, Cd²⁺, Pt²⁺, Hg²⁺, Ge²⁺, Sn²⁺, Pb²⁺, Se²⁺, Te²⁺, Po²⁺, Bi²⁺, Eu²⁺, No²⁺, or combinations thereof, but are not limited thereto. Monovalent metal may be Li⁺, Na⁺, K⁺, Rb⁺, Cs⁺, Fr⁺, Ag⁺, Hg⁺, Ti⁺, or combinations thereof, trivalent metal may be Cr³⁺, Fe³⁺, Co³⁺, Ru³⁺, Rh³⁺, Ir³⁺, Au³⁺, Al³⁺, Ga³⁺, In³⁺, Ti³⁺, As³⁺, Sb³⁺, Bi³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Ac³⁺, Am³⁺, Cm³⁺, Bk³⁺, Cf³⁺, Es³⁺, Fm³⁺, Md³⁺, Lr³⁺, or combinations thereof.

In addition, X may be F⁻, Cl⁻, Br⁻, I⁻, At⁻, or combinations thereof.

The three-dimensional metal halide perovskite crystal may be a metal halide perovskite, and the crystal structure of the metal halide perovskite has a central metal (B) in the center, and has a face centered cubic (FCC) structure. 6 halogen elements (X) are located on all surfaces of the hexahedron, and 8 elements of A or A′ (organic ammonium, organic phosphonium, or alkali metal) are located at all vertices of the hexahedron. Also, all sides of the hexahedron are orthogonal, and it includes not only a cubic structure with the same horizontal length, vertical length, and height, but also a tetragonal structure having the same horizontal length and vertical length but different heights.

The phenylalkylamine compound (Y) of Formula 27 acts as an ion transfer inhibitor and forms a self-assembled shell upon crystallization by reacting with metal halide perovskite ions through a proton transfer reaction in a solvent.

Examples of the phenylalkylamine compound of Formula 27 used in the present invention may include phenylmethanamine, (4-fluorophenyl)methanamine, (4-(trifluoromethyl)phenyl)methanamine, 2-phenylethanamine, 1-phenylpropan-2-amine, 1-phenylpropane-1-amine, 1-phenylethane-1,2-diamine, 2-(4-fluorophenyl)ethanamine, 1-(4-fluorophenyl)propan-2-amine, 1-(4-fluorophenyl)propan-1-amine, 1-(4-fluorophenyl)ethane-1,2-diamine, 2-(4-(trifluoromethyl)phenyl)ethanamine, 1-(4-(trifluoromethyl)phenyl)propan-2-amine, 1-(4-(trifluoromethyl)phenyl)propan-1-amine, 3-phenylpropan-1-amine, 4-phenylbutan-2-amine, 1-phenylbutan-2-amine, 1-phenylbutan-1-amine, 3-phenylpropane-1,2-diamine, 3-(4-fluorophenyl)propan-1-amine, 4-(4-fluorophenyl)butan-2-amine, 1-(4-fluorophenyl)butan-1-amine, 4-phenylbutan-1-amine, 5-phenylpentan-2-amine, 1-phenylpentan-3-amine, 1-phenylpentan-1-amine, 4-(4-fluorophenyl)butan-1-amine, 1-(4-fluorophenyl)pentan-3-amine, 1-(4-fluorophenyl)pentan-1-amine, 5-phenylpentan-1-amine, 1-phenylhexan-1-amine, 1-phenylhexan-2-amine, 1-phenylhexan-3-amine, 6-phenylhexan-2-amine, 1-(4-fluorophenyl)hexan-1-amine, 1-(4-fluorophenyl)hexan-3-amine, 6-phenylhexan-1-amine or 1-phenylheptane-1-amine, but are not limited thereto.

The chemical structures in the example of compounds that may be used in the phenylalkylamine compound (Y) of the above chemical formula 27 are summarized as shown in Table 3.

TABLE 3

| Example | Name | Structure |
|---|---|---|
| 1 | Phenylmethanamine | 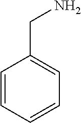 |
| 2 | (4-fluorophenyl) methanamine | 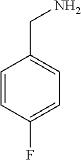 |
| 3 | (4-(trifluoromethyl) phenyl)methanamine | 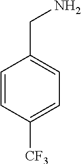 [SMILES: NCc1ccc(C(F)(F)F)cc1] |
| 4 | 2-phenylethylanamine | 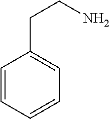 |
| 5 | 1-phenylpropane-2- amine | 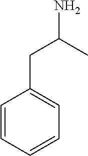 |
| 6 | 1-phenylpropan-1- amine | 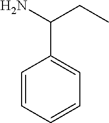 |
| 7 | 1-phenylethane-1,2- diamine | 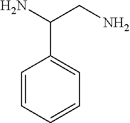 |
| 8 | 2-(4- fluorophenyl) ethanamine | 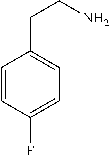 |
| 9 | 1-(4- fluorophenyl) propane- 2-amine | 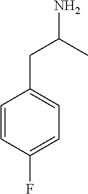 |
| 10 | 1-(4- fluorophenyl) propane-1-amine | 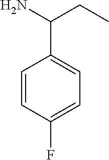 |
| 11 | 1-(4- fluorophenyl) ethane-1,2-diamine | 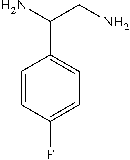 [SMILES: NCC(N)c1ccc(F)cc1] |
| 12 | 2-(4- (trifluoromethyl) phenyl)ethanamine | 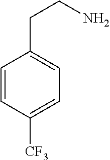 [SMILES: NCCc1ccc(C(F)(F)F)cc1] |
| 13 | 1-(4- (trifluoromethyl) phenyl)propane- 2-amine | 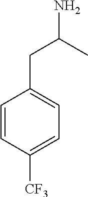 |
| 14 | 1-(4- (trifluoromethyl) phenyl)propane- 1-amine | 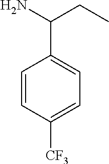 |
| 15 | 3- phenylpropane- 1-amine | 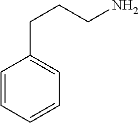 |
| 16 | 4-phenylbutane-2- amine | 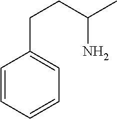 |
| 17 | 1- phenylbutane-2- amine | 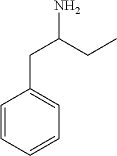 |
| 18 | 1- phenylbutane-1- amine | 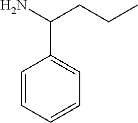 |
| 19 | 3-phenylpropane- 1,2-diamine | 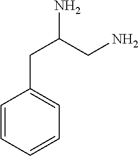 [SMILES: NCC(N)Cc1ccccc1] |
| 20 | 3-(4- fluorophenyl) propane-1-amine | 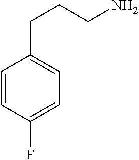 [SMILES: NCCCc1ccc(F)cc1] |
| 21 | 4-(4- fluorophenyl) butane-2- amine | 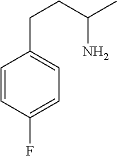 |
| 22 | 1-(4- fluorophenyl) butane-1-amine | 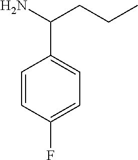 |
| 23 | 4- phenylbutane- 1-amine | 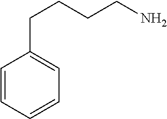 [SMILES: NCCCCc1ccccc1] |
| 24 | 5- phenylpentane-2- amine | 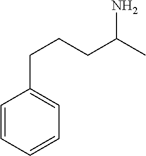 |
| 25 | 1- phenylpentane- 3-amine | 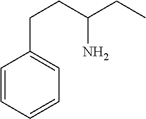 |
| 26 | 1-phenylpentane- 1-amine | 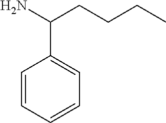 |
| 27 | 4-(4- fluorophenyl) butane-1- amine | 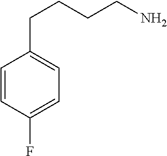 [SMILES: NCCCCc1ccc(F)cc1] |
| 28 | 1-(4- fluorophenyl) pentane-3-amine | 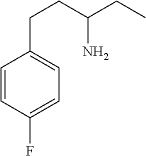 |
| 29 | 1-(4- fluorophenyl) pentane-1- amine | 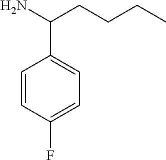 |
| 30 | 1- phenylpentane-1- amine | 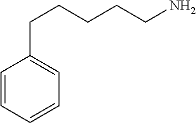 [SMILES: NCCCCCc1ccccc1] |
| 31 | 1- phenylhenxane- 1-amine | 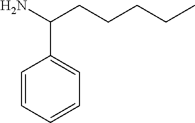 |
| 32 | 1- phenylhenxane-2- amine | 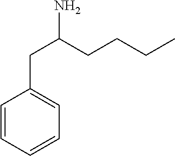 |
| 33 | 1- phenylhenxane-3- amine | 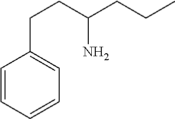 |
| 34 | 6- phenylhenxane-2- amine | 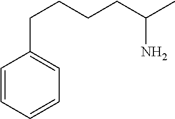 |
| 35 | 1-(4- fluorophenyl)hexane- 1-amine | 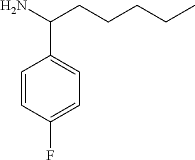 |
| 36 | 1-(4- fluorophenyl) hexane-3- amine | 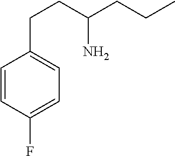 |
| 37 | 6- phenylhexane- 1-amine | 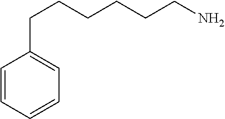 [SMILES: NCCCCCCc1ccccc1] |
| 38 | 1- phenylheptne- 1-amine | 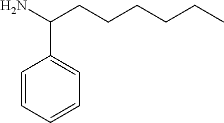 |

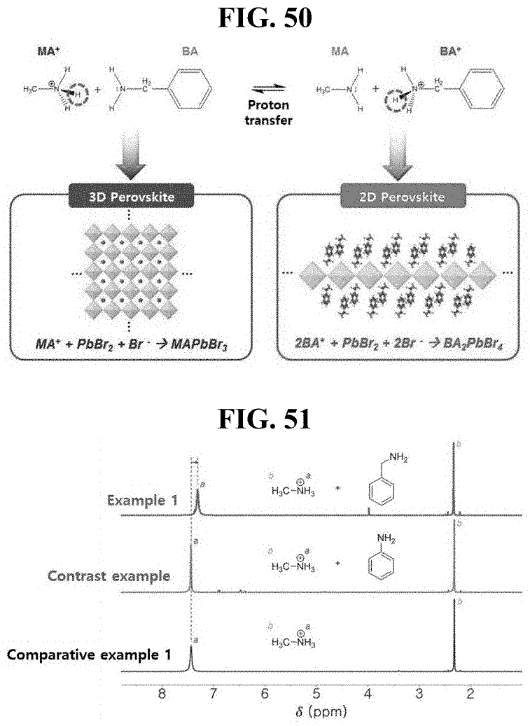

FIG. 49 shows a mechanism for forming a core/shell structure of a metal halide perovskite film according to an embodiment of the present invention, and FIG. 50 shows formation principle of each shell structure and a core structure of a metal halide perovskite film according to an embodiment of the present invention. The formation principle of the core-shell structure of the metal halide perovskite film according to the present invention is as follows.

When organic ammonium is present in an ionic state in the metal halide perovskite bulk precursor solution, when a phenylalkylamine additive is added to the solution, the organic ammonium and phenylalkylamine immediately act as acids and bases, respectively, and the acid-base. Through the reaction, protons are transferred from the organic ammonium to the phenylalkylamine additive. The phenylalkylamine added is a strong basic substance having a basicity (pK_{b}) of 7 or less, more preferably 5 or less, and changes to the phenyl alkylammonium form through an immediate proton transfer reaction with most of the organic ammonium, as shown in FIG. 49. Likewise, it exists in an active state capable of participating in the formation of 2D metal halide perovskite crystals. This proton transfer reaction can be confirmed by the fact that the proton of the methylammonium ion at 7.4 ppm on the chemical transfer position in the nuclear magnetic resonance spectroscopy spectrum of FIG. 51 moves to 7.2 ppm after adding a small amount of phenyl methylamine

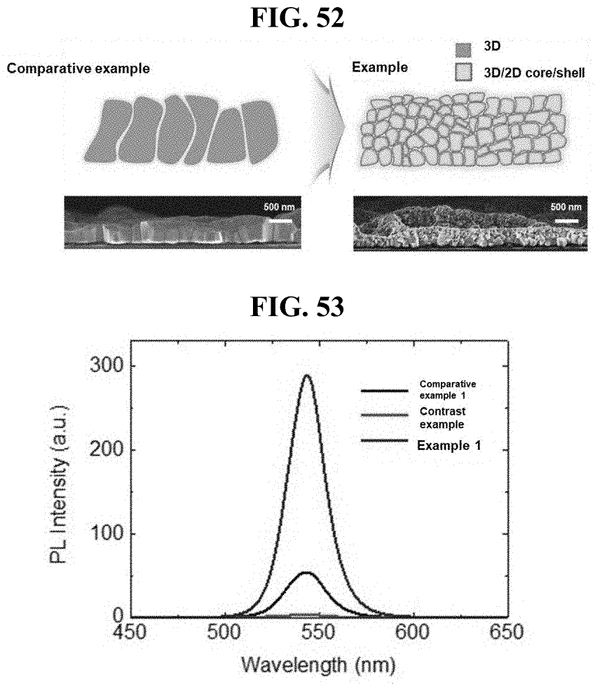

On the other hand, as a comparative example, the structure is similar to that of phenylalkylamine, but in the case of phenylamine (aniline) without alkyl group between phenyl and amine, it exhibits weak basicity with a basicity of 7 or more, and acid-base reaction does not occur with the organic ammonium of metal halide perovskite precursor solution, so proton transfer does not occur (see FIG. 51). As a result, it is not possible to participate in the formation of the 2D metal halide perovskite shell, and thus improvement in luminescence efficiency and lifetime or a two-dimensional crystal structure is not observed (see FIG. 52 to 54).

Therefore, in order to obtain a metal halide perovskite having a 3D/2D core-shell crystal structure of the present invention, a proton transfer reaction of organic ammonium in the metal halide perovskite is essential, and such a proton transfer reaction is performed between a phenyl group and an amine. By including an alkyl group, it can be achieved through the addition of a phenylalkylamine compound having strong basicity.

The size of the crystal of the metal halide perovskite having a 3D/2D core-shell crystal structure in the metal halide perovskite film according to the present invention may be 10 nm to 1 μm, but is not limited thereto.

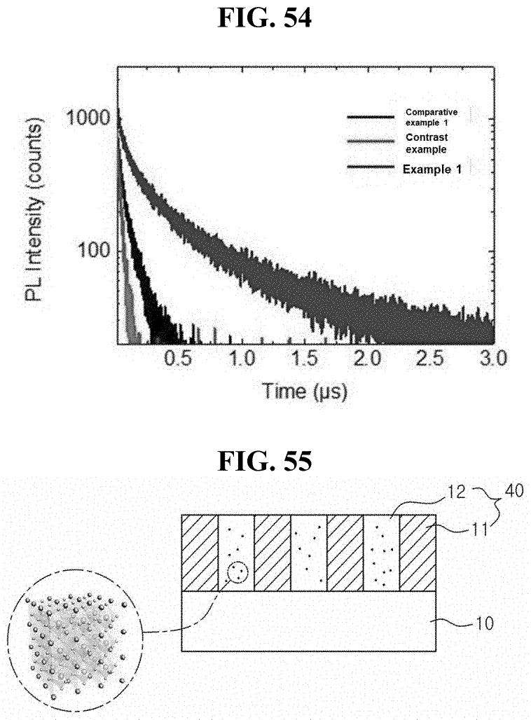

According to present invention, metal halide perovskite films with 3D/2D core-shell crystal structure are shown to have approximately six times more photoluminescence (PL) intensity than bulk nanocrystal metal halide perovskite films with original 3D crystal structure, as well as significantly improved relative PL efficiency and PL lifetime (see FIGS. 53 and 54). Therefore, the metal halide perovskite film having a 3D/2D core-shell crystal structure can be usefully used in a light emission layer of a light-emitting device.

In addition, the present invention provides a method of manufacturing a metal halide perovskite film having a 3D/2D core-shell crystal structure.

The method of manufacturing a metal halide perovskite film having a 3D/2D core-shell crystal structure of the present invention is as follows. The method of manufacturing a metal halide perovskite film having a 3D/2D core-shell crystal structure has preparing a mixed solution by adding a phenylalkylamine compound of Formula 1 to a metal halide perovskite bulk precursor solution S100, and manufacturing a metal halide perovskite film having a 3D/2D core-shell crystal structure S200 by coating and coating a mixed solution of the metal halide perovskite bulk precursor solution and a phenylalkylamine compound on a member for depositing a light emission layer.

Hereinafter, the present invention will be described step by step.

First, S100 is a step of preparing a mixed solution of a metal halide perovskite bulk precursor solution and a phenylalkylamine compound.

The metal halide perovskite bulk precursor solution may be formed by dissolving AX and BX₂ in a solvent at a predetermined ratio. For example, a metal halide perovskite bulk precursor solution in which ABX₃ metal halide perovskite is dissolved may be prepared by dissolving AX and BX₂ in an aprotic solvent at a ratio of 1.06:1.

In addition, the metal halide perovskite bulk precursor solution may be formed by mixing at least one of AX and A′X and BX₂ in an aprotic solvent.

The solvent used to prepare the metal halide perovskite bulk precursor solution is dimethylformamide, γ-butyrolactone, N-methylpyrrolidone, dimethyl sulfoxide, or combinations thereof.

The concentration of the metal halide perovskite bulk precursor solution may be 0.01M to 1.5M. If the concentration of the metal halide perovskite bulk precursor solution is less than 0.01M, the substrate to be coated cannot be completely covered due to the low concentration, and the flatness is lowered. Therefore, it is impossible to operate as light-emitting device due to leakage current when applied as a light-emitting device. And, if it exceeds 1.5M, there is a problem in that the crystals are aggregated in the process of forming a thin film due to a high concentration, resulting in a large crystal and a rough surface.

Since the description of the phenylalkylamine compound is the same as described above, it will be omitted to avoid redundant description.

In the mixed solution of the metal halide perovskite bulk precursor solution and the phenylalkylamine compound, the phenylalkylamine compound can be mixed in a ratio of 0.1 mol. % to 20 mol. % with respect to the metal halide perovskite bulk precursor solution. For example, the mixing ratio of the phenylalkylamine compound to the metal halide perovskite bulk precursor solution may include a range in which the lower value of two numbers of 0.1 mol. %, 0.5 mol. %, 1 mol. %, 1.5 mol. %, 2 mol. %, 2.5 mol. %, 3 mol. %, 3.1 mol. %, 3.2 mol. %, 3.3 mol. %, 3.4 mol. %, 3.5 mol. %, 3.6 mol. %, 3.7 mol. %, 3.8 mol. %, 3.9 mol. %, 4 mol. %, 4.1 mol. %, 4.2 mol. %, 4.3 mol. %, 4.4 mol. %, 4.5 mol. %, 4.6 mol. %, 4.7 mol. %, 4.8 mol. %, 4.9 mol. %, 5 mol. %, 5.1 mol. %, 5.2 mol. %, 5.3 mol. %, 5.4 mol. %, 5.5 mol. %, 5.6 mol. %, 5.7 mol. %, 5.8 mol. %, 5.9 mol. %, 6 mol. %, 6.1 mol. %, 6.2 mol. %, 6.3 mol. %, 6.4 mol. %, 6.5 mol. %, 6.6 mol. % is a lower limit and the higher value is an upper limit.

If the phenylalkylamine compound is mixed in less than 0.1 mol. %, a self-assembled shell may not be formed, and if the phenylalkylamine compound is mixed in more than 20 mol. %, since the 2D metal halide perovskite structure is dominantly formed, there may be a problem in that a core-shell structure, in which the 2D metal halide perovskite surrounds only the crystal surface while maintaining the 3D metal halide perovskite crystal, is not obtained. In addition, since the amount of residual organic ammonium increases by conversion to an amine structure through a proton transfer reaction, charge injection and transport, and efficient radiative recombination may be hindered when applied in a light-emitting device.

The phenylalkylamine compound receives protons from organic ammonium ions in the metal halide perovskite bulk precursor solution and changes into a cationic form.

Next, step S200 is a fabricating a metal halide perovskite film having a 3D/2D core-shell crystal structure by coating a mixed solution of the metal halide perovskite bulk precursor solution and a phenylalkylamine compound on a light emission layer.

The member for depositing the light emission layer may be a substrate, an electrode, or a semiconductor layer which can be used in a light-emitting device. In addition, the member for depositing the light emission layer may have a form in which a substrate/electrode is sequentially stacked or a form in which a substrate/electrode/semiconductor layer is sequentially stacked.

Since the description of the substrate, the electrode, or the semiconductor layer is the same as described above, detailed description will be omitted.

Coating methods can be selected from groups of spin-coating, bar-coating, nozzle printing, spray-coating, slot-coating, gravure printing, inkjet printing, screen printing, electrohydrodynamic jet printing, and electrospray, but are not limited thereto.

After coating, during crystallization, the above phenylalkylamine compounds in the form of cations react with metal ions and halogen ions in a solution of metal halide perovskite bulk precursors to form a two-dimensional self-assembled shell, resulting in metal halide perovskite crystals in core-shell structures.

### <Self-Assembled Polymer-Metal Halide Perovskite Light-Emitting Device Including a Metal Halide Perovskite Light Emission Layer>

According to another embodiment of the present invention, the emission layer may include a self-assembled polymer-metal halide perovskite emission layer.

FIG. 55 is a schematic diagram of a self-assembled polymer-metal halide perovskite light emission layer according to an embodiment of the present invention.

Referring to FIG. 55, the self-assembled polymer-metal halide perovskite light emission layer 40 according to the present invention may be formed on the member for depositing the light emission layer 10, and has the self-assembled polymer 11 forming a pattern and a metal halide perovskite nanocrystal particle layer 12 formed inside the pattern of the self-assembled polymer 11.

In the self-assembled polymer-metal halide perovskite light emission layer according to the present invention, the self-assembled polymer 11 is composed of two or more polymers, and the two or more polymers are covalently linked through one end of a chain. Molecules in the polymer can spontaneously construct a periodic structure in the form of a cylinder at the nanoscale level due to intermolecular interactions. By removing a specific polymer from the self-assembled polymer consisted of the cylindrical structure, periodic patterns can be formed, and the patterns can confine the metal halide perovskite nanocrystal, the luminescence efficiency can be improved and the ion migration phenomenon between the metal halide perovskite crystals can be blocked, so stability can be improved, and the emission wavelength of the light-emitting diode can be shifted toward blue (blue-shift), and PLQY and luminance can be improved.

These self-assembled polymers 11 may be used including PEO (Polyethylene oxide), PS (Polystyrene), PCL (Polycaprolactone), PAN (Polyacrylonitrile), PMMA (Poly(methyl methacrylate)), polyimide, PVDF (Poly(vinylidene fluoride)), PVK (Poly(n-vinylcarbazole)), PVC (Polyvinylchloride), a random copolymer, an alternating copolymer, a block copolymer, or a graft copolymer consisting of two or more polymers selected from the group consisting of above polymers and their respective derivatives, but is not limited thereto.

The self-assembled polymer may be composed of a single layer or multiple layers of two or more depending on the thickness of the light emission layer to be formed.

For the self-assembly polymer-metal halide perovskite light emission layer according to present invention, the pattern of the above self-assembled polymer 11 may be formed by removing a particular composition of polymer from a mass of two or more types expressed in a cylinder-shaped structure.

The width of the formed self-assembled polymer pattern is preferably 10 to 100 nm, more preferably 10 to 30 nm.

In the self-assembled polymer-metal halide perovskite light emission layer according to the present invention, the metal halide perovskite nanocrystal particles constituting the metal halide perovskite nanocrystal particle layer 12 are a light emitter forming a light emission layer, it may include a metal halide perovskite or metal halide perovskite nanocrystals or colloidal nanoparticles that can be dispersed in an organic solvent.

Since the metal halide perovskite is the same as described above, a detailed description will be omitted.

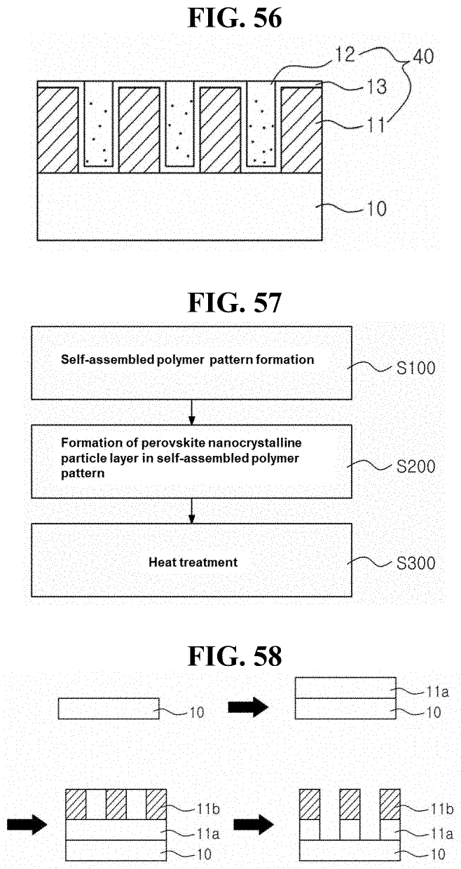

Meanwhile, as shown in FIG. 56, an organic material layer 13 surrounding the self-assembled polymer 11 may be further included between the patterned self-assembled polymer 11 and the metal halide perovskite nanocrystal particle region 12.

When the width of the pattern of the self-assembled polymer 11 is too large, the organic material layer 13 may be coated on the self-assembled polymer 11 to reduce the width.

The organic material layer 13 may be formed of a polymer having the same composition as that of the self-assembled polymer, or other polymers. As an example, the organic material used in the organic material layer is PEO (Polyethylene oxide), PS (Polystyrene), PCL (Polycaprolactone), PAN (Polyacrylonitrile), PMMA (Poly(methyl methacrylate)), polyimide, polythiophene, polyaniline, polypyrrole, poly(3,4-ethylenedioxythiophene), PVDF (Poly (vinylidene fluoride)), PVK (Poly(n-vinylcarbazole)), PVC (Polyvinylchloride), or a mixture thereof, but is not limited thereto.

The organic material layer 13 may be formed on the self-assembled polymer pattern by a deposition method used in the industry, for example, the chemical vapor deposition (CVD) or thermal deposition method (thermal deposition) can be used, but it is not limited thereto.

The thickness of the organic material layer 13 may be adjusted according to the width of the formed self-assembled polymer pattern, and may be, for example, 1 to 20 nm, but is not limited thereto.

Meanwhile, the light emission layer according to present invention may include an organic layer 13 surrounding the self-assembled polymer 11 between the patterned self-assembled polymer 11 and the metal halide perovskite nanocrystal particle 12 as shown in FIG. 57.

When the width of the pattern of the self-assembled polymer 11 is too large, the organic material layer 13 may be coated on the self-assembled polymer 11 to reduce the width.

The organic material layer 13 may be formed of a polymer having the same composition as that of the self-assembled polymer, or other polymers. As an example, the organic material used in the organic material layer is PEO (Polyethylene oxide), PS (Polystyrene), PCL (Polycaprolactone), PAN (Polyacrylonitrile), PMMA (Poly(methyl methacrylate)), polyimide, polythiophene, polyaniline, polypyrrole, poly(3,4-ethylenedioxythiophene), PVDF (Poly (vinylidene fluoride)), PVK (Poly(n-vinylcarbazole)), PVC (Polyvinylchloride), or a mixture of thereof, but is not limited thereto.

The organic material layer 13 may be formed on the self-assembled polymer pattern by a deposition method used in the art, for example, the chemical vapor deposition (CVD) or thermal deposition method (thermal deposition) can be used, but it is not limited thereto.

The thickness of the organic material layer 13 may be adjusted according to the width of the formed self-assembled polymer pattern, and may be, for example, 1 to 20 nm, but is not limited thereto.

Hereinafter, a method of manufacturing a metal halide perovskite light-emitting device including the self-assembled polymer light emission layer will be described.

FIG. 57 is a flow chart illustrating a method of manufacturing a self-assembled polymer-metal halide perovskite light emission layer according to an embodiment of the present invention.

Referring to FIG. 57, a method of manufacturing a self-assembled polymer-metal halide perovskite light emission layer of the present invention includes forming a self-assembled polymer pattern on a member for depositing the light emission layer S100, preparing a light emission layer by forming a metal halide perovskite nanocrystal particle layer in the prepared self-assembled polymer pattern S200, and heat-treatment of the light emission layer S300.

Hereinafter, the present invention will be described step by step.

First, step S100 is forming a self-assembled polymer pattern on a member for depositing a light emission layer.

In the above step, a member for depositing a light emission layer is prepared.

The member for depositing the light emission layer may be a substrate, an electrode, or a semiconductor layer. The substrate, electrode, or semiconductor layer can be used in a light-emitting device. In addition, the member for depositing the light emission layer may have a form in which a substrate/electrode is sequentially stacked or a form in which a substrate/electrode/semiconductor layer is sequentially stacked.

Since the description of the substrate, the electrode, or the semiconductor layer is the same as described above, a detailed description will be omitted.

Next, a self-assembled polymer pattern is formed on the member for applying the emission layer.

In the self-assembled polymer used in the present invention, since two or more kinds of polymers are formed in a cylinder shape on the member for depositing the light emission layer through a self-assembly reaction, a pattern can be formed by removing one of the polymers in the form of a cylinder.

As an example, as shown in FIG. 58, a random copolymer thin film 11a is formed on the substrate 10, and after forming a PS-b-PMMA block copolymer thin film 11b having a cylinder shape on the random copolymer thin film 11a, in the cylindrical block copolymer obtained through self-assembly, the PMMA cylinder portion and the random copolymer thin film under the PMMA may be selectively etched to form a self-assembled polymer pattern in which only the PS portion is left.

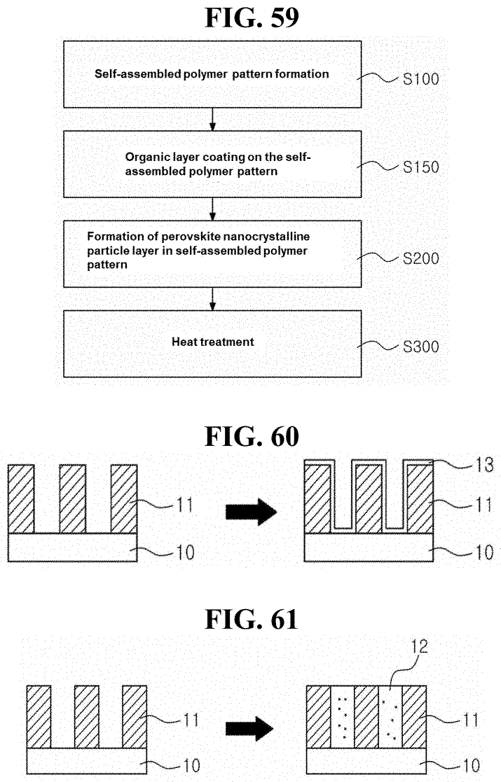

In addition, as shown in FIG. 59, after forming the self-assembled polymer pattern, a step S150 of forming the organic material layer 13 on the self-assembled polymer 11 on which the pattern is formed may be additionally performed.

When the width of the pattern of the self-assembled polymer 11 is too large, the organic material layer 13 may be coated on the self-assembled polymer 11 as shown in FIG. 61 to reduce the width.

The organic material layer 13 may be formed of a polymer having the same composition as that of the self-assembled polymer, or other polymers. As an example, the organic material used in the organic material layer is PEO (Polyethylene oxide), PS (Polystyrene), PCL (Polycaprolactone), PAN (Polyacrylonitrile), PMMA (Poly(methyl methacrylate)), polyimide, polythiophene, polyaniline, polypyrrole, poly(3,4-ethylenedioxythiophene), PVDF (Poly (vinylidene fluoride)), PVK (Poly(n-vinylcarbazole)), PVC (Polyvinylchloride), or a mixture thereof, but is not limited thereto.

The organic material layer 13 may be formed on the self-assembled polymer pattern by a deposition method used by those skilled in the art, for example, the chemical vapor deposition (CVD) or thermal deposition method (thermal deposition) can be used, but it is not limited thereto.

The thickness of the organic material layer 13 may be adjusted according to the width of the formed self-assembled polymer pattern, and may be, for example, 1 to 20 nm, but is not limited thereto.

Next, S200 is a step of preparing a light emission layer by forming a metal halide perovskite nanocrystal particle layer in the prepared self-assembled polymer pattern.

The methods of forming the metal halide perovskite nanocrystal particle layer include preparing a first solution in which a metal halide perovskite is dissolved in a protic solvent; and forming a metal halide perovskite nanocrystal particle layer by putting the first solution into a self-assembled polymer pattern.

First, a first solution in which a metal halide perovskite is dissolved in a protic solvent is prepared. The method of preparing the first solution in which the metal halide perovskite is dissolved in the protic solvent is the same as described above, and thus a detailed description thereof will be omitted.

Next, the first solution is put into a self-assembled polymer pattern to form a metal halide perovskite nanocrystal particle layer.

Specifically, as shown in FIG. 61, the first solution is located in a self-assembled polymer pattern pierced in a cylindrical shape. As location method, a solution may be dropped drop by drop or a solution process may be used, but is not limited thereto.

The solution process includes spin-coating, bar coating, slot-die coating, gravure-printing, nozzle printing, and ink-jet printing. printing), screen printing, electrohydrodynamic jet printing, or electrospray.

In addition, metal halide perovskite nanoparticles may be prepared through an inverse nano-emulsion method.

Specifically, preparing a first solution in which a metal halide perovskite is dissolved in a protic solvent and a second solution in which an alkyl halide surfactant is dissolved in an aprotic solvent; and solution may be mixed with the second solution and located in a self-assembled polymer pattern to form a metal halide perovskite nanocrystal layer.

The preparation of the first solution in which the protic solvent and the metal halide perovskite are dissolved is as described above.

Also, when preparing the second solution, the aprotic solvent is dichloroethylene, trichloroethylene, chloroform, chlorobenzene, dichlorobenzene, styrene, dimethylformamide, dimethyl sulfoxide, xylene, toluene, cyclohexene or isopropyl alcohol, but is not limited to.

In addition, the alkyl halide surfactant may have a structure of alkyl-X. The halogen element corresponding to X include Cl, Br, or I. In addition, the alkyl structure includes acyclic alkyl having a structure of CₙH₂ₙ₊₁, a primary alcohol having a structure such as CₙH₂ₙ₊₁OH, a secondary alcohol, and a tertiary alcohol, or alkylamine having a structure of alkyl-N (ex. hexadecyl amine, 9-Octadecenylamine 1-Amino-9-octadecene (C₁₉H₃₇N)), p-substituted aniline, phenyl ammonium or fluorine ammonium.

Meanwhile, a carboxylic acid (COOH) surfactant may be used instead of the alkyl halide surfactant.

For example, surfactants may contain 4,4′-azobis(4-cyanovaleric acid), acetic acid, 5-aminosalicylic acid, acrylic acid, L-aspentic acid, 6-bromohexanoic acid, bromoacetic acid, dichloroacetic acid, ethylenediaminetetraacetic acid, isobutyric acid, itaconic acid, maleic acid, r-maleimidobutyric acid, L-Malic acid, 4-nitrobenzoic acid, 1-pyrenecarboxylic acid or oleic acid, but are not limited to this.

In the step of forming a metal halide perovskite nanocrystal layer by mixing the first solution with the second solution and placing it in a self-assembled polymer pattern, it is preferable to mix the first solution dropwise with the second solution. Further, the second solution may be stirred. For example, nanoparticles may be synthesized by slowly adding the first solution in which an organic-inorganic metal halide perovskite (OIP) is dissolved to a second solution in which an alkyl halide surfactant is dissolved, which is being stirred vigorously.

In this case, when the first solution is dropped into the second solution and mixed, organic-inorganic metal halide perovskite (OIP) is precipitated from the second solution due to a difference in solubility. The organic-inorganic metal halide perovskite (OIP) precipitated in the second solution is stabilized by an alkyl halide surfactant to form well-dispersed organic-inorganic metal halide perovskite nanocrystals (OIP-NC). Accordingly, a solution including organic-inorganic metal halide perovskite nanocrystals and a plurality of alkyl halide organic ligands surrounding the organic-inorganic metal halide perovskite nanoparticles can be prepared.

Thereafter, the solution containing the metal halide perovskite nanoparticles may be located in a self-assembled polymer pattern pierced in a cylindrical shape using the method described above to form a metal halide perovskite nanocrystal layer.

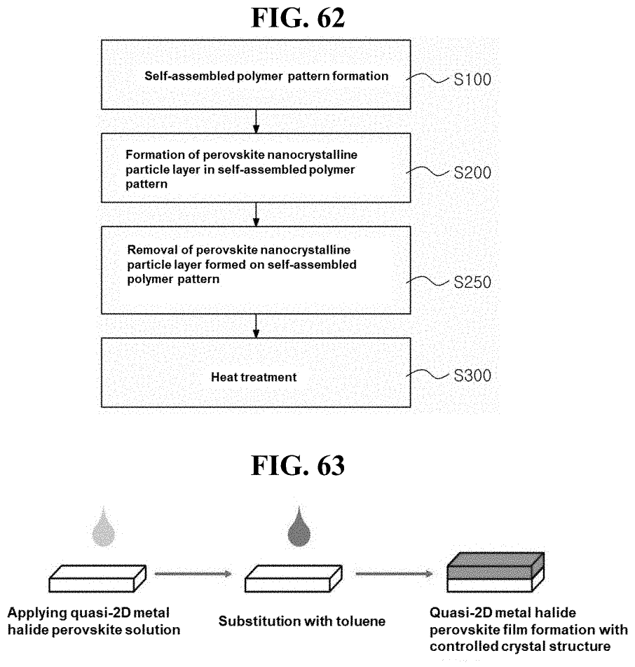

However, as shown in FIG. 62, when the metal halide perovskite nanocrystal layer is formed on the polymer pattern over the height of the polymer pattern, an additional step S250 can be taken to remove the metal perovskite nanocrystal layer formed on the above polymer pattern as shown in FIG. 63.

Removal of the metal halide perovskite nanocrystal layer formed on the polymer pattern can be performed by dropping the solvent capable of dissolving metal halide perovskite onto the metal halide perovskite nanocrystal layer, dissolving only the metal halide perovskite nanocrystal layer at the top of the self-assembled polymer pattern.

Next, S300 is a step of heat-treating the prepared light emission layer.

The heat treatment may be performed at 60° C. to 80° C. for 5 to 15 minutes.

Through the heat treatment, the solvent is evaporated so that the metal halide perovskite nanocrystals are strongly bonded to the polymer pattern.

In an embodiment of the present invention, CsBr and PbBr₂ are dissolved in dimethyl sulfoxide (DMSO) to spin coat the metal halide perovskite solution on a patterned substrate, and heat-treated for 10 minutes at 70° C. to fabricate a self-assembled polymer-metal halide perovskite light emission layer.

The self-assembled polymer-metal halide perovskite light emission layer prepared by the above method confines the metal halide perovskite nanocrystal in the self-assembled polymer pattern, thereby shifting the light emission wavelength toward blue, the luminescence efficiency of the metal halide perovskite material can be improved, and the self-assembled polymer located between the metal halide perovskite nanocrystal layers can prevent the ion migration between the metal halide perovskite nanocrystal layers. Therefore, stability can be improved.

<Metal Halide Perovskite Light-Emitting Device Including a Quasi-2D Metal Halide Perovskite Light Emission Layer with a Controlled Nanocrystal Structure>

According to another embodiment of the present invention, when the light emission layer has a quasi-2D structure, it may include a quasi-2D metal halide perovskite light emission layer with a controlled nanocrystal structure. The quasi-2D structure may be a Ruddlesden-Popper phase or a Dion-Jacobson phase.

Recently, high luminescence efficiency from quasi-2-dimensional metal halide perovskites has been reported through charge transfer and charge confinement from two-dimensional metal halide perovskite region that have high bandgap to three-dimensional metal halide perovskite having low bandgap. However, since the metal halide perovskite crystal is randomly crystallized without the tendency of the crystal orientation and distribution, it is difficult to control the dimensional distribution, so in order to manufacture a high-efficiency light-emitting device, additional interfacial treatment must be performed to reduce interfacial quenching and charge imbalance. Therefore, it is necessary to develop a new process for an effective energy structure capable of controlling the number and distribution of dimensions of the metal halide perovskite emission layer and preventing charge dissociation.

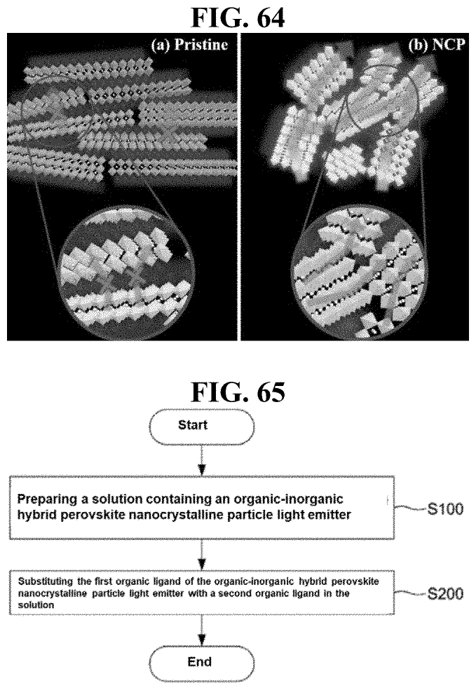

The quasi-2D metal halide perovskite light emission layer with a controlled nanocrystal structure according to the present invention may be produced by method for producing quasi-2D metal halide perovskite film with controlled crystal structure including step of forming a quasi-2D structure metal halide perovskite film by coating a quasi-2D structure metal halide perovskite solution on a substrate, and a step of controlling a multi-phase structure of the quasi-2D structure metal halide perovskite crystals in a three-dimensional structure by dropping a solvent having a boiling point of at least 100° C. on the quasi-2D structure metal halide perovskite film. (FIG. 63, FIG. 64)

In addition, preferably, the solvent may be one or more selected from the group consisting of toluene, xylene, butanol, pentanol, hexanol, heptanol, octanol, octane, and decane, or a combination thereof, but is not limited thereto.

Also preferably, the quasi-2D metal halide perovskite may include a single-phase structure of A′₂Aₙ₋₁BₙX₃ₙ₊₁ or a multi-phase structure having different n values. The quasi-2D structure may be a Ruddlesden-Popper phase or a Dion-Jacobson phase.

Also preferably, A and A′ may be monovalent cations, B may be a metal material, and X may be a halogen element.

The monovalent cation may be a monovalent organic cation or an alkali metal. For example, the monovalent organic cation may be organic ammonium (RNH₃)⁺, organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺ or (CₙF₂ₙ₊₁NH₃)₂⁺ (x, n is an integer greater than or equal to 1, R=hydrocarbon derivative, H, F, Cl, Br, I) or combinations thereof, but is not limited thereto. The alkali metal may be Li⁺, Na⁺, K⁺, Rb⁺, Cs⁺, Fr⁺, or combinations thereof, but is not limited thereto.

In addition, preferably, the organic cations may be acetamidinium, azaspironanium, benzene diammonium, benzylammonium, butanediammonium, iso-butylammonium, n-butylammonium, t-butylammonium, cyclohexylammonium, cyclohexylmethylammonium, diazobicyclooctanedinium, diethylammonium, N,N-diethylethane diammonium, dimethylammonium, dodecylammonium, ethanediammonium, ethylammoniuium, 4-fluoro-benzylammonium, 4-fluoro-phenylethylammonium, 4-fluoro-phenylammonium, formamidinium, guanidinium, hexanediammnium, hexylammonium, imidazolium, 2-methoxyethylammonium, 4-methoxy-phenylethylammonium, 4-methoxy-phenylammonium, methylammonium, morpholinium, octylammonium, pentylammonium, piperazinediium, piperidinium, propanediammonium, iso-propylammonium, di-isopropylammonium, n-propylammonium, pyridinium, 2-pyrrolidin-1-ium-1-yethylammonium, pyrrolidinium, quinclidin-1-ium, 4-trifluoromethyl-benzylammonium, 4-trifluoromethyl ammonium, or combinations thereof, but are not limited thereto.

The B may be a divalent transition metal, a rare earth metal, an alkaline earth metal, a combination of a monovalent metal and a trivalent metal, an organic material (a monovalent, divalent, trivalent cation), or a combination thereof. In addition, preferably, the divalent transition metal, rare earth metal, and alkaline earth metal may be Be²⁺, Mg²⁺, Ca²⁺, Sr²⁺, Ba²⁺, Ra²⁺, Mn²⁺, Fe²⁺, Co²⁺, Ni²⁺, Cu²⁺, Zn²⁺, Ru²⁺, Pd²⁺, Cd²⁺, Pt²⁺, Hg²⁺, Ge²⁺, Sn²⁺, Pb²⁺, Se²⁺, Te²⁺, Po²⁺, Bi²⁺, Eu²⁺, No²⁺, or combinations thereof, but are not limited thereto. Monovalent metal may be Li⁺, Na⁺, K⁺, Rb⁺, Cs⁺, Fr⁺, Ag⁺, Hg⁺, Ti⁺, or combinations thereof, trivalent metal may be Cr³⁺, Fe³⁺, Co³⁺, Ru³⁺, Rh³⁺, Ir³⁺, Au³⁺, Al3⁺, Ga³⁺, In³⁺, Ti³⁺, As³⁺, Sb³⁺, Bi³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Ac³⁺, Am³⁺, Cm³⁺, Bk³⁺, Cf³⁺, Es³⁺, Fm³⁺, Md³⁺, Lr³⁺, or combinations thereof.

In addition, X may be F⁻, Cl⁻, Br⁻, I⁻, At⁻, or combinations thereof.

In addition, preferably, the solvent used in the preparation of the quasi-2D structure metal halide perovskite solution may be dimethylformamide, gamma-butyrolactone, N-methylpyrrolidone, dimethylsulfoxide, or combinations thereof.

Also preferably, the concentration of the quasi-2D structure metal halide perovskite solution may be 0.01M to 0.5M.

In addition, preferably, the coating method can be selected from a group of spin coatings, bar coatings, nozzle printing, spray coatings, slot die coatings, gravure printing, inkjet printing, screen printing, electrohydrodynamic jet printing and electrospray.

<Ligand Substitution of Metal Halide Perovskite Nanocrystal for High-Efficiency Light-Emitting Devices>

If the light emission layer is a metal halide perovskite nanocrystal, the organic ligand surrounding the metal halide perovskite nanocrystal can be replaced with a shorter ligand or a ligand containing phenyl or fluoride to produce more efficient nanocrystal light emitter and light-emitting devices.

This section describes the method of manufacturing metal halide perovskite nanocrystal emitters in which organic ligand is replaced according to an embodiment of the present invention.

FIG. 65 is a flow chart illustrating a method of manufacturing a metal halide perovskite nanocrystal light emitter in which an organic ligand is substituted according to an embodiment of the present invention.

Referring to FIG. 65, the method for manufacturing a metal halide perovskite nanocrystal light emitter substituted with an organic ligand according to the present invention includes preparing a solution including a metal halide perovskite nanocrystal light emitter S100, and substituting a second organic ligand for the first organic ligand of the metal halide perovskite nanocrystal particle light emitter in the solution S200.

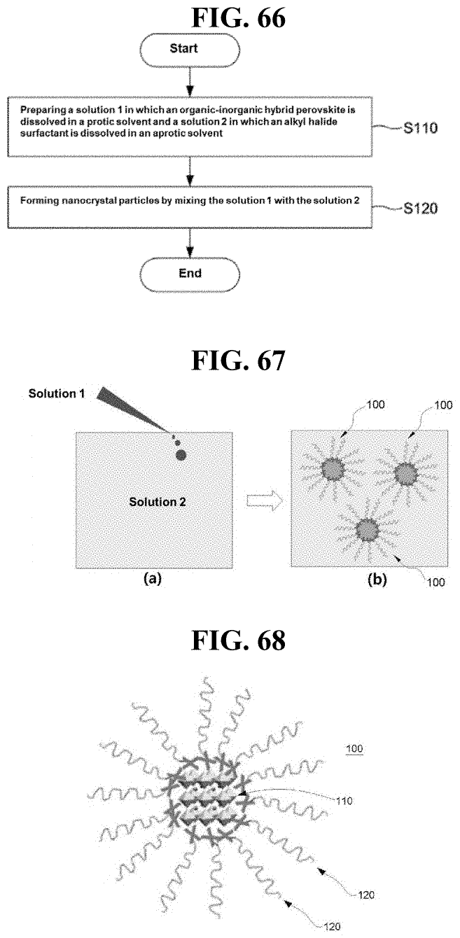

First, a solution containing a metal halide perovskite nanocrystal light emitter is prepared S100. A manufacturing example for this will be described with reference to FIG. 66 to 69.

FIG. 66 is a flow chart showing a method of manufacturing a metal halide perovskite nanocrystal light emitter according to an embodiment of the present invention.

Referring to FIG. 66, a metal halide perovskite nanocrystal light emitter according to the present invention may be fabricated through an inverse nano-emulsion method.

First, a first solution in which a metal halide perovskite is dissolved in a protic solvent and a second solution in which an alkyl halide surfactant is dissolved in an aprotic solvent are prepared S110.

The protic solvent may include dimethylformamide, gamma-butyrolactone or N-methylpyrrolidone, or dimethylsulfoxide, but is not limited thereto.

The metal halide perovskite may be a material having a three-dimensional crystal structure, a two-dimensional crystal structure, a one-dimensional crystal structure, or a zero-dimensional crystal structure.

The metal halide perovskite is ABX₃(3D), A₄BX₆(0D), AB₂X₅(2D), A₂BX₄(2D), A₂BX6(0D), A₂B⁺B³⁺X₆(3D), A₃B₂X₉(2D) or Aₙ₋₁BₙX₃ₙ₊₁ (quasi-2D) (n is an integer between 2 and 6). A is a monovalent cation, B is a metal material, and X may be a halogen element. The quasi-2D structure may be a Ruddlesden-Popper phase or a Dion-Jacobson phase.

Since specific examples of A, B, and X are the same as described above, they are omitted to avoid redundant description.

These metal halide perovskites can be prepared by combining AX and BX₂ in a certain ratio. For example, a first solution in which A₂BX₃ metal halide perovskite is dissolved may be prepared by dissolving AX and BX₂ in a ratio of 2:1 in a protic solvent. In addition, the aprotic solvent may include dichloroethylene, trichloroethylene, chloroform, chlorobenzene, dichlorobenzene, styrene, dimethylformamide, dimethyl sulfoxide, xylene, toluene, cyclohexene or isopropyl alcohol, but is not limited to.

The alkyl halide surfactant may have an alkyl-X structure. The halogen element corresponding to X may include Cl, Br, or I. In addition, the alkyl structure at this time includes an acyclic alkyl having a structure of CₙH₂ₙ₊₁, a primary alcohol having a structure such as CₙH₂ₙ₊₁OH, a secondary alcohol, and a tertiary alcohol, alkylamine having the structure of alkyl-N (ex. Hexadecyl amine, 9-Octadecenylamine 1-Amino-9-octadecene (C₁₉H₃₇N)), p-substituted aniline, phenyl ammonium or fluorine ammonium, but is not limited thereto.

These metal halide perovskites can be prepared by combining AX and BX₂ in a certain ratio. For example, a first solution in which A₂BX₃ metal halide perovskite is dissolved may be prepared by dissolving AX and BX₂ in a ratio of 2:1 in a protic solvent. In addition, the aprotic solvent may include dichloroethylene, trichloroethylene, chloroform, chlorobenzene, dichlorobenzene, styrene, dimethylformamide, dimethyl sulfoxide, xylene, toluene, cyclohexene or isopropyl alcohol, but is not limited thereto.

The alkyl halide surfactant may have an alkyl-X structure. The halogen element corresponding to X may include Cl, Br, or I. In addition, the alkyl structure at this time includes an acyclic alkyl having a structure of CₙH₂ₙ₊₁, a primary alcohol having a structure such as CₙH₂ₙ₊₁OH, a secondary alcohol, and a tertiary alcohol, alkylamine having the structure of alkyl-N (ex. hexadecyl amine, 9-octadecenylamine 1-amino-9-octadecene (C₁₉H₃₇N)), p-substituted aniline, phenyl ammonium or fluorine ammonium.

Meanwhile, a carboxylic acid (COOH) surfactant may be used instead of the alkyl halide surfactant, and the type of the carboxylic acid surfactant is as described above.

Then, the first solution is mixed with the second solution to form nanocrystal particles (S200).

In the step of forming a metal halide perovskite nanocrystal layer by mixing the first solution with the second solution, it is preferable to mix the first solution dropwise with the second solution. Further, the second solution may be stirred. For example, nanoparticles may be synthesized by slowly adding a first solution in which an organic-inorganic metal halide perovskite (OIP) is dissolved into a second solution in which an alkyl halide surfactant is dissolved, which is being stirred strongly.

When the first solution is dropped into the second solution and mixed, organic-inorganic metal halide perovskite (OIP) is precipitated from the second solution due to a difference in solubility. The organic-inorganic metal halide perovskite (OIP) precipitated in the second solution is stabilized by an alkyl halide surfactant to form well-dispersed organic-inorganic metal halide perovskite nanocrystals (OIP-NC). Accordingly, as shown in FIG. 68, a metal halide perovskite nanocrystal light emitter including an organic-inorganic metal halide perovskite nanocrystal structure and a plurality of alkyl halide organic ligands surrounding the organic-inorganic metal halide perovskite nanocrystal structure may be prepared.

Next, in the solution, the first organic ligand of the metal halide perovskite nanocrystal light emitter is substituted with a second organic ligand S200.

Second organic ligand having a length shorter than that of the first organic ligand or containing a phenyl group or a fluorine group may be added to the solution to replace the first organic ligand with the second organic ligand. The substitution reaction may be performed by applying constant heat.

The second organic ligand may include an alkyl halide. For example, the second organic ligand may have a structure of alkyl-X′. The halogen element corresponding to X′ may include Cl, Br, or I. In addition, the alkyl structure includes an acyclic alkyl having a structure of CₙH₂ₙ₊₁, a primary alcohol having a structure such as CₙH₂ₙ₊₁OH, a secondary alcohol, and a tertiary alcohol, alkylamine having the structure of alkyl-N (ex. hexadecyl amine, 9-octadecenylamine, 1-amino-9-octadecene (C₁₉H₃₇N)), p-substituted aniline, phenyl ammonium or fluorine ammonium, but is not limited thereto.

In addition, the second organic ligand contains alkyl halide, and the halogen element of the second organic ligand is characterized by its high affinity with the central metal of the above inorganic metal halide perovskite nanocrystal structure than the halogen element of the first organic ligand.

For example, when the first organic ligand is CH₃(CH₂)₁₇NH₃Br, the organic ligand substitution can be done by using a short-length alkyl halide having a halogen element having a higher affinity with the central metal of the metal halide perovskite nanocrystal structure than the first organic ligand and adding CH₃(CH₂)₈NH₃I with heat. Accordingly, CH₃(CH₂)₈NH₃I will become the second organic ligand surrounding the nanocrystal structure, and eventually the length of the organic ligand of the nanocrystal light emitter can be reduced.

The metal halide perovskite nanocrystal particle light emitter according to the present invention forms a nanocrystalline structure with the alkyl halide (first organic ligand) used as a surfactant that surrounds the surface of the metal halide perovskite to stabilize the surface of the metal halide perovskite precipitated as described above.

On the other hand, if the length of the alkyl halide surfactant is short, the size of the formed crystalline particles increases, so it may be formed to exceed 900 nm. In this case, due to the thermal ionization and delocalization of charge carriers in the large nanocrystal particle, there may be a fundamental problem in that excitons do not emit light and are separated into free charge carriers and disappear.

That is, the size of the metal halide perovskite crystal particles to be formed and the length of the alkyl halide surfactant used to form the nanocrystal particle are inversely proportional.

Therefore, by using an alkyl halide having a certain length or more as a surfactant, the size of the crystalline particles of the metal halide perovskite formed can be controlled to be less than a certain size or less. For example, octadecyl-ammonium bromide as an alkyl halide surfactant may be used to form organic-inorganic hybrid metal halide perovskite nanocrystal particles having a size of 900 nm or less.

Therefore, in order to form nanocrystal particles of a certain size or less, an alkyl halide (first organic ligand) having a certain length or longer is used, and then, by substituting such a first organic ligand with a second ligand having a short length or containing a phenyl group or a fluorine group, energy transfer or charge injection into the nanocrystal structure is further increased, thereby increasing luminous efficiency. Furthermore, durability or stability can also be increased by the substituted hydrophobic ligand.

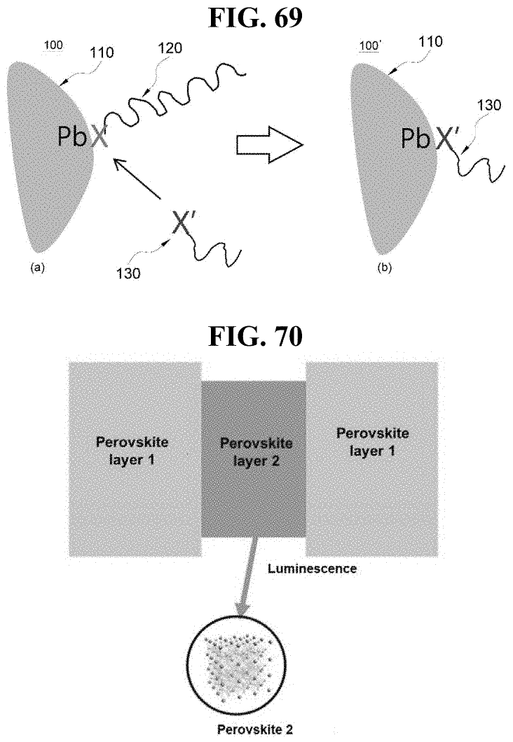

This replacement step S200 will be described in more detail with reference to FIG. 69.

FIG. 69 is a schematic diagram showing a method of manufacturing a metal halide perovskite nanocrystal particle light emitter in which an organic ligand is substituted according to an embodiment of the present invention.

Referring to FIG. 69(a), the perovskite nanocrystal particle light emitter 100 including a metal halide perovskite nanocrystal structure 110 and a first organic ligand 120 surrounding the nanocrystal structure 110 is prepared. The nanocrystal particle light emitter 100 may be prepared in a state contained in a solution (solution state). Meanwhile, as shown, the central metal of the metal halide perovskite nanocrystal structure 110 is Pb.

Then, the second organic ligand 130 is added to the solution containing the nanocrystal particle light emitter 100.

Referring to FIG. 69(b), the first organic ligand 120 is replaced with the second organic ligand 130 by the addition of the second organic ligand 130. This organic ligand substitution may be performed by using a difference in affinity strength between the central metal of the metal halide perovskite nanocrystal structure 110 and the halogen element. For example, the affinity with the central metal is stronger in the order of Cl<Br<I.

Accordingly, when the halogen element (X) of the first organic ligand 120 is Cl, ligand substitution may be performed using the halogen element (X′) of the second organic ligand 130 as Br or I.

Therefore, the organic ligand-substituted metal halide perovskite nanocrystal particle light emitter with improved luminescence efficiency can be formed by replacing the first organic ligand 120 with the second organic ligand 130 having a short length or containing a phenyl group or a fluorine group 100′.

As another example, the above-described organic-inorganic metal halide perovskite nanocrystal particles substituted with the organic ligands or organic ligand-substituted inorganic metal halide perovskite nanocrystal particles can be applied as a photoactive layer in solar cell application. Such a solar cell may include a first electrode, a second electrode, and a photoactive layer including the above-described metal halide perovskite nanocrystal particles positioned between the first electrode and the second electrode.

<Metal Halide Perovskite Light-Emitting Device Including a Metal Halide Perovskite Light Emission Layer Having a Tandem Structure>

According to another embodiment of the present invention, the emission layer may include a metal halide perovskite having a tandem structure.

In the light-emitting device according to an embodiment of the present invention, the light emission layer 40 has a tandem structure in which a first light-emitting material layer and a second light-emitting material layer are alternately stacked, and the first light-emitting material layer and the second light-emitting material layer may have different band gaps. The light emission layer may be formed by co-depositing a metal halide perovskite of a first light-emitting material layer and a perovskite of a second light-emitting material layer. Until now, the metal halide perovskite light emission layer used in the metal halide perovskite light-emitting device is mainly manufactured through a solution process. However, the solution process has a disadvantage in that the uniformity of the thin film to be formed is low, thickness control is not easy, and materials that can be mixed are limited by the characteristics of the solvent. In the metal halide perovskite light-emitting device, the worst performance impediment factor is the non-uniform thin film. In a thin film device composed of a stacked thin film, the non-uniformity of the thin film is one of the factors that greatly deteriorates the device performance by breaking the charge balance and generating a leakage current. In particular, since the morphology of the thin film varies greatly depending on the conditions for forming the thin film and the surrounding environment, the uniformity of the thin film is very important in the performance of the metal halide perovskite light-emitting device. An example of a non-uniform thin film is a general spin coating process that forms CH₃NH₃PbBr₃. If the additional nanocrystal pinning process is not used, there is a problem that the void is formed in the form of an isolated crystal due to spontaneous crystallization [Science 2015, 350, 1222]. However, in the case of using the nanocrystal pinning process, the film quality of the thin film can be greatly influenced by the experimental environment, so even if the same process is used, there is a disadvantage in that the film quality has a large deviation. In addition, since the film quality of the thin film is improved only in the region where the nanocrystal is pinned, there may be limitations in implementing a large-area device. However, there has not been an example of manufacturing the metal halide perovskite light emission layer by evaporation deposition process. The position of the electron-hole recombination region in the device, that is, the emission spectrum of the device may be affected by the thickness of the emission layer and may vary depending on the energy level of the material used. Accordingly, in the present invention, a thin film is prepared by co-depositing the first light-emitting material layer and the second light-emitting material layer through an evaporation method. By co-depositing the first light-emitting material layer and the second light-emitting material layer, a uniform thin film can be formed, it is easy to control the thickness of the thin film, and the size of the formed metal halide perovskite crystal is reduced. Excitons or charge carriers are spatially constrained, the luminescence efficiency can be improved.

FIG. 70 is a cross-sectional view showing a light emission layer having a tandem structure according to an embodiment of the present invention.

Referring to FIG. 70, in the light-emitting device according to an embodiment of the present invention, the light emission layer 40 has a tandem structure in which a first light-emitting material layer and a second light-emitting material layer are alternately stacked, and the first light-emitting material layer and the second light-emitting material layer may have different band gaps.

In more detail, a band gap of the first light-emitting material layer may be larger than a band gap of the second light-emitting material layer. Specifically, the energy level of the valance band maximum (VBM) of the first light-emitting material layer may be lower than the energy level of the VBM of the second light-emitting material layer, and the conduction band minimum (CBM) of the first light-emitting material layer may be higher than the energy level of the CBM of the second light-emitting material layer. The energy level of the valence band maximum (VBM) of the emission layer can be lower than the work function of the positive electrode and the HOMO (Highest Occupied Molecular Orbital) energy level of the hole injection layer, and higher than the work function of the cathode and the HOMO energy level of the electron transport layer. The energy level of the conduction band minimum (CBM) of the emission layer may be lower than the work function of the anode and the LUMO (Lowest Unoccupied Molecular Orbital) energy level of the hole injection layer, and higher than the work function of the cathode or the LUMO of the electron transport layer.

That is, in the case of a light emission layer in which metal halide perovskites having different band gaps are alternately arranged and stacked, the energy transfer behavior may vary according to the energy level of the material. Accordingly, since energy transfer occurs from the first light-emitting material layer having a larger band gap to the second light-emitting material layer having a smaller band gap, light emission may occur only in the second light-emitting material layer. So, the electron-hole recombination zone of the light-emitting device can be controlled. Therefore, the energy level of the material used to control the location at which light emission occurs may be important.

Measurement of the energy level of the VBM (Valence Band Maximum) of the light-emitting material layer containing the metal halide perovskite is performed by UV photoelectron spectroscopy (UPS), which is a method of measuring the ionization potential by irradiating UV on the surface of the thin film and detecting the electrons that come out of the material can be used. Alternatively, cyclic voltammetry (CV), which measures the oxidation potential through voltage sweep after dissolving the substance to be measured in a solvent together with an electrolyte, may be used. In addition, the PYSA (Photoemission Yield Spectrometer in Air) method can be used to measure the ionization potential in the atmosphere using an AC-3 (RKI) device. Also, the energy level of the conduction band minimum (CBM) of the metal halide perovskite can be obtained by measuring IPES (Inverse Photoelectron Spectroscopy) or electrochemical reduction potential. IPES is a method to determine the energy level of CBM by irradiating an electron beam onto a thin film and measuring the light emitted. In addition, in the measurement of the electrochemical reduction potential, a reduction potential may be measured through a voltage sweep after dissolving a substance to be measured in a solvent together with an electrolyte. Alternatively, the energy level of the conduction band minimum (CBM) can be calculated using the energy level of the valence band maximum (VBM) and the singlet energy level obtained by measuring the degree of UV absorption of the target material.

Specifically, the energy level of the Valence Band Maximum (VBM) of the present specification is measured through an AC-3 (RKI) measuring instrument after vacuum deposition of the target material to a thickness of 50 nm or more on the ITO substrate. In addition, the energy level of the conduction band minimum (CBM) is determined by measuring the absorption spectrum (Abs) and the photoluminescence spectrum (PL) of the prepared sample, and then calculating the edge energy of Abs spectrum, and regarding difference of the calculated edge energies as band gap energy, and calculating the energy level of the valence band maximum (VBM) by subtracting the bandgap from the energy level of the conduction band minimum (CBM) measured in AC-3.

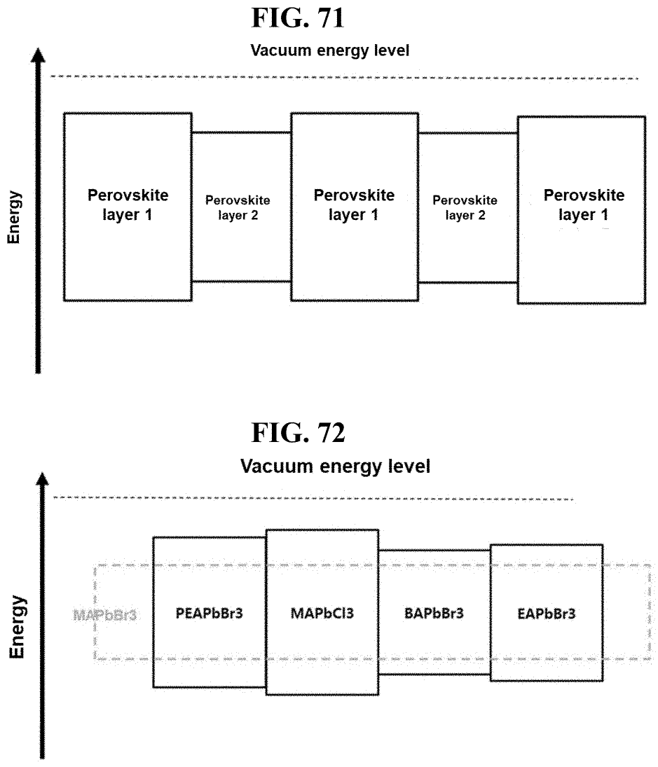

FIG. 71 illustrates energy levels of a light emission layer having a tandem structure in which first and second light-emitting material layers are alternately stacked according to an embodiment of the present invention.

In the present invention, light emission may occur in the second light-emitting material layer. Accordingly, the metal halide perovskite of the first light-emitting material layer having a larger band gap and the metal halide perovskite of the second light-emitting material layer having a smaller band gap are alternately disposed to have a tandem structure. That is, the energy level of the valence band maximum (VBM) of the first light-emitting material layer may be lower than the energy level of the VBM of the second light-emitting material layer, and the energy level of the conduction band minimum (CBM) of the first light-emitting material layer may be higher than the energy level of the CBM of the second light-emitting material layer

That is, the energy level of the valence band maximum (VBM) of the first light-emitting material layer may be lower than the energy level of the VBM of the second light-emitting material layer, and the conduction band minimum (CBM) of the first light-emitting material layer may be higher than the energy level of the CBM of the second light-emitting material layer.

FIG. 72 illustrates energy levels of materials used in a light emission layer having a tandem structure in which first and second light-emitting material layers are alternately stacked according to an embodiment of the present invention.

Referring to FIG. 72, the energy level of the Valence Band Maximum (VBM) of MAPbBr₃ is (−)5.9 eV, and the energy level of the Conduction Band Minimum (CBM) is (−) 3.6 eV. The MAPbBr₃ may be used as a metal halide perovskite included in the second light-emitting material layer. At this time, in the case of PEAPbBr₃, since the energy level of the highest valence band (VBM) is (−)6.4 eV, it is lower than the energy level of the highest valence band (VBM, Valence Band Maximum) of MAPbBr₃, and the lowest electron band (CBM, Conduction Band minimum) is (−)2.5 eV, which is higher than the energy level of the electron band (CBM, Conduction Band Minimum) of MAPbBr₃. Therefore, when MAPbBr₃ is used as a metal halide perovskite included in the second light-emitting material layer, PEAPbBr₃ can be used as a metal halide perovskite included in the first light-emitting material layer. That is, according to the present invention, the first light-emitting material layer including PEAPbBr₃ and the second light-emitting material layer including MAPbBr₃ are alternately stacked to manufacture a light emission layer having a tandem structure. In addition, when MAPbBr₃ is used as a metal halide perovskite included in the second light-emitting material layer, MAPbCl₃, BAPbBr₃, or EAPbBr₃ may also be used as a metal halide perovskite included in the first light-emitting material layer, but is not limited thereto.

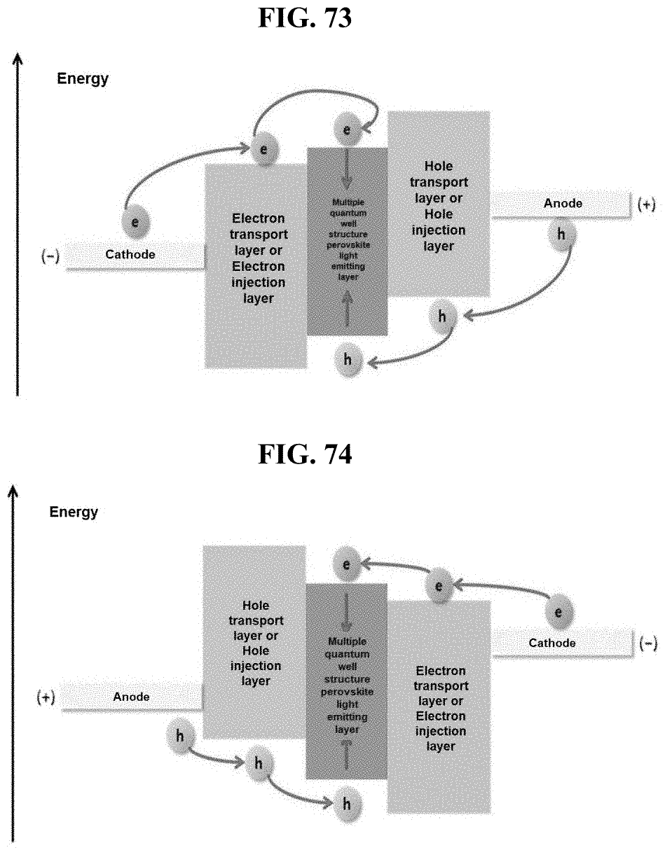

FIG. 73 shows energy levels of constituent layers in a light-emitting device (normal structure) including a light emission layer according to an embodiment of the present invention, and FIG. 74 shows the energy levels of the constituent layers in a light-emitting device (inverted structure) including a light emission layer according to another embodiment of the present invention.

FIGS. 73 and 74, in the light-emitting device according to an embodiment of the present invention, the energy level of the VBM (Valence Band Maximum) of the light emission layer 40 is the highest occupied molecular orbital (HOMO) of the hole injection layer is lower than the energy level of the electron transport layer, and higher than the energy level of the highest occupied molecular orbital (HOMO) of the electron transport layer. When having such an energy level, when a forward bias is applied to the light-emitting device, it becomes easier for holes from the anode 20 to flow into the light emission layer 40 through the hole injection layer 30. In addition, in the light-emitting device according to an embodiment of the present invention, it is preferred that the energy level of the electron band minimum (CBM) of the light emission layer is lower than that of the lower unoccupied molecular orbital (LUMO) of the hole injection layer, and higher than the energy level of LUMO (lowest unoccupied molecular orbital) of the electron transport layer. By having such an energy level, electrons and holes introduced into the light emission layer 40 are combined to form excitons, and light may be emitted while the excitons undergo transition to the ground state.

<Stacked Tandem Metal Halide Perovskite Light-Emitting Diode>

According to another embodiment of the present invention, the metal halide perovskite described above may be used in a stacked hybrid light-emitting diode.

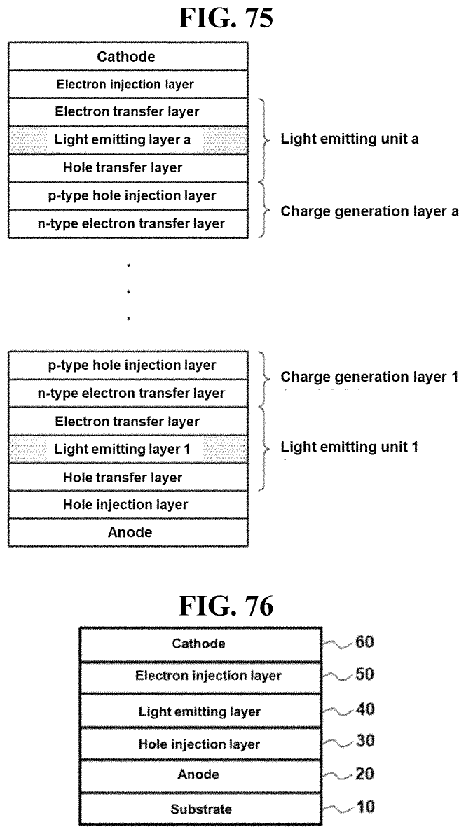

Referring to FIG. 75, a hybrid light-emitting diode according to an embodiment includes an anode, first to a-th light-emitting units, 1 to a-1 charge generation layers, and a cathode (here, a is an integer greater than or equal to 2). Hereinafter, for convenience, a hybrid light-emitting diode including up to the a-th light-emitting unit may be referred to as a-th light-emitting diode.

The anode may include ITO, FTO, graphene, nanowires, or polymer electrodes, but is not limited thereto. The anode may be formed of a polymer electrode or CNT through a solution process, or may include a transparent electrode material such as ITO and IZO through a sputtering process.

The charge generation layer may include an n-type layer for generating and injecting electrons, or a p-type layer for generating and injecting holes, and electrons and holes may be injected into adjacent light-emitting units without resistance. The n-type layer may be an electron transport layer, and the p-type layer may be a hole injection layer.

The n-type electron transport layer may be an organic material alone or an organic material doped with an n-type dopant in an amount of about 5 to 40%. The electron transfer organic material may include quinoline derivatives, especially tris(8-hydroxyquinoline) aluminum(Alq₃), bis(2-methyl-8-quinolinolate)-4-(phenylphenolato)aluminum(Balq), bis(10-hydroxybenzo [h] quinolinato)-beryllium (Bebq₂), 2,9-dimethyl-4,7-diphenyl-1,10-phenanthroline (BCP), 4,7-diphenyl-1,10-phenanthroline (Bphen), 2,2′,2″-(benzene-1,3,5-triyl)-tris(1-phenyl-1H-benzimidazole) (TPBI), 3-(4-biphenyl)-4-(phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-Diphenyl-1,10-phenanthroline (NBphen), Tris(2,4,6-trimethyl-3-(pyridin-3-yl)phenyl)borane (3TPYMB), phenyl-phenyl-dipyrenylphosphine oxide (POPy₂), 3,3′,5,5′-tetra[(m-pyridyl)-phen-3-yl]biphenyl (BP4mPy), 1,3,5-tri[(3-pyridyl)-phen-3-yl]benzene (TmPyPB), 1,3-bis[3,5-di(pyridin-3-yl)phenyl]benzene (BmPyPhB), bis(10-hydroxybenzo[h]quinolinato)beryllium (Bepq₂), diphenylbis(4-(pyridin-3-yl)phenyl)silane (DPPS), 1,3,5-tri(p-pyrid-3-Yl-phenyl)benzene (TpPyPB), 1,3-bis[2-(2,2′-bipyridin-6-yl)-1,3,4-oxadiazo-5-yl]benzene (Bpy-OXD), 6,6′-bis[5-(biphenyl-4-yl)-1,3,4-oxadiazo-2-yl]-2,2′-bipyridyl (BP-OXD-Bpy), TSPO1 (diphenylphosphine oxide-4-(triphenylsilyl)phenyl), TPBi(1,3,5-tris(N-phenylbenzimidazol-2-yl)benzene), Tris (8-quinolinorate) aluminum (Alq3), 2,5-diaryl silol derivative (PyPySPyPy), perfluorinated compound (PF-6P), or COTs (octasubstituted cyclooctatetraene), but is not limited thereto.

The n-type dopant may be an alkali metal, alkaline earth metal such as Li, Na, K, Rb, Cs, Be, Mg, Ca, Sr, and Ba, a carbonate-based compound, azide-based compound, a nitride-based compound, a nitrate-based compound, a phosphate-based compound, or a quinolate-based compound. An example of a compound based on an alkali metal or alkaline earth metal may be Li₂CO₃, LiNO₃, RbNO₃, Rb₂CO₃, AgNO₃, Ba(NO₃)₂, Mn(NO₃)₂, Zn(NO₃)₂, CsNO₃, Cs₂CO₃, CsF, CsN₃, FePo₄ or NaN₃, but are not limited thereto.

The thickness of the n-type electron transport layer may be about 5 to 50 nm.

The p-type hole injection layer may be an organic material alone or an organic material doped with a p-type dopant in an amount of about 5 to 40%.

Specifically, the hole transport organic material may be at least one selected from the group consisting of Fullerene(C₆₀), HAT-CN, F₁₆CuPC, CuPC, m-MTDATA [4,4′,4″-tris (3-methylphenylphenylamino) triphenylamine], NPB [N,N′-Di(1-naphthyl)-N,N′-diphenyl-(1,1′-biphenyl)-4,4′-diamine)], TDATA, 2T-NATA, Pani/DBSA (Polyaniline/Dodecylbenzenesulfonic acid: Polyaniline/Dodecylbenzenesulfonic acid), PEDOT/PSS (Poly(3,4-ethylenedioxythiophene)/Poly(4-styrenesulfonate): Poly(3,4-ethylenedioxythiophene)/poly(4-styrene) Sulfonate)), Pani/CSA (Polyaniline/Camphor sulfonic acid: polyaniline/camphor sulfonic acid) and PANI/PSS (Polyaniline)/Poly(4-styrenesulfonate): polyaniline)/poly(4-styrenesulfonate)), 1,3-bis(carbazol-9-yl)benzene (MCP), 1,3,5-tris(carbazol-9-yl)benzene (TCP), 4,4′,4″-tris(carbazol-9-yl)triphenylamine (TCTA), 4,4′-bis(carbazol-9-yl)biphenyl (CBP), N,N′-Bis(naphthalen-1-yl)-N,N′-bis(phenyl)benzidine (NPB), N,N′-bis(naphthalen-2-yl)-N,N′-bis(phenyl)-benzidine (β-NPB), N,N′-bis(naphthalen-1-yl)-N,N′-bis(phenyl)-2,2′-dimethylbenzidine (α-NPD), di-[4,-(N,N-ditolyl-amino)-phenyl]cyclohexane (TAPC), N,N,N′,N′-tetra-naphthalen-2-yl-benzidine (β-TNB) and N4,N4,N4′,N4′-tetra(biphenyl-4-yl)biphenyl-4,4′-diamine (TPD15), poly(9,9-dioctylfluorene-co-bis-N,N′-(4-butylphenyl)-bis-N,N′-phenyl-1,4-phenylenediamine) (PFB), poly(9,9′-dioctylfluorene-co-N-(4-butylphenyl)diphenylamine) (TFB), poly(9,9′-dioctylfluorene-co-bis-N,N′-(4-butylphenyl)-bis-N,N′-phenylbenzidine) (BFB), poly(9,9-dioctylfluorene-co-bis-N,N′-(4-methoxyphenyl)-bis-N,N′-phenyl-1, and 4-phenylenediamine) (PFMO), but is not limited thereto.

The p-type dopant may be F4-TCNQ, FeCl₃, WO₃, MoO₃, ReO₃, Fe₃O₄, MnO₂, SnO₂, CoO₂, CuPC, metal oxide, or a hole injection organic material having a deep LUMO level.

The thickness of the p-type hole injection layer may be about 5 to 30 nm.

The stacked hybrid light-emitting diode according to the embodiment includes at least two or more light-emitting units. In FIG. 76, each light-emitting unit is illustrated to include a hole transport layer, a light emission layer, or an electron transport layer, but is not limited thereto.

In addition, a hole blocking layer (not shown) may be located between the emission layer 40 and the electron transport layer 50. In addition, an electron blocking layer (not shown) may be located between the light emission layer 40 and the hole transport layer. However, the present invention is not limited thereto, and the electron transport layer 50 may serve as a hole blocking layer, or the hole transport layer may serve as an electron blocking layer.

The anode 20 may be a conductive metal oxide, a metal, a metal alloy, or a carbon material. Conductive metal oxides include ITO, AZO(Al-doped ZnO), GZO(Ga-doped ZnO), IGZO(In,Ga-doped ZnO), MZO(Mg-doped ZnO), Mo-doped ZnO, Al-doped MgO, Ga-doped MgO, F-doped SnO₂, Nb-doped TiO₂, CuAlO₂, or a combination thereof. Metals or metal alloys suitable as the anode 20 may be Au and CuI. The carbon material may be graphite, graphene, or carbon nanotubes.

The cathode 70 is a conductive film having a lower work function than the anode 20, for example, the cathode 70 may be metals such as aluminum, magnesium, calcium, sodium, potassium, indium, yttrium, lithium, silver, lead, or cesium, or it can be formed using a combination of two or more types.

The anode 20 and the cathode 70 may be formed using a sputtering method, a vapor deposition method, or an ion beam deposition method. The hole injection layer 30, the hole transport layer, the light emission layer 40, the hole blocking layer, the electron transport layer 50, and the electron injection layer 60 can be deposited independent of each other by a vapor deposition method or a coating method such as spraying and spin coating, dipping, printing, doctor blading, or electrophoresis.

The hole injection layer 30 and/or the hole transport layer is a layer having a HOMO level between the work function level of the anode 20 and the HOMO level of the emission layer 40, and it functions to increase the efficiency of hole injection or transport from the anode 20 to the emission layer 40.

The hole injection layer 30 or the hole transport layer may include a material commonly used as a hole transport material, and one layer may include different hole transport material layers. The hole transport material may be, for example, mCP (N,Ndicarbazolyl-3,5-benzene), PEDOT:PSS (poly(3,4-ethylenedioxythiophene):polystyrenesulfonate), NPD (N,N′-di(1-naphthyl)-N,N′-diphenylbenzidine), N,N′-Bis(3-methylphenyl)-N,N′-diphenylbenzidine (TPD), DNTPD (N4,N4′-Bis[4-[bis(3-methylphenyl)amino]phenyl]-N4,N4′-diphenyl-[1,1′-biphenyl]-4,4′-diamine), N,N′-diphenyl-N,N′-dinaphthyl-4,4′-diaminobiphenyl, N,N,N′N′-tetra-p-tolyl-4,4′-diaminobiphenyl, N,N,N′N′-tetraphenyl-4,4′-diaminobiphenyl, Porphyrin compound derivatives such as copper(II)1,10,15,20-tetraphenyl-21H,23H-porphyrin, TAPC (1,1-Bis[4-[N,N′-Di(p-tolyl)Amino]Phenyl]Cyclohexane), N,N,N-tri(p-tolyl)amine, 4,4′, triarylamine derivatives such as 4′-tris[N-(3-methylphenyl)-N-phenylamino]triphenylamine, carbazole derivatives such as N-phenylcarbazole and polyvinylcarbazole, phthalocyanine derivatives such as metal-free phthalocyanine and copper phthalocyanine; starburst amine derivatives; Enaminestilbene derivatives, derivatives of aromatic tertiary amines and styrylamine compounds or polysilane. Such a hole transport material may serve as an electron blocking layer.

The hole injection layer 30 may also include a hole injection material. For example, the hole injection layer may include at least one of a metal oxide and a hole injection organic material.

When the hole injection layer 30 includes a metal oxide, the metal oxide may contain one or more metal oxides selected from the group consisting of MoO₃, WO₃, V₂O₅, nickel oxide (NiO), copper oxide (Copper(II) Oxide: CuO), copper aluminum oxide (CAO, CuAlO₂), Zinc Rhodium Oxide (ZRO, ZnRh₂O₄), GaSnO, and metal-sulfide (FeS, ZnS or CuS).

When the hole injection layer 30 contains a hole injection organic material, the hole injection layer 30 may be formed according to a method arbitrarily selected from a variety of known methods such as vacuum deposition method, spin coating method, cast method, Langmuir-Blodgett (LB) method, spray coating method, dip coating method, gravure coating method, reverse offset coating method, screen printing method, slot-die coating method, and nozzle printing method.

The hole injecting organic material may be at least one selected from the group consisting of Fullerene(C₆₀), HAT-CN, F₁₆CuPC, CuPC, m-MTDATA [4,4′,4″-tris (3-methylphenylphenylamino) triphenylamine], NPB [N,N′-Di(1-naphthyl)-N,N′-diphenyl-(1,1′-biphenyl)-4,4′-diamine)], TDATA, 2T-NATA, Pani/DBSA (Polyaniline/Dodecylbenzenesulfonic acid: Polyaniline/Dodecylbenzenesulfonic acid), PEDOT/PSS (Poly(3,4-ethylenedioxythiophene)/Poly(4-styrenesulfonate): Poly(3,4-ethylenedioxythiophene)/poly(4-styrene) Sulfonate)), Pani/CSA (Polyaniline/Camphor sulfonic acid: polyaniline/camphor sulfonic acid) and PANI/PSS (Polyaniline)/Poly(4-styrenesulfonate): polyaniline)/poly(4-styrenesulfonate)).

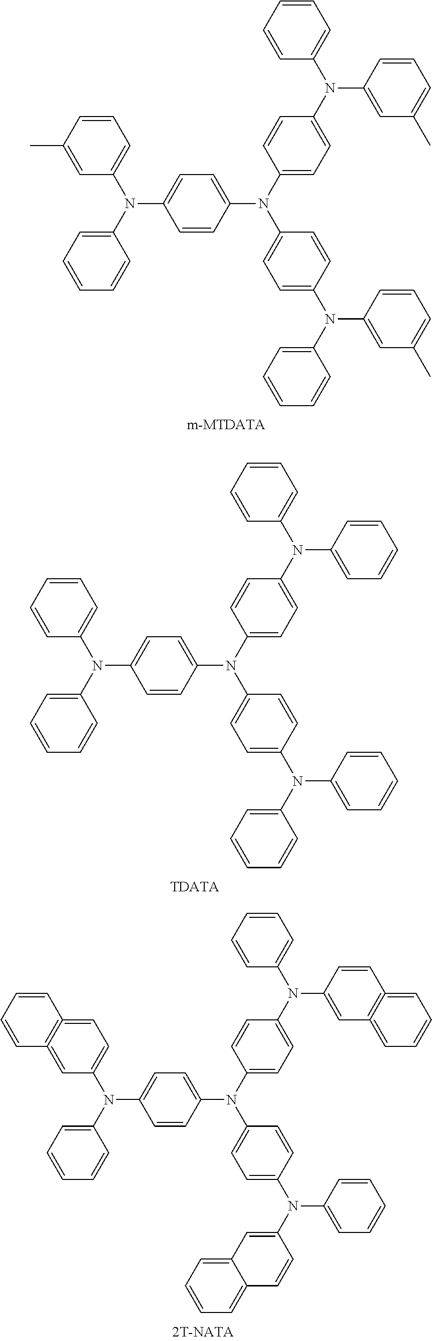

For example, the hole injection layer may be a layer doped with the metal oxide on the hole injection organic material matrix. In this case, the doping concentration is preferably 0.1 wt % to 80 wt % based on the total weight of the hole injection layer.

The hole injection layer may have a thickness of 1 nm to 1000 nm. For example, the thickness of the hole injection layer may include a range in which the lower value of the number is the lower limit value and the higher value is the upper limit value selected from the group of 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm, 101 nm, 102 nm, 103 nm, 104 nm, 105 nm, 106 nm, 107 nm, 108 nm, 109 nm, 110 nm, 111 nm, 112 nm, 113 nm, 114 nm, 115 nm, 116 nm, 117 nm, 118 nm, 119 nm, 120 nm, 125 nm, 130 nm, 135 nm, 140 nm, 145 nm, 150 nm, 155 nm, 160 nm, 165 nm, 170 nm, 175 nm, 180 nm, 185 nm, 190 nm, 195 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 450 nm, 500 nm, 550 nm, 600 nm, 650 nm, 700 nm, 750 nm, 800 nm, 850 nm, 900 nm, 950 nm, 1000 nm. Also, preferably, the thickness of the hole injection layer may be 10 nm to 200 nm. When the thickness of the hole injection layer satisfies the above-described range, the driving voltage is not increased so that a high-quality organic device can be implemented.

In addition, a hole transport layer may be further formed between the light emission layer and the hole injection layer.

The hole transport layer may include a known hole transport material. For example, the hole transport material that may be included in the hole transport layer may be at least one selected from the group consisting of 1,3-bis(carbazol-9-yl)benzene (MCP), 1,3,5-tris(carbazol-9-yl)benzene (TCP), 4,4′,4″-tris(carbazol-9-yl)triphenylamine (TCTA), 4,4′-bis carbazol-9-yl)biphenyl (CBP), N,N′-bis (Naphthalen-1-yl)-N,N′-bis(phenyl)benzidine (NPB), N,N′-bis(naphthalen-2-yl)-N,N′-bis(phenyl)-benzidine (β-NPB), N,N′-bis(naphthalen-1-yl)-N,N′-bis(phenyl)-2,2′-dimethylbenzidine (α-NPD), di-[4,-(N,N-ditolyl-amino)-phenyl]cyclohexane (TAPC), N,N,N′,N′-tetra-naphthalen-2-yl-benzidine (Nβ-TNB) and N4,N4,N4′,N4′-tetra(biphenyl-4-yl)biphenyl-4,4′-diamine (TPD15), poly(9,9-dioctylfluorene-co-bis-N,N′-(4-butylphenyl)-bis-N,N′-phenyl-1,4-phenylenediamine) (PFB), poly(9,9′-dioctylfluorene-co-N-(4-butylphenyl)diphenylamine) (TFB), poly(9,9′-dioctylfluorene-co-bis-N,N′-(4-butylphenyl)-bis-N,N′-phenylbenzidine) (BFB), poly(9,9-dioctylfluorene-co-bis-N,N′-(4-methoxyphenyl)-bis-N,N′-phenyl-1, and 4-phenylenediamine) (PFMO), but is not limited thereto.

Among the hole transport layers, for example, in the case of TCTA, in addition to the hole transport role, it may play a role of preventing diffusion of excitons from the emission layer.

The hole transport layer may have a thickness of 1 nm to 100 nm. For example, the thickness of the hole transport layer may include a range in which the lower value of the number is the lower limit value and the higher value is the upper limit value selected from the group of 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm. Also, preferably, the thickness of the hole injection layer may be 10 nm to 60 nm. When the thickness of the hole transport layer satisfies the above-described range, light efficiency of the organic light-emitting diode may be improved and luminance may be increased.

The electron injection layer 60 and/or the electron transport layer 50 are layers having an LUMO level between the work function level of the cathode 70 and the LUMO level of the emission layer 40, and it functions to increase the efficiency of injection or transport of electrons from the cathode 70 to the emission layer 40.

The electron injection layer 60 may be, for example, LiF, NaCl, CsF, Li₂O, BaO, BaF₂, or Liq (lithium quinolate).

The electron transport organic material may include Quinoline derivatives, especially tris(8-hydroxyquinoline) aluminum(Alq₃), bis(2-methyl-8-quinolinolate)-4-(phenylphenolato)aluminum(Balq), bis(10-hydroxybenzo [h] quinolinato)-beryllium (Bebq₂), 2,9-dimethyl-4,7-diphenyl-1,10-phenanthroline (BCP), 4,7-diphenyl-1,10-phenanthroline (Bphen), 2,2′,2″-(benzene-1,3,5-triyl)-tris(1-phenyl-1H-benzimidazole) (TPBI), 3-(4-biphenyl)-4-(phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-Diphenyl-1,10-phenanthroline (NBphen), Tris(2,4,6-trimethyl-3-(pyridin-3-yl)phenyl)borane (3TPYMB), phenyl-phenyl-dipyrenylphosphine oxide (POPy2), 3,3′,5,5′-tetra[(m-pyridyl)-phen-3-yl]biphenyl (BP4mPy), 1,3,5-tri[(3-pyridyl)-phen-3-yl]benzene (TmPyPB), 1,3-bis [3,5-di(pyridin-3-yl)phenyl]benzene (BmPyPhB), bis(10-hydroxybenzo[h]quinolinato)beryllium (Bepq2), Diphenylbis(4-(pyridin-3-yl)phenyl)silane (DPPS), 1,3,5-tri(p-pyrid-3-Yl-phenyl)benzene (TpPyPB), 1,3-bis[2-(2,2′-bipyridin-6-yl)-1,3,4-oxadiazo-5-yl]benzene (Bpy-OXD), 6,6′-bis[5-(biphenyl-4-yl)-1,3,4-oxadiazo-2-yl]-2,2′-bipyridyl (BP-OXD-Bpy), TSPO1 (diphenylphosphine oxide-4-(triphenylsilyl)phenyl), TPBi(1,3,5-tris(N-phenylbenzimidazol-2-yl)benzene), Tris (8-quinolinorate) aluminum (Alq3), 2,5-diaryl silol derivative (PyPySPyPy), perfluorinated compound (PF-6P), or COTs (Octasubstituted cyclooctatetraene).

The hole transport layer may have a thickness of 5 nm to 100 nm. For example, the thickness of the hole transport layer may include a range in which the lower value of the number is the lower limit value and the higher value is the upper limit value selected from the group of 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, or 100 nm. Also, preferably, the thickness of the hole injection layer may be 15 nm to 60 nm. When the thickness of the electron transport layer satisfies the above-described range, excellent electron transport characteristics can be obtained without an increase in driving voltage.

The electron injection layer 60 may include a metal oxide. Since the metal oxide has n-type semiconductor properties, it has excellent electron transport capability, and further, it is a material that is not reactive to air or moisture, and may be selected from semiconductor materials having excellent transparency in a visible light region.

The electron injection layer 60 may include, for example, one or more metal oxides selected from aluminum doped zinc oxide (AZO), alkali metal (Li, Na, K, Rb, Cs or Fr) doped AZO, TiOₓ (x is a real number of 1 to 3), indium oxide (In₂O₃), tin oxide (SnO₂), zinc oxide (ZnO), zinc tin oxide (Zinc Tin Oxide), gallium oxide (Ga₂O₃), tungsten oxide (WO₃), aluminum oxide, titanium oxide, vanadium oxide (V₂O₅, vanadium (IV))) oxide (VO₂), V₄O₇, V₅O₉, or V₂O₃), molybdenum oxide (MoO₃ or MoOₓ), copper oxide (CuO), nickel oxide (NiO), copper aluminum oxide (CAO, CuAlO₂), zinc rhodium oxide (ZRO, ZnRh₂O₄), iron oxide, chromium oxide, bismuth oxide, IGZO (indium-Gallium Zinc Oxide), and ZrO₂, but is not limited thereto. As an example, the electron injection layer 60 may be a metal oxide thin film layer, a metal oxide nanoparticle layer, or a layer including metal oxide nanoparticles in the metal oxide thin film.

The electron injection layer 60 may be formed using a wet process or a vapor deposition method.

When the electron injection layer 60 is formed by a solution method (ex. a sol-gel method) as an example of a wet process, the electron injection layer 60 may be formed with heat treatment after applying the mixture for an electron injection layer containing at least one of a sol-gel precursor of a metal oxide and a metal oxide in the form of nanoparticles and a solvent. In this case, the solvent may be removed by heat treatment or the electron injection layer 60 may be crystallized. The method of providing the mixed solution for the electron injection layer on the substrate 10 is a known coating method, for example, a spin coating method, a cast method, a Langmuir-Blodgett (LB) method, a spray coating method, a dip coating method, gravure coating method, a reverse offset coating method, a screen printing method, a slot-die coating method, a nozzle printing method, or a dry transfer printing method may be selected, but the present invention is not limited thereto.

The sol-gel precursor of the metal oxide may contain at least one selected from the group consisting a metal salt (e.g., metal halide, metal sulfate, metal nitrate, metal perchlorate, metal acetate, metal carbonate), metal salt hydrate, metal hydroxide, metal alkyl, metal of alkoxide, metal carbide, metal acetylacetonate, metal acid, metal acid salt, metal acid hydrate, metal sulfide, metal acetate, metal alkanoate, metal phthalocyanine, metal nitride, and metal carbonate.

When the metal oxide is ZnO, the ZnO sol-gel precursor may be at least one selected from the group consisting of zinc sulfate, zinc fluoride, zinc chloride, zinc bromide, zinc iodide, zinc perchlorate, zinc hydroxide (Zn(OH)₂), zinc acetate (Zn(CH₃COO)₂), zinc acetate hydrate (Zn(CH₃(COO)₂.nH₂O), Diethyl zinc (Zn(CH₃CH₂)₂), zinc nitrate (Zn(NO₃)₂), zinc nitrate (Zn(NO₃)₂.nH₂O), zinc carbonate (Zn(CO₃)), zinc acetylacetonate (Zn(CH₃COCHCOCH₃))2), and zinc acetylacetonate hydrate (Zn(CH₃COCHCOCH₃)₂.nH₂O), but is not limited thereto.

When the metal oxide is indium oxide (In₂O₃), at least one selected from the group consisting of Indium nitrate hydrate (In(NO₃)₃.nH₂O), indium acetate (In(CH₃COO)₂), indium acetate hydrate (In(CH₃(COO)₂.nH₂O), indium chloride (InCl, InCl₂, InCl₃), indium nitrate (In(NO₃)₃), indium nitrate hydrate (In(NO₃)₃nH₂O), indium acetylacetonate In(CH₃COCHCOCH₃)₂), and indium acetylacetonate hydrate (In(CH₃COCHCOCH₃)₂.nH₂O) may be used as the In₂O₃ sol-gel precursor.

When the metal oxide is tin oxide (SnO₂), at least one selected from the group consisting of tin acetate (Sn(CH₃COO)₂), tin acetate hydrate (Sn(CH₃(COO)₂.nH₂O), tin chloride (SnCl₂, SnCl₄), tin chloride hydrate (SnClₙnH₂O), tin acetylacetonate (Sn(CH₃COCHCOCH₃)₂), and tin acetylacetonate hydrate (Sn(CH₃COCHCOCH₃)₂.nH₂O) may be used as the SnO₂ sol-gel precursor.

When the metal oxide is gallium oxide (Ga₂O₃), at least one selected from the group consisting of gallium nitrate (Ga(NO₃)₃), gallium nitrate hydrate (Ga(NO₃)₃.nH₂O), gallium acetylacetonate (Ga(CH₃COCHCOCH₃)₃), Gallium acetylacetonate hydrate (Ga(CH₃COCHCOCH₃)₃H₂O), and gallium chloride (Ga₂Cl₄, GaCl₃) may be used as the Ga₂O₃ sol-gel precursor.

When the metal oxide is tungsten oxide (WO₃), at least one selected from the group consisting of tungsten carbide (WC), tungstic acid powder (H₂WO₄), tungsten chloride (WCl₄, WCl₆), tungsten isopropoxide (W(OCH(CH₃)₂)₆), sodium tungstate (Na₂WO₄), sodium tungstate hydrate (Na₂WO₄.nH₂O), ammonium tungstate ((NH₄)₆H₂W₁₂O₄₀), ammonium tungstate hydrate ((NH₄)₆H₂W₁₂O₄₀.nH₂O), and tungsten ethoxide (W(OC₂H₅)₆ may be used as the WO₃ sol-gel precursor.

When the metal oxide is aluminum oxide, at least one selected from the group consisting of aluminum chloride (AlCl₃), aluminum nitrate (Al(NO₃)₃), aluminum nitrate hydrate (Al(NO₃)₃.nH₂O), and aluminum butoxide (Al(C₂H₅CH(CH₃)O)) may be used as the aluminum oxide sol-gel precursor.

When the metal oxide is titanium oxide, at least one selected from the group consisting of titanium isopropoxide (Ti(OCH(CH₃)₂)₄), titanium chloride (TiCl₄), titanium ethoxide (Ti(OC₂H₅)₄), and titanium butoxide (Ti(OC₄H₉)₄) may be used as the titanium oxide sol-gel precursor.

When the metal oxide is vanadium oxide, at least one selected from the group consisting of vanadium isopropoxide (VO(OC₃H₇)₃), ammonium vanadate (NH₄VO₃), vanadium acetylacetonate (V(CH₃COCHCOCH₃)₃), and vanadium acetylacetonate hydrate (V(CH₃COCHCOCH₃)₃.nH₂O) may be used as the vanadium oxide sol-gel precursor.

When the metal oxide is molybdenum oxide, at least one selected from the group consisting of molybdenum isopropoxide (Mo(OC₃H₇)₅), molybdenum chloride isopropoxide (MoCl₃(OC₃H₇)₂), ammonium molybdenate ((NH₄)₂MoO₄), and ammonium molybdenate hydrate ((NH₄)₂MoO₄.nH₂O) may be used as the molybdenum oxide sol-gel precursor.

When the metal oxide is copper oxide, at least one selected from the group consisting of copper chloride (CuCl, CuCl₂), copper chloride hydrate (CuCl₂.nH₂O), copper acetate (Cu(CO₂CH₃), Cu(CO₂CH₃)₂), Copper acetate hydrate (Cu(CO₂CH₃)₂.nH₂O), copper acetylacetonate (Cu(C₅H₇O₂)₂), copper nitrate (Cu(NO₃)₂), copper nitrate hydrate (Cu(NO₃)₂.nH₂O), copper bromide (CuBr, CuBr₂)), copper carbonate (CuCO₃Cu(OH)₂), copper sulfide (Cu₂S, CuS), copper phthalocyanine (C₃₂H₁₆N₈Cu), copper trifluoroacetate (Cu(CO₂CF₃)₂), copper isobutyrate (C₈H₁₄CuO₄), copper ethylacetoacetate (C₁₂H₁₈CuO₆), copper 2-ethylhexanoate ([CH₃(CH₂)₃CH(C₂H₀)CO₂]₂Cu), copper fluoride (CuF₂), copper formate hydrate ((HCO₂)₂CuH₂O), copper gluconate (C₁₂H₂₂CuO₁₄), Copper hexafluoroacetylacetonate (Cu(C₅HF₆O₂)₂), copper hexafluoroacetylacetonate hydrate (Cu(C₅HF₆O₂)₂.nH₂O), copper methoxide (Cu(OCH₃)₂), copper neodecanoate (C₁₀H₁₉O₂Cu), copper perchlorate (Cu(ClO₄)₂.6H₂O), copper sulfate (CuSO₄), copper sulfate hydrate (CuSO₄.nH₂O), copper tartrate hydrate ([—CH(OH)CO₂]₂Cu.nH₂O), copper trifluoroacetylacetonate (Cu(C₅H₄F₃O₂)₂), copper trifluoromethanesulfonate ((CF₃SO₃)₂Cu), and tetraamine copper sulfate hydrate (Cu(NH₃)₄SO₄.H₂O) may be used as the copper oxide sol-gel precursor.

When the metal oxide is nickel oxide, at least one selected from the group consisting of nickel chloride (NiCl₂), nickel chloride hydrate (NiCl₂.nH₂O), nickel acetate hydrate (Ni(OCOCH₃)₂.4H₂O), nickel nitrate hydrate (Ni(NO₃)₂.6H₂O), nickel acetylacetonate (Ni(C₅H₇O₂)₂), nickel hydroxide (Ni(OH)₂), nickel phthalocyanine (C₃₂H₁₆N₈Ni), and nickel carbonate hydrate (NiCO₃₂Ni(OH)₂.nH₂O) may be used as the nickel oxide sol-gel precursor.

When the metal oxide is iron oxide, at least one selected from the group consisting of iron acetate (Fe(CO₂CH₃)₂), iron chloride (FeCl₂, FeCl₃), iron chloride hydrate (FeCl₃.nH₂O), iron acetylacetonate (Fe(C₅H₇O₂)₃), iron nitrate hydrate (Fe(NO₃)₃.9H₂O), iron phthalocyanine (C₃₂H₁₆FeN₈), and iron oxalate hydrate (Fe(C₂O₄).nH₂O, and Fe₂(C₂O₄)₃.6H₂O) may be used as the sol-gel precursor of iron oxide.

When the metal oxide is chromium oxide, at least one selected from a group consisting of chromium chloride (CrCl₂, CrCl₃), chromium chloride hydrate (CrCl₃.nH₂O), chromium carbide (Cr₃C₂), chromium acetylacetonate (Cr(C₅H₇O2)₃), at least one selected from the group consisting of chromium nitrate hydrate (Cr(NO₃)₃.nH₂O), chromium hydroxide (CH₃CO₂)₇Cr₃(OH)₂, and chromium acetate hydrate ([(CH₃CO₂)₂CrH₂O]₂) may be used as the chromium oxide sol-gel precursor

When the metal oxide is bismuth oxide, at least one selected from a group consisting of bismuth chloride (BiCl₃), bismuth nitrate hydrate (Bi(NO₃)₃.nH₂O), bismuth acetic acid ((CH₃CO₂)₃Bi), and bismuth carbonate ((BiO)₂CO₃) may be used as the bismuth oxide sol-gel precursor.

When the metal oxide nanoparticles are contained in the mixed solution for the electron injection layer, the average particle diameter of the metal oxide nanoparticles may be 10 nm to 100 nm.

The solvent may be a polar solvent or a non-polar solvent. For example, examples of the polar solvent include alcohols and ketones, and examples of the nonpolar solvent include aromatic hydrocarbons, alicyclic hydrocarbons, or aliphatic hydrocarbon-based organic solvents. As an example, the solvent is may be one or more selected from ethanol, dimethylformamide, ethanol, methanol, propanol, butanol, isopropanol. Methyl ethyl ketone, propylene glycol (mono) methyl ether (PGM), isopropyl cellulose (IPC), ethylene carbonate (EC), methyl cellosolve (MC), ethyl cellosolve, 2-methoxy ethanol and ethanol amine, but is not limited thereto.

For example, when forming the electron injection layer 60 made of ZnO, the mixture for the electron injection layer contains zinc acetate dehydrate as a precursor of ZnO and may include a combination of 2-methoxy ethanol and ethanol amine as a solvent, but is not limited thereto.

The heat treatment conditions can vary depending on the type and content of the selected solvent, but it is generally preferably performed within the range of 100° C. to 350° C. and 0.1 hour to 1 hour. When the heat treatment temperature and time satisfy this range, the solvent removal is effective and the device may not be deformed.

When the electron injection layer 60 is formed using a deposition method, deposition can be performed by various known methods such as electron beam deposition, thermal evaporation, sputter deposition, atomic layer deposition, and chemical vapor deposition. The deposition conditions vary depending on the target compound, the structure of the target layer, and thermal properties, but for example, it is preferred that the deposition temperature range is of 25 to 1500° C., specifically 100 to 500° C., the vacuum degree has range of 10⁻¹⁰ to 10⁻³ torr, and the deposition rate may be within the range of 0.01 to 100 Å/sec.

The electron injection layer 60 may have a thickness of 5 nm to 100 nm. For example, the thickness of the electron injection layer is a range in which the lower value of the number is the lower limit value and the higher value is the upper limit value selected from the group of 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 51 nm, 52 nm, 53 nm, 54 nm, 55 nm, 56 nm, 57 nm, 58 nm, 59 nm, 60 nm, 61 nm, 62 nm, 63 nm, 64 nm, 65 nm, 66 nm, 67 nm, 68 nm, 69 nm, 70 nm, 71 nm, 72 nm, 73 nm, 74 nm, 75 nm, 76 nm, 77 nm, 78 nm, 79 nm, 80 nm, 81 nm, 82 nm, 83 nm, 84 nm, 85 nm, 86 nm, 87 nm, 88 nm, 89 nm, 90 nm, 91 nm, 92 nm, 93 nm, 94 nm, 95 nm, 96 nm, 97 nm, 98 nm, 99 nm, 100 nm. In addition, preferably, the thickness of the electron injection layer may be 15 nm to 60 nm.

The above hole injection layer 30, the vacuum transport layer, the electron injection layer 60, or the electron transport layer 50 may normally be applied to substances used in conventional organic light-emitting diodes.

The above hole injection layer 30, hole transport layer, electron injection layer 60, or electron transport layer 50 may be formed by performing in a randomly selected manner among the various methods including vacuum deposition method, spin coating method, spray method, deep coating method, bar coating method, nozzle printing method, slot-die coating method, gravure printing method, cast method and Langmuir-Blodgett (LB) method. The conditions and coating conditions for thin film formation may vary depending on the target compound, and the structure and thermal properties of the intended layer.

The substrate 10 serves as a support for the light-emitting device, and may be a transparent material. In addition, the substrate 10 may be a flexible material or a hard material, and preferably may be a flexible material.

The material of the substrate 10 is one of glass, sapphire, quartz, silicon, polyethylene terephthalate (PET), polystyrene (PS), polyimide (polyimide, PI), polyvinyl chloride (PVC), polyvinylpyrrolidone (PVP), polyethylene (PE), etc., but is not limited thereto.

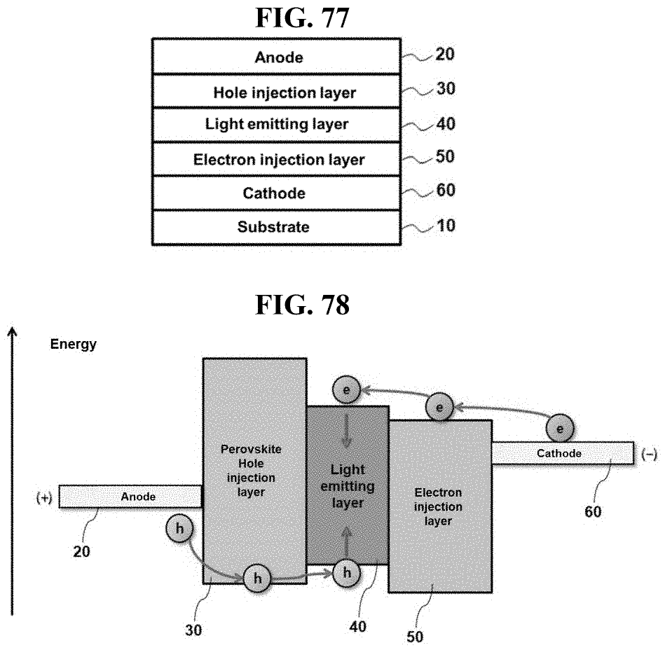

The substrate 10 may be located under the anode 20 or may be located above the cathode 70. In other words, the anode 20 may be formed before the cathode 70 on the substrate, or the cathode 70 may be formed before the anode 20. Accordingly, the light-emitting device may have both the normal structure of FIG. 76 and the inverse structure of FIG. 77.

The emission layer 40 is formed between the hole injection layer 30 and the electron injection layer 60, and the holes (h) injected from the anode 20 and the electrons (e) injected from the cathode 70 combines to form excitons, and the excitons transition to a ground state and light is emitted to cause light emission.

A stacked hybrid light-emitting diode according to an embodiment includes at least one organic light emission layer and at least one metal halide perovskite light emission layer. Specifically, a first emission layer including a metal halide perovskite emitter and a second emission layer including an organic emitter may be included. Depending on the embodiment, the first emission layer may include a metal halide perovskite emitter, and the second emission layer may include an organic emitter.

An embodiment may include a combination of orange-red and sky-blue emitters or a combination of red, green, and blue emitters. As described above, in the stacked hybrid white light-emitting diode according to an exemplary embodiment, emitters emitting different colors may form white light by emitting at the same time.

Furthermore, an organic light emitter and a metal halide perovskite light emitter that emit light of the same wavelength in a visible light region may be included. In this case, the current efficiency of the stacked hybrid light-emitting diode may be equal to the sum of the current efficiencies of each light-emitting unit.

As an organic light emitter, a fluorescent low-molecular organic material, a phosphorescent low-molecular organic material, a thermally activated delayed fluorescence (TADF) organic material or a polymer may be used, but the present invention is not limited thereto.

The fluorescent organic light emitter may include at least one of the dopants from the group of 4-(dicyanomethylene)-2-t-butyl-6-(1,1,7,7-tetramethyljulolidyl-9-enyl)-4H-pyran (DCJTB), (E)-2-(2-(4-(Dimethylamino)styryl)-6-methyl-4H-pyran-4-ylidene)malononitrile (DCM), and 5,6-bis(4-(9,9-dimethylacridin-10(9H)-yl)phenyl)pyrazine-2,3-dicarbonitrile (Ac-CNP).

Phosphorescent organic light emitters may include at least one of the dopants from the group of Bt₂Ir(acac), tris(1-phenylisoquinoline) iridium(III) (Ir(piq)₃), Bis(2-(3,5-dimethylphenyl)-4-phenylpyridine)(2,2,6,6-tetramethylheptane-3,5-diketonate)iridium(III)(Ir(dmppy-ph)₂tmd), Bis(2-benzo[b]thiophen-2-yl-pyridine)(acetylacetonate)iridium(III)(Ir(btp)₂(acac)), Bis[1-(9,9-dimethyl-9H-fluoren-2-yl)-isoquinoline](acetylacetonate)iridium(III)(Ir(fliq)₂(acac)), Bis[2-(9,9-dimethyl-9H-fluoren-2-yl)quinoline](acetylacetonate)iridium(III)(Ir(flq)₂(acac)), Bis[2-(4-n-hexylphenyl)quinoline](acetylacetonate)iridium(III)(Hex-Ir(phq)₂(acac)), Tris[2-(4-n-hexylphenyl)quinoline)]iridium(III)(Hex-Ir(phq)₃, and Bis(2-phenylquinoline)(2-(3-methylphenyl)pyridinate)iridium(III)(Ir(phq)₂tpy).

Thermally activated delayed fluorescence (TADF) organic light emitter may include at least one of the dopants from the group of Dibenzo{[f,f′]-4,4′,7,7′-tetraphenyl}diindeno [1,2,3-cd:1′,2′,3′-lm]perylene (DBP), 2,3,5,6-Tetrakis[3,6-bis(1,1-dimethylethyl)-9H-carbazol-9-yl]benzonitrile (4CzBN), 7,10-Bis(4-(diphenylamino)phenyl)-2,3-dicyanopyrazino phenanthrene (TPA-DCPP), 2,8-Di-tert-butyl-5,11-bis(4-tert-butylphenyl)-6,12-diphenyltetracene (TBRb), 2-(9-phenyl-9H-carbazol-3-yl)-10, and 10-dioxide-9H-thioxanthen-9-one (TXO-PhCz).

Since the metal halide perovskite is the same as described above, a detailed description will be omitted.

The hybrid light-emitting diode according to an embodiment of the present invention includes a metal halide perovskite light emitter having a half-width (FWHM) of about 20 nm or less together with an organic light emitter, so that the manufacturing cost can be significantly reduced, and white light of high color purity can be realized by performing solution process up to at least the second light-emitting unit.

<Light-Emitting Device Including a Metal Halide Perovskite Charge Transport Layer>

The light-emitting device according to an embodiment of the present invention may be characterized in which a metal halide perovskite charge transport layer is included.

In the present specification, the “charge transport layer” refers to an hole injection layer, a hole transport layer, an electron transport layer, or an electron injection layer adjacent to the light emission layer that moves holes or electrons from the anode or the cathode to the light emission layer. In general, the charge transport layer refers to a hole injection layer or an electron injection layer adjacent to the emission layer, but in the case of a light-emitting device including a hole transport layer between the emission layer and the hole injection layer, and an electron transport layer between the emission layer and the electron injection layer, a hole transport layer or an electron transport layer adjacent to the light emission layer is also included in the charge transport layer.

Referring to FIG. 76, a light-emitting device including a metal halide perovskite charge transport layer according to the present invention includes an anode 20 and a cathode 60, and a light emission layer 40 located between the two electrodes, and the hole injection layer 30 may be provided between the anode 20 and the light emission layer 40 to facilitate injection of holes. In addition, an electron injection layer 50 for facilitating injection of electrons may be provided between the light emission layer 40 and the cathode 60.

In addition, the light-emitting device according to the present invention may further include an hole transport layer 35 for transporting holes between the hole injection layer 30 and the light emission layer 40.

In addition, the light-emitting device according to the present invention may further include an electron transport layer 45 for transporting electrons between the hole injection layer 30 and the light emission layer 40.

In addition, a hole blocking layer (not shown) may be located between the emission layer 40 and the electron transport layer 45. In addition, an electron blocking layer (not shown) may be located between the light emission layer 40 and the hole transport layer 35. However, the present invention is not limited thereto, and the electron transport layer 45 may function as a hole blocking layer, or the hole transport layer 35 may function as an electron blocking layer.

In addition, a hole transport layer may be further formed between the light emission layer and the hole injection layer.

The hole injection layer 30, the emission layer 40, the hole transport layer, the electron injection layer 60, or the electron transport layer 50 may be materials used in conventional organic light-emitting diodes.

On the other hand, in the light-emitting device, a feature of the present invention is that at least one selected from the group consisting of the hole injection layer 30, the hole transport layer 35, the electron transport layer 45, and the electron injection layer 50 may be a thin film of metal halide perovskite.

Specifically, the present invention provides anode, cathode, and a light emission layer located between the anode and the cathode, at least one first charge transport layer of a hole injection layer and a hole transport layer located between the anode and the light emission layer, and at least one second charge transport layer of an electron injection layer and an electron transport layer located between the light emission layer and the cathode. The first charge transport layer or the second charge transport layer adjacent to the light emission layer is a metal halide perovskite thin film.

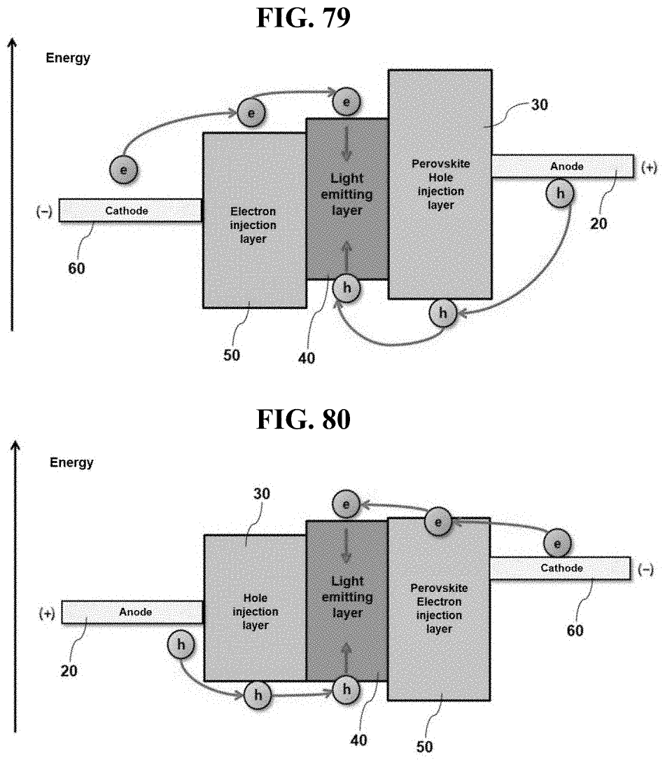

In the light-emitting device according to an embodiment of the present invention, the first charge transport layer (e.g., the hole injection layer 30) may be a metal halide perovskite thin film (see FIGS. 78 and 79).

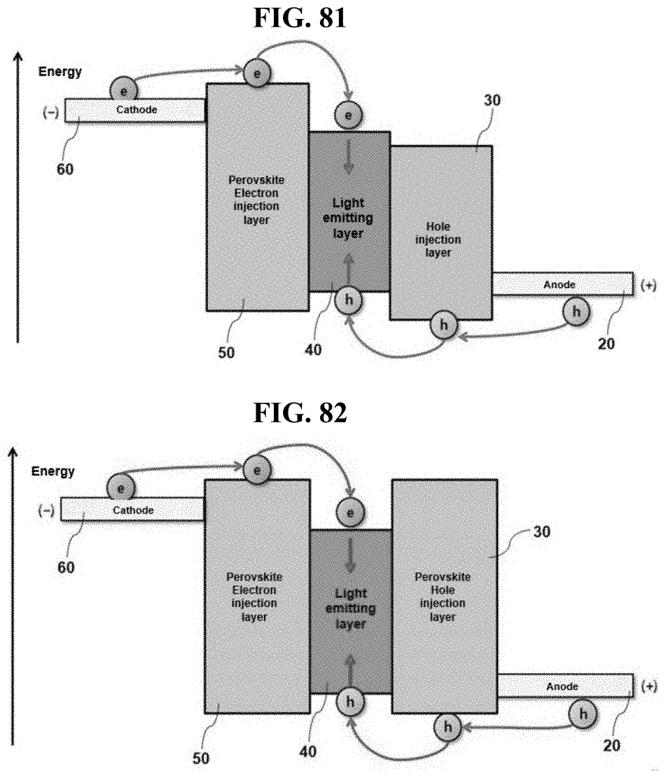

In the light-emitting device according to an embodiment of the present invention, the second charge transport layer (e.g., the electron injection layer 50) may be a metal halide perovskite thin film (see FIGS. 80 and 81).

In addition, the present invention provides an anode, a cathode, a light emission layer located between the anode and the cathode, a first charge transport layer of a hole injection layer and a hole transport layer located between the anode and the light emission layer, and second charge transport layer of an electron injection layer and an electron transport layer located between the light emission layer and the cathode, wherein the first charge transport layer and the second charge transport layer adjacent to the light emission layer are metal halide perovskite thin film.

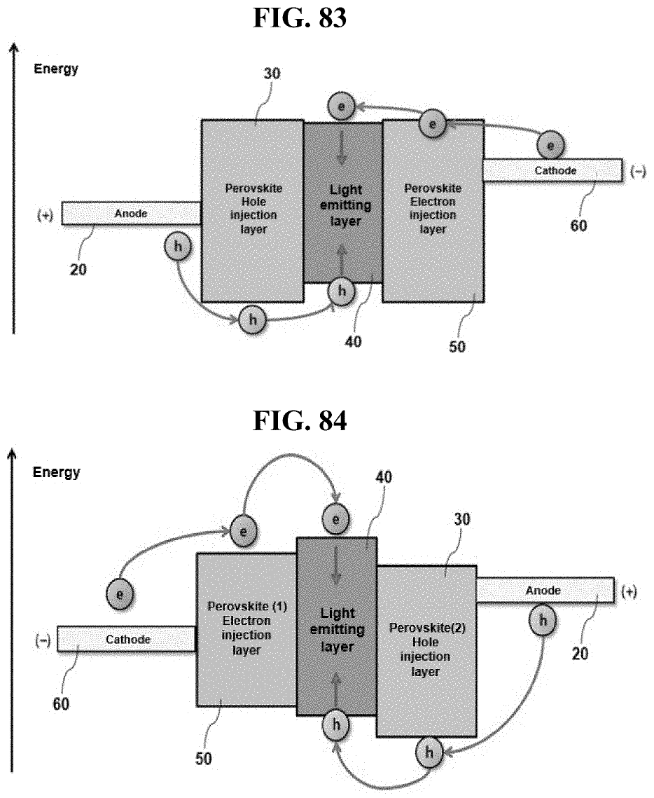

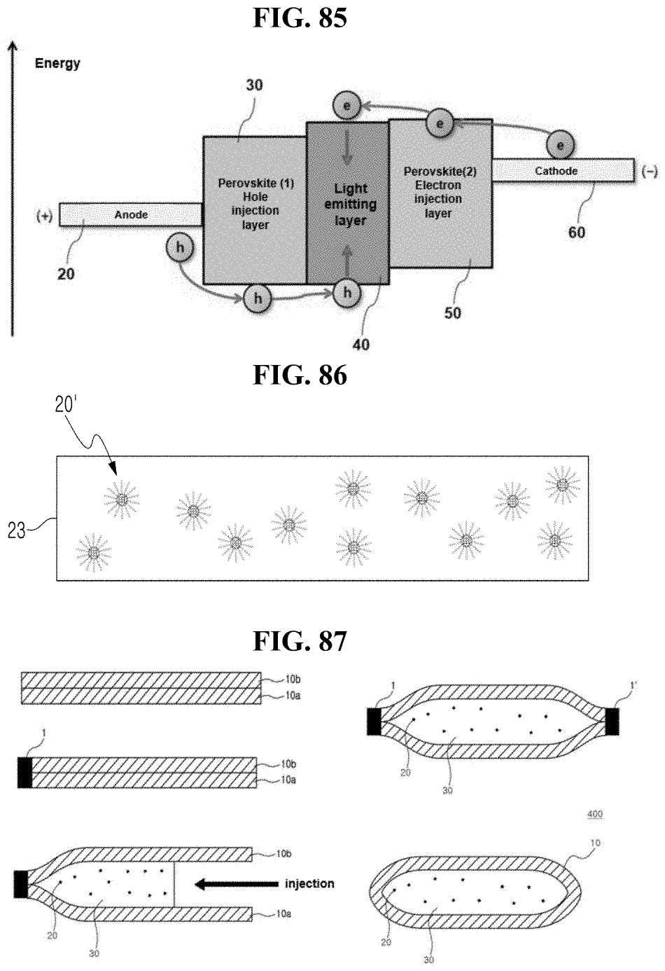

In the light-emitting device according to an embodiment of the present invention, a first charge transport layer (e.g., a hole injection layer 30) and a second charge transport layer (eg, an electron injection layer 50) may be metal halide perovskites thin film. The metal halide perovskite thin films constituting the first and second charge transport layers may be the same (see FIGS. 82 and 83) or different (see FIGS. 84 and 85).

The metal halide perovskite thin film used in the metal halide perovskite light-emitting device has been used only as a light emission layer. However, since the metal halide perovskite has an energy level similar to that of an organic semiconductor material used in a light-emitting device and has higher charge mobility than an organic semiconductor, it is very promising not only as a light emission layer but also a charge transport layer.

Since the metal halide perovskite used is the same as described above, a detailed description will be omitted.

<Metal Halide Perovskite Wavelength Converting Body>

According to another embodiment of the present invention, the metal halide perovskite described above may be used as a wavelength converting body.

A light-emitting diode (LED) is a semiconductor device that converts current into light, and is mainly used as a light source of a display device. The light-emitting diode has very small size compared to conventional light sources, has low power consumption, has a long lifetime, and exhibits very excellent characteristics, such as a fast reaction speed. In addition, since it does not emit harmful electromagnetic waves such as ultraviolet lights and does not use mercury and other discharge gases, it is environmentally friendly. The light-emitting device is mainly formed through a combination of a light-emitting diode using wavelength converting particles such as phosphors.

This wavelength converting body is different from the fluorescence of general semiconductor materials in that it can be used in a light-emitting device in a form combined with light source. Wavelength converting particles play a role of converting the wavelength of a light-emitting diode as light source into a wavelength of low energy. Therefore, it is possible to perform a function of inducing light to emit white light or simultaneously emit light at multiple wavelengths of the monochromatic light-emitting diode by using the wavelength converting particles. In addition, preferably, wavelength converting particles having excellent color purity characteristics can be used to effectively improve the low color gamut of an existing light-emitting device that is difficult to realize vivid colors.

The wavelength converting layer 100 is also referred to as a color conversion layer or a color converting film, and preferably has a flat shape to prevent scattering, and preferably has a surface roughness of 50 nm or less. More preferably, the surface roughness may be 20 nm or less.

The wavelength converting body emits wavelength-converted light when light (incident light) incident from the outside reaches the above-described metal halide perovskite wavelength converting particles. Therefore, the wavelength converting body according to the present invention functions to convert the wavelength of light by means of a metal halide perovskite. Hereinafter, among the incident light, light having a wavelength shorter than the emission wavelength of the aforementioned metal halide perovskite wavelength converting particles is referred to as excitation light. In addition, a light source emitting the above-described excitation light is referred to as an excitation light source.

The wavelength converting body according to an embodiment of the present invention is a wavelength converting body that converts the wavelength of light generated from an excitation light source into a specific wavelength, and it is characterized in that it contains a dispersion medium that disperses the metal halide perovskite.

In the hybrid wavelength converting body according to an embodiment of the present invention, the dispersion medium may be in a liquid state, and the metal halide perovskite may be uniformly dispersed, and if the material is irradiated with ultraviolet rays, it is hardened and thus can serve to fix the metal halide perovskite.

The dispersion medium may be a photopolymerizable polymer formed by a photopolymerization reaction of a photopolymerizable monomer.

Also preferably, the polymer may play a role of protecting the metal halide perovskite from external chemical species such as oxygen or moisture by surrounding the metal halide perovskite. In addition, the polymer may play a role in preventing migration of halide ions that may occur during the electrical operation of the metal halide perovskite.

The photopolymerizable monomer is not particularly limited as long as it contains at least one of a carbon-carbon double bond and a triple bond and can be polymerized by light. In addition, preferably, the photopolymerizable monomer may be a monofunctional or polyfunctional ester of acrylic acid having at least one ethylenic double bond.

The photopolymerizable monomer including at least one of a carbon-carbon double bond and a triple bond is at least one selected from a group of a diacrylate compound, a triacrylate compound, a tetraacrylate compound, and a pentaacrylate. It may be selected from (pentaacrylate) compounds, and hexaacrylate compounds, or combinations thereof.

Specific example of the photopolymerizable monomer including at least one of the carbon-carbon double bond and triple bond may include ethyleneglycol diacrylate, triethyleneglycol diacrylate, diethyleneglycol diacrylate, 1,4-butanediol diacrylate, 1,6-hexanediol diacrylate, neopentylglycol diacrylate neopentylglycol diacrylate, pentaerythritol diacrylate, pentaerythritol triacrylate, pentaerythritol tetraacrylate, dipentaerythritol diacrylate, dipentaerythritol diacrylate, dipentaerythritol pentaacrylate, dipentaerythritol hexaacrylate, bisphenol A epoxyacrylate, bisphenol A diacrylate, trimethylolpropane triacrylate, novolac epoxy acrylate, ethyleneglycolmonomethyletheracrylate, trisacryllooxyethyl phosphate, diethyleneglycol diacrylate, triethylene glycol, triethyleneglycol diacrylate or propyleneglycol diacrylate, but is not limited thereto.

The cured product of the photopolymerizable monomer may be a cured product of a photopolymerizable monomer including at least one of a carbon-carbon double bond and a triple bond, and a thiol compound having at least two thiol groups.

In addition, the photopolymerizable monomer may be a photoresist material. The photoresist material may be a silicone or epoxy material.

The photoresist material may be a commercial photoresist. The commercial photoresist materials can be AZ Electronics Materials' AZ 5214E PR, AZ 9260 PR, AZ AD Promoter-K (HMDS), AZ nLOF 2000 Series, AZ LOR-28 PR, AZ 10xT PR, AZ 5206-E, AZ GXR-601, AZ 04629; SU-8 from MICROCHEM, 950 PMMA, 495 PMMA; S1800 from micropossit; DNR-L300, DSAM, DPR, DNR-H200, DPR-G from Dongjin Semichem, or CTPR-502 from Kotem, but is not limited thereto.

A photoinitiator may be used to cure the photopolymerizable monomer, and a photoinitiator may be included in the metal halide perovskite-polymer composite. The kind of the photoinitiator is not particularly limited and may be appropriately selected. For example, usable photoinitiators include triazine-based compounds, acetophenone-based compounds, benzophenone-based compounds, thioxanthone-based compounds, benzoin-based compounds, oxime-based compounds, carbazole-based compounds, diketone-based compounds, sulfonium borate-based compounds, diazo-based compounds, nonimidazolium-based compounds, or a combination thereof, but is not limited thereto.

Examples of the triazine-based compound are 2,4,6-trichloro-s-triazine, 2-phenyl-4,6-bis (trichloromethyl)-s-triazine, 2-(3′,4′-dimethoxystyryl)-4,6-bis(trichloromethyl)-s-triazine, 2-(4′-methoxynaphtyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloromethyl)-s-triazine (2-biphenyl-4,6,-bis(trichloromethyl), bis(trichloromethyl)-6-styryl-s-triazine, 2-(naphtho-1-yl)-4,6-bis(trichloromethyl)-s-triazine (2-nafto-1-yl)-4,6-bis(trichloromethyl), 2-(4-methoxynaphtho-1-yl)-4,6-bis(trichloromethyl)-s-triazine (2-(4-methoxynafto-1-yl)-4,6-bis(trichloromethyl)-s-triazine, 2,4-trichloromethyl(piperonyl)-6-triazine), or 2,4-(trichloromethyl(4′-methoxystyryl)-6-triazine, but not limited to.

Examples of the acetophenone-based compound are 2,2′-diethoxy acetophenone, 2,2′-dibutoxy acetophenone, 2-2-hydroxy-2-methyl propiophenone, pt-butyl trichloro acetophenone, pt-butyl dichloro acetophenone, 4-chloro acetophenone, 2,2′-dichloro-4-phenoxy acetophenone, 2-methyl-1-(4-(methylthio)phenyl)-2-morpholino propan-1-one, 2-benzyl-2-dimethylamino-1-(4-morpholino phenyl)-butan-1-one, or the like, but is not limited thereto.

Examples of the benzophenone-based compound include benzophenone, benzoyl benzoate, methyl 2-benzoylbenzoate, 4-phenyl benzophenone, hydroxybenzophenone, benzophenone acrylate, 4,4′-bis (dimethylamino) benzophenone, 4,4′-dichlorobenzophenone, 3,3′-dimethyl-2-methoxy benzophenone, or the like, but is not limited thereto.

Examples of the thioxanthone-based compound include thioxanthone, 2-methyl thioxantone, isopropyl thioxantone, and 2,4-diethyl thioxantone. Santon (2,4-diethyl thioxantone), 2,4-diiospropyl thioxantone, 2-chloro thioxantone, or the like, but is not limited thereto.

Examples of the benzoin-based compound include benzoine, benzoine methyl ether, benzoine ethyl ether, benzoine isopropyl ether, benzoine isobutyl ether, benzyl dimethyl ketal, or the like, but is not limited thereto.

Examples of the oxime compound are 2-(o-benzoyloxime)-1-[4-(phenylthio)phenyl]-1,2-octanedione or 1-(o-acetyloxime)-1-[9-ethyl-6-(2-methylbenzoyl)-9H-carbazol-3-yl]ethane, but is not limited thereto. The metal halide perovskite-polymer composite obtained by curing the photopolymerizable monomer is formed in a form in which a polymer surrounds the surface of the metal halide perovskite described above.

The metal halide perovskite-polymer composite may be preferably attached on a substrate or may be an independent film.

In the present specification, the “metal halide perovskite-polymer composite film” includes all films made of the metal halide perovskite-polymer composite.

FIG. 86 is a schematic diagram showing a metal halide perovskite-polymer composite film according to another embodiment of the present invention.

In addition, when the metal halide perovskite-polymer composite is manufactured in the form of a film attached to a specific substrate, the metal halide perovskite-polymer composite film may further include a polymeric binder. In this case, a plurality of metal halide perovskites are dispersed in a polymer composed of a cured product of a photopolymerizable monomer including a carbon-carbon unsaturated bond and a polymeric binder. The polymeric binder may serve to improve adhesion between the substrate and the metal halide perovskite-polymer composite.

The substrate 10 serves as a support for a light-emitting device, and may be a transparent material. In addition, the substrate 10 may be a flexible material or a hard material, and preferably may be a flexible material.

The material of the substrate 10 is glass, sapphire, quartz, silicon, polyethylene terephthalate (PET), polystyrene (PS), polyimide (polyimide, PI), polyvinyl chloride (PVC), polyvinylpyrrolidone (PVP), polyethylene (PE), or the like, but is not limited thereto.

The polymer binder may be an acrylic polymer binder, a cardo polymer binder, or a polymer of a combination thereof, but is not limited thereto.

The acrylic polymer binder may be a copolymer of a first unsaturated monomer containing a carboxyl group and a second unsaturated monomer copolymerizable therewith. The first unsaturated monomer may be a carboxylic acid vinyl ester compound such as acrylic acid, maleic acid, methacrylic acid, vinyl acetate, itaconic acid, 3-butenoic acid, fumaric acid, vinyl benzoate, or a combination thereof, but is not limited thereto.

The second unsaturated monomer is an alkenyl aromatic compound, an unsaturated carboxylic acid ester compound, an unsaturated carboxylic acid amino alkyl ester compound, an unsaturated carboxylic acid glycidyl ester compound, a vinyl cyanide compound, a hydroxy alkyl acrylate, or a combination thereof, but is not limited thereto.

Also preferably, the second unsaturated monomer is styrene, α-methylstyrene, vinyltoluene, vinylbenzylmethylether, methyl acrylate, ethyl acrylate, butyl acrylate, benzyl acrylate, cyclohexyl acrylate, phenyl acrylate, 2-aminoethylacrylate, 2-dimethylaminoethylacrylate, N-phenylmaleimide, N-benzylmaleimide, N-alkylmaleimide, 2-dimethylaminoethylmethacrylate, acrylonitrile, unsaturated amide compounds such as glycidyl acrylate, acrylamide, 2-hydroxy ethyl acrylate and 2-hydroxy butyl acrylate, 2-hydroxyethyl acrylate, 2-hydroxy butyl acrylate, or a combination thereof, but is not limited thereto.

The acrylic polymer binder is a methacrylic acid/benzyl methacrylate copolymer, methacrylic acid/benzyl methacrylate/styrene copolymer, methacrylic acid/benzyl methacrylate/2-hydroxyethyl methacrylate copolymer It may be a combination, methacrylic acid/benzyl methacrylate/styrene/2-hydroxyethyl methacrylate copolymer, or a combination thereof, but is not limited thereto.

The weight-average molecular weight of the polymeric binder may be about 1,000 to about 150,000 g/mol. Also, preferably, it may be about 2,000 to about 30,000 g/mol. In the case that the weight average molecular weight of the polymeric binder is about 2,000 to about 30,000 g/mol, the metal halide perovskite-polymer composite film has excellent physical and chemical properties and has an appropriate viscosity, and has excellent adhesion when fabricating metal halide perovskite-polymer composite film.

The metal halide perovskite-polymer composite film may further include a light diffusing agent. The light diffusing agent may be metal oxide particles, metal particles, and combinations thereof, but is not limited thereto. The light diffusing agent may serve to increase the probability of encountering the metal halide perovskite with the incident light of the composition by increasing the refractive index of the composition.

The light diffusing agent may include inorganic oxide particles such as alumina, silica, zirconia, titania and zinc oxide, or metal particles such as gold, silver, copper, and platinum, but is not limited thereto. At this time, a dispersant may be added to increase the dispersibility of the light diffusing agent.

The wavelength converting layer may further include a barrier film. The barrier film may be positioned above and below the wavelength converting layer to prevent penetration of moisture and oxygen. When a barrier film is attached to the wavelength converting layer, the barrier film may serve to protect the wavelength converting layer from external air including moisture and oxygen. In particular, since the metal halide perovskite has poor stability against moisture and oxygen, the stability of the wavelength converting layer including the barrier film can be greatly improved.

It is advantageous to prevent moisture and oxygen penetration by placing the barrier film on both sides above and below the wavelength converting layer. Ultimately, it is desirable to secure stability with just one layer without an additional barrier film by putting the function of such a barrier film on the wavelength converting layer. Such a barrier film may be made of a polymer or ceramic material.

Hereinafter, a method of manufacturing a metal halide perovskite wavelength converting layer according to another embodiment of the present invention will be described.

First, a metal halide perovskite wavelength converting particle is prepared.

Thereafter, the above-described wavelength converting particles are dispersed in a dispersion medium.

Wavelength converting particles are dispersed in the dispersion medium described above. The dispersion medium may be in a liquid state. When the dispersion medium is in a liquid state, when the dispersion medium and the wavelength converting particles dispersed in the dispersion medium are sealed by a sealing member to be described later, the shape thereof is not restricted, and thus it can be applied to various types of devices. The dispersion medium may be, for example, an epoxy resin or silicone. Since the wavelength converting particles must receive excitation light and emit wavelength converting light, the dispersion medium is preferably a material that is not discolored or deteriorated by excitation light or the like.

After that, the metal halide perovskite wavelength converting particles and the dispersion medium are sealed with a sealing member.

FIG. 87 is a cross-sectional view showing a method of sealing a wavelength converting body according to an embodiment of the present invention.

Referring to FIG. 87(a), a first sealing member 10a and a second sealing member 10b are stacked.

Sealing members may use polymers or silicone that are not corroded by dispersion medium 30 in which metal halide perovskite wavelength converting particles 20 are dispersed. In particular, since the polymer resin can be heated and gradually recovered, it can be used to form a pack-type wavelength converting body with dispersion medium 30 dispersed wavelength converting body by using a heat adhesion process.

Referring to FIG. 87(b), the first sealing member 10a and the second sealing member 10b may be heated and bonded using a heat-adhesion process to prevent the metal halide perovskite wavelength converting particles 20 and dispersion medium 30 from leaking from the sealing member 10a, 10b. However, if the metal halide perovskite wavelength converting particles 20 and dispersion medium 30 do not leak, it is possible to use other adhesive processes besides the thermal adhesion process.

Referring to FIG. 87(c), the dispersion medium 30 in which the metal halide perovskite wavelength converting particles 20 are dispersed is injected from the other side to which the first sealing member 10a and the second sealing member 10b are not attached.

Referring to FIG. 87(d), the other side 1 of the first sealing member 10a and the second sealing member 10b is bonded using a thermal adhesion process to seal the dispersion medium 30 dispersed by metal halide perovskite wavelength change particles 20.

Referring to FIG. 87(e), it can be seen that the metal halide perovskite wavelength converting body 400 is formed, in which a dispersion medium 30 that has dispersed wavelength converting material 20 is sealed with a sealing member 10. The metal halide perovskite wavelength converting body 400 has the advantage of being able to be applied to light-emitting devices without an additional ligand purification process to remove unreacted ligands, because wavelength-converting nanoparticles 20 containing metal halide perovskite nanocrystals are sealed after they are dispersed in a dispersion medium 30. Thus, it can prevent oxidation of wavelength converting particles during ligand purification process, showing high color purity and light efficiency when applied to light-emitting devices. In addition, the process can be simplified.

FIG. 88 is a cross-sectional view of a light-emitting device including a wavelength converting layer according to an embodiment of the present invention.

Referring to FIG. 88, the light-emitting device according to an embodiment of present invention includes a base structure 100, excitation light source 200 that emits a certain wavelength of light positioned on the base structure 100, and a wavelength converting layer 400B having wavelength converting particles wavelength converting particle located in the optical path of the excitation light source 200 described above.

The base structure 100 described above may be a package frame or a base substrate. When the base structure 100 is a package frame, the package frame may include the base substrate. The base substrate may be a submount substrate or a wafer for light-emitting diodes. The wafer for light-emitting diodes indicates a state before being separated into light-emitting diode chips, and indicates a state in which a light-emitting diode device is formed on the wafer. The base substrate may be a silicon substrate, a metal substrate, a ceramic substrate, or a resin substrate.

The base structure 100 described above may be a package lead frame or a package pre-mold frame. The base structure 100 may include a bonding pad (not shown). Bonding pads may contain Au, Ag, Cr, Ni, Cu, Zn, Ti, Pd, or the like. External connection terminals (not shown) connected to bonding pads may be located on the outer side of the base structure 100. The bonding pads and the external connection terminals may be those provided in the package lead frame.

The excitation light source 200 is located on the base structure 100 described above. It is preferable that the above-described excitation light source 200 emits light having a wavelength shorter than that of the wavelength converting particles of the wavelength converting layer 400B. The above-described excitation light source 200 may be any one of a light-emitting diode and a laser diode. In addition, when the base structure 100 is a wafer for wafer for light-emitting diode, the step of arranging the excitation light source may be omitted. For example, the excitation light source 200 may use a blue LED, and as the blue LED, a gallium nitride-based LED emitting blue light of 420 nm to 480 nm may be used.

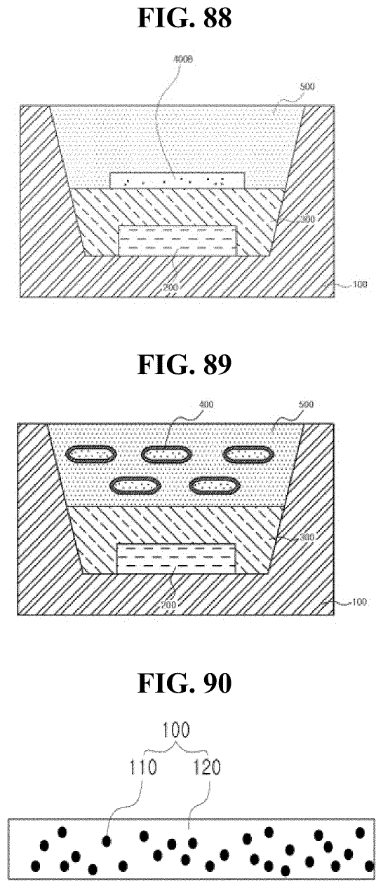

As shown in FIG. 89, the first encapsulation part 300 may be formed by filling the encapsulating material for covering the excitation light source 200. The first encapsulation part 300 may not only serve to encapsulate the excitation light source 200, but may also serve as a protective film. In addition, when the above-described wavelength converting layer 400B is positioned on the first encapsulation part 300, a second encapsulation part 500 may be further formed to protect and fix the wavelength converting layer 400B. The sealing material may include at least one of epoxy, silicone, acrylic polymer, glass, carbonate polymer, or mixtures thereof.

The first encapsulation part 300 can be formed using various methods such as a compression molding method, a transfer molding method, a dotting method, a blade coating method, a screen coating method, dip coating, spin coating, spray, or inkjet printing. However, the first encapsulation part 300 may be omitted.

In the embodiment of this invention, the above light-emitting devices are designed specific to the unit cell, but if the base structure is a submount substrate or wafer for wafer for light-emitting diode, the above submount substrate or wafer for light-emitting diode can be cut and processed into each unit cell.

In addition, preferably, the wavelength converting layer may have stretchable properties.

The stretchable wavelength converting layer according to the present invention is characterized in that it includes the metal halide perovskite described above.

FIG. 90 is a cross-sectional view schematically illustrating a stretchable wavelength converting layer according to an embodiment of the present invention.

Referring to FIG. 90, the stretchable wavelength converting layer 100 according to this invention may contain the color converting particles 110 and t stretchable polymers 120 in which the color converting particles 110 are dispersed.

The color converting particles 110 of this invention may be dispersed within the stretchable polymer 120. The wavelength converting layer 100 may contain a stretchable polymer 120 to be flexible.

The wavelength converting layer 100 is also called the color converting layer or color converting film, and it is desirable to have a flat shape to prevent scattering, and to have a surface roughness of 50 nm or less. More preferably, the above surface roughness may not be more than 20 nm.

The stretchable polymer 120 is a homo copolymer, an alternating copolymer, a random copolymer, a block copolymer, a multiblock copolymer, or a graft copolymer including at least one selected from the group consisting of polydimethylsiloxane (PDMS), polyurethane (PU), styrene butadiene styrene (SBS), styrene ethylene butylene styrene (SEBS), ecoflex, hydrogel, organic Gel (organogel), PEO (Polyethylene oxide), PS (Polystyrene), PCL (Polycaprolactone), PAN (Polyacrylonitrile), PMMA (Poly (methyl methacrylate)), polyimide (Polyimide), PVDF (Poly (vinylidene fluoride)), PVK (Poly(n-vinylcarbazole)), PVC (Polyvinylchloride), polyethylene terephthalate, polyethylene naphthalene, polycarbonate, polyacrylate, polyether sulfone, polypropylene, polymethylphenylsiloxane, polydiphenylsiloxane, polysiloxane, and ORMOCER, or derivatives and combinations thereof.

In addition, derivatives of the polydimethylsiloxane (PDMS), polyurethane (PU), styrene butadiene styrene (SBS), styrene ethylene butylene styrene (SEBS), ecoflex, hydrogel, organic gel, PEO (Polyethylene oxide), PS (Polystyrene), PCL (Polycaprolactone), PAN (Polyacrylonitrile), PMMA (Poly(methyl methacrylate)), Polyimide, PVDF (Poly(vinylidene fluoride)), PVK (Poly(n-vinylcarbazole)), PVC (Polyvinylchloride), polyethylene terephthalate, polyethylene naphthalene, polycarbonate, polyacrylate, polyether sulfone, polypropylene, polymethylphenylsiloxane, polydiphenylsiloxane, polysiloxane, or ORMOCER may contain hydrogen bonds. As an example, the hydrogen bond may be F—H . . . F, O—H . . . N, O—H . . . O, N—H . . . N, N—H . . . O, or OH—H . . . OH₃⁺.

The stretchable polymer 120 may be capable of self-healing by having a self-repairing ability from scratches and damage.

The stretchability of the stretchable polymer 120 may be 5% or more along the tensile direction. Preferably it may be 10% or more, more preferably 20% or more, more preferably 30% or more, more preferably 50% or more, more preferably 100% or more. Accordingly, the stretchable wavelength converting layer 100 may be stretched by 5% or more without breaking by the applied strain, and it is preferable that the stretchable wavelength converting layer 100 is usually stretched by 20% or more.

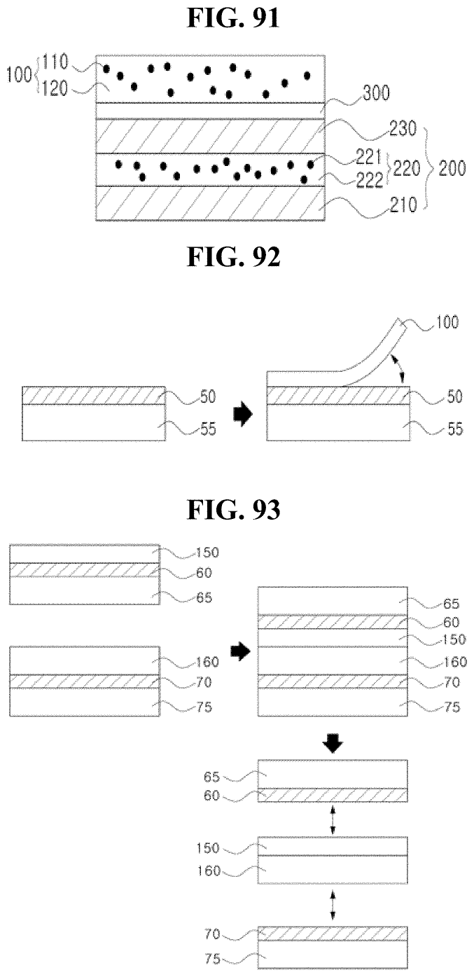

FIG. 91 is a cross-sectional view of a stretchable light-emitting device according to an embodiment of the present invention.

Referring to FIG. 91, the stretchable light-emitting device includes a stretchable wavelength converting layer 100, a stretchable light source 200, and a bonding layer 300.

The wavelength converting layer 100 includes color converting particles 110 for wavelength conversion of excitation light and a stretchable polymer 120 in which the color converting particles 110 are dispersed. In addition, a bonding layer 300 is formed between the wavelength converting layer 100 and the stretchable light source 200. The bonding layer 300 may be any material that maintains bonding even when the wavelength converting layer 100 and the light source 200 are elongated, and minimizes absorption of light by the light source.

The configuration and material of the wavelength converting layer are the same as those described in FIG. 90.

In addition, the stretchable light source 200 includes light-emitting particles 221 and a dispersion polymer 222 in which the light-emitting particles 221 are dispersed. It is preferable that the dispersion polymer 222 also has a stretchability.

The light emitted from the stretchable light source 200 can reach the stretchable wavelength converting layer 100. Light (hereinafter referred to as excitation light) that reaches the stretchable wavelength converting layer 100 may be converted to have the wavelength range of the light and emit light (hereinafter referred to as wavelength conversion light) that has a different wavelength range than the incident wavelength range.

Stretchable light source 200 may be inorganic light-emitting diode (LED), organic light-emitting diode (OLED), perovskite light-emitting diode (PeLED), light-emitting electrochemical cell (LEEC), alternative-current electroluminescence (ACEL), quantum dot light-emitting diodes (QDLEDs), light-emitting capacitors (LEC), or light-emitting transistors (LET). For example, the stretchable light source 200 may be a stretchable perovskite light-emitting diode (PeLED), and may be a QDLED. In particular, QDLED is provided in a form in which quantum dots are dispersed in a dispersion polymer 222.

When the stretchable light source 200 is stretched by 5%, more preferably 10% or more, electroluminescence, external quantum efficiency, and current efficiency of the device do not change or can be reduced to less than 50%. Accordingly, the stretchability of the stretchable light source 200 may be 5% or more along the stretching direction.

The stretchable light source 200 includes a lower electrode 210, a light emission layer 220, and an upper electrode 230. It is preferable that the lower electrode 210 and the upper electrode 230 are stretchable materials and have conductivity. For example, it is preferable that the lower electrode 210 and the upper electrode 230 are ionic hydrogel.

It is desirable for stretchable light sources 200 to emit light with shorter wavelengths than those emitted from color converting particles in the wavelength converting layer. For example, if a stretchable light source 200 is a blue stretchable light source that emits blue light (400-490 nm), the color converting particles within the wavelength converting layer placed on the light source may absorb the above blue light. The color-conversion particles here may be particles that can convert the light to red or green. In other words, the absorbed blue light in the wavelength converting layer can be emitted by the red conversion particles into the red light, and the green light by the green conversion particles can be emitted. In addition, if a stretchable light source is UV (less than 400 nm) stretchable light sources, the stretchable color converting layer including both blue, green or red-converting particles may emit blue, green or red light.

FIG. 92 is a schematic diagram illustrating a method of manufacturing a stretchable wavelength converting layer according to an embodiment of the present invention.

In the present invention, by forming a thin film on the surface of the substrate treated with the self-assembled monolayer, the polymer thin film can be easily peeled off from the substrate due to the low surface energy of the substrate surface. Therefore, the thickness of the polymer thin film, which is the wavelength converting layer, can be precisely controlled.

Referring to FIG. 92, self-assembled monolayer 50 is prepared. The self-assembled monolayer 50 need to have low surface energy. This allows the wavelength converting layer 100 to be easily peeled off from the substrate 55. It is desirable that the above self-assembled monolayer 50 consists of octadecyltrimethoxysilane (OTMS).

When the OTMS-treated substrate is used, the wavelength converting layer 100 can be formed thinly (about 70 μm) by spin coating, and there is an advantage of being able to precisely control the desired thickness through the lamination of the thin film. The thickness of the wavelength converting layer 100 is preferably greater than 70 μm and less than 1 mm, and more preferably 70 μm or more and 140 μm. More preferably, it may be from 80 μm to 130 μm, and even more preferably from 80 μm to 100 μm.

Furthermore, if the above wavelength converting layer 100 thin films are formed on Si or glass substrates that are not surface-treated with OTMS, the film is not easily removed from the substrates due to the high adhesion of the wavelength converting layer thin films, and it is difficult to stack further on a stretchable light source.

In addition, if the above wavelength converting layer 100 thin film is formed on an Si or glass substrate without OTMS treatment, the it is difficult to form a thin wavelength converting layer less than 100 μm because stretchable polymer in which the metal halide perovskite is dispersed is highly viscous.

A color conversion precursor solution in which metal halide perovskite nanocrystals or quantum dots are dispersed is coated on the self-assembled monolayer 50. It is preferable that the color conversion precursor solution contains SEBS (Styrene Ethylene Butylene Styrene). The SEBS is preferable for the purpose of dispersing metal halide perovskite nanocrystals because there is no additional crosslinking process unlike other stretchable polymers.

After spin coating, the wavelength converting layer 100 in a form of a film may be easily peeled off from the substrate 55.

FIG. 93 is another schematic diagram for explaining a method of manufacturing a stretchable wavelength converting layer according to an embodiment of the present invention.

Referring to FIG. 93, the above wavelength converting layer may be formed in plural. For example, the first self-assembled monolayer 60 is formed on the first substrate 65 and the first wavelength converting layer 150 is formed on the first self-assembled monolayer 60. Apart from the first wavelength converting layer 150, a second self-assembled monolayer 70 is formed on the second substrate 75 and a second wavelength converting layer 160 is formed on the second self-assembled monolayer 70.

The first wavelength converting layer 150 may form green light and may have metal halide perovskite nanoparticles. In addition, the second wavelength converting layer 160 forms red light and may have quantum dots. The first wavelength converting layer 150 and the second wavelength converting layer 160 are bonded to each other. Since SEBS is contained in the polymer constituting the wavelength converting layer, each wavelength converting layer is easily bonded without the intervention of other bonding agents. Accordingly, the bonded at least two types of wavelength converting layers are separated from the bonded self-assembled monolayers.

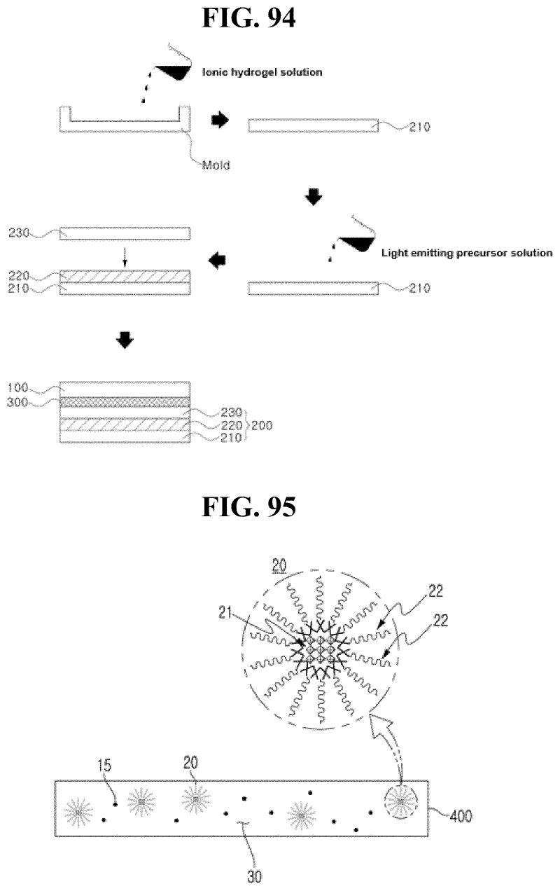

FIG. 94 is a schematic diagram illustrating a method of manufacturing the stretchable light-emitting device of FIG. 91 according to an embodiment of the present invention.

Referring to FIG. 94, an ionic hydrogel solution is prepared. The ionic hydrogel solution is put into a mold having a specific shape, and when cured, it is formed into an ionic hydrogel. The ionic hydrogel functions as a lower electrode or an upper electrode of FIG. 91. The ionic hydrogel has a network structure in which a water-soluble polymer forms a three-dimensional crosslink by a physical or chemical bond. Therefore, it does not dissolve in an aqueous environment and may contain a significant amount of moisture. In addition, since it has ions inside, it has the feature that current can be transported through the movement of ions by an applied electric field.

In addition, when the lower electrode 210 composed of the lower first ionic hydrogel is formed, the light emission layer 220 is formed on the first ionic hydrogel. The light emission layer has light-emitting particles evenly dispersed in the dispersible polymer. The light-emitting particles may include quantum dots or metal halide perovskite particles of FIG. 91. In addition, it is preferable that the dispersible polymer constituting the light emission layer 220 is a material having an elongation force, such as PDMS.

A second ionic hydrogel serving as the upper electrode 230 is formed on the emission layer 220. Through this, the two ionic hydrogels function as positive and negative electrodes with the light emission layer as the center. Through this, the light emission layer may perform a light-emitting operation.

In addition, the wavelength converting layer 100 illustrated in FIG. 91 may be adhered to the second ionic hydrogel. When bonding between the stretchable light source 200 and the wavelength converting layer 100 is not easy, it is preferable to use a material having less absorption of light formed in the light emission layer 220 as the adhesive layer 300 used. The material of the adhesive layer 300 may be variously selected by a person skilled in the art.

In the embodiment of the present invention, PDMS is used as a polymer in order to have the stretchability in the light emission layer 220. Since PDMS is a non-conductor, the light emitting particles of the light emission layer 220 are excited by an electric field of an AC voltage applied between the two layers of ionic hydrogels, and the excited state and the ground state are repeated by the AC voltage. Through this, the light emission operation is performed.

Further, light formed by performing a light emission operation is incident on the wavelength converting layer. If the light source emits blue light and the wavelength converting layer has metal halide perovskite nanocrystals or quantum dots forming red and green light, a light-emitting device having a stretchability forms white light. Through this, a white light source can be obtained even with a very thin thickness, and can be used in various display environments.

<Hybrid Wavelength Converting Layer>

The above-described wavelength converting layer may be a hybrid wavelength converting layer further including a non-perovskite quantum dot without metal halide perovskites (hereafter, “non-perovskite” quantum dot) or a non-perovskite phosphor without metal halide perovskites (hereafter, “non-perovskite” phosphor).

FIG. 95 shows a hybrid wavelength converting body according to an embodiment of the present invention.

Referring to FIG. 95, the hybrid wavelength converting body 400 following the one-run example of this invention includes metal halide perovskite nanocrystal particles 20, non-perovskite quantum dots 15 and dispersion medium 30.

When light incident from the outside (incident light) reaches the metal halide perovskite nanocrystal particles, wavelength-converted light is emitted. Therefore, the hybrid wavelength converting body 400 according to the present invention functions to convert the wavelength of light by means of metal halide perovskite nanocrystal particles and non-perovskite quantum dots.

In this case, among the incident light, light having a wavelength shorter than that of the aforementioned metal halide perovskite nanocrystal particles is referred to as excitation light. In addition, a light source that emits the above-described excitation light is referred to as an excitation light source.

The hybrid wavelength converting body according to the present invention includes both a metal halide perovskite nanocrystal particle 20, which may have a lamellar-like structure in which organic and inorganic planes are alternately stacked, and a non-perovskite quantum dot, 15 as wavelength converting particles.

In addition, the hybrid wavelength converting body according to the present invention may simultaneously include the metal halide perovskite nanocrystal particle 20 and the non-perovskite phosphor.

In the present invention, the non-perovskite wavelength converting body can be classified into a quantum dot and a fluorescent material. The quantum dots are semiconductor particles having a size of several nanometers or less, and have a size smaller than a Bohr diameter, thereby exhibiting a quantum confinement effect. Therefore, the smaller the size of the quantum dot, the greater the bandgap energy, and the emission wavelength can be adjusted according to the size of the quantum dot. On the other hand, since the fluorescent material has a size larger than the Bohr diameter, the bandgap energy does not change according to the size of the particle or crystal, and it refers to a material that emits light depending on the crystal structure or molecular structure.

In the hybrid wavelength converting body according to the present invention, hereinafter, as an example of a non-perovskite-based wavelength converting body, it will be described centering on a non-perovskite-based quantum dot, but is not limited thereto, and non-perovskite phosphors are also included in the scope of the present invention.

Since the metal halide perovskite is the same as described above, a detailed description will be omitted.

The metal halide perovskite nanocrystal may further include a plurality of organic ligands 20 surrounding the metal halide perovskite nanocrystal 10. The organic ligands 20 at this time are a material used as a surfactant and may include an alkyl halide. Accordingly, the alkyl halide used as a surfactant to stabilize the surface of the metal halide perovskite precipitated as described above becomes an organic ligand surrounding the surface of the metal halide perovskite nanocrystal. On the other hand, when the length of the alkyl halide surfactant is short, the size of the formed nanocrystal increases, so it can be formed in excess of 10 μm, and can undergo a fundamental problem that excitons are separated into a free charge carriers and quenched by thermal ionization and delocalization of the charge carrier in the large nanocrystal. Accordingly, the size of the metal halide perovskite nanocrystals formed by using an alkyl halide having a predetermined length or longer as a surfactant can be controlled to a predetermined size or less. The metal halide perovskite nanocrystal particle 100 according to the present invention may include a metal halide perovskite nanocrystal structure 110 that can be dispersed in an organic solvent. The organic solvent at this time may be a polar solvent or a non-polar solvent.

For example, the polar solvent may include acetic acid, acetone, acetonitrile, dimethylformamide, gamma butyrolactone, N-methylpyrrolidone, ethanol or dimethylsulfoxide, and the non-polar solvent may include dichloroethylene, trichloroethylene, chloroform, chlorobenzene, dichlorobenzene, styrene, dimethylformamide, dimethyl sulfoxide, xylene, toluene, cyclohexene, or isopropyl alcohol, but is not limited thereto.

In addition, the shape of the metal halide perovskite nanocrystal may be generally used in this field. The shape of the metal halide perovskite nanocrystal may be a 0-dimensional, 1-dimensional or 2-dimensional. As an example, it may be in the shape of a sphere, an ellipsoid cube, a hollow cube, a pyramid, a cylinder, a cone, an elliptic column, hollow sphere, Janus particle, prism, multipod, polyhedron, nano tube, nano wire, nano fiber, or nanoplatelet.

In addition, the size of the crystalline particles may be 1 nm to 10 μm or less. For example, it may be 1 nm, 2 nm, 3 nm, 4 nm, 5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 μm. The size of the particle can be defined as a range with the lower value as the minimum value and the larger value as the maximum value among the two numbers selected above. It is preferably 8 nm or more and 300 nm or less, and more preferably 10 nm or more and 30 nm or less. On the other hand, the size of the crystalline particles means a size that does not take into account the length of a ligand to be described later, that is, the size of the remaining portions excluding the ligand. If the size of the crystalline particle is greater than 1 μm, there may be a fundamental problem in which excitons are quenched by thermal ionization and delocalization of charge carriers in large crystals. More desirable, the size of the above crystalline particle may also be greater than the Bohr diameter, as noted above. The phenomenon of thermal ionization and delocalization of the charge carriers above may gradually occur as the nanocrystals exceed 100 nm in size. If it is over 300 nm, the phenomenon will take place more, and if it is over 1 μm, it will be governed by the phenomenon because it is a complete bulk regime.

For example, when the crystalline particles are spherical, the diameter of the crystalline particles may be 1 nm to 10 μm. Preferably, it may be 1 nm, 3 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm or 10 μm.

In addition, the band gap energy of such crystalline particles may be 1 eV to 5 eV. Preferably, the band gap energy of the nanocrystal particle is a range in which the lower value of the number is the lower limit value and the higher value is the upper limit value selected from the group of 1 eV, 1.1 eV, 1.2 eV, 1.3 eV, 1.4 eV, 1.5 eV, 1.6 eV, 1.7 eV, 1.8 eV, 1.81 eV, 1.82 eV, 1.83 eV, 1.84 eV, 1.85 eV, 1.86 eV, 1.87 eV, 1.88 eV, 1.89 eV, 1.9 eV, 1.91 eV, 1.92 eV, 1.93 eV, 1.94 eV, 1.95 eV, 1.96 eV, 1.97 eV, 1.98 eV, 1.99 eV, 2 eV, 2.01 eV, 2.02 eV, 2.03 eV, 2.04 eV, 2.05 eV, 2.06 eV, 2.07 eV, 2.08 eV, 2.09 eV, 2.1 eV, 2.11 eV, 2.12 eV, 2.13 eV, 2.14 eV, 2.15 eV, 2.16 eV, 2.17 eV, 2.18 eV, 2.19 eV, 2.2 eV, 2.21 eV, 2.22 eV, 2.23 eV, 2.24 eV, 2.25 eV, 2.26 eV, 2.27 eV, 2.28 eV, 2.29 eV, 2.3 eV, 2.31 eV, 2.32 eV, 2.33 eV, 2.34 eV, 2.35 eV, 2.36 eV, 2.37 eV, 2.38 eV, 2.39 eV, 2.4 eV, 2.41 eV, 2.42 eV, 2.43 eV, 2.44 eV, 2.45 eV, 2.46 eV, 2.47 eV, 2.48 eV, 2.49 eV, 2.5 eV, 2.51 eV, 2.52 eV, 2.53 eV, 2.54 eV, 2.55 eV, 2.56 eV, 2.57 eV, 2.58 eV, 2.59 eV, 2.6 eV, 2.61 eV, 2.62 eV, 2.63 eV, 2.64 eV, 2.65 eV, 2.66 eV, 2.67 eV, 2.68 eV, 2.69 eV, 2.7 eV, 2.71 eV, 2.72 eV, 2.73 eV, 2.74 eV, 2.75 eV, 2.76 eV, 2.77 eV, 2.78 eV, 2.79 eV, 2.8 eV, 2.9 eV, 3 eV, 3.1 eV, 3.2 eV, 3.3 eV, 3.4 eV, 3.5 eV, 3.6 eV, 3.7 eV, 3.8 eV, 3.9 eV, 4 eV, 4.1 eV, 4.2 eV, 4.3 eV, 4.4 eV, 4.5 eV, 4.6 eV, 4.7 eV, 4.8 eV, 4.9 eV, and 5 eV.

In general, the metal halide perovskite can control the emission wavelength by controlling the halide ion at the X site. However, since the halide ions of the metal halide perovskite are highly mobile, halide ion migration may occur. For this reason, when metal halide perovskite nanoparticles with different halide ion composition are used in a wavelength converting body, the composition of the metal halide perovskite nanoparticle changes due to ion migration, so that the emission wavelength band of the wavelength converting body is easy changed. Therefore, it is very difficult to obtain stable light emission of two or more emission peaks with a wavelength converting body using only metal halide perovskite. In addition, aggregation of the metal halide perovskite nanoparticle may occur due to the high reactivity of the metal halide perovskite, and luminescence efficiency may decrease.

In addition, the existing inorganic quantum dots used for wavelength converting bodies essentially contain cadmium (Cd) for high color purity and luminescence performance, and the cadmium is very harmful to the human body, so according to the Restriction of Hazardous Substances Directive (RoHS) standards, after 2022, it can only be used at less than 100 ppm, and in the case of quantum dots that do not use cadmium, the color purity is very low as the half width (FWHM) is 35 nm or more. In addition, semiconductor materials constituting quantum dots are very expensive, and a large amount of quantum dots is required for manufacturing a wavelength converting body due to the low absorbance of the quantum dots, so there is a problem of cost increase.

However, the hybrid wavelength converting body according to the present invention replaces a part of the inorganic quantum dots in the wavelength converting body with metal halide perovskite nanoparticle that do not contain cadmium, thus the cadmium content in the wavelength converting body can be greatly reduced. This is of great commercial importance as it can reduce the harmfulness of wavelength converting bodies and also enable wavelength converting bodies to meet RoHS criteria. In particular, metal halide perovskite nanoparticle have a greater absorbance than the above inorganic quantum dots, so only a smaller amount of the luminescent material than conventional inorganic quantum dots can be used to obtain equivalent or higher efficiency properties.

In addition, in the hybrid wavelength converting body according to the present invention, the non-perovskite quantum dots do not contain halide ions. Therefore, halide ion migration does not occur between the non-perovskite quantum dots and the metal halide perovskite nanocrystal particle. Thus, the composition of metal halide perovskite nanocrystal particle within the hybrid wavelength converting body under this invention does not change, so the above metal halide perovskite nanocrystal particle can obtain stable luminescence without changing the luminous wavelength.

Therefore, the hybrid wavelength converting body according to the present invention is essentially different from the conventional non-perovskite wavelength converting body or metal halide perovskite wavelength converting body, and is a more advanced wavelength converting body.

The metal halide perovskite nanocrystal particle and the non-perovskite quantum dots may convert light generated from an excitation light source into different wavelengths. Specifically, with respect to blue light generated from an excitation light source, the metal halide perovskite nanocrystal may emit green light, and the non-perovskite quantum dots may emit red light.

The green light is in a range in which the lower value of two numbers selected from the group of 500 nm, 501 nm, 502 nm, 503 nm, 504 nm, 505 nm, 506 nm, 507 nm, 508 nm, 509 nm, 510 nm, 511 nm, 512 nm, 513 nm, 514 nm, 515 nm, 516 nm, 517 nm, 518 nm, 519 nm, 520 nm, 521 nm, 522 nm, 523 nm, 524 nm, 525 nm, 526 nm, 527 nm, 528 nm, 529 nm, 530 nm, 531 nm, 532 nm, 533 nm, 534 nm, 535 nm, 536 nm, 537 nm, 538 nm, 539 nm, 540 nm, 541 nm, 542 nm, 543 nm, 544 nm, 545 nm, 546 nm, 547 nm, 548 nm, 549 nm, 550 nm, 560 nm, 570 nm, 580 nm is the lower limit value and the higher value of the two is the upper limit value. The red light is in a range in which the lower value of two numbers selected from the group of 590 nm, 600 nm, 601 nm, 602 nm, 603 nm, 604 nm, 605 nm, 606 nm, 607 nm, 608 nm, 609 nm, 610 nm, 611 nm, 612 nm, 613 nm, 614 nm, 615 nm, 616 nm, 617 nm, 618 nm, 619 nm, 620 nm, 621 nm, 622 nm, 623 nm, 624 nm, 625 nm, 626 nm, 627 nm, 628 nm, 629 nm, 630 nm, 631 nm, 632 nm, 633 nm, 634 nm, 635 nm, 636 nm, 637 nm, 638 nm, 639 nm, 640 nm, 641 nm, 642 nm, 643 nm, 644 nm, 645 nm, 646 nm, 647 nm, 648 nm, 649 nm, 650 nm, 660 nm, 670 nm, 680 nm, 690 nm, 700 nm is the lower limit value and the higher value of the two is the upper limit value.

When a metal halide perovskite nanocrystal emits green light and a non-perovskite quantum dot emits red light, the excitation light is effectively converted into green light due to the high absorbance of the metal halide perovskite nanocrystal. It is possible to induce energy transfer from metal halide perovskite nanocrystals to non-perovskite quantum dots. Therefore, it is possible to secure efficiency characteristics equal to or higher than that of conventional non-perovskite quantum dot wavelength converting bodies with a smaller amount of luminescent material, and stable light emission by effectively reducing the self-energy transfer of metal halide perovskite nanoparticle.

In the hybrid wavelength converting body according to the present invention, since the metal halide perovskite nanocrystal particle and the non-perovskite quantum dots are heterogeneous wavelength converting particles, a large difference in absorption and light emission characteristics exist. In addition, the metal halide perovskite has very high absorption coefficient. Therefore, it is difficult to match the mixing ratio when compared to the conventional quantum dot wavelength converting body. Accordingly, in the hybrid wavelength converting body according to the present invention, it is important to adjust the mixing ratio of the metal halide perovskite nanocrystal particle and the non-perovskite quantum dots so that the luminance of green light and red light is at the same level.

In this case, based on the weight ratio of metal halide perovskite nanocrystal particle to the sum of the weights of the quantum dots, the mixing ratio of the metal halide perovskite nanocrystal particle and the quantum dots may be from 20 wt % to 80 wt %. For example, the weight ratio of the metal halide perovskite nanocrystal particle to the sum of the weights of the metal halide perovskite nanocrystal particle and the quantum dots is a range in which the lower value of the two number selected from the group of 20 wt %, 25 wt %, 30 wt %, 35 wt %, 40 wt %, 45 wt %, 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 70 wt %, 75 wt %, 80 wt % is the lower limit value and the higher value of the two is the upper limit value. In addition, preferably, the weight ratio of the metal halide perovskite nanocrystal particle to the sum of the weights of the metal halide perovskite nanocrystal particle and the quantum dots may be 50 wt % to 66 wt %, outside the above range, if the mixing ratio of the metal halide perovskite nanocrystal particle is large, the aggregation of the metal halide perovskite may occur, so stable wavelength conversion cannot be performed, and self-energy transition between the metal halide perovskite nanocrystal particles (i.e. self-absorption) occurs, thus there is a problem that the luminescence efficiency is greatly reduced or the emission wavelength is changed.

The non-perovskite quantum dots 15 are Si-based nanocrystals, II -IV group compound semiconductor nanocrystals, III-V group compound semiconductor nanocrystals, IV-VI group compound semiconductor nanocrystals, boron quantum dots, carbon quantum dots, metal quantum dots, or it may include at least one of and mixtures thereof.

The II-IV-based compound semiconductor nanocrystals may be any one selected from the group consisting of CdS, CdSe, CdTe, ZnS, ZnSe, ZnTe, HgS, HgSe, HgTe, CdSeS, CdSeTe, CdTe, ZnSeS, ZnSeTe, ZnSTe, HgSeS, HgSeTe, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeS, CdHgSeTe, and CdHgSe, but is not limited thereto.

The III-V group compound semiconductor nanocrystals may be any one selected from the group consisting of GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs, but is not limited thereto.

The IV-VI compound semiconductor nanocrystal may be SbTe, but is not limited thereto.

The carbon quantum dots may be graphene quantum dots, carbon quantum dots, C₃N₄ alternating quantum dots, or polymer quantum dots, but are not limited thereto.

The metal quantum dots may be Au, Ag, Al, Cu, Li, Cu, Pd, Pt, or alloys thereof, but are not limited thereto.

For hybrid wavelength converting body under this invention, the above dispersion medium may be liquid, uniformly distributing the above metal halide perovskite nanoparticle and the above non-perovskite quantum dots, and immobilizing them when cured with ultraviolet irradiation to be hardened. The dispersion medium can be at least one of the epoxy resins, silicon, or their mixtures, but are not limited to them.

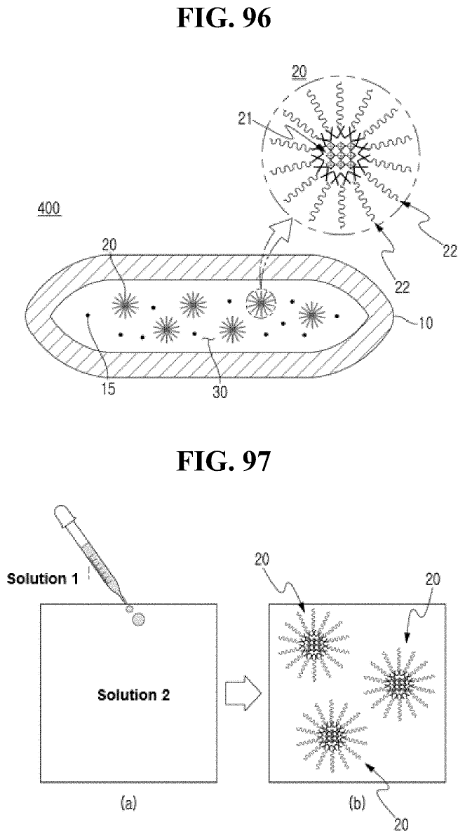

FIG. 96 is a schematic diagram showing a hybrid wavelength converting body according to another embodiment of the present invention.

Referring to FIG. 96, the hybrid wavelength converting body 400 under other examples of this invention may contain metal halide perovskite nanocrystal particle 20, non-perovskite quantum dots 15, dispersion medium 30, and additional sealing members 10 sealing the dispersion medium.

In addition, hybrid wavelength converting bodies in other examples of present invention may include metal halide perovskite nanocrystal particles, non-perovskite phosphors, and sealing members that seal the dispersion medium.

These sealing members 10 may be consist of materials of a type that are not corroded by dispersion medium in which metal halide perovskite nanocrystal particles and non-perovskite quantum dots or non-perovskite phosphor are dispersed, which is, preferably, at least one of epoxy resin, acrylic polymer, glass, carbonate polymer, silicon, and their mixture, but not limited thereof. For example, the polymer resin can be heated and gradually the adhesion can be improved, so it can be used as a sealing material to form a pack in which metal halide perovskite nanocrystal particles and non-perovskite quantum dots are dispersed inside. The manufacturing method of hybrid wavelength converting bodies 400 using these sealing members will be described in detail in the following <Manufacturing methods of hybrid wavelength converting bodies>.

Hereinafter, a method of manufacturing a hybrid wavelength converting body according to the present invention will be described.

First, metal halide perovskite nanocrystal particles and non-perovskite quantum dots are prepared as wavelength converting particles.

Since the description of the metal halide perovskite nanocrystal particle and the non-perovskite quantum dots is the same as described above, it will be omitted to avoid redundant description.

As the non-perovskite quantum dots, quantum dots commonly used in the art can be used, commercially available ones may be used, or may be prepared by methods commonly used in the art.

The metal halide perovskite nanocrystal particle may be prepared according to the following method, but is not limited thereto.

FIG. 97 is a schematic diagram showing a method of manufacturing a metal halide perovskite nanocrystal particle used as a wavelength converting particle in a hybrid wavelength converting body according to an embodiment of the present invention.

Referring to FIG. 97, the metal halide perovskite nanocrystal particle may be prepared through the aforementioned inverse nano-emulsion method or ligand-assisted reprecipitation method, but is not limited thereto. Since the inverse nano-emulsion method and the ligand-assisted reprecipitation method are as described above, detailed descriptions are omitted.

The metal halide perovskite nanocrystal particle described above can be dispersed in all organic solvents. Accordingly, since the size, emission wavelength spectrum, ligand, and constituent elements can be easily adjusted, it can be applied to various electronic devices.

Meanwhile, the size of the crystalline particles of the metal halide perovskite can be controlled by controlling the length or shape factor of the alkyl halide surfactant. For example, shape factor control can be sized through linear, tapered, or inverted triangular surfactants.

Furthermore, the form of metal halide perovskite nanocrystals may be commonly used in the art. The form of metal halide perovskite nanocrystals can be zero-dimensional, one-dimensional or two-dimensional. Examples include spherical (sphere), ellipsoid cube, hollow cube, pyramid, cylinder, cone, elliptic column, hollow sphere, Janus particle, prism, multipod, polyhedron, nano tube, nano wire, nano fiber, or nanoplatelet.

In addition, the size of the crystalline particles may be 1 nm to 10 μm or less. For example, 1 nm, 2 nm, 3 nm, 4 nm, 5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 μm. The size of the particle can be defined as a range with the lower value as the minimum value and the larger value as the maximum value among the two numbers selected above. It is preferably 8 nm or more and 300 nm or less, and more preferably 10 nm or more and 30 nm or less. On the other hand, the size of the crystalline particles at this time means a size that does not take into account the length of a ligand to be described later, that is, the size of the remaining portions excluding the ligand. When the size of the crystalline particles is 1 μm or more, there is a fundamental problem that excitons do not emit light due to thermal ionization and delocalization of charge carriers in a large crystal, but are separated into free charges and disappeared. In addition, more preferably, as described above, the size of the crystalline particles may be greater than or equal to a Bohr diameter. The thermal ionization and delocalization of the charge carrier may gradually appear when the size of the nanocrystal exceeds 100 nm. If it is more than 300 nm, the phenomenon will appear more, and if it is more than 1 μm, it is completely bulky and is subject to the above phenomenon.

For example, when the crystalline particles are spherical, the diameter of the crystalline particles may be 1 nm to 10 μm. Preferably, it may be 1 nm, 3 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm or 10 μm.

In addition, the band gap energy of the nanocrystal particle may be 1 eV to 5 eV. Preferably, the band gap energy of the nanocrystal particle is a range in which the lower value of the two numbers selected from the group of 1 eV, 1.1 eV, 1.2 eV, 1.3 eV, 1.4 eV, 1.5 eV, 1.6 eV, 1.7 eV, 1.8 eV, 1.81 eV, 1.82 eV, 1.83 eV, 1.84 eV, 1.85 eV, 1.86 eV, 1.87 eV, 1.88 eV, 1.89 eV, 1.9 eV, 1.91 eV, 1.92 eV, 1.93 eV, 1.94 eV, 1.95 eV, 1.96 eV, 1.97 eV, 1.98 eV, 1.99 eV, 2 eV, 2.01 eV, 2.02 eV, 2.03 eV, 2.04 eV, 2.05 eV, 2.06 eV, 2.07 eV, 2.08 eV, 2.09 eV, 2.1 eV, 2.11 eV, 2.12 eV, 2.13 eV, 2.14 eV, 2.15 eV, 2.16 eV, 2.17 eV, 2.18 eV, 2.19 eV, 2.2 eV, 2.21 eV, 2.22 eV, 2.23 eV, 2.24 eV, 2.25 eV, 2.26 eV, 2.27 eV, 2.28 eV, 2.29 eV, 2.3 eV, 2.31 eV, 2.32 eV, 2.33 eV, 2.34 eV, 2.35 eV, 2.36 eV, 2.37 eV, 2.38 eV, 2.39 eV, 2.4 eV, 2.41 eV, 2.42 eV, 2.43 eV, 2.44 eV, 2.45 eV, 2.46 eV, 2.47 eV, 2.48 eV, 2.49 eV, 2.5 eV, 2.51 eV, 2.52 eV, 2.53 eV, 2.54 eV, 2.55 eV, 2.56 eV, 2.57 eV, 2.58 eV, 2.59 eV, 2.6 eV, 2.61 eV, 2.62 eV, 2.63 eV, 2.64 eV, 2.65 eV, 2.66 eV, 2.67 eV, 2.68 eV, 2.69 eV, 2.7 eV, 2.71 eV, 2.72 eV, 2.73 eV, 2.74 eV, 2.75 eV, 2.76 eV, 2.77 eV, 2.78 eV, 2.79 eV, 2.8 eV, 2.9 eV, 3 eV, 3.1 eV, 3.2 eV, 3.3 eV, 3.4 eV, 3.5 eV, 3.6 eV, 3.7 eV, 3.8 eV, 3.9 eV, 4 eV, 4.1 eV, 4.2 eV, 4.3 eV, 4.4 eV, 4.5 eV, 4.6 eV, 4.7 eV, 4.8 eV, 4.9 eV, and 5 eV, is the lower limit value and the higher value of the two is the upper limit value.

Hereinafter, a method of manufacturing a hybrid wavelength converting body according to an embodiment of the present invention will be described in detail.

(a) Dispersion Medium Curing Method

In the method of manufacturing a hybrid wavelength converting body according to the present invention, the dispersion medium curing method comprises preparing a first dispersion solution by dispersing metal halide perovskite nanocrystal particle, and non-metal halide perovskite quantum dots or non-metal halide perovskite phosphors as wavelength converting particle in a dispersion solvent, preparing a second dispersion solution by dispersing a dispersion medium in the first dispersion solution, and coating the second dispersion solution on a substrate and irradiating ultraviolet light to polymerize and cure the dispersion medium to form a hybrid wavelength converting body.

First, in the step of preparing the first dispersion solution, metal halide perovskite nanocrystal particle, and non-metal halide perovskite quantum dots or nonperovskite phosphors are dispersed together as wavelength converting particle in the dispersion solvent to form a colloidal solution.

In this case, the above dispersion solvent is a material having a property that does not affect the performance of metal halide perovskite nanocrystal particle, non-metal halide perovskite quantum dots, and non-perovskite phosphors as wavelength converting particle. The dispersion solvent may be selected from methanol, ethanol, tert-butanol, xylene, toluene, hexane, octane, cyclohexane, dichloroethylene, chloroform, and chlorobenzene, but is not limited thereto. In the hybrid wavelength converting body, since the metal halide perovskite nanocrystal particle and the non-metal halide perovskite quantum dots are heterogeneous wavelength converting particles, they exhibit a large difference in absorption and light emission depending on the wavelength. In addition, the metal halide perovskite has a very large absorbance. Therefore, it is difficult to match the mixing ratio compared to the conventional quantum dot wavelength converting body. The mixing ratio of the metal halide perovskite nanocrystal particle and the non-metal halide perovskite quantum dots is preferably 1:1 to 2:1 by weight, outside the above range, large mixing ratios of metal halide perovskite nanocrystal particles can cause metal halide perovskite aggregation, resulting in no stable wavelength conversion, and significant self-absorption among metal halide perovskite nanocrystal particles.

Next, a second dispersion solution is prepared by mixing a dispersion medium with the first dispersion solution. The dispersion medium may be in a liquid state, and uniformly disperse the metal halide perovskite nanoparticle and the non-metal halide perovskite quantum dots or non-perovskite phosphors, and serves to immobilize the metal halide perovskite nanoparticle and the non-metal halide perovskite quantum dots or non-perovskite phosphors when irradiated with ultraviolet rays. The dispersion medium may be at least one of epoxy resin, silicone, and mixtures thereof, but is not limited thereto.

Next, a second dispersion solution is coated on the substrate. While coating the second dispersion solution, the dispersion solvent is removed to form a wavelength converting body in which metal halide perovskite nanocrystal particle and non-metal halide perovskite quantum dots or non-perovskite phosphors are uniformly mixed in a dispersion medium.

At this time, the coating method be selected from a variety of methods of a spin coating method, a spray method, a dip coating method, a bar coating method, a nozzle printing method, a slot-die coating method, a gravure printing method, a screen printing method, a brush painting method or a roll coating method, etc.

Next, the dispersion medium is polymerized and cured. The polymerization and curing may be performed by irradiating ultraviolet lights, and the ultraviolet lights used may be those having a wavelength of, for example, 350 to 400 nm, but are not limited thereto.

As the dispersion medium is polymerized and cured, a wavelength converting body crosslinked in a state, in which metal halide perovskite nanocrystal particle and non-metal halide perovskite quantum dots or non-perovskite luminescent materials are uniformly mixed in the dispersion medium, is produced.

Thereafter, if necessary, the step of additionally removing the substrate may be further included.

(b) Synthesis of In-Situ Metal Halide Perovskite Nanocrystal Particle

In the method of manufacturing a hybrid wavelength converting body according to the present invention, the in-situ metal halide perovskite nanocrystal particle synthesis method comprises preparing a metal halide perovskite precursor solution by dissolving a metal halide perovskite precursor in a solvent preparing a third dispersion solution by mixing a non-perovskite-based quantum dot and a dispersion medium with the metal halide perovskite precursor solution, and forming a hybrid wavelength converting body by coating and crystallizing the third dispersion solution on a substrate, and polymerizing and curing the dispersion medium by irradiating ultraviolet lights.

First, in the step of preparing a metal halide perovskite precursor solution, the metal halide perovskite precursor may be dissolved in a solvent.

In this case, the solvent may dissolve a metal halide perovskite precursor material, and may be a material having a property that does not affect the performance of a non-perovskite quantum dot. The solvent may be selected from dimethylformamide, dimethylsulfoxide, acetonitrile, gamma butyrolactone, methylpyrrolidone, and isopropyl alcohol, but is not limited thereto.

In the step of preparing the third dispersion solution, a colloidal solution is formed by dispersing a non-perovskite-based quantum dot and a dispersion medium together in the metal halide perovskite precursor solution. The third dispersion solution prepared is thus a colloidal solution in which a metal halide perovskite precursor is dissolved, and quantum dots and polymers are dispersed.

After that, a third dispersion solution is coated on the substrate. While coating the third dispersion solution, the dispersion solvent is removed to crystallize the metal halide perovskite precursor material on the substrate, so that a hybrid wavelength converting body is prepared, in which metal halide perovskite nanocrystal particle and non-perovskite quantum dots are uniformly mixed.

The coating method can be selected from a variety of methods of a spin coating method, a spray method, a dip coating method, a bar coating method, a nozzle printing method, a slot-die coating method, a gravure printing method, a screen printing method, a brush painting method or a roll coating method, etc.

Next, the dispersion medium is polymerized and cured. The polymerization and curing may be performed by irradiating ultraviolet lights, and the ultraviolet lights used may be those having a wavelength of, for example, 350 to 400 nm, but are not limited thereto.

As the dispersion medium is polymerized and cured, a wavelength converting body in which metal halide perovskite nanocrystal particles and non-perovskite quantum dots are uniformly mixed in the dispersion medium is prepared.

In this case, the step of coating the third dispersion solution on the substrate and the step of irradiating ultraviolet rays may be performed in a different order or may be performed simultaneously.

Thereafter, if necessary, the step of additionally removing the substrate may be further included.

(c) Dispersion Medium Sealing Method

In the method of manufacturing a hybrid wavelength converting body according to the present invention, the dispersion medium sealing method comprises stacking a first sealing member and a second sealing member, adhering one side of the first sealing member and the second sealing member, injecting dispersion medium, in which metal halide perovskite nanocrystal particle and non-perovskite quantum dots as wavelength-converting particles are dispersed, between the first and second sealing members through the other side where the first and second sealing members are not attached together, and sealing the dispersion medium, in which metal halide perovskite nanocrystal particle and non-perovskite quantum dots are dispersed as wavelength converting particle, with sealing members, which is done by bonding the first sealing member with the second sealing member at the other side of the two sealing members.

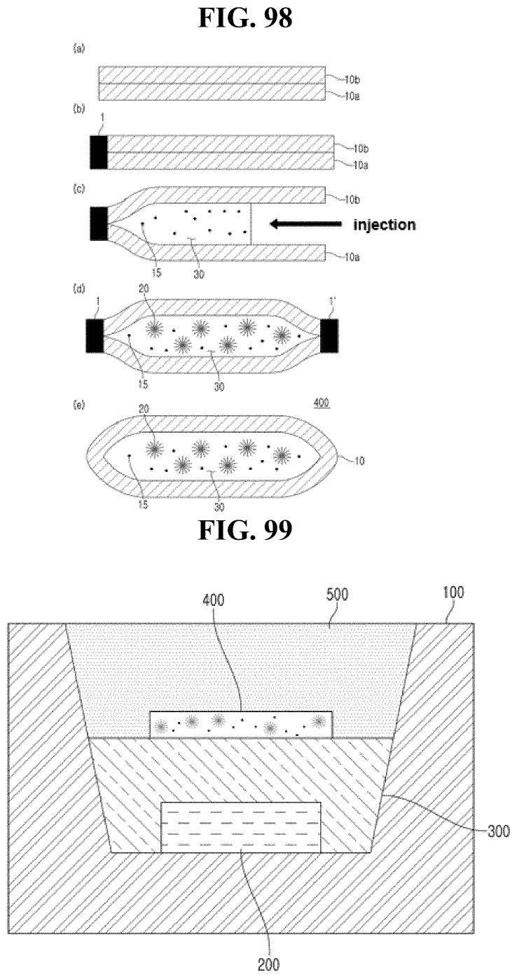

FIG. 98 is a cross-sectional view showing a method of manufacturing a hybrid wavelength converting body using a sealing method according to an embodiment of the present invention.

Hereinafter, a method of manufacturing a hybrid wavelength converting body using the sealing method will be described in detail with reference to FIG. 98.

Referring to FIG. 98(a), a first sealing member 10a and a second sealing member 10b are stacked.

The sealing member is a polymer resin or silicone that is not corroded by the dispersion medium 30 in which the metal halide perovskite nanocrystal particle 20 and the non-perovskite quantum dots 15 are dispersed as wavelength converting particle. In particular, since the polymer resin can be heated and thus the adhesive property is gradually improved, it can be used to form a pack-type wavelength converting body with dispersion medium 30, in which dispersed wavelength converting particles 15, 20 are dispersed, by using a thermal adhesion process.

Referring to FIG. 98(b), one side 1 of the first sealing member 10a and the second sealing member 10b may be heated and adhered via the thermal bonding process so that the above-described wavelength converting particles 15, 20 and the dispersion medium 30 do not leak out of the sealing member 10a, 10b.

Referring to FIG. 98(c), the dispersion medium 30 with wavelength converting particle 15, 20 dispersed is injected through the other side where the first sealing member 10a and second sealing member 10b are not bonded.

Referring to FIG. 98(d), the dispersion medium 30 in which the wavelength converting particle 15, 20 are dispersed is sealed with sealing members 10a and 10b by using a thermal bonding process to bond the first sealing member 10a with the second sealing member 10b at the other side 1.

Referring to FIG. 98(e), it can be seen that the hybrid wavelength converting body 400 in which the dispersion medium 30, in which the wavelength converting particle 15, 20 are dispersed, is sealed with sealing members 10.

Hybrid wavelength converting bodies 400 manufactured in the above method have the advantage of being able to apply to light-emitting devices without the need for a additional ligand purification process, as they are sealed in a state that metal halide perovskite nanocrystal particles 20 and non-perovskite quantum dots are dispersed 15. Therefore, it can prevent oxidation of wavelength converting particles during ligand purification, which results in high color purity and luminescence when applied to light-emitting devices. In addition, the process can be simplified.

In addition, the above hybrid wavelength converting body 400 can significantly reduce the cadmium content by replacing some of the conventional quantum dot wavelength converting bodies with metal halide perovskite nanoparticles that do not contain cadmium. In particular, since metal halide perovskite nanoparticle have a higher absorbance than quantum dots, only a smaller amount of light emitter than conventional quantum dots can be used to obtain more than equivalent efficiency properties.

In addition, the present invention provides a light-emitting device including the hybrid wavelength converting body.

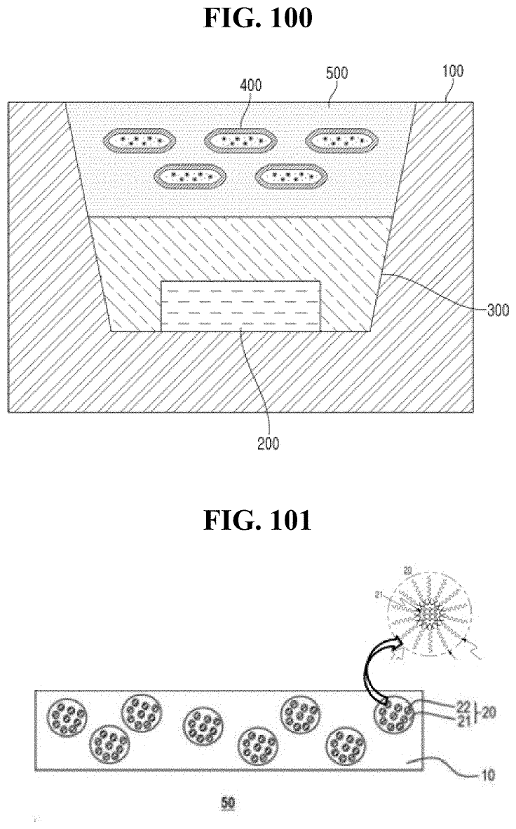

FIG. 99 and FIG. 100 are cross-sectional views of a light-emitting device according to an embodiment of the present invention.

Referring to FIGS. 99 and 100, the light-emitting device according to one example of this invention includes the base structure 100, at least one excitation light source 200 placed on the base structure 100 and emitting a light with a predetermined wavelength, and hybrid wavelength converting body 400 placed on the light path of the excitation light source 200.

The base structure 100 described above may be a package frame or a base substrate. When the base structure 100 is a package frame, the package frame may include the base substrate. The base substrate may be a submount substrate or a wafer for light-emitting diode. The wafer for light-emitting diode is in a state before being separated into light-emitting diode chips, and indicates a state in which a light-emitting diode device is formed on the wafer. The base substrate 100 may be a silicon substrate, a metal substrate, a ceramic substrate, or a resin substrate.

The base structure 100 described above may be a package lead frame or a package pre-mold frame. The base structure 100 may include a bonding pad (not shown). Bonding pads may contain Au, Ag, Cr, Ni, Cu, Zn, Ti, Pd, or the like. External connection terminals (not shown) connected to bonding pads may be located on the outer side of the base structure 100. The bonding pads and the external connection terminals may be those provided in the package lead frame.

The excitation light source 200 can be located on the base structure 100. The light source 200 is preferable to emit light that has a shorter wavelength than the emitting wavelength of the wavelength converting body 400 of the hybrid wavelength converting body (metal halide perovskite nanocrystal particle and non-perovskite quantum dot) according to present invention. The light source 200 may be either a light-emitting diode or a laser diode. In addition, if the base structure 100 is a wafer for light-emitting diode, the stage of placing the light source here may be omitted. For example, excitation light source 200 can include blue LEDs, which can use gallium nitride LEDs that emit blue light from 420 nm to 480 nm.

As in FIGS. 99 and 100, the first encapsulation part 300 may be formed by the filling of the encapsulation material encapsulating the aforementioned light source 200. The aforementioned first encapsulation part 300 may serve as a protective shield as well as to cover the aforementioned light source 200. In addition, if the wavelength converting body 400 is located on the first encapsulation part 300, the second encapsulation part 500 may be formed to protect and secure it. The encapsulation material may contain epoxy, silicon, acrylic polymer, glass, or carbonate polymer.

The first encapsulation part 300 can be formed by using various methods such as a compression molding method, a transfer molding method, a dotting method, a blade coating method, a screen coating method, dip coating, spin coating, spray, or inkjet printing. However, the first encapsulation part 300 may be omitted.

Since the detailed description of the hybrid wavelength converting body 400 is the same as described above, it will be omitted to avoid redundant description.

As shown in FIGS. 99 and 100, the second encapsulation part 500 may be formed by filling the encapsulating material for encapsulating the wavelength converting body 400 on the wavelength converting body 400 described above. The second encapsulation part 500 may use the same material as the first encapsulation part 300 described above, and may be formed through the same manufacturing method.

In addition, the light-emitting device according to the present invention may also include groove parts including a bottom surface on which the excitation light source is to be mounted and a side surface on which a reflector is formed, and support parts that have an electrodes supporting the groove and electrically connected to the excitation light source.

The above-described light-emitting device can be applied to lighting, backlight units, as well as light-emitting devices.

In the embodiment of this invention, the above light-emitting device is designed specific to the unit cell, but if the base structure is a submount substrate or wafer for light-emitting diode, the above submount substrate or wafer for light-emitting diode may be cut and processed into each unit cell.

On the other hand, in the manufacture of a metal halide perovskite wavelength converting body, since the metal halide perovskite is agglomerated with each other in the dispersion medium, it is not uniformly dispersed, and self-absorption between the agglomerated metal halide perovskite crystals may decrease, thereby reducing luminescence efficiency, and a luminescence wavelength band may be changed. Therefore, it is very important that the metal halide perovskite is uniformly dispersed in the dispersion medium.

When the metal halide perovskite emitter further includes a plurality of organic ligands surrounding the metal halide perovskite nanocrystal, in general, the organic ligands have hydrophobic properties, thus the type of dispersion medium that can be prepared is limited.

Meanwhile, the metal halide perovskite has very low stability against oxygen and moisture. Therefore, it is preferable to use a dispersion medium having a low permeability for oxygen and moisture in order to prepare a stable metal halide perovskite wavelength converting body. However, since such a dispersion medium having a low permeability to oxygen and moisture is generally not compatible with a hydrophobic material, it may be difficult to obtain a uniform dispersion when mixed with the metal halide perovskite. In order to solve this problem, a method of mixing a metal halide perovskite and a dispersion medium at a high temperature may be used, but luminescence efficiency may decrease because the metal halide perovskite is vulnerable to heat.

To solve this problem, if the metal halide perovskite emitters contains plurality of organic ligands surrounding the metal halide perovskite nanocrystals, preferably the wavelength converting body may have a form in which metal halide perovskite particles encapsulated by an encapsulating resin are dispersed in a matrix resin.

FIG. 101 is a cross-sectional view of an encapsulated metal halide perovskite wavelength converting film according to an embodiment of the present invention.

Referring to FIG. 101, the metal halide perovskite may have a structure encapsulated by the first dispersion medium, and the encapsulated metal halide perovskite may have a structure dispersed in the second dispersion medium.

In addition, preferably, the first dispersion medium may be characterized by uniformly dispersing the metal halide perovskite due to good compatibility with the organic ligand.

In addition, preferably, the dispersion medium may be a polymer. Preferably, the polymer may be characterized in that it has a polar group in at least one of a backbone or a side chain. The polar group may be adsorbed on the surface of the metal halide perovskite to increase the dispersibility of the metal halide perovskite.

In the case of having a polar group in the main chain of the polymer, the main chain of the polymer may be characterized in that it includes polyester, ethyl cellulose, polyvinylpyridine, or combinations thereof, but is not limited thereto.

In the case of having a polar group in the side chain of the polymer, the polar group may be characterized in that it contains an oxygen component, preferably the polar group —OH, —COOH, —COH, —CO—, —O—, or a combination thereof, but is not limited thereto.

In addition, it is preferable that the polymer has a number average molecular weight of about 300 g/mol to 100,000 g/mol. If the number average molecular weight of the polymer is out of the above range and is less than 300 g/mol, the distance between the quantum dots in the quantum dot-polymer bead is insufficient, so that the luminescence efficiency may decrease, and if it exceeds 100,000 g/mol, the bead size becomes excessively large. Defects may occur in the film forming process. The polymer may be a thermosetting resin or a wax-based compound.

Specifically, the thermosetting resin may be selected from a combination of them from a group of a silicone resin, epoxy resin, petroleum resin, phenol resin, urea resin, melamine resin, unsaturated polyester resin, amino resin, butyl rubber, isobutylene rubber, acrylic rubber, and urethane rubber, but is not limited thereto.

The silicone resin may be a liquid siloxane polymer. The siloxane polymer is a dimethyl silicone oil, methylphenyl silicone oil, diphenyl silicone oil, polysiloxane, a diphenyl siloxane copolymer, methyl hydrogen silicone oil, methyl hydroxyl silicone oil, fluoro silicone oil, polyoxyether copolymer, amino-modified silicone oil, epoxy-modified silicone oil, carboxyl-modified silicone oil, carbonyl-modified silicone oil, methacryl-modified silicone oil, mercapto-modified silicone oil, polyether-modified silicone oil, methylstyryl silicone oil, alkyl-modified silicone oil or fluoro-modified silicone oil, but is not limited thereto.

The epoxy resin may be bisphenol A, bisphenol F, bisphenol AD, bisphenol S, hydrogenated bisphenol A, or combinations thereof, but are not limited thereto.

The thermosetting resin may additionally be used as a catalyst or a curing agent according to a thermosetting mechanism. In addition, preferably, the catalyst may be a platinum catalyst, and the curing agent may be an organic peroxide or an amine having a liquid aromatic ring at room temperature.

Also preferably, the organic peroxide is 2,4-dichlorobenzoyl peroxide, benzoyl peroxide, dicumyl peroxide, di-tertiary- It may be butyl perbenzoate (methyl-tert-butylperbenzoate) or 2,5-bis (tert-butylperoxy) benzoate (2,5-bis (tert-butylperoxy) benzoate), but is not limited thereto.

The amine having a liquid aromatic ring at the above or at room temperature is at least one or a combination of them selected from a group of diethyltoluenediamine, 1-methyl-3,5-diethyl-2,4-diaminobenzene, 1-methyl-3,5-diethyl-2,6-diaminobenzene, 1,3,5-triethyl-2,6-diaminobenzene, 3,3′-diethyl-4,4-diaminodiphenylmethane, and 3,3′,5,5′-tetramethyl-4,4′-diaminodiphenylmethane, but is not limited thereto.

The wax-based compound may be in a solid state at room temperature, but may have a melting point of 40° C. to 150° C., and may be a resin having a molecular weight of 100 to 100,000. In addition, it may be preferably petroleum wax, animal natural wax, vegetable natural wax, or synthetic wax, but is not limited thereto.

The second dispersion medium serves to disperse the encapsulated metal halide perovskite, and preferably may be a material having low oxygen and moisture permeability.

In addition, preferably, the above secondary dispersion medium may be characterized by photocurable polymerization compounds.

For example, the second dispersion medium may be an acrylic resin.

The photocurable polymerization compound may be a photopolymerizable monomer, a photopolymerizable oligomer, or a combination thereof. The photopolymerizable monomer and the photopolymerizable oligomer are not particularly limited as long as they contain at least one of a carbon-carbon double bond and a triple bond and are polymerizable by light.

In particular, when the second dispersion medium is an acrylic resin, the photopolymerizable monomer and the photopolymerizable oligomer may be an acrylic monomer and an acrylic oligomer, respectively.

The acrylic oligomer may be an epoxy acrylic resin. The epoxy acrylic resin may be a resin in which an epoxide group of the epoxy resin is substituted with an acrylate group. Like the epoxy resin, the epoxy acrylate resin may have a low moisture permeability and air permeability due to its main chain properties.

Also preferably, the epoxy acrylate resin is bisphenol-A glycerolate diacrylate, bisphenol-A ethoxylate diacrylate, bisphenol-A glycerolate dimethacrylate, bisphenol-A ethoxylate dimethacrylate, or a combination thereof, but is not limited thereto.

The acrylic monomer may be an unsaturated group-containing acrylic monomer, an amino group-containing acrylic monomer, an epoxy group-containing acrylic monomer, a carboxylic acid group-containing acrylic monomer, or combinations thereof, but is not limited thereto.

The unsaturated group-containing acrylic monomer is at least one or a combination of them selected from a group of methyl acrylate, methyl methacrylate, ethyl acrylate, ethyl methacrylate, n-propyl acrylate, n-propyl methacrylate, i-propylacrylate, i-propyl methacrylate, n-butylacrylate, n-butyl methacrylate, i-butylacrylate, i-butyl methacrylate, sec-butyl acrylate, sec-butyl methacrylate, t-butyl acrylate, t-butyl methacrylate, 2-hydroxyethyl acrylate, 2-hydroxyethyl methacrylate, 2-hydroxypropyl acrylate, 2-hydroxypropyl methacrylate, 3-hydroxypropyl acrylic 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate (4-hydroxybutyl acrylate), 4-hydroxybutyl methacrylate, allyl acrylate, allyl methacrylate, benzyl acrylate, benzyl methacrylate methacrylate, cyclohexyl acrylate, cyclohexyl methacrylate, phenyl acrylate, phenyl methacrylate, 2-methoxyethyl acrylate, 2-methoxyethyl methacrylate, 2-phenoxyethyl acrylate, 2-phenoxyethyl methacrylate, methoxydiethylene methoxydiethyleneglycol acrylate, methoxydiethyleneglycol methacrylate, methoxytriethyleneglycol acrylate, methoxytriethyleneglycol methacrylate, Methoxy propyleneglycol acrylate, methoxypropyleneglycol methacrylate, methoxydipropylene glycol acrylate, methoxydipropyleneglycol methacrylate, isobornyl acrylate, isobornyl methacrylate, dicyclopentaacrylate, dicyclopentamethacrylate, 2-hydroxy-3-phenoxypropyl acrylate, 2-hydroxy 2-hydroxy-3-phenoxypropyl methacrylate, glycerol monoacrylate, glycerol monomethacrylate, but are not limited thereto.

The amino group-containing acrylic monomer is at least one or a combination of them selected from a group of 2-aminoethyl acrylate, 2-aminoethyl methacrylate, 2-dimethylaminoethyl acrylate, 2-dimethylaminoethyl methacrylate, 2-aminopropyl acrylate, 2-aminopropyl methacrylate, 2-dimethylaminopropyl acrylate, 2-dimethylaminopropyl methacrylate, 3-aminopropyl acrylate, 3-aminopropyl methacrylate, 3-dimethylaminopropyl acrylate, 3-dimethylaminopropyl methacrylate, but is not limited thereto.

The epoxy group-containing acrylic monomer is at least one or a combination of them selected from a group of glycidyl acrylate, glycidyl methacrylate, glycidyloxyethyl acrylate, glycidyloxyethyl methacrylate, glycidyloxypropyl acrylate, glycidyloxypropyl methacrylate, glycidyloxybutyl acrylate, and glycidyloxybutyl methacrylate, but is not limited thereto.

The carboxylic acid group-containing acrylic monomer is at least one or a combination of them selected from a group of acrylic acid, methacrylic acid, acrylo oxyacetic acid, methacrylo oxyacetic acid, acryloyl oxypropionic acid, methacryloyl oxypropionic acid, acrylo oxybutric acid, and methacrylo oxybutric acid, but is not limited thereto.

In addition, the photopolymerizable monomer may be a photoresist material. The photoresist material may be a silicone or epoxy material.

The photoresist material may be a commercial photoresist. The commercial photoresist materials may be AZ 5214E PR, AZ 9260 PR from AZ AD Promoter-K (HMDS); AZ nLOF 2000 Series, AZ LOR-28 PR, AZ 10xT PR, AZ 5206-E, AZ GXR-601, AZ 04629 from AZ Electronics Materials; SU-8, 950 PMMA, and 495 PMMA from MICROCHEM; S1800 from micropossit; DNR-L300, DSAM, DPR, DNR-H200, and DPR-G from Dongjin Semichem; or CTPR-502 from Kotem, but is not limited thereto.

In addition, preferably, the second dispersion medium may further include a photoinitiator.

The kind of the photoinitiator is not particularly limited and may be appropriately selected. Preferably, the photoinitiator is at least one or a combination of them selected from a group of a triazine-based compound, acetophenone-based compound, benzophenone-based compound, thioxanthone-based compound, benzoin-based compound, oxime compounds, carbazole compounds, diketone compounds, sulfonium borate compounds, diazo compounds, and nonimidazolium compounds, but is not limited thereto.

Examples of the triazine-based compound are 2,4,6-trichloro-s-triazine, 2-phenyl-4,6-bis (trichloromethyl)-s-triazine, 2-(3′,4′-dimethoxy styryl)-4,6-bis(trichloromethyl)-s-triazine, 2-(4′-methoxy naphthyl)-4,6-bis(trichloromethyl))-s-triazine, 2-(p-methoxyphenyl)-4,6-bis(trichloro methyl)-s-triazine, 2-(p-tolyl)-4,6-bis(trichloromethyl)-s-triazine, 2-biphenyl-4,6-bis(trichloromethyl)-s-triazine, bis(trichloromethyl)-6-styryl-s-triazine (bis(trichloro methyl)-6-styryl-s-triazine), 2-(naphtho-1-yl)-4,6-bis(trichloromethyl)-s-triazine, 2-(4-methoxy naphtho-1-yl)-4,6-bis(trichloromethyl)-s-triazine, 2,4-Trichloromethyl(piperonyl)-6-triazine, or 2,4-(trichloromethyl(4′-methoxy styryl)-6-Triazine, but is not limited thereto.

Examples of the acetophenone-based compound are 2,2-diethoxy acetophenone, 2,2,-dibutoxy acetophenone, 2-2-hydroxy-2-methyl propiophenone, pt-butyl trichloro acetophenone, pt-butyl dichloro acetophenone, 4-Chloro acetophenone, 2,2-dichloro-4-phenoxy acetophenone, 2-methyl-1-(4-(methylthio)phenyl)-2-morpholino propan-1-one, or 2-benzyl-2-dimethylamino-1-(4-morpholinophenyl)-butan-1-one, but is not limited thereto.

Examples of the benzophenone-based compound include benzophenone, benzoyl benzoate, methyl 2-benzoylbenzoate, 4-phenyl benzophenone, hydroxy benzophenone, benzophenone acrylate, 4,4-bis (dimethylamino) benzophenone, 4,4-dichlorobenzophenone, 3,3-dimethyl-2-methoxy benzophenone, or the like, but is not limited thereto.

Examples of the thioxanthone-based compound include thioxanthone, 2-methyl thioxantone, isopropyl thioxantone, 2,4-diethyl thioxantone, 2,4-diisopropyl thioxantone, or 2-chloro thioxantone, but is not limited thereto.

Examples of the benzoin-based compound are benzoine, benzoine methyl ether, benzoine ethyl ether, benzoine isopropyl ether, benzoine isobutyl ether, or benzyl dimethyl ketal, but is not limited thereto.

Example of the oxime compound are 2-(o-benzoyloxime)-1-[4-(phenylthio)phenyl]-1,2-octanedione or 1-(o-acetyloxime)-1-[9-ethyl-6-(2-methylbenzoyl)-9H-carbazol-3-yl]ethanone, but is not limited thereto.

Meanwhile, the second dispersion medium may further include a crosslinking agent for crosslinking.

Preferably, the crosslinking agent is at least one or a combination of them selected from a group of ethylene glycol (di(metha)acrylate, polyethyleneglycol di(metha)acrylate, trimethylolpropane di(metha)acrylate, trimethylolpropane tri(metha)acrylate, pentaerythritol tri(metha)acrylate, pentaerythritol tetra(metha)acrylate, 2-trisacrylo oxymethylethylpthalic acid, propyleneglycol di(metha)acrylate, polypropyleneglycol di(metha)acrylate, dipentaerythritol penta(metha)acrylate, and dipentaerythritol hexa(metha)acrylate), but is not limited thereto.

In addition, when the metal halide perovskite-polymer composite is manufactured in the form of a film attached to a specific substrate, the second dispersion medium may further include a polymer binder. The polymeric binder may serve to improve adhesion between the substrate and the metal halide perovskite-polymer composite.

The substrate 10 serves as a support for a light-emitting device, and may be a transparent material. In addition, the substrate 10 may be a flexible material or a hard material, and preferably may be a flexible material.

The material of the substrate 10 is glass, sapphire, quartz, silicon, polyethylene terephthalate (PET), polystyrene (PS), polyimide (polyimide, PI), polyvinyl chloride (PVC), polyvinylpyrrolidone (PVP), or polyethylene (PE), but is not limited thereto.

The polymer binder may be an acrylic polymer binder, a cardo polymer binder, or a polymer of a combination thereof, but is not limited thereto.

The acrylic polymer binder may be a copolymer of a first unsaturated monomer containing a carboxyl group and a second unsaturated monomer copolymerizable therewith. The first unsaturated monomer may be a carboxylic acid vinyl ester compound such as acrylic acid, maleic acid, methacrylic acid, vinyl acetate, itaconic acid, 3-butenoic acid, fumaric acid, vinyl benzoate, or a combination thereof, but is not limited thereto.

The second unsaturated monomer is at least one or a combination of them selected from a group of an alkenyl aromatic compound, an unsaturated carboxylic acid ester compound, an unsaturated carboxylic acid amino alkyl ester compound, an unsaturated carboxylic acid glycidyl ester compound, a vinyl cyanide compound, and a hydroxy alkyl acrylate, but is not limited thereto.

Also preferably, the second unsaturated monomer is at least one or a combination of them selected from a group of styrene, α-methylstyrene, vinyltoluene, vinylbenzylmethylether, methylacrylate, ethylacrylate, butylacrylate, benzyl acrylate, cyclohexylacrylate, phenyl acrylate, 2-aminoethylacrylate, 2-dimethylaminoethylacrylate, N-phenylmaleimide, N-benzylmaleimide, N-alkylmaleimide, 2-dimethylaminoethylmethacrylate, acrylonitrile, and unsaturated amide compounds such as glycidyl acrylate and acrylamide, 2-hydroxy ethyl acrylate, and 2-hydroxy butyl acrylate, but is not limited thereto.

The acrylic polymer binder is at least one or a combination of them selected from a group of a methacrylic acid/benzyl methacrylate copolymer, methacrylic acid/benzyl methacrylate/styrene copolymer, methacrylic acid/benzyl methacrylate/2-hydroxyethyl methacrylate copolymer, and methacrylic acid/benzyl methacrylate/styrene/2-hydroxyethyl methacrylate copolymer, but is not limited thereto.

The metal halide perovskite-polymer composite film may further include a light diffusing agent. The light diffusing agent may be metal oxide particles, metal particles, or combinations thereof, but is not limited thereto. The light diffusing agent may serve to increase the probability of encountering the metal halide perovskite with the incident light of the composition by increasing the refractive index of the composition.

The light diffusing agent may include inorganic oxide particles such as alumina, silica, zirconia, titania, and zinc oxide, or metal particles such as gold, silver, copper, and platinum, but is not limited thereto. A dispersant may be added to increase the dispersibility of the light diffusing agent.

Hereinafter, a method of manufacturing a metal halide perovskite wavelength converting body having a structure in which capsulated metal halide perovskite particles capsulated are dispersed in the matrix resin will be described.

The first dispersion medium and the second dispersion medium may be cured sequentially.

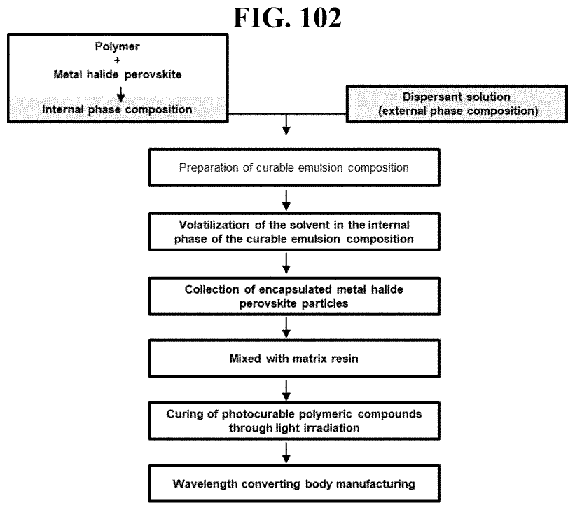

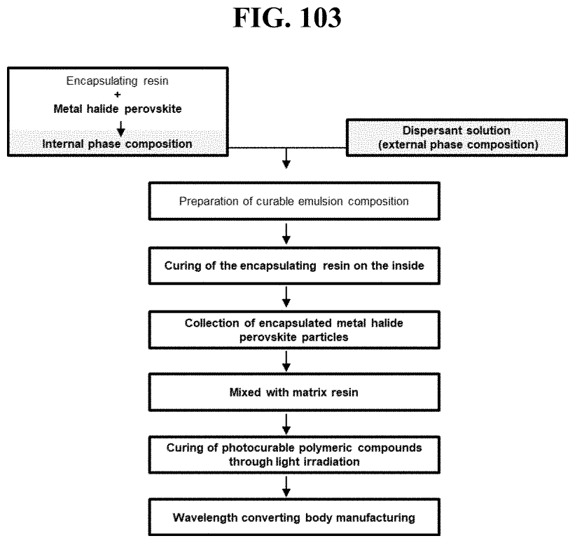

FIGS. 102 and 103 are schematic diagrams showing a method of manufacturing a metal halide perovskite wavelength converting body having a structure in which encapsulated particles are dispersed according to an embodiment of the present invention.

Referring to FIGS. 102 and 103, a method of manufacturing a metal halide perovskite wavelength converting body is characterized with having a structure in which encapsulated particles are dispersed according to an embodiment of the present invention uses a curable emulsion composition. As described above, the emulsion refers to a solution in which a liquid droplet is uniformly dispersed in different types of droplets that are not miscible (immiscible). In the present specification, the fine droplets discontinuously present in the curable emulsion composition are defined as “inner phase”, and the composition continuously present in the emulsion composition in addition to the inner phase is defined as “outer phase”.

Referring to FIGS. 102 and 103, first, a solution capable of forming an inner phase is prepared.

Referring to FIG. 103, the above inner phase is for the manufacture of metal halide perovskites encapsulated by the first dispersion medium and may be characterized by the inclusion of metal halide perovskites and polymers.

The metal halide perovskite may be a material having a three-dimensional crystal structure, a two-dimensional crystal structure, a one-dimensional crystal structure, or a zero-dimensional crystal structure.

The metal halide perovskite is ABX₃(3D), A₄BX₆(0D), AB₂X₅(2D), A₂BX₄(2D), A₂BX₆(0D), A₂B⁺B³⁺X₆(3D), A₃B₂X₉(2D) or Aₙ₋₁BₙX₃ₙ₊₁ (quasi-2D) (n is an integer between 2 and 6) may be included. A is a monovalent cation, B is a metal material, and X may be a halogen element. The quasi-2D structure may be a Ruddlesden-Popper phase or a Dion-Jacobson phase.

The monovalent cation may be a monovalent organic cation or an alkali metal. For example, the monovalent organic cation is organic ammonium (RNH₃⁺), organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺ or (CₙF₂ₙ₊₁NH₃)₂⁺ (x, n is an integer of 1 or more, R=hydrocarbon derivative, alkyl, alkyl fluoride derivatives, H, F, Cl, Br, I), or combinations thereof, but are not limited thereto. The alkali metal may be Li⁺, Na⁺, K⁺, Rb⁺, Cs⁺, Fr⁺, or combinations thereof, but is not limited thereto.

In addition, preferably, the organic cation is at least one or a combination of them selected from a group of acetamidinium, azaspironanium, benzene diammonium, benzylammonium, butanediammonium, iso-butylammonium, n-butylammonium, t-butylammonium, cyclohexylammonium, cyclohexylmethylammonium, diazobicyclooctanedinium, diethylammonium, N,N-diethylpropane diammonium, dimethylammonium, N,N-dimethylethane diammonium, dimethylpropane diammonium, dodecylammonium, ethanediammonium, ethylammoniuium, 4-fluoro-benzylammonium, 4-fluoro-phenylethylammonium, 4-fluoro-phenylammonium, formamidinium, guanidinium, hexanediammonium, hexylammonium, imidazolium, 2-methoxyethylammonium, 4-methoxy-phenlylethylammonium, 4-methoxy-phenylammonium, methylammonium, morpholinium, octylammonium, pentylammonium, piperazinediium, piperidinium, propanediammonium, iso-propylammonium, di-iso-propylammonium, n-propylammonium, pyridinium, 2-pyrrolid-1ium-1-yethylammonium, pyrrolidinium, quinclidin-1-ium, 4-trifluoromethyl-benzylammonium, and 4-trifluoromethyl ammonium, but is not limited thereto.

B may be a divalent transition metal, a rare earth metal, an alkaline earth metal, a monovalent metal, a combination of a trivalent metal, an organic substance (a monovalent, divalent, or trivalent cation), or a combination thereof. Also, preferably, the divalent transition metal, rare earth metal, and alkaline earth metal are Be²⁺, Mg²+, Ca²⁺, Sr²⁺, Ba²⁺, Ra²⁺, Mn²⁺, Fe²⁺, Co²⁺, Ni²⁺, Cu²⁺, Zn²⁺, Ru²⁺, Pd²⁺, Cd²⁺, Pt²⁺, Hg²⁺, Ge²⁺, Sn²⁺, Pb²⁺, Se²⁺, Te²⁺, Po²⁺, Bi²⁺, Eu²⁺, No²⁺, or combinations thereof, but are not limited thereto. The monovalent metal may be Li⁺, Na⁺, K⁺, Rb⁺, Cs⁺, Fr⁺, Ag⁺, Hg⁺, Ti⁺, or combinations thereof, and the trivalent metal is Cr³⁺, Fe³⁺, Co³⁺, Ru³⁺, Rh³⁺, Ir³⁺, Au³⁺, Al³⁺, Ga³⁺, In³⁺, Ti³⁺, As³⁺, Sb³⁺, Bi³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Ac³⁺, Lu³⁺, Bk³⁺, Cf³⁺, Es³⁺, Fm³⁺, Md³⁺, Lr³⁺, or combinations thereof.

In addition, X may be F⁻, Cl⁻, Br⁻, I⁻, At⁻, or combinations thereof.

The metal halide may be in the form of nanocrystal particles.

The metal halide perovskite nanocrystal may further include a plurality of organic ligands 20 surrounding the metal halide perovskite nanocrystal 10. The organic ligands 20 are a material used as a surfactant, and may include an alkyl halide, an amine ligand, a carboxylic acid or a phosphonic acid. Detailed descriptions of the alkyl halide, amine ligand, carboxylic acid, and phosphonic acid are as described in <Metal Halide perovskite nanocrystal particles>.

In addition, the form of the metal halide perovskite nanocrystal may be a form generally used in the art. The shape of the metal halide perovskite nanocrystal may be a 0-dimensional, 1-dimensional or 2-dimensional shape. As an example, it may be in the form of a sphere, an ellipsoid cube, a hollow cube, a pyramid, a cylinder, a cone, an elliptic column, hollow sphere, Janus particle, prism, multipod, polyhedron, nanotube, nanowire, nanofiber, or nanoplatelet.

Preferably, the polymer may be characterized in that it has a polar group in at least one of a backbone or a side chain. The polar group may be adsorbed on the surface of the metal halide perovskite to increase the dispersibility of the metal halide perovskite.

In the case of having a polar group in the main chain of the polymer, the main chain of the polymer may be characterized in that it includes polyester, ethyl cellulose, polyvinylpyridine, or combinations thereof, but is not limited thereto.

In the case of having a polar group in the side chain of the polymer, the polar group may be characterized in that it contains an oxygen component, preferably the polar group —OH, —COOH, —COH, —CO—, —O— or combinations thereof, but is not limited thereto.

In addition, it is preferable that the polymer has a number average molecular weight of about 300 g/mol to 100,000 g/mol. If the number average molecular weight of the polymer is out of the above range and is less than 300 g/mol, the distance between the quantum dots in the quantum dot-polymer bead is insufficient, so that the luminescence efficiency may decrease, and if it exceeds 100,000 g/mol, the bead size becomes excessively large. Defects may occur in the film forming process.

Referring to FIG. 103, the above inner phase is for the manufacture of metal halide perovskite particles encapsulated by the first dispersion medium encapsulating resin, which can be characterized by the inclusion of metal halide perovskite and encapsulating resin.

The encapsulating resin encapsulates multiple metal halide perovskites to form a uniform dispersion within the matrix resin, and is not limited to materials that can uniformly distribute metal halides with hydrophilic properties.

Meanwhile, the encapsulating resin may be a thermosetting resin or a wax-based compound.

Preferably, the thermosetting resin may be a liquid resin that exists as a liquid at room temperature. In addition, preferably, the thermosetting resin may include a thermosetting resin that is cured by heat or a phase-mixed curable resin that is cured by heat, but is not limited thereto.

In addition, preferably, the thermosetting resin may be characterized in that thermal curing occurs or is accelerated at a temperature of 100° C. When the temperature at which thermal curing occurs or is accelerated exceeds 100° C., the metal halide perovskite crystal structure vulnerable to heat may be decomposed.

Specifically, the thermosetting resin is at least one or a combination of them selected from a group of a silicone resin, epoxy resin, petroleum resin, phenol resin, urea resin, melamine resin, unsaturated polyester resin, amino resin, butyl rubber, isobutylene rubber, acrylic rubber, and urethane rubber, but is not limited thereto.

The silicone resin may be a liquid siloxane polymer. The siloxane polymer may be a dimethyl silicone oil, methylphenyl silicone oil, diphenyl silicone oil, polysiloxane, a diphenyl siloxane copolymer, methyl hydrogen silicone oil, methyl hydroxyl silicone oil, fluoro silicone oil, polyoxyether copolymer, amino-modified silicone oil, epoxy-modified silicone oil, carboxyl-modified silicone oil, carbonyl-modified silicone oil, methacryl-modified silicone oil modified silicone oil, mercapto-modified silicone oil, polyether-modified silicone oil, methylstyryl silicone oil, alkyl-modified silicone oil modified silicone oil or fluoro-modified silicone oil, but is not limited thereto.

The epoxy resin may be bisphenol A, bisphenol F, bisphenol AD, bisphenol S, hydrogenated bisphenol A, or combinations thereof, but are not limited thereto.

The thermosetting resin may additionally be used as a catalyst or a curing agent according to a thermosetting mechanism. In addition, preferably, the catalyst may be a platinum catalyst, and the curing agent may be an organic peroxide or an amine having a liquid aromatic ring at room temperature.

The amine having a liquid aromatic ring at the above or at room temperature is diethyltoluenediamine, 1-methyl-3,5-diethyl-2,4-diaminobenzene, 1-methyl-3,5-diethyl-2,6-diaminobenzene, 1,3,5-triethyl-2,6-diaminobenzene, 3,3-diethyl-4,4-diaminodimethylphenylmethane, 3,3,5,5-tetramethyl-4,4-diaminodiphenylmethane or combination thereof, but is not limited thereto.

The wax-based compound may be in a solid state at room temperature, but may have a melting point of 40° C. to 150° C., and may be a resin having a molecular weight of 100 to 100,000. In addition, it may be preferably petroleum wax, animal natural wax, vegetable natural wax, or synthetic wax, but is not limited thereto.

The inner phase may include a metal halide perovskite and a solvent capable of dispersing the encapsulating resin. The solvent is preferably a non-polar solvent, but is not limited thereto. For example, the non-polar solvent is dichloroethylene, trichloroethylene, chloroform, chlorobenzene, dichlorobenzene, styrene, dimethylformamide, dimethylsulfoxide, xylene, toluene, cyclohexane, or isopropylalcohol, but is not limited thereto.

After the inner phase solution is formed, the inner phase solution is mixed with a dispersant solution to form a curable emulsion composition. The solvent of the dispersant solution is not limited as long as it can form an emulsion with the inner phase solution, and may preferably be a polar solvent. Specifically, the polar solvent is acetic acid, acetone, acetonitrile, dimethylformamide, gamma butyrolactone, N-methylpyrrolidone, ethanol, or dimethylsulfoxide, but is not limited thereto. The dispersant solution forms an outer phase in the curable emulsion composition formed by mixing.

If the above encapsulation resin is a wax-based compound, it may be converted to liquid phase by applying heat above the melting point of the wax-based compound in order to apply it to the curable emulsion composition. The melting point of the waxy compound may vary depending on the type of waxy compound, but preferably the melting point of the waxy compound below 100° C. If the melting point exceeds 100° C. to apply to curable emulsion compound, the heat-vulnerable metal halide perovskite crystal structure may be decomposed.

The curable emulsion composition may be formed while stirring with a magnetic stirrer, and preferably, the stirring speed may be 500 rpm or more. When the stirring speed is out of the above range and is less than 500 rpm, droplets of the inner phase solution may be aggregated and then the inner phase solution and the dispersant solution can be separated from each other.

When the curable emulsion composition is formed by the above method, the metal halide perovskite can be encapsulated in various ways depending on the composition of the inner phase. The obtained encapsulated particles may be collected after removing the solvent, which can be followed by a subsequent encapsulation process using a matrix resin and an encapsulating resin.

Referring to FIG. 102, when the inner phase includes metal halide perovskite and polymer, the solvent of the inner phase may be volatilized. Volatilizing the solvent in the inner phase may be performed by a method of decompressing the curable emulsion composition. When the solvent in the inner phase is removed by the above process, the metal halide perovskite may be encapsulated by a polymer contained in the inner phase. The first dispersion medium becomes the polymer.

Referring to FIG. 103, metal halide perovskite can be encapsulated in a variety of ways depending on the type of encapsulating resin, if the above inner phase includes metal halide perovskite and encapsulating resin. The first dispersion medium may be formed by curing the above encapsulating resin.

In particular, if the encapsulating resin is thermosetting resin, the encapsulated particle may be manufactured by thermal curing the encapsulating resin inside the curable emulsion composition by applying heat to the curable emulsion composition. The temperature of thermal curing and the type of thermosetting resin may be selected, preferably not more than 100° C. If the temperature of thermal curing exceeds 100° C., the metal halide perovskite crystal structure may be decomposed.

When the encapsulating resin is a wax-based compound, the metal halide perovskite may be encapsulated without heating which is used to form a curable emulsion composition.

Referring to FIG. 103, after forming the encapsulated metal halide perovskite particles by the above process, the solvent in the droplet may be removed and the metal halide perovskite particles can be collected.

Thereafter, the obtained encapsulated metal halide perovskite particles are mixed with a matrix resin to prepare a metal halide perovskite particle-matrix resin mixture. Preferably, the matrix may be a material having low oxygen and moisture permeability. In addition, preferably, the matrix resin may be a photocurable polymerization compound.

For example, the photocurable polymerization compound may be an acrylic resin.

The photocurable polymerization compound may be a photopolymerizable monomer, a photopolymerizable oligomer, or a combination thereof. The photopolymerizable monomer and the photopolymerizable oligomer are not particularly limited as long as they contain at least one of a carbon-carbon double bond and a triple bond and are polymerizable by light.

In particular, when the photocurable polymerization compound is an acrylic resin, the photopolymerizable monomer and the photopolymerizable oligomer may be an acrylic monomer and an acrylic oligomer, respectively.

The acrylic oligomer may be an epoxy acrylic resin. The epoxy acrylic resin may be a resin in which an epoxide group of the epoxy resin is substituted with an acrylate group. Like the epoxy resin, the epoxy acrylate resin may have low moisture permeability and air permeability due to its main chain properties.

Also preferably, the epoxy acrylate resin is bisphenol-A glycerolate diacrylate, bisphenol-A ethoxylate diacrylate, bisphenol A glycerolate dimethacrylate, bisphenol A ethoxylate dimethacrylate, or a combination thereof, but is not limited thereto.

The acrylic monomer may be an unsaturated group-containing acrylic monomer, an amino group-containing acrylic monomer, an epoxy group-containing acrylic monomer, a carboxylic acid group-containing acrylic monomer, or combinations thereof, but is not limited thereto.

The unsaturated group-containing acrylic monomer may be methylacrylate, methyl methacrylate, ethylacrylate, ethyl methacrylate, n-propylacrylate, n-propyl methacrylate, i-propylacrylate, i-propyl methacrylate, n-butylacrylate, n-Butyl methacrylate, i-butylacrylate, i-butyl methacrylate, sec-butylacrylate, sec-butyl methacrylate, t-butylacrylate, t-butyl methacrylate, 2-hydroxyethyl acrylate, 2-hydroxy 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate, cyclohexyl acrylate, cyclohexyl methacrylate, phenyl acrylate, phenyl methacrylate, 2-methoxyethyl acrylate, 2-methoxyethyl methacrylate, 2-phenoxyethyl acrylate, 2-phenoxyethyl methacrylate, methoxydiethylene methoxydiethyleneglycol acrylate, methoxydiethyleneglycol methacrylate, methoxytriethyleneglycol acrylate, methoxytriethyleneglycol methacrylate, methoxy propyleneglycol acrylate, methoxypropyleneglycol acrylate, methoxypropyleneglycol methacrylate, methoxydipropyleneglycol acrylate, methoxydipropyleneglycol methacrylate, isoboronyl acrylate, isoboronyl methacrylate, dicyclopenta acrylate, dicyclopenta methacrylate, 2-hydroxy-3-phenoxypropyl acrylate, 2-hydroxy-3-phenoxypropyl methacrylate, glycerol monoacrylate, glycerol monomethacrylate, or a combination thereof, but is not limited thereto.

The amino group-containing acrylic monomer may be 2-aminoethyl acrylate, 2-aminoethyl methacrylate, 2-dimethylaminoethyl acrylate, and 2-dimethyl 2-dimethylaminoethyl methacrylate, 2-aminopropyl acrylate, 2-aminopropyl methacrylate, 2-dimethylaminopropyl acrylate acrylate, 2-dimethylaminopropyl methacrylate, 3-aminopropyl acrylate, 3-aminopropyl methacrylate, 3-dimethylaminopropyl acrylate, 3-dimethylaminopropyl methacrylate, or combination thereof, but is not limited thereto.

The epoxy group-containing acrylic monomer may be glycidyl acrylate, glycidyl methacrylate, glycidyloxyethyl acrylate, glycidyloxyethyl methacrylate, glycidyloxypropyl acrylate, glycidyloxypropyl methacrylate, glycidyloxybutyl acrylate, glycidyloxybutyl methacrylate), or combinations thereof, but is not limited thereto.

The carboxylic acid group-containing acrylic monomers may be acrylic acid, methacrylic acid, acryloyl oxyacetic acid, methacryloyl oxyacetic acid, and acryloyl oxypropionic acid, methacryloyl oxypropionic acid, acryloyl oxybutric acid, methacryloyl oxybutric acid, or combinations thereof, but are limited thereto.

In addition, the photopolymerizable monomer may be a photoresist material. The photoresist material may be a silicone or epoxy material.

The photoresist material may be a commercial photoresist. The commercial photoresist materials may be AZ 5214E PR, AZ 9260 PR, AZ AD Promoter-K (HMDS), AZ nLOF 2000 Series, AZ LOR-28 PR, AZ 10xT PR, AZ 5206-E, AZ GXR-601, AZ 04629 from AZ Electronics Materials; SU-8, 950 PMMA, and 495 PMMA from MICROCHEM; S1800 from micropossit; DNR-L300, DSAM, DPR, DNR-H200, and DPR-G from Dongjin Semichem; CTPR-502 from Kotem, but is not limited thereto.

The mixture may further include a photoinitiator for photocuring according to the type of the photocurable polymer compound.

Example of the benzophenone-based compound includes benzophenone, benzoyl benzoate, methyl 2-benzoylbenzoate, 4-phenyl benzophenone, hydroxybenzophenone, acrylated benzophenone acrylate, 4,4-bis(dimethylamino)benzophenone, 4,4-dichlorobenzophenone, 3,3-dimethyl-2-methoxy benzophenone, or the like, but are not limited thereto.

Example of the thioxanthone-based compound includes thioxantone, 2-methyl thioxantone, isopropyl thioxantone, and 2,4-diethyl thioxantone, 2,4-diiospropyl thioxantone, 2-chloro thioxantone, or the like, but is not limited thereto.

Example of the benzoin-based compound includes benzoine, benzoine methyl ether, benzoine ethyl ether, benzoine isopropyl ether, benzoine isobutyl ether, benzyl dimethyl ketal, or the like, but is not limited thereto.

Example of the oxime compound is 2-(o-benzoyloxime)-1-[4-(phenylthio)phenyl]-1,2-octanedione or 1-(o-acetyloxime)-1-[9-ethyl-6-(2-methylbenzoyl)-9H-carbazol-3-yl]ethanone.

Meanwhile, the mixture may further include a crosslinking agent for crosslinking.

Preferably, the crosslinking agent is ethyleneglycol di(meth)acrylate, polyethyleneglycol di(meth)acrylate, trimethylolpropane di(metha)acrylate, pentaerythritol tri(metha)acrylate, pentaerythritol tetra(meth)acrylate, 2-trisacrylo oxymethylethylpthalic acid, propylene glycol di(metha)acrylate, polypropyleneglycol di(metha)acrylate, dipentaerythritol penta(metha)acrylate, dipentaerythritol hexa(metha)acrylate, or a combination thereof, but is not limited thereto.

After preparing the mixture, the mixed solution may be cured to obtain a wavelength converting body having a structure in which a metal halide perovskite encapsulated in a second dispersion medium formed by curing the matrix resin is dispersed.

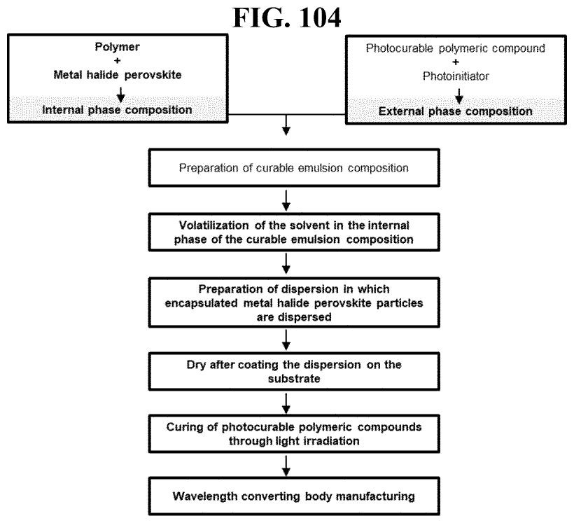

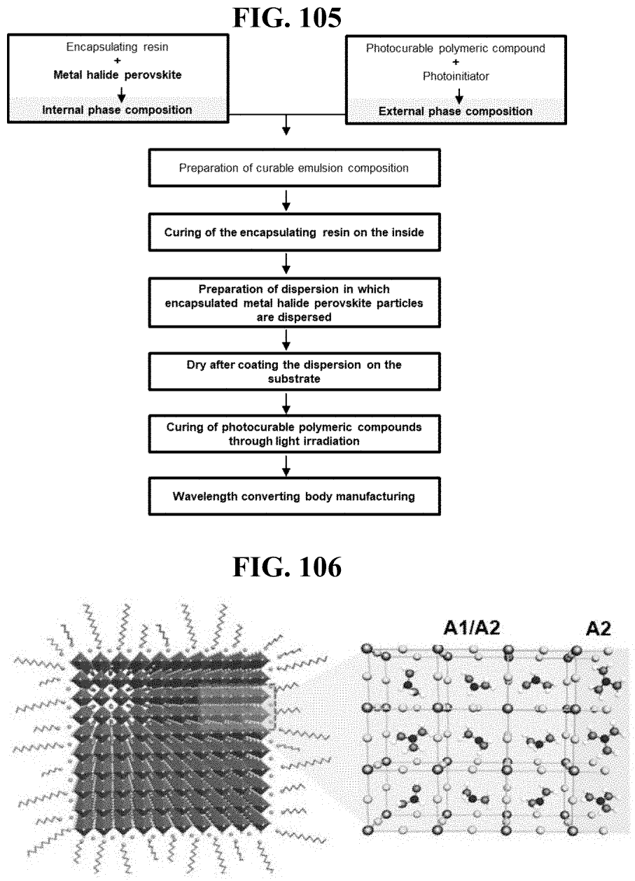

FIGS. 104 and 105 are schematic diagrams showing a method of manufacturing a metal halide perovskite wavelength converting body having a structure in which encapsulated particles are dispersed according to another embodiment of the present invention.

Referring to FIGS. 104 and 105, the manufacturing method of metal halide perovskite wavelength converting body with encapsulated particles dispersed according to the example of the present invention is characterized by the use of curable emulsion composition, without an additional process to collect encapsulated metal halide perovskites.

Since the description of the metal halide perovskite is the same as described above, a detailed description will be omitted.

The metal halide may be in the form of nanocrystal.

The metal halide perovskite nanocrystal may further include a plurality of organic ligands 20 surrounding the metal halide perovskite nanocrystal 10. The organic ligands 20 are a material used as a surfactant, and may include an alkyl halide, an amine ligand, and a carboxylic acid or a phosphonic acid.

Examples of the available alkyl halide, amine ligand, carboxylic acid, or phosphonic acid are the same as described above, and thus are omitted to avoid redundant description.

In addition, the form of the metal halide perovskite nanocrystal may be a form generally used in the art. The shape of the metal halide perovskite nanocrystal may be a 0-dimensional, 1-dimensional, or 2-dimensional shape. As an example, It may be in the form of a sphere, an ellipsoid, a hollow cube, a pyramid, a cylinder, a cone, an elliptic column, hollow sphere, Janus particle, prism, multipod, polyhedron, nano tube, nano wire, nano fiber or nanoplatelet.

Referring to FIGS. 104 and 105, first a solution that can form an inner phase is prepared.

Referring to FIG. 104, the above inner phase is intended to manufacture particles where metal halide perovskites are encapsulated by the first dispersion medium, and may be characterized by the inclusion of metal halide perovskite and polymers.

Preferably, the polymer may be characterized in that it has a polar group in at least one of a backbone or a side chain. The polar group may be adsorbed on the surface of the metal halide perovskite to increase the dispersibility of the metal halide perovskite.

In the case of having a polar group in the main chain of the polymer, the main chain of the polymer may be characterized in that it includes polyester, ethyl cellulose, polyvinylpyridine, or combinations thereof, but is not limited thereto.

When having a polar group in the side chain of the polymer, the polar group may be characterized in that it contains an oxygen component, preferably the polar group —OH, —COOH, —COH, —CO—, —O— or combination thereof, but is not limited thereto.

Furthermore, it is recommended that the polymers have a number average molecular weight of between 300 g/mol and 100,000 g/mol. If the number average molecular weight of the polymer is less than 300 g/mol outside the above range, the distance between quantum dots within the quantum dot-polymer bead may be insufficient and thus the photoluminescence quantum efficiency can be lowered, and if the bead size exceeds 100,000 g/mol, it may become too large and cause defects in the film forming process.

Referring to FIG. 105, the inner phase is intended to manufacture particles where metal halide perovskites are encapsulated by the first dispersion medium, and may be characterized that it includes metal halide perovskite and encapsulating resin.

The encapsulating resin encapsulates multiple metal halide perovskites to form a uniform dispersion within the matrix resin, and is not limited to any specific material if the resin has hydrophilic properties that can uniformly disperse the metal halides.

Meanwhile, the above encapsulating resin may be thermosetting resin, or waxy compound.

Preferably, the thermosetting resin above may be a liquid resin present as a liquid at room temperature. In addition, preferably, the above thermosetting resin may is cured by heat, or cured at room temperature whose curing can be facilitated by heat, but is not limited thereto

In addition, preferably, the above thermosetting resin may be characterized that the thermal curing occurs or can be facilitated at 100° C. Metal halide perovskite crystal structures vulnerable to heat can be decomposed if the temperature at which thermal curing occurs or is promoted exceeds 100° C. outside the above range.

Specifically, the thermosetting resin may be selected from silicone resin, epoxy resin, petroleum resin, phenolic resin, element resin, melamine resin, unsaturated polyester resin, amino resin, butyl rubber, isobutylene rubber, acrylic rubber, urethane rubber and their combination, but is not limited thereto.

The silicone resin may be a liquid siloxane polymer. The siloxane polymer is dimethyl silicone oil, methylphenyl silicone oil, diphenyl silicone oil, polysiloxane, a diphenyl siloxane copolymer, methyl Hydrogen silicone oil, methyl hydroxyl silicone oil, fluoro silicone oil, polyoxyether copolymer, amino-modified silicone oil, epoxy-modified silicone oil, carboxyl-modified silicone oil, carbonyl-modified silicone oil, methacryl-modified silicone oil, mercapto-modified silicone oil, polyether-modified silicone oil, methylstyryl silicone oil, alkyl-modified silicone oil or fluoro-modified silicone oil, but is not limited thereto.

The epoxy resin may be bisphenol A, bisphenol F, bisphenol AD, bisphenol S, hydrogenated bisphenol A, or combinations thereof, but is not limited thereto.

The thermosetting resin may additionally be used as a catalyst or a curing agent according to a thermosetting mechanism. In addition, preferably, the catalyst may be a platinum catalyst, and the curing agent may be an organic peroxide or an amine having a liquid aromatic ring at room temperature.

In addition, preferably, the organic peroxide is 2,4-dichlorobenzoyl peroxide, benzoyl peroxide, dicumyl peroxide, methyl-tert-butylperbenzoate or 2,5-bis (tert-butylperoxy) benzoate, but is not limited thereto.

The amine having a aromatic ring that is a liquid state at the above or at room temperature is diethyltoluenediamine, 1-methyl-3,5-diethyl-2,4-diaminobenzene, 1-methyl-3,5-diethyl-2,6-diaminobenzene, 1,3,5-triethyl-2,6-diaminobenzene, 3,3-diethyl-4,4-diaminodimethylphenylmethane, 3,3,5,5-tetramethyl-4,4-diaminodiphenylmethane or combinations thereof, but is not limited thereto.

The wax-based compound may be solid at room temperature, but may have a melting point of 40° C. to 150° C., and may be a resin having a molecular weight of 100 to 100,000. In addition, it may be preferably petroleum wax, animal natural wax, vegetable natural wax, or synthetic wax, but is not limited thereto.

The inner phase may include a metal halide perovskite and a solvent capable of dispersing the encapsulating resin. The solvent is preferably a non-polar solvent, but is not limited thereto. For example, the non-polar solvent is dichloroethylene, trichloroethylene, chloroform, chlorobenzene, dichlorobenzene, styrene, dimethylformamide, dimethylsulfoxide, xylene, toluene, cyclohexane, or isopropylalcohol, but is not limited thereto.

After forming the inner phase solution, the inner phase solution is mixed with a dispersant solution to form a curable emulsion composition. The solvent of the dispersant solution is not limited as long as it can form an emulsion with the inner phase solution, and may preferably be a polar solvent. Specifically, the polar solvent is acetic acid, acetone, acetonitrile, dimethylformamide, gamma butyrolactone, N-methylpyrrolidone, ethanol, or dimethylsulfoxide, but is not limited thereto. The above dispersant solution forms an outer phase in the curable emulsion composition formed by mixing.

When the encapsulating resin is a wax-based compound, in order to apply it to a curable emulsion composition, it may be converted into a liquid state by applying heat above the melting point of the wax-based compound. The melting point of the wax-based compound may vary depending on the type of the wax-based compound, but it is preferable to select a melting point of the wax-based compound having a melting point of 100° C. or less, and if the melting point exceeds 100° C., in the process of applying heat above the melting point of the wax-based compound for application to the curable emulsion composition, the metal halide perovskite crystal structure which is vulnerable to heat may be decomposed.

The curable emulsion composition may be performed while stirring with a magnetic stirrer, and preferably the stirring speed may be 500 rpm or more. When the stirring speed is out of the above range and is less than 500 rpm, droplets of the inner phase solution may be aggregated to separate the inner phase solution and the dispersant solution from each other.

Referring to FIGS. 104 and 105, the outer phase includes a photocurable compound. For example, the photocurable polymerization compound may be an acrylic resin.

The photocurable polymerization compound may be a photopolymerizable monomer, a photopolymerizable oligomer, or a combination thereof. The photopolymerizable monomer and the photopolymerizable oligomer are not particularly limited as long as they contain at least one of a carbon-carbon double bond and a triple bond, and are polymerizable by light.

In particular, when the photocurable polymerization compound is an acrylic resin, the photopolymerizable monomer and the photopolymerizable oligomer may be an acrylic monomer and an acrylic oligomer, respectively.

The acrylic oligomer may be an epoxy acrylic resin. The epoxy acrylic resin may be a resin in which an epoxide group of the epoxy resin is substituted with an acrylate group. Like the epoxy resin, the epoxy acrylate resin may have low moisture permeability and air permeability due to its main chain properties.

Also preferably, the epoxy acrylate resin is bisphenol-A glycerolate diacrylate, bisphenol-A ethoxylate diacrylate, bisphenol-A glycerolate dimethacrylate, bisphenol A ethoxylate dimethacrylate, or a combination thereof, but is not limited thereto.

The acrylic monomer may be an unsaturated group-containing acrylic monomer, an amino group-containing acrylic monomer, an epoxy group-containing acrylic monomer, a carboxylic acid group-containing acrylic monomer, or combinations thereof, but is not limited thereto.

The unsaturated group-containing acrylic monomer is methylacrylate, methyl methacrylate, ethylacrylate, ethyl methacrylate, n-propylacrylate, n-propyl methacrylate, i-propylacrylate, i-propyl methacrylate, n-butylacrylate, n-butyl methacrylate, i-butylacrylate, i-butyl methacrylate, sec-butylacrylate, sec-butyl methacrylate, t-butylacrylate, t-butyl methacrylate, 2-hydroxyethyl acrylate, 2-hydroxy 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate, cyclohexyl acrylate, cyclohexyl methacrylate, phenyl acrylate, phenyl methacrylate, 2-methoxyethyl acrylate, 2-methoxyethyl methacrylate, 2-phenoxyethyl acrylate, 2-phenoxyethyl methacrylate, methoxydiethyleneglycol acrylate, methoxydiethyleneglycol methacrylate, methoxytriethyleneglycol acrylate, methoxytriethyleneglycol methacrylate, methoxy propyleneglycol acrylate, methoxypropyleneglycol methacrylate, methoxydipropyleneglycol acrylate, methoxydipropyleneglycol methacrylate, isoboronyl acrylate, isoboronyl methacrylate, dicyclopenta acrylate, dicyclopenta methacrylate, 2-hydroxy-3-phenoxypropyl acrylate, 2-hydroxy-3-phenoxypropyl methacrylate, glycerol monoacrylate, glycerol monomethacrylate, or a combination thereof, but is not limited thereto.

The amino group-containing acrylic monomer is 2-aminoethyl acrylate, 2-aminoethyl methacrylate, 2-dimethylaminoethyl acrylate, and 2-dimethyl 2-dimethylaminoethyl methacrylate, 2-aminopropyl acrylate, 2-aminopropyl methacrylate, 2-dimethylaminopropyl acrylate, 2-dimethylaminopropyl methacrylate, 3-aminopropyl acrylate, 3-aminopropyl methacrylate, 3-dimethylaminopropyl acrylate, 3-dimethylaminopropyl methacrylate, or a combination thereof, but is not limited thereto.

The epoxy group-containing acrylic monomer is glycidyl acrylate, glycidyl methacrylate, glycidyloxyethyl acrylate, glycidyloxyethyl methacrylate, glycidyloxypropyl acrylate, glycidyloxypropyl methacrylate, glycidyloxybutyl acrylate, glycidyloxybutyl methacrylate or a combination thereof, but is not limited thereto.

The carboxylic acid group-containing acrylic monomers include acrylic acid, methacrylic acid, acrylo oxyacetic acid, methacrylo oxyacetic acid, acryloyl oxypropionic acid, methacryloyl oxypropionic acid, acrylo oxybutric acid, methacrylo oxybutric acid, or combinations thereof, but are limited thereto.

In addition, the photopolymerizable monomer may be a photoresist material. The photoresist material may be a silicone or epoxy material.

The photoresist material may be a commercial photoresist. The commercial photoresist materials are AZ 5214E PR, AZ 9260 PR, AZ AD Promoter-K (HMDS), AZ nLOF 2000 Series, AZ LOR-28 PR, AZ 10xT PR, AZ 5206-E, AZ GXR-601, and AZ 04629 from AZ Electronics Materials; SU-8, 950 PMMA, and 495 PMMA from MICROCHEM; S1800 from micropossit; DNR-L300, DSAM, DPR, DNR-H200, and DPR-G from Dongjin Semichem; or CTPR-502 from Kotem, but is not limited thereto.

The mixture may further include a photoinitiator for photocuring according to the type of the photocurable polymer compound. The photoinitiator may be a benzophenone-based compound, a thioxanthone-based compound, a benzoin-based compound, or an oxime-based compound, but is not limited thereto.

Example of the benzophenone-based compound includes benzophenone, benzoyl benzoate, methyl 2-benzoylbenzoate, 4-phenyl benzophenone, hydroxybenzophenone, acrylated benzophenone acrylate, 4,4-bis(dimethylamino)benzophenone, 4,4-dichlorobenzophenone, 3,3-dimethyl-2-methoxy benzophenone, or the like, but is not limited thereto.

Example of the thioxanthone-based compound includes thioxantone, 2-methyl thioxantone, isopropyl thioxantone, 2,4-diethyl thioxantone, 2,4-diiospropyl thioxantone, 2-chloro thioxantone, or the like, but are not limited thereto.

Example of the benzoin-based compound includes benzoine, benzoine methyl ether, benzoine ethyl ether, benzoine isopropyl ether, benzoine isobutyl ether, benzyl dimethyl ketal, or the like, but are not limited thereto.

Example of the oxime compound includes 2-(o-benzoyloxime)-1-[4-(phenylthio)phenyl]-1,2-octanedione or 1-(o-acetyloxime)-1-[9-ethyl-6-(2-methylbenzoyl)-9H-carbazol-3-yl]ethanone, but is not limited thereto.

Meanwhile, the mixture may further include a crosslinking agent for crosslinking (or curing).

Preferably, the crosslinking agent is ethyleneglycol di(metha)acrylate, polyethyleneglycol di(metha)acrylate, trimethylolpropane di(metha)acrylate, trimethylolpropane tri(metha)acrylate, pentaerythritol tri(metha)acrylate, pentaerythritol tetra(metha)acrylate, 2-trisacrylo oxymethylethylpthalic acid, propyleneglycol di(metha)acrylate, polypropyleneglycol di(metha)acrylate, dipentaerythritol penta(metha)acrylate, dipentaerythritol hexa(metha)acrylate, or combinations thereof, but is not limited thereto.

Referring to FIG. 104, when the inner phase is characterized in that it contains a metal halide perovskite and a polymer, the solvent of the inner phase may be volatilized. Volatilizing the solvent in the inner phase may be performed by a method of decompressing the curable emulsion composition. When the solvent on the inner phase is removed by the above process, the metal halide perovskite may be encapsulated by a polymer contained in the inner phase.

Referring to FIG. 105, when the inner phase includes a metal halide perovskite and an encapsulating resin, the metal halide perovskite may be encapsulated in various ways depending on the type of the encapsulating resin.

In particular, when the encapsulation resin is a thermosetting resin, it may be converted to liquid phase by applying heat above the melting point of the wax-based compound in order to apply it to the curable emulsion composition. The melting point of the waxy compound may vary depending on the type of waxy compound, but preferably the melting point of the waxy compound below 100° C. If the melting point exceeds 100° C. to apply to curable emulsion composition, the heat-vulnerable metal halide perovskite crystal structure may be decomposed.

If the above encapsulation resin is a wax-based compound, it may be converted to liquid phase by applying heat above the melting point of the wax-based compound in order to apply it to the curable emulsion composition.

When the encapsulating resin is a wax-based compound, the metal halide perovskite may be encapsulated by removing heat applied to form a curable emulsion composition.

A dispersion in which encapsulated metal halide perovskite particles are dispersed is prepared by the encapsulation process.

Referring to FIGS. 104 and 105, the curable emulsion composition is then coated on a substrate and dried to form a coating film.

The material of the substrate 10 is glass, sapphire, quartz, silicon, polyethylene terephthalate (PET), polystyrene (PS), polyimide (PI), polyvinyl chloride (PVC), polyvinylpyrrolidone (PVP), polyethylene (PE), or the like, but is not limited thereto.

The method provided on the substrate 10 can be selected from known coating method, for example, a spin coating method, a cast method, a Langmuir-Blodgett (LB) method, a spray coating method, a dip coating method, a gravure coating method, a reverse offset method, a screen printing method, a slot-die coating method, a nozzle printing method, and a dry transfer printing method, but the present invention is not limited thereto. Drying may be performed by a known drying method generally known in related art, for example, a hot air heating method, or an induction heating method, but is not limited thereto.

The coating film formed by the coating and drying has a structure in which the metal halide perovskite encapsulated in the photocurable polymer compound in the outer phase composition is uniformly dispersed. Subsequently, light is irradiated to the coating film to cure the photocurable polymer compound to prepare a wavelength converting body having a structure in which the metal halide perovskite encapsulated in the second dispersion medium is uniformly dispersed. The second dispersion medium is characterized in that it is prepared by curing the photocurable polymer compound.

<Perovskite Nanoparticles with Suppressed Defects Through the Addition of Medium-Sized Organic Cations>

Hereinafter, a perovskite nanoparticle in which defect generation is suppressed through the addition of medium-sized organic cation is provided.

In general, the crystal structure of perovskite forms a BX₆ octahedron between a B metal substance and a halogen element, and a cation A is located between the formed BX₆ octahedron to form a crystal structure. Therefore, the size of the A cation is limited by the size of the BX₆ octahedron. At this time, the combination of A, B, and X that can make the perovskite crystal can be determined simply by calculating the tolerance factor (t). The tolerance factor is defined by the following equation.

$$t = \frac{{R}_{A} + {R}_{X}}{\sqrt{2} ( {R}_{B} + {R}_{X} )}$$

(R_{A}, R_{B}, and R_{X} are the ionic radii of A, B and X, respectively)

In order for the perovskite to have a three-dimensional crystal structure, it is preferable that the tolerance factor has a value of about 0.8 or more and about 1.0 or less. Since the tolerance factor also depends on the central metal B and the halide anion X, a reference point for this invention should be set. To determine the boundary point of the tolerance factor, the reference element of central metal B can be set to Pb and the reference element of the X can be set to bromide, and FAPbBr₃ can be taken as the reference crystal. This is because FAPbBr₃ is a single cation and has a tolerance factor close to 1 (approximately 1.01), the crystal itself is stable, and the luminescence efficiency is high. Therefore, in order to prevent confusion in the present invention, a table is presented directly. Therefore, if this criterion (B═Pb and X═Br criterion) has a tolerance factor of 1.01 or more, considering the radius of A, A cannot be included in the space between the BX₆ octahedron, resulting in distortion of the crystal. For example, when B is Pb²⁺ and X is Br⁻, the cation at site A may be Rb⁺, Cs⁺, methylammonium, or formamidinium.

However, when the metal halide perovskite light emitter is formed only in a combination with the A site cation that satisfies the above-described tolerance factor condition of 0.8 or more and 1.01 or less, the crystal structure becomes more unstable due to the smaller size of the A site in the particle. Since the bonding inside the metal halide perovskite is weakened, there are more defects that may inevitably reduce the luminescence efficiency and stability of the metal halide perovskite light emitter. On the other hand, if a medium-sized organic cation having a tolerance factor greater than 1.01 and smaller than 3 when only the cation is included in the perovskite crystal is included in the crystal, defects of the perovskite light emitter can be effectively controlled.

Accordingly, in the present invention, in a state in which the first monovalent cation (A₁) capable of making a tolerance factor of 1.01 or less when only the A site cation is included in the A-site of a perovskite crystal, and the second monovalent organic cation (A₂) capable of making a tolerance factor of 1.01 or more and less than 3 is mixed, it provides a colloidal perovskite light emitting particle, characterized in that the second monovalent organic cation (A₂) is simultaneously included both in the inside and on the surface of the perovskite crystal.

A₂ organic cations having a tolerance factor greater than 1.01 are relatively difficult to be included inside metal halide perovskite crystals because they have a size larger than the space between BX₆ octahedra. Therefore, a small amount of A₂ organic cation can be accommodated to form a metal halide perovskite crystal, but when a larger amount of A₂ organic cation is added than the amount capable of forming a crystal, an excessive amount of A₂ organic cation is not included in a perovskite crystal and is located on the surface of perovskite nanoparticles or at the grain boundaries of perovskites.

Since it is located on the surface of nanoparticles and plays a role of suppressing defects while enclosing particles like a shell, the high luminescence efficiency can be maintained without gradual decrease. In addition, the size of the particles is reduced by the larger cations (i.e. medium-sized ions) surrounding the surface like a shell, and the confinement of excitons or charges is better, thereby increasing the radiative recombination. Furthermore, if it has a symmetrical structure such as guanidinium among medium-sized cations, light emission can be more efficiently and stably emitted.

When only one type of cation is used purely, the tolerance factor (t) of the metal halide perovskite material can be referred by the related literature [Nature Photonics, 2015, 11, 582; Chemical Science, 2016, 7, 4548; Chemical Science, 2015, 6, 3430; Science, 2016, 354, 206; Journal of Materials Chemistry A, 2017, 5, 18561].

When the tolerance factors are calculated for the representative A, B, and X site ions constituting the perovskite, the following table is shown.

| | | X site | | | |
|---|---|---|---|---|---|
| | | Floride | Chloride | Bromide | Iodide |
| B site = Be | | | | | |
| A site | Ammonium | 1.119 | 1.023 | 1.003 | 0.977 |
| | Hydroxylammoniurn | 1.404 | 1.242 | 1.209 | 1.163 |
| | Methylammonium | 1.408 | 1.245 | 1.212 | 1.166 |
| | Hydrazinium | 1.408 | 1.245 | 1.212 | 1.166 |
| | Azetidinium | 1.543 | 1.349 | 1.309 | 1.254 |
| | Formamidinium | 1.555 | 1.358 | 1.317 | 1.262 |
| | Imidaozolium | 1.575 | 1.374 | 1.332 | 1.275 |
| | Dimethylammonium | 1.632 | 1.417 | 1.373 | 1.313 |
| | Pyrrolinium | 1.632 | 1.417 | 1.373 | 1.313 |
| | Ethylammonium | 1.64 | 1.424 | 1.379 | 1.318 |
| | Guanidinium | 1.657 | 1.436 | 1.391 | 1.329 |
| | Tetramethylammonium | 1.714 | 1.48 | 1.432 | 1.366 |
| | Thiazolium | 1.828 | 1.558 | 1.514 | 1.441 |
| | Tropylium | 1.881 | 1.608 | 1 552 | 1.476 |
| B site = Mg | | | | | |
| A site | Ammonium | 0.968 | 0.914 | 0.902 | 0.886 |
| | Hydroxylammoniurn | 1.215 | 1.11 | 1.087 | 1.056 |
| | Methylammonium | 1.218 | 1.112 | 1.09 | 1.058 |
| | Hydrazinium | 1.218 | 1.112 | 1.09 | 1.058 |
| | Azetidinium | 1.335 | 1.205 | 1.177 | 1.138 |
| | Formamidinium | 1.345 | 1.213 | 1.185 | 1.145 |
| | Imidaozolium | 1.363 | 1.227 | 1.198 | 1.158 |
| | Dimethylammonium | 1.412 | 1.266 | 1.235 | 1.191 |
| | Pyrrolinium | 1.412 | 1.266 | 1.235 | 1.191 |
| | Ethylammonium | 1.42 | 1.272 | 1.24 | 1.196 |
| | Guanidinium | 1.434 | 1.283 | 1.251 | 1.206 |
| | Tetramethylammonium | 1.483 | 1.322 | 1.288 | 1.24 |
| | Thiazolium | 1.582 | 1.4 | 1.361 | 1.308 |
| | Tropylium | 1.628 | 1.437 | 1.396 | 1.339 |
| B site = Pb | | | | | |
| A site | Ammonium | 0.784 | 0.771 | 0.768 | 0.763 |
| | Hydroxylammoniurn | 0.984 | 0.936 | 0.925 | 0.909 |
| | Methylammonium | 0.987 | 0.938 | 0.927 | 0.912 |
| | Hydrazinium | 0.987 | 0.938 | 0.927 | 0.912 |
| | Azetidinium | 1.081 | 1.016 | 1.001 | 0.98 |
| | Formamidinium | 1.09 | 1.023 | 1.008 | 0.987 |
| | Imidaozolium | 1.104 | 1.035 | 1.019 | 0.997 |
| | Dimethylammonium | 1.144 | 1.068 | 1.051 | 1.026 |
| | Pyrrolinium | 1.144 | 1.068 | 1.051 | 1.026 |
| | Ethylammonium | 1.15 | 1.072 | 1.055 | 1.03 |
| | Guanidinium | 1.161 | 1.082 | 1.064 | 1.039 |
| | Tetramethylammonium | 1.201 | 1.115 | 1.095 | 1.068 |
| | Thiazolium | 1.281 | 1.181 | 1.158 | 1.126 |
| | Tropylium | 1.319 | 1.212 | 1.187 | 1.153 |
| B site = Sn | | | | | |
| A site | Ammonium | 0.797 | 0.781 | 0.778 | 0.773 |
| | Hydroxylammoniurn | 1 | 0.948 | 0.937 | 0.92 |
| | Methylammonium | 1.003 | 0.951 | 0.939 | 0.922 |
| | Hydrazinium | 1.003 | 0.951 | 0.939 | 0.922 |
| | Azetidinium | 1.099 | 1.03 | 1.014 | 0.992 |
| | Formamidinium | 1.108 | 1.037 | 1.021 | 0.998 |
| | Imidaozolium | 1.122 | 1.049 | 1.032 | 1.009 |
| | Dimethylammonium | 1.163 | 1.082 | 1.064 | 1.038 |
| | Pyrrolinium | 1.163 | 1.082 | 1.064 | 1.038 |
| | Ethylammonium | 1.169 | 1.087 | 1.069 | 1.043 |
| | Guanidinium | 1.18 | 1.096 | 1.078 | 1.051 |
| | Tetramethylammonium | 1.221 | 1.13 | 1.11 | 1.081 |
| | Thiazolium | 1.302 | 1.197 | 1.173 | 1.14 |
| | Tropylium | 1.34 | 1.228 | 1.203 | 1.167 |
| B site = Eu | | | | | |
| A site | Ammonium | 0.791 | 0.776 | 0.773 | 0.768 |
| | Hydroxylammoniurn | 0.992 | 0.942 | 0.931 | 0.915 |
| | Methylammonium | 0.995 | 0.944 | 0.933 | 0.917 |
| | Hydrazinium | 0.995 | 0.944 | 0.933 | 0.917 |
| | Azetidinium | 1.09 | 1.023 | 1.008 | 0.986 |
| | Formamidinium | 1.099 | 1.03 | 1.014 | 0.992 |
| | Imidaozolium | 1.113 | 1 042 | 1.026 | 1.003 |
| | Dimethylammonium | 1.154 | 1.075 | 1.057 | 1.032 |
| | Pyrrolinium | 1.154 | 1.075 | 1.057 | 1.032 |
| | Ethylammonium | 1.159 | 1.08 | 1.062 | 1.037 |
| | Guanidinium | 1.171 | 1.089 | 1.071 | 1.045 |
| | Tetramethylammonium | 1.211 | 1.122 | 1.102 | 1.074 |
| | Thiazolium | 1.792 | 1.189 | 1.166 | 1.133 |
| | Tropylium | 1.329 | 1.22 | 1.195 | 1.16 |

The A₂ organic cation may be ethylammonium, guanidinium, tert-butylammonium, diethylammonium, dimethylammonium, ethane-1.2.-diammonium, imidazolium, n-propylammonium, iso-propylammonium, pyrrolidinium, or combinations thereof, but is not limited thereto.

The amount of the A₂ organic cation that may be included in the crystal may vary depending on the type of A₁ cation and A₂ organic cation that are added to the perovskite crystal. When the A₂ cation are included in the crystal, the crystal is unstable in terms of enthalpy due to steric hindrance because of the large size of A₂, but the crystal may be stabilized due to an increase in entropy caused by mixing. Therefore, the amount of the A₂ organic cation that can be included in the crystal can be determined by extracting the range that the generated energy by summing the enthalpy energy change and the entropy energy change is negative with a function of the proportion of the A₂ precursor. The enthalpy energy change and the entropy energy change can be obtained by DFT calculation.

In particular, when the A₁ organic cation is formamidinium, the A₂ organic cation is guanidinium, the B-site cation is Pb²⁺, and the X-site anion is Br⁻. When the proportion of the mixture changes to 0%, 12.5%, 25%, 50%, 75%, 100%, the enthalpy energy increases to 0 meV, 7.7 meV, 17.5 meV, 44.5 meV, 72.7 meV, and 82.5 meV, and, the entropy energy changes to 0 meV, −10 meV, −14.7 meV, −17.9 meV, −14.7 meV, and 0 meV, respectively.

The A₂ organic cation contained in the crystal can stabilize the perovskite crystal due to the entropy effect and suppress the generation of defects in the crystal, and an excessive amount of A₂ organic cation that is not contained inside the perovskite crystal can passivate defects generated on the surface of the perovskite nanocrystal by forming a structure surrounding the perovskite nanocrystal (see FIG. 114).

It may be characterized in that the ratio of the A₂ organic cation to the mixture of the A₁ cation and A₂ organic cation among the monovalent cation of the A site (i.e. A site cation precursor ratio) is more than the ratio that can be maximally included in the perovskite crystal and is less than or equal to a ratio when the surface of the metal halide perovskite nanoparticles is completely enclosed. For example, it may be 5% or more and 60% or less.

In addition, preferably the ratio may include a range where the lower value among two numbers selected from 5%, 6%, 7%, 8%, 9%, 10%, 11%, 12%, 13%, 14%, 15%, 16%, 17%, 18%, 19%, 20%, 22%, 24%, 26%, 28%, 30%, 32%, 34%, 36%, 38%, 40%, 45%, 50%, 55%, and 60% is a lower limit value and a higher value of the two numbers is an upper limit value.

If the ratio of the A₂ organic cations is less than 5% outside the above range, all of the mixed A₂ organic cations are contained inside the perovskite crystal, so that the defects formed on the surface of the perovskite nanoparticles cannot be effectively controlled, and if it exceeds 60%, the size of the perovskite nanoparticles is greatly reduced because an excess of A₂ organic cations contained in the perovskite nanoparticles are more than the amount that can completely cover the surface of the perovskite nanoparticles. As the surface-to-volume ratio increases, the quantum efficiency decreases, and the color purity decreases due to light emission depending on the quantum confinement effect.

Preferably, the A₂ organic cation may be guanidinium. When the A₂ ion is guanidinium, the number of hydrogen bonds that can be formed in the crystal increases, and thus the inside of the perovskite crystal may be additionally stabilized.

The A₂ organic cation is ethylammonium, guanidinium, tert-butylammonium, diethylammonium, dimethylammonium, ethane-1.2.-diammonium, imidazolium, n-propylammonium, iso-propylammonium, pyrrolidinium, or combinations thereof, but is not limited thereto.

The amount of the A₂ organic cation that may be included in the crystal may vary depending on the type of A₁ cation and A₂ organic cation that are added to the perovskite crystal. When the A₂ cation are included in the crystal, the crystal is unstable in terms of enthalpy due to steric hindrance due to the large size of A₂, but the crystal may be stabilized due to an increase in entropy due to mixing. Therefore, the amount of the A₂ organic cation that can be included in the crystal can be determined by extracting a range that the generated energy summing the enthalpy energy change and the entropy energy change is negative with a change of the cation precursor ratio (i.e. the ratio of A₂ precursor to the total A site cation precursors). The enthalpy energy change and the entropy energy change can be obtained by DFT calculation.

The A₂ organic cation contained in the crystal can stabilize the perovskite crystal due to the entropy effect and suppress the generation of defects in the crystal, and an excessive amount of A₂ organic cation that is not contained inside the perovskite crystal can passivate defects generated on the surface of the perovskite nanocrystal by forming a structure surrounding the perovskite nanocrystal. (see FIG. 114).

It may be characterized in that the ratio of the A₂ organic cation to the mixture of the A₁ cation and A₂ organic cation among the monovalent cation of the A site (i.e. A site cation ratio) is more than the ratio that can be maximally included in the perovskite crystal and is less than or equal to a ratio when the surface of the metal halide perovskite nanoparticles is completely enclosed. For example, the ratio may be 5% or more and 60% or less.

In addition, preferably the ratio may include a range between two numbers selected from 5%, 6%, 7%, 8%, 9%, 10%, 11%, 12%, 13%, 14%, 15%, 16%, 17%, 18%, 19%, 20%, 22%, 24%, 26%, 28%, 30%, 32%, 34%, 36%, 38%, 40%, 45%, 50%, 55%, and 60%, in which a lower value of the two numbers is a lower limit value and a higher value of the two numbers is an upper limit value.

If the ratio of the A₂ organic cations is less than 5% outside the above range, all of the mixed A₂ organic cations are contained inside the perovskite crystal, so that the defects formed on the surface of the perovskite nanoparticles cannot be effectively controlled, and if it exceeds 60%, the size of the perovskite nanoparticles is greatly reduced because an excess of A₂ organic cations contained in the perovskite nanoparticles are more than the amount that can completely cover the surface of the perovskite nanoparticles. As the surface-to-volume ratio increases, the luminescence quantum efficiency decreases, and the color purity decreases due to light emission depending on the quantum confinement effect.

Preferably, the A₂ organic cation may be guanidinium. When the A₂ ion is guanidinium, the number of hydrogen bonds that can be formed in the crystal increases, and thus the inside of the perovskite crystal may be additionally stabilized.

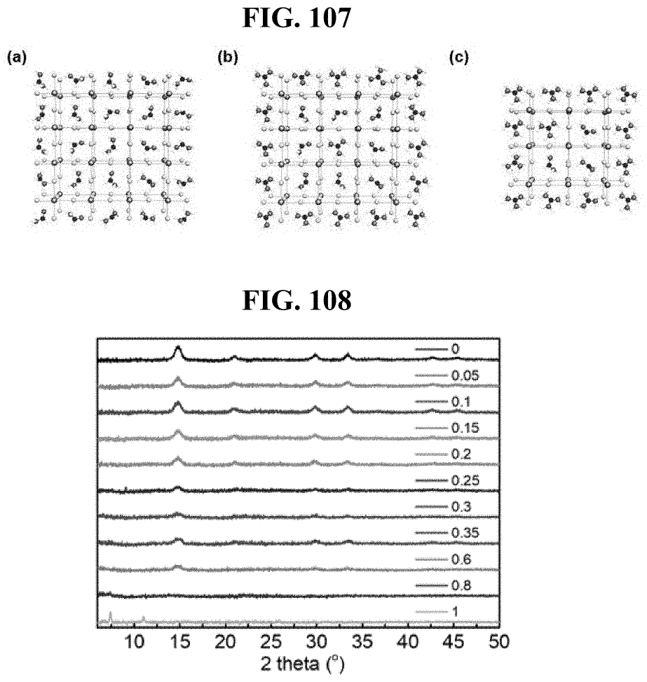

In an embodiment of the present invention, the A₁ cation may be formamidinium (FA), B may be Pb, X may be Br, and the A₂ organic cation may be guanidinium. Referring to the schematic diagram of FIG. 106, as A₂ is added to the A₁BX₃ perovskite nanocrystal particles (FIG. 107(a)), when the appropriate amount (more than the ratio that can be maximally contained in the crystal and less than the ratio when the surface of metal halide perovskite nanocrystal particles is completely enclosed) added, only a part of A₂ ions are contained in the crystal and the remaining A₂ ions form a surrounding structure (FIG. 107(b)), and when A₂ exceeds an appropriate amount (when added in excess than the amount capable of completely covering the surface of the perovskite nanoparticles), the size of the perovskite nanocrystals decreases (FIG. 107(c)).

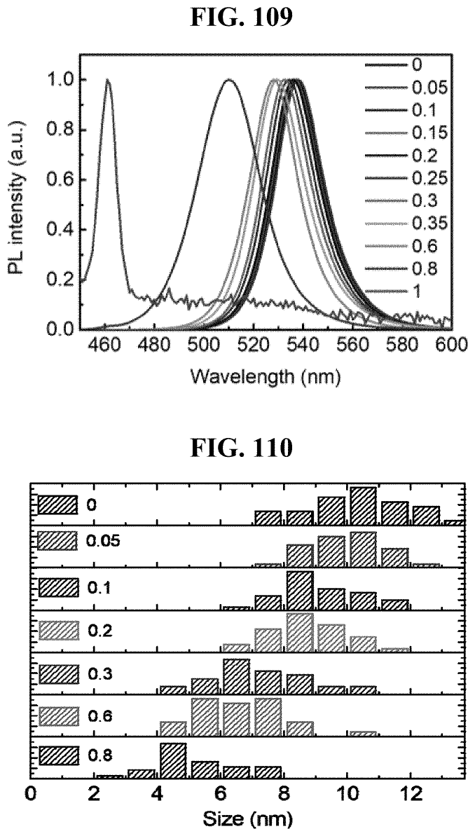

Accordingly, referring to FIGS. 108 and 109, in the above embodiment, when the mixing ratio of A₂ is 5% or less, all of A₂ is contained inside the perovskite crystal to expand the crystal to make the steady-state photoluminescence wavelength red-shifted. On the other hand, when 5% or more of A₂ is added, the crystal lattice does not change and the steady-state photoluminescence wavelength is blue-shifted. The blue-shift may be due to a decrease in the size of perovskite nanoparticles (FIG. 110).

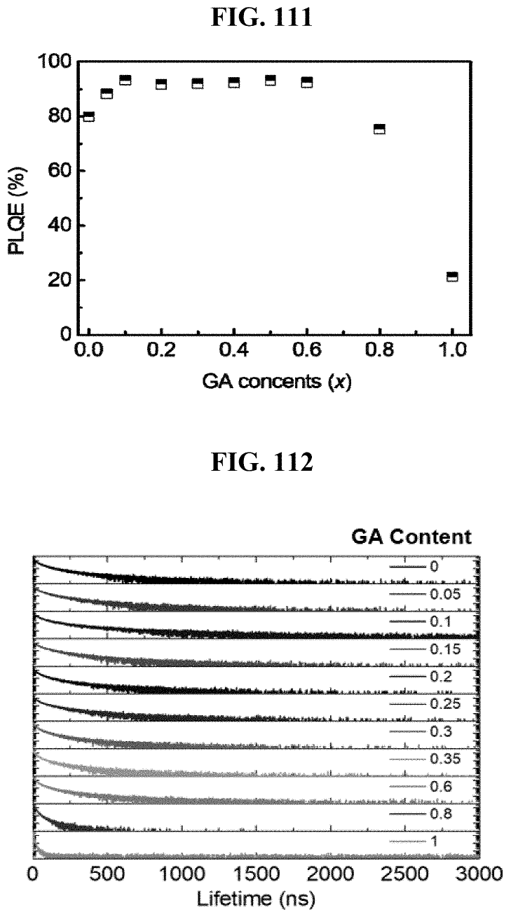

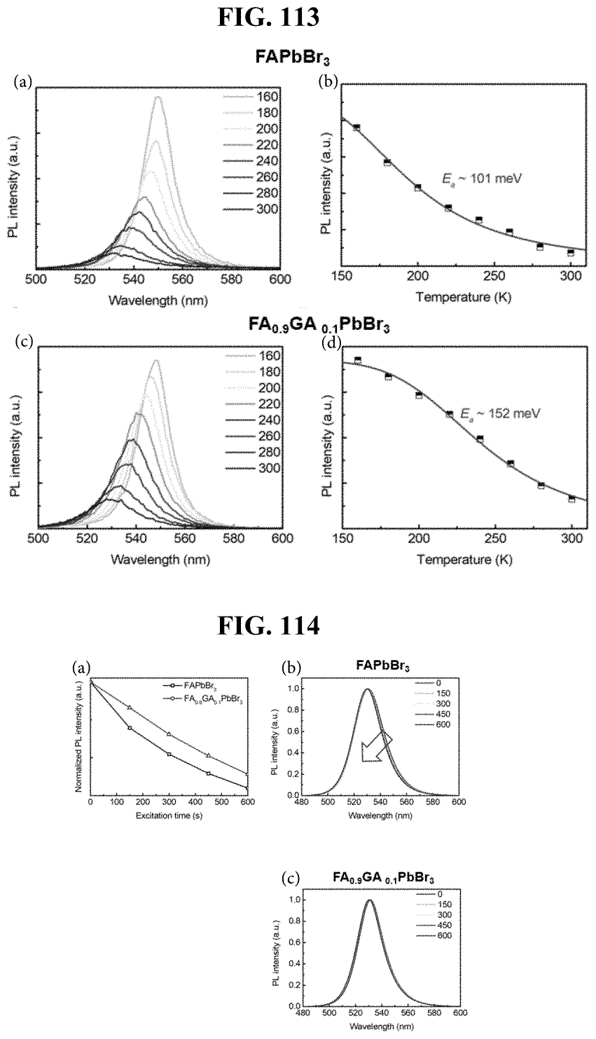

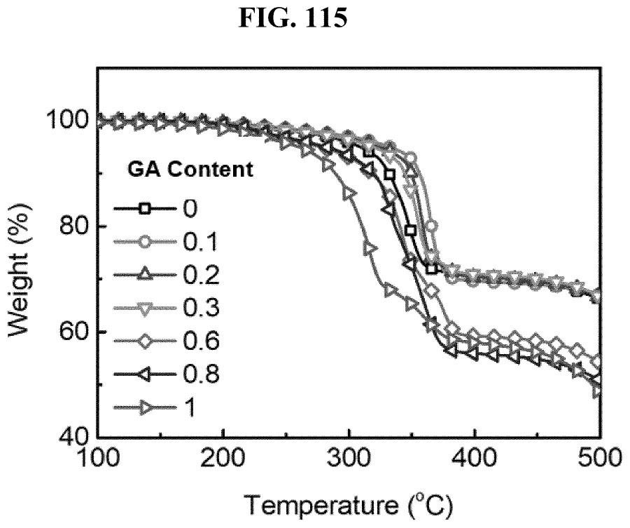

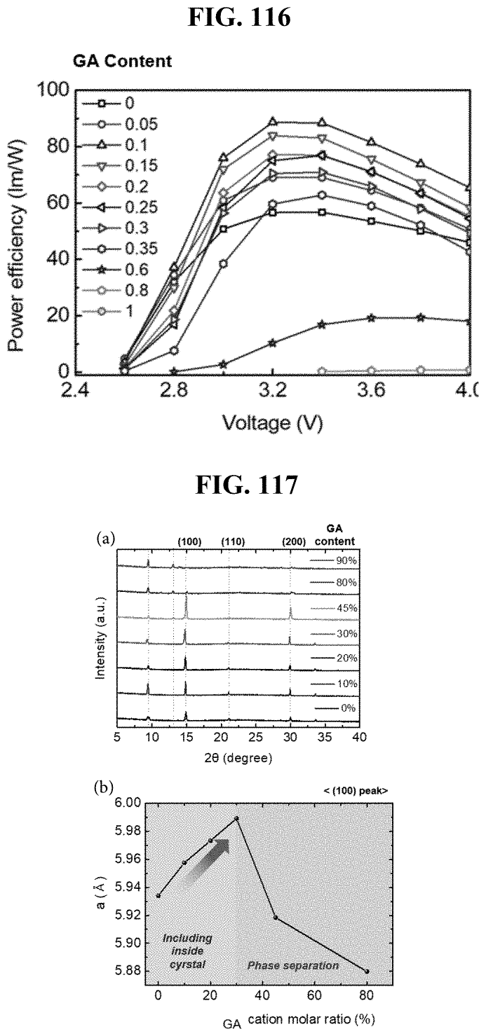

In the above embodiment, as a result of measuring the photoluminescence properties before and after adding A₂ organic cation with ratio a 5% or more and 60% or less, which corresponds to the ratio range where the ratio of the A₂ organic cation to the mixture of the A₁ cation and A₂ organic cation among the monovalent cations at the A site is greater than or equal to the ratio that can be maximally included inside the perovskite crystal and is less than the ratio when completely surrounding the surface of perovskite nanoparticles, it was confirmed that after adding A₂ organic cations, photoluminescence quantum efficiency (PLQY, photoluminescence quantum yield) (FIG. 111) increases, the photoluminescence lifetime (PL lifetime) is extended (FIG. 112), and the exciton binding energy determined by temperature dependent photoluminescence increases (FIG. 113), and the stability against thermal decomposition upon UV irradiation is improved (FIG. 114), the stability against thermal decomposition was improved (FIG. 115), and the luminous efficiency when manufacturing a light-emitting diode was improved (FIG. 116).

Thus, in the perovskite material according to the present invention, the medium-sized monovalent organic cations (A₂) contained in the perovskite crystal stabilize the perovskite crystal due to the entropy effect and suppress defects in the crystal. A₂ cations that are not included in the perovskite crystal form a structure surrounding the perovskite nanocrystal particles, and passivates defects that are formed on the surface of the perovskite nanocrystal particles. As a result, photoluminescence quantum efficiency, photoluminescence lifetime, and stability are improved, and thus, it can be effectively used in a light-emitting layer or a wavelength converting layer of a light-emitting device.

An example of a light-emitting device including a perovskite material in which defect generation is controlled through the addition of a medium-sized organic cation according to the present invention is the same as the description of the light-emitting device described above, and a detailed description is omitted to avoid redundant description.

<Perovskite with Suppressed Defects Through 4 Types of Mixed Cationic Structure>

Hereinafter, there is provided a perovskite light emitter in which the generation of defects is controlled using the four kinds of mixed cationic structure, which is the core of the present invention.

In general, the crystal structure of perovskite is that the B metal substance and the halogen element form a BX₆ octahedron, and a cation A is located between the formed BX₆ octahedron to form a crystal structure. Therefore, the size of the A cation is limited by the size of the BX₆ octahedron. At this time, the combination of A, B, and X that can make the perovskite crystal can be determined simply by calculating the tolerance factor (t). The tolerance factor is defined by the following equation.

$$t = \frac{{R}_{A} + {R}_{X}}{\sqrt{2} ( {R}_{B} + {R}_{X} )}$$

(R_{A}, R_{B}, and R_{X} are the ionic radii of A, B and X, respectively)

In order for the perovskite to have a three-dimensional crystal structure, it is preferable that the tolerance factor has a value of 0.8 or more and 1.1 or less. When the tolerance factor exceeds the above range and has a value of 1.01 or more, the ionic radius of A site is not favorable for inclusion of the A ion in the interspace between the BX₆ octahedra and thus the crystal is distorted. For example, when B is Pb²⁺ and X is Br⁻, the cation at site A may be Rb⁺, Cs⁺, methylammonium, or formamidinium. However, when the metal halide perovskite light emitter is formed only with the combination of the A site cation that satisfies the above-described tolerance factor condition of 0.8 or more and 1.01 or less, the crystal structure becomes unstable due to the small size of the A site cation. Since bonding inside the metal halide perovskite is weakened, there are many defects that may inevitably reduce the luminescence efficiency and stability of the metal halide perovskite light emitter. In this case, when only the medium-sized organic cations having a tolerance factor greater than 1.01 and smaller than 3 are added to the crystal, even though they are single species of ions, defects of the perovskite light emitter can be effectively controlled.

The tolerance factor (t) of the APbX₃ (A=medium-sized cation, X═I, Br, Cl) structure obtained using only the medium-sized cation added here can be 1.1, 1.15, 1.2, 1.25, 1.3, 1.35, 1.4, 1.45, 1.5, 1.55, 1.6, 1.65, 1.7, 1.75, 1.8, 1.85, 1.9, 1.95, 2.0, 2.1, 2.2, 2.3, 2.4, 2.5, 2.6, 2.7, 2.8, 2.9, or 3.0. The range can be determined by using the smaller value of the two numbers selected from the above numbers as the lower limit value and the larger value of the two numbers as the upper limit value. The most preferred range when adding a medium-sized cation (e.g. guanidinium) to FAPbBr₃ is in the range of 1.6-2.1.

In the present invention, a material includes at least one type of cation having a large t value such as guanidinium is unconditionally, and includes the cations of 2, 3, 4, 5, 6, and 7 types.

Examples of embodiments of the present invention include a halide perovskite polycrystalline thin film containing the mixed cation and a device using the same.

Examples of embodiments of the present invention include halide perovskite nanocrystal particles containing the mixed cations and a device using the same.

According to the present invention, when formed as nanoparticles, it is possible to achieve high efficiency even with two cations including medium-sized ions, and when formed as a polycrystalline thin film, it is possible to implement high efficiency with more than four cations.

In addition, when organic cations with an above tolerance factor greater than 1.01 and less than 3 are included in the crystal in excess of a certain level or more, the tolerance factor of the mixed cationic perovskite crystal can become larger than 1, resulting in deterioration of the crystal stability and the luminescence properties. At this time, if some of the A-site cations that satisfy the tolerance factor condition of 0.8 or more and less than 1.01 are replaced with cations providing a lower tolerance factor, the tolerance factor of the entire mixed cation perovskite crystal decreases. In this case, it is possible to maximize the defect suppression effect by including the medium-sized cations in the crystal at a higher ratio that provide a tolerance factor of 1.01 or more and less than 3.

The content of the medium-sized organic cation can range from 5% to 60%. For example, it may be 5%, 6%, 7%, 8%, 9%, 10%, 11%,12%, 13%, 14%, 15%, 20%, 30%, 40%, 50%, and 60%. In this proportion, the photoluminescence efficiency can be the best. Looking at the optimum point of the external quantum efficiency from the viewpoint of the electroluminescent device, it may be preferably 8% to 20% or less, and more preferably 8% to 15% or less.

In this invention, a perovskite polycrystalline thin film characterized by the simultaneous inclusion of cations inside and on the surface of perovskite crystals, in which the cation is comprised of the first monovalent cation (A₁, A₃, A₄) that can make a tolerance factor of less than 1 and the second monovalent cation (A₂) that can make a tolerance factor of more than 1.01 and less than 3.

A₂ organic cations having a tolerance factor greater than 1.01 are relatively difficult to be included in metal halide perovskite crystals because they have a size larger than the interspace between BX₆ octahedra. Therefore, a small amount of A₂ organic cations can form a metal halide perovskite crystal, but when a larger amount of A₂ organic cations are added than the amount capable of forming a crystal, an excess of A₂ organic cations will not be used to form a perovskite crystal but instead are included in the perovskite grain boundaries or are located on the surface of the perovskite polycrystalline thin film.

The A₂ organic cation is ethylammonium, guanidinium, tert-butylammonium, diethylammonium, dimethylammonium, ethane-1.2.-diammonium, imidazolium, n-propylammonium, iso-propylammonium, pyrrolidinium, or combinations thereof, but is not limited thereto.

The amount of A₂ organic cations that may be included in the crystal may vary depending on the types of A₁, A₃, and A₄ cations constituting the perovskite crystal and the type of A₂ organic cations added. When the A₂ ions are included in the crystal, the crystal is unstable in terms of enthalpy due to steric hindrance caused by the large size of A₂, but the crystal may be stabilized due to an increase in entropy by mixing. Therefore, the amount of the A₂ organic cation that can be included in the crystal can be determined by extracting a range that the generated energy summing the enthalpy energy change and the entropy energy change is negative with a function of the precursor ratio of the cation. The enthalpy energy change and the entropy energy change can be obtained by DFT calculation.

The A₂ organic cation contained inside the crystal can stabilize the perovskite crystal and suppress the generation of defects in the crystal due to the entropy effect.

Among the monovalent cations at the A site, the ratio of the A₂ organic cation to the mixture of the A₁, A₃, A₄ cation and A₂ organic cation is the ratio that can be included in the perovskite crystal. Hereinafter, for example, it may be characterized in that it is 5% or more and 60% or less.

In addition, preferably, the ratio is 5%, 6%, 7%, 8%, 9%, 10%, 11%, 12%, 13%, 14%, 15%, 16%, 17%, 18%, 19%, 20%, 22%, 24%, 26%, 28%, 30%, 32%, 34%, 36%, 38%, 40%, 45%, 50%, 55%, or 60% and include a range in which a lower value among of two numbers selected from the above is a lower limit value and a higher value of the two is an upper limit value.

When the ratio of A₂ organic cations is less than 5% outside the above range, all of the mixed A₂ organic cations are contained inside the perovskite crystal, so that defects formed on the surface of the perovskite crystal cannot be effectively suppressed, and in the case of exceeding 30%, an excessive amount of A₂ organic cations more than the amount that can completely cover the surface of the perovskite crystal will cause phase separation of the perovskite crystals, and the formation of perovskite crystal other than three-dimensional perovskite crystal, which results in poor luminescence efficiency and electrical conduction characteristics.

Preferably, the A₂ organic cation may be guanidinium. When the A₂ ion is guanidinium, the number of hydrogen bonds that can be formed inside the crystal increases, so that the inside of the perovskite crystal can be additionally stabilized.

In addition, preferably, the ratio is 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 35%, 40%, 45%, 50%, 55%, or 60%. It may include a range in which the lower value of the two numbers out of the above ratios is the lower limit value and the higher value has the upper limit value. Preferably the ratio includes a range from 8% to 30%. In the case of a polycrystalline thin film, when quadruple ions containing guanidinium are used, the most optimal device luminous efficiency can be obtained in a range near 10% of the guanidinium ratio, that is, 8%-20%. Even when all including particles and polycrystals are considered, the most optimal device luminous efficiency can be obtained in a range around 10%, that is, in a range of 8%-15%.

If the proportion of A₂ organic cations is less than 5% outside the above range, both mixed A₂ organic cations are contained inside the perovskite crystal and the defects formed on the perovskite crystal surface cannot be effectively controlled, and if the proportion exceeds 30%, the remaining A₂ organic cations can cause phase separation of perovskite crystals and thus form perovskite crystals other than three-dimensional perovskite crystals, which can cause lower luminescence efficiency and electrical conductivity than those in three-dimensional perovskite crystals.

The ratio of the A₁, A₃ and A₄ cations of the monovalent cations of the above A site to the all A cation mixture can be taken as the rest of proportion excluding the proportion of the above A₂ organic cations, and the above invention can be characterized by the combination that can still allow the tolerance factor to be 1.01 or less even after the tolerance factors increases by including A₂ organic cation in the perovskite crystal.

Preferably, A₁ and A₃ are formamidinium (FA) and cesium (Cs), respectively, and A₄ is methylammonium (MA). The ratio of A₃ is 1%, 2%, 3%, 4%, 5%, 6%, 7%, 8%, 9%, 10%, 11%, 12%, 13%, 14%, 15%, 16%, 17%, 18%, 19%, or 20%. The lower value of the two numbers selected from the above is the lower limit and the higher value has the upper limit. The ratio of A₄ is 5%, 6%, 7%, 8%, 9%, 9.1%, 9.2%, 9.3%, 9.4%, 9.5%, 9.6%, 9.7%, 9.8%, 9.9%, 10%, 10.1%, 10.2%, 10.3%, 10.4%, 10.5%, 10.6%, 10.7%, 10.8%, 10.9%, 11%, 12%, 13%, 14%, or 15%, and may include a range in which the lower value of the two numbers selected from the above is the lower limit value and the higher value have the upper limit value. The ratio of A₁ may fall into the remaining range excluding A₃ and A₄ above.

In an embodiment of the present invention, the combination of A₁, A₃, and A₄ cation is composed of formamidinium (FA), methylammonium (MA), cesium (Cs), B is taken as Pb, and X is taken as Br. Accordingly, the A₂ organic cation can be used as guanidinium.

Referring to FIG. 117, according to the mixing ratio of adding A₂ to the A₁BX₃ perovskite polycrystalline thin film (FIG. 117(a)), A₂ ions are contained in the crystal up to about 25%, thereby increasing the lattice constant of the crystal. (FIG. 117(b)), when an A₂ organic cation in excess of an appropriate amount is added, a new crystal is formed and the crystal structure is changed to show a different pattern.

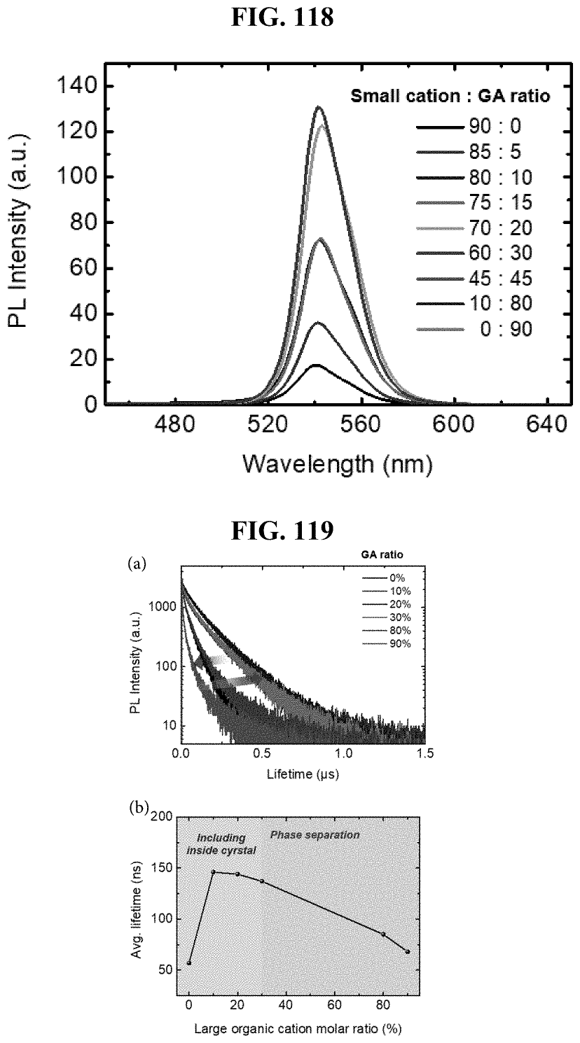

In the above embodiment, the ratio of the A₂ organic cation in the mixture of the A₁, A₃, A₄ cation and A₂ organic cation among the monovalent (monovalent) cations at the A site is the ratio that can be contained in the perovskite crystal at the maximum. As a result of measuring the photoluminescence properties before and after adding 5% or more and 90% or less of the A₂ organic cation, until the A₂ organic cation was added at a ratio of about 30% or less, the steady-state photoluminescence gradually increased (see FIG. 118), and the photoluminescence (PL) lifetime became longer (see FIGS. 118 and 119).

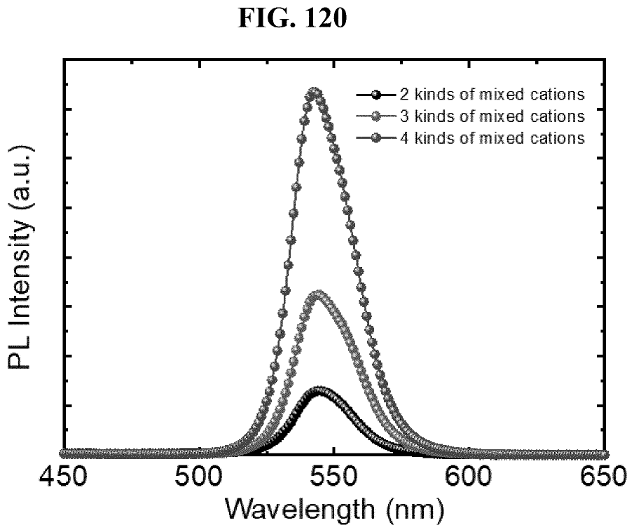

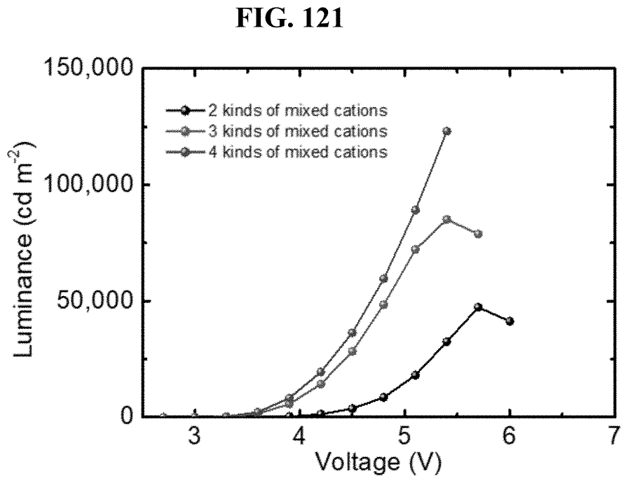

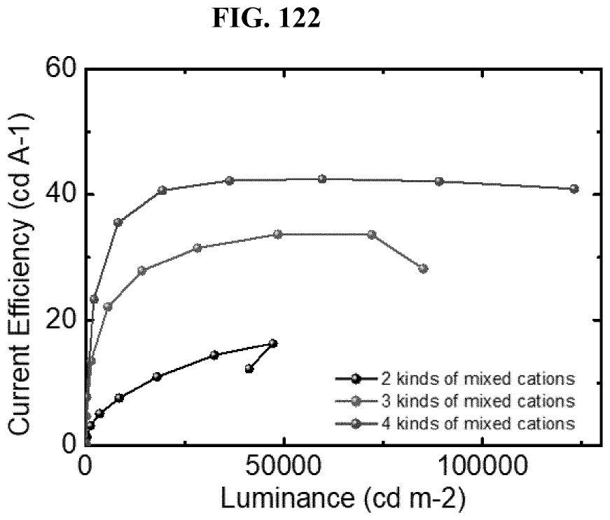

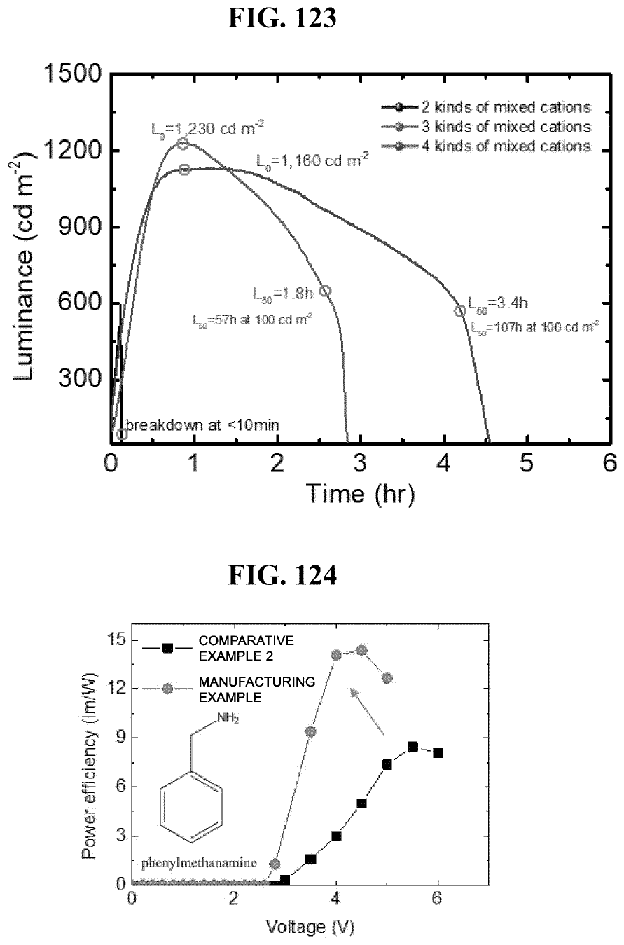

In the above embodiment, the two types of mixed cationic structures of A₁ and A₂ are the basic mixing structures that can form a three-dimensional perovskite crystal. The three types of mixed cationic structures of A₁, A₂, and A₄ have additionally A₄ cations with the maximum ratio that can be contained within the perovskite crystal. A₁, A₂, A₃ and A₄ mixed cation structures are a combination that A₃ cation with a tolerance factor of 1.01 or less is mixed in a ratio that allows an optimal crystal stabilization. Measurement of the luminescence characteristics of perovskite polycrystalline thin films of these two, three and four mixed cationic structures shows improved rectified photoluminescence intensity in order of two<three<four mixed cationic structures see FIG. 120), maximum electroluminescence of perovskite light-emitting devices in the same order (see FIG. 121), improved current efficiency and reduced roll-off in the same order (see FIG. 122), and also the improved operational lifetime of the light-emitting diode in the same order (see FIG. 123).

Thus, medium-sized monovalent cation (A₂) contained within perovskite crystals can stabilize perovskite crystals and inhibit the production of defects within the crystals due to its entropy effect, and the excess A₂ cations not contained within perovskite crystals form a structure surrounding perovskite nanocrystal particles to passivate the surface of perovskite nanocrystal particles, thereby improving photoluminescence quantum efficiency, photoluminescence lifetime and stability, thus it can be useful for the light-emitting layer or wavelength converting layer of the light emitting device.

An example of a light-emitting device including a perovskite material in which defect generation is controlled through the addition of a medium-sized organic cation according to the present invention is the same as the description of the light-emitting device described above, and a detailed description will be omitted to avoid redundant description.

### EMBODIMENT MODES OF THE PRESENT INVENTION

Hereinafter, the present invention will be described in detail by examples and experimental examples. However, the following examples and experimental examples are merely illustrative of the present invention, and the contents of the present invention are not limited by the following examples and experimental examples.

### PREPARATION EXAMPLE 1

### Preparation of a Perovskite Film Having a 3D/2D Core-Shell Crystal Structure Using Phenylalkylamine

A first solution is prepared by dissolving organic-inorganic hybrid perovskite in a polar solvent. Dimethylsulfoxide is used as a polar solvent, and CH₃NH₃PbBr₃ is used as an organic-inorganic hybrid perovskite.

The CH₃NH₃PbBr₃ used has a ratio of CH₃NH₃Br to PbBr₂ of 1.06:1, and mixed solution in which the mass of CH₃NH₃PbBr₃ relative to the total precursor solution is 35 wt % (to be 1.2M) is used.

Next, 1 uL of phenylmethanamine is added to about 0.3 mL of the first solution to prepare a second solution.

After the second solution is deposited on a glass substrate, spin coating is performed while rotating the glass substrate at a speed of 3,000 rpm to prepare a perovskite film.

The prepared thin film is heat-treated at 90° C. for 10 minutes.

### PREPARATION EXAMPLE 2 TO 38

A perovskite film is prepared in the same manner as in Preparation Example 1, except that the phenylalkylamine compound of Table 3 is used instead of phenylmethylamine as an additive.

### COMPARATIVE EXAMPLE 1

### Preparation of Perovskite Film

A solution having a ratio of CH₃NH₃Br and PbBr₂ of 1.06:1 in a dimethylsulfoxide solvent without the addition of a phenylalkanamine compound and a mass of CH₃NH₃PbBr₃ relative to the total precursor solution of 35 wt % (to be 1.2M) is deposited on a glass substrate. After solution deposition, spin coating is performed while rotating the glass substrate at a speed of 3,000 rpm to prepare a perovskite film.

### EXPERIMENTAL EXAMPLE 1

### Changes in the Nuclear Magnetic Resonance Spectrum of the Perovskite Film According to the Addition of the Phenylalkanamine Compound

In the manufacture of the perovskite film according to the present invention, in order to examine the change in the perovskite structure according to the addition of the phenylalkanamine compound, the nuclear magnetic resonance (NMR) spectrum of the perovskite films prepared in Preparation Example 1 and Comparative Example 1 is analyzed, and the results are shown in FIG. 51.

As shown in FIG. 51, when compared with the NMR spectrum of the perovskite film of Comparative Example 1, the peak of the NMR of the perovskite film of Preparation Example 1 of the present invention can be seen that the proton peak of methylammonium cation has shifted from 7.4 ppm to 7.2 ppm. This is a result of the binding of the proton of the methylammonium cation to the phenylmethanamine molecule (basicity: pK_{b}=4.66) with strong basicity through proton transfer between the phenylalkanamine compound and the organic ammonium cation in the perovskite. On the other hand, as a Comparative Example, when the molecule of phenylamine (basicity: pK_{b}=9.4) with weak basicity is added via same process, the proton peak of the methylammonium cation is maintained at 7.4 ppm. Therefore, it can be seen that strong basicity is required for the proton transfer reaction.

### EXPERIMENTAL EXAMPLE 2

### Changes in the Surface Structure of the Perovskite Film According to the Addition of the Phenylalkanamine Compound

In the preparation of the perovskite film according to the present invention, in order to examine the change in the perovskite structure according to the addition of the phenylalkanamine compound, the surfaces of the perovskite films prepared in Preparation Example 1 and Comparative Example 1 are observed with a scanning microscope, and the results are shown in FIG. 52.

As shown in FIG. 52, the perovskite film of Comparative Example 1 is made of bulk polycrystals having a size of 200 nm to 300 nm, but the perovskite film of Preparation Example 1 is composed of crystals that are reduced in size as crystallization is terminated to less than 100 nm. The reduction in size is due to the formation of a self-assembled shell of 2D structure on the core of 3D structure according to the addition of the phenylalkanamine compound.

### EXPERIMENTAL EXAMPLE 3

### Changes of the Luminescent Properties of the Perovskite Film According to the Addition of the Phenylalkanamine Compound

In the preparation of the perovskite film according to the present invention, in order to investigate the effect of the addition of the phenylalkanamine compound on the luminescent properties of the perovskite film, photoluminescence characteristics are measured for the perovskite films prepared in Preparation Example 1 and Comparative Example 1 by using a spectrofluorometer, and the results are shown in FIG. 53.

As shown in FIG. 53, the conventional perovskite film having a 3D crystal structure of Comparative Example 1 shows a peak having a photoluminescence intensity of about 50 a.u. near a wavelength of 550 nm, whereas the perovskite film having a 3D/2D core-shell crystal structure in which phenylalkanamine compound is added according to the present invention exhibits a photoluminescence intensity of about 300 a.u. in the same wavelength range, thereby it is appeared to be increasing the luminescence property by about 6 times compared to the conventional 3D perovskite film.

On the other hand, as a comparative example, when phenylamine molecules (basicity: pK_{b}=9.4) with weak basicity are added via same process, the perovskite film does not exhibit photoluminescence properties in the same wavelength range. Because phenylamine shows weak basicity with a basicity of 7 or more, it does not have an acid-base reaction with organic ammonium of the perovskite precursor solution, so that proton transfer does not occur and it does not participate in the formation of the 2D perovskite shell.

As above description, the perovskite film having a 3D/2D core-shell crystal structure according to the present invention exhibits significantly increased light emitting properties compared to the conventional 3D perovskite film, so it can be usefully used as a light emitting layer of a light emitting device.

### EXPERIMENTAL EXAMPLE 4

### Changes in Charge Lifetime Properties of Perovskite Films According to the Addition of Phenylalkanamine Compound

In the preparation of the perovskite film according to the present invention, in order to examine the effect on the charge lifetime characteristics of the perovskite film according to the addition of the phenylalkanamine compound, the charge lifetimes of the films prepared in Preparation Example 1 and Comparative Example 1 are measured, and the results are shown in FIG. 54.

FIG. 54 is graph showing the charge lifetime characteristics of the perovskite film according to the presence or absence of a self-assembled shell according to an embodiment of the present invention.

As shown in FIG. 54, the conventional perovskite film having a 3D crystal structure of Comparative Example 1 has a charge lifetime of only 0.5 μs, whereas the perovskite film having the 3D/2D core-shell crystal structure by the addition of the phenylalkanamine compound according to the present invention exhibits a lifetime of 2.0 μs or more, and indicates that the lifetime is increased by about 4 times or more compared to the conventional 3D perovskite film.

On the other hand, as a comparative example, when the phenylamine (basicity: pK_{b}=9.4) with weak basicity is added via same process, the perovskite film exhibits a lifetime of less than 0.5 μs, it is not rather good than the conventional 3D perovskite film.

As above description, the perovskite film having a 3D/2D core-shell crystal structure according to the present invention exhibits significantly increased lifetime characteristics compared to the conventional 3D perovskite film, so it can be usefully used as a light emitting layer of a light emitting device.

### MANUFACTURING EXAMPLE

### Manufacture of Light Emitting Device

A FTO substrate (a glass substrate coated with an FTO anode) is prepared, a conductive material PEDOT:PSS (AI4083 from Heraeus) is spin-coated on the FTO anode, and then heat-treated at 150° C. for 30 minutes to form hole injection layer with a thickness of 50 nm.

Next, a solution in which phenylmethanamine is added to the perovskite bulk polycrystal precursor solution prepared in Preparation Example 1 is deposited on the hole injection layer and spin-coated while rotating at a speed of 3000 rpm. The prepared thin film is heat-treated at 90° C. for 10 minutes to form a perovskite light emitting layer having a 3D/2D core-shell crystal structure.

Thereafter, 1,3,5-Tris(1-phenyl-1H-benzimidazol-2-yl)benzene (TPBI) having a thickness of 50 nm is deposited on the perovskite light emitting layer having the 3D/2D core-shell crystal structure in a high vacuum of less than 1×10⁻⁷ Torr, so that electron transport layer is formed. LiF of 1 nm thickness is deposited to form an electron injection layer, and aluminum of 100 nm thickness is formed on the electron injection layer as a negative electrode. Therefore, perovskite light emitting diode is fabricated.

### COMPARATIVE EXAMPLE 2

A perovskite light emitting diode is fabricated according to a conventional method without adding phenylmethanamine to the perovskite bulk polycrystal precursor solution.

### EXPERIMENTAL EXAMPLE 5

### Current Efficiency Measurement of Light Emitting Diode

In the perovskite light emitting diode according to the present invention, the current efficiency is measured for the perovskite light emitting diodes prepared in Manufacturing Example and Comparative Example 2, and the results are shown in FIG. 124.

As shown in FIG. 124, the perovskite having a 3D/2D core-shell crystal structure according to the present invention compared to the conventional perovskite light emitting diode of Comparative Example 2 has been shown that the current efficiency of the perovskite light emitting diode including the light emitting layer is improved.

Improvement of current efficiency is considered to be because, in the perovskite light emitting layer having a 3D/2D core-shell crystal structure according to the present invention, the formed self-assembled shell prevents ion movement in the organic-inorganic hybrid perovskite.

### EXPERIMENTAL EXAMPLE 6

### Operation Lifetime Measurement of Light Emitting Diode

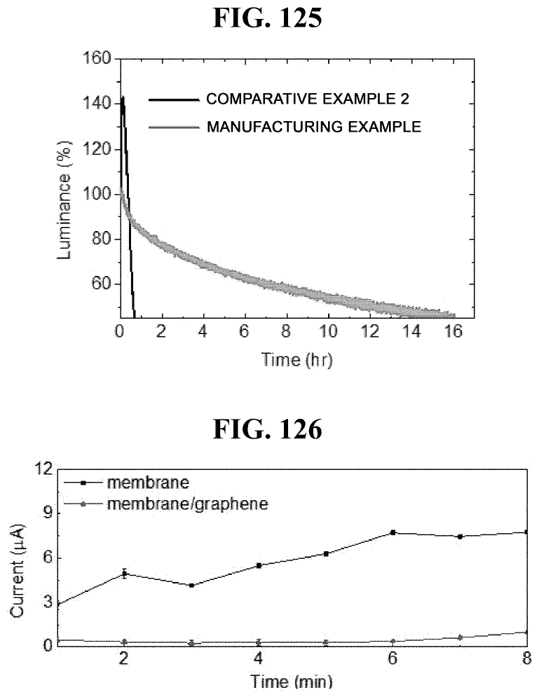

In the perovskite light emitting diode according to the present invention, the operation lifetime is measured for the perovskite light emitting diodes manufactured in Manufacturing Example and Comparative Example 2, and the results are shown in FIG. 125.

As shown in FIG. 125, the operation lifetime of the conventional perovskite light emitting diode of Comparative Example 2 does not exceed 1 hour, but a perovskite light emitting layer having a 3D/2D core-shell crystal structure according to the present invention has significantly improved operation lifetime that is more than 12 hours. The light emission for more than 12 hours is considered to be because the 2D shell prevented the movement of the Br anion, which moves most easily in the electric field applied during the operation of the perovskite light emitting diode.

As above description, the light emitting device including the perovskite film having a 3D/2D core-shell crystal structure according to the present invention as the light emitting layer has improved current efficiency and operation lifetime compared to the light emitting device including the conventional perovskite film. Therefore, it can be usefully used instead of the conventional light emitting device.

### PREPARATION EXAMPLE 38

### Preparation of Oxide Electrode in which Graphene Barrier Layer

(1) Forming Single-Layer Graphene Film

A copper foil (Cu-foil) (8 cm×10 cm) is placed in a quartz tube, and the quartz tube containing the copper foil is placed in a furnace, and the temperature is raised to 1060° C. while supplying H₂ (15 sccm). After heating, coppers oxidized on the foil are reduced to produce copper fine particles while the temperature is maintained for 30 minutes. Thereafter, CH₄ (60 sccm) and H₂ (15 sccm) are supplied to the quartz tube for 30 minutes, and a graphene film is grown on the foil. Then, after cooling to 500° C. for 10 minutes while supplying H₂, and then cooled to room temperature at 10 mtorr for 120 minutes, so that a single layer graphene film is formed on the foil.

(2) Forming a Single-Layer Graphene Barrier Layer on the Surface of the Oxide Electrode

A polymethyl methacrylate (PMMA) layer (4.6 g PMMA: 100 ml chlorobenzene) dissolved in chlorobenzene is coated on the single-layer graphene film prepared in (1), such that a PMMA polymer support layer is formed on the graphene film and PMMA/graphene/copper foil thin film. After forming the PMMA/graphene/copper foil thin film, the polymer/graphene/copper foil film is immersed in an ammonium persulfate (APS) solution (11 g APS: 600 ml distilled water) that is a copper etching solution for more than 6 hours to etch copper. Then, the residual etching solution is washed with distilled water to obtain a PMMA/graphene film.

Then, the PMMA/graphene film formed in the solution is pulled out and moved to an ITO substrate to form a PMMA/graphene film on the ITO substrate, and then immersed in acetone to remove the PMMA layer, so that single-layer graphene film is formed on ITO substrate.

### COMPARATIVE EXAMPLE 3

ITO substrate without the graphene barrier layer is used.

### EXPERIMENTAL EXAMPLE 7

### Measurement of Ion Permeability to Acid of Graphene Barrier Layer

The ITO substrate with the graphene barrier layer formed in Preparation Example 38 according to the present invention and the ITO substrate without the graphene barrier layer of Comparative Example 3 are attached in the space between the two water baths containing distilled water and 0.1M hydrochloric acid solution, and the ions movement characteristics between the two tanks are measured using the Ag/AgCl electrode as a reference electrode.

As a result, as shown in FIG. 126, in the case of a conventional ITO substrate, the ion concentration increases with time in a water bath containing distilled water, thereby ion mobility characteristics is exhibited. However, the substrate according to the present invention on which the graphene barrier layer is formed does not show a change in ion concentration with time. From this, it can be confirmed that the movement of ions is largely prevented by the graphene barrier layer.

### MANUFACTURING EXAMPLE 2

### Manufacturing Light Emitting Diode Having the Graphene Barrier Layer

After spin-coating a conductive material PEDOT:PSS (pH: about 2) (AI4083 from Heraeus) on the graphene barrier layer of the ITO electrode with the graphene barrier layer prepared in Example 38, a hole injection layer having a thickness of 40 nm is formed through heat treatment at 150° C. for 30 minutes.

Next, a MAPbBr₃ perovskite solution is spin-coated on the hole injection layer and heat-treated at 90° C. for 10 minutes to form a perovskite light emitting layer.

Thereafter, a negative electrode is formed by depositing aluminum with a thickness of 100 nm on the perovskite light emitting layer, thereby the light emitting diode is manufactured.

### COMPARATIVE EXAMPLE 4

### Manufacturing Light Emitting Diode without the Graphene Barrier Layer

The hole injection layer having PEDOT:PSS (pH: about 2), the perovskite light emitting layer and the negative electrode of aluminum are formed on the conventional ITO electrode, so that the light emitting diode is manufactured.

### EXPERIMENTAL EXAMPLE 8

### Time of Flight-Secondary Ion Mass Spectrometry (TOF-SIMS)

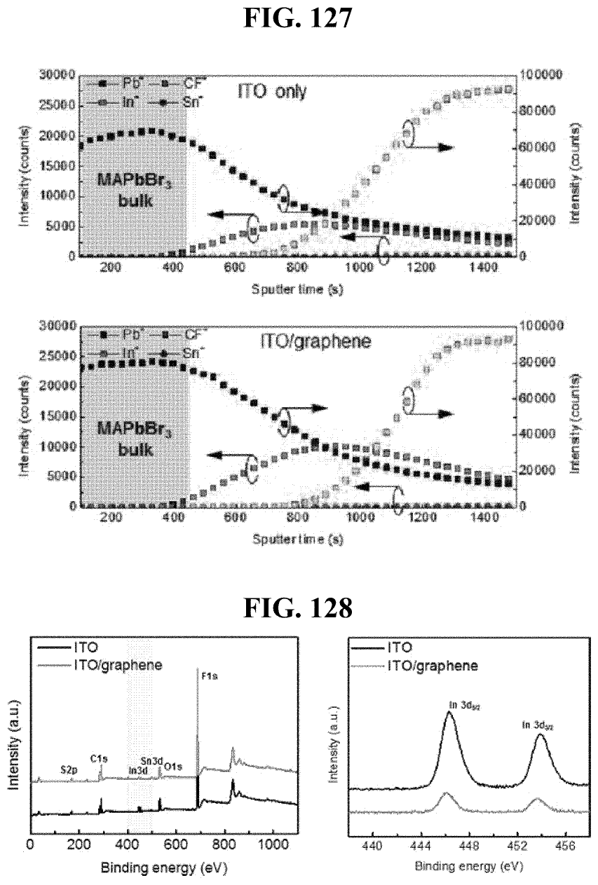

The perovskite light emitting diode including an ITO electrode with a graphene barrier layer formed in Manufacturing Example 2 according to the present invention, and the perovskite light emitting diode of Comparative Example 4 including a conventional ITO electrode are prepared. TOF-SIMS analysis is performed on the perovskite light emitting diodes, and the results are shown in FIG. 127.

As shown in FIG. 127, in the perovskite light emitting diode including the ITO electrode with the graphene barrier layer, the In⁺ peak is pushed back when the graphene barrier layer is stacked. It is confirmed that the dissolution properties of ITO can be reduced by the acidity of PEDOT:PSS.

### EXPERIMENTAL EXAMPLE 9

### X-Ray Photoelectron Spectroscopy

X-ray photoelectron analysis for a thin film in which an acidic hole injection layer is deposited on an ITO electrode having a graphene barrier layer of Manufacturing Example 2 according to the present invention and a thin film in which an acidic hole injection layer is deposited on a conventional ITO electrode for comparison is performed, and the results are shown in FIG. 128.

As shown in FIG. 128, when an acidic hole injection layer is deposited on a conventional ITO electrode, a large amount of In⁺ composition is detected on the acidic hole injection layer, whereas when an acidic hole injection layer is deposited on the ITO electrode having a graphene barrier layer formed according to the present invention, it is found that the In⁺ composition detected on the acidic hole injection layer decreased sharply. Through this, it can be confirmed that the graphene barrier layer prevents dissolution of the ITO electrode against acid and In⁺ diffusion.

### EXPERIMENTAL EXAMPLE 10

### Exciton Lifetime Analysis of Perovskite Light Emitting Body

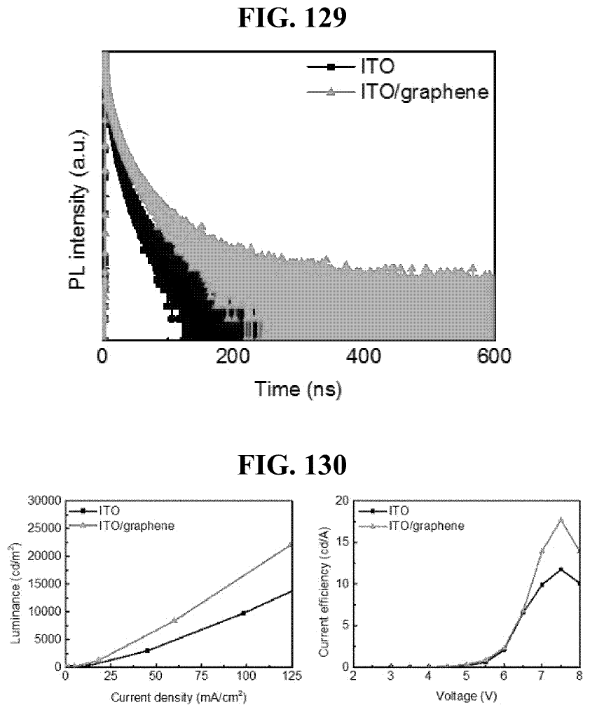

Exciton lifetime changes of the light emitting layer in the perovskite light emitting diode including the ITO electrode with the graphene barrier layer formed in Manufacturing Example 2 according to the present invention and the light emitting layer of the perovskite light emitting diode of Comparative Example 4 including the conventional ITO electrode are measured, and the results are shown in FIG. 129.

As shown in FIG. 129, in the case of a general ITO electrode, the electrode is partially dissolved by the contacted acidic PEDOT:PSS and chemical species such as In⁺ are eluted, and exciton dissociation in the perovskite light emitting layer occurs, so that the exciton lifetime is very short 200 ns. However, it can be seen that when the graphene barrier layer is laminated on the ITO electrode according to the present invention, the graphene barrier layer prevents the diffusion of chemical species such as In⁺ into the perovskite light emitting layer, thereby the exciton lifetime is improved.

### EXPERIMENTAL EXAMPLE 11

### Electric Characteristics Analysis of Perovskite Light Emitting Diode

Luminance and current efficiency for the perovskite light emitting diode including the ITO electrode with the graphene barrier layer formed in Manufacturing Example 2 according to the present invention and the perovskite light emitting diode of Comparative Example 4 including the conventional ITO electrode is measured, and the results are shown in FIG. 130.

As shown in FIG. 130, when the graphene barrier layer is laminated on the ITO electrode according to the present invention, the graphene barrier layer prevents the diffusion of chemical species such as In⁺ into the perovskite light emitting layer, so that the perovskite light emitting diode of Manufacturing Example 2 exhibits higher characteristics in luminance and current efficiency than when the conventional ITO electrode is used.

On the other hand, the embodiments of the present invention disclosed in the present specification and drawings are merely presented as specific examples to aid understanding, and are not intended to limit the scope of the present invention. It will be apparent to those of ordinary skill in the art to which the present invention pertains that other modifications based on the technical idea of the present invention can be implemented in addition to the embodiments disclosed herein.

1. A perovskite film consisted of a perovskite crystal having 3D/2D core-shell crystal structure comprising:
a core consisting of three-dimensional perovskite crystals of ABX₃ or A′₂BX₃ₙ₊₁ (n is an integer from 3 to 100); and
a two-dimensional perovskite surrounding the core as self-assembled shell and having Y₂Aₘ₋₁BX₃ₘ₊₁ (m is an integer of 1 to 100) in which a phenylalkanamine compound (Y) of the following formula 27 is self-assembled through a proton transfer reaction,
wherein the A or the A′ is an alkali metal ion or a monovalent organic cation selected from group consisting of organic ammonium (RNH₃)⁺, organic amidinium derivative (RC(═NR₂)NR₂)⁺, organic guanidinium derivative (R₂NC(═NR₂)NR₂)⁺, organic diammonium (CₓH₂ₓ₋ₙ₊₄)(NH₃)ₙ⁺, ((CₓH₂ₓ₊₁)ₙNH₃)(CH₃NH₃)ₙ⁺, (RNH₃)₂⁺, (CₙH₂ₙ₊₁NH₃)₂⁺, (CF₃NH₃)⁺, (CF₃NH₃)ₙ⁺, ((CₓF₂ₓ₊₁)ₙNH₃)₂(CF₃NH₃)ₙ⁺, ((CₓF₂ₓ₊₁)ₙNH₃)₂⁺ or (CₙF₂ₙ₊₁NH₃)₂⁺ (x, and n is an integer greater than or equal to 1, R=hydrocarbon derivative, H, F, Cl, Br, or I) and combinations thereof,
wherein the B is a divalent transition metal, a rare earth metal, an alkaline earth metal, a monovalent metal, a trivalent metal, or a combination thereof,
wherein X is F⁻, Cl⁻, Br⁻, I⁻, At⁻ or a combination thereof. 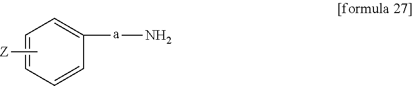
(In formula 27, “a” is unsubstituted linear alkyl or branched alkyl C1 to C10, or amine-substituted linear alkyl or branched alkyl of C1 to C10. “Z” is F or CF₃.)

2. The perovskite film of claim 1, wherein the phenylalkanamine compound of the following formula 27 is selected from group consisting of phenylmethanamine, (4-fluorophenyl)methanamine, (4-(trifluoromethyl)phenyl)methanamine, 2-phenylethanamine, 1-phenylpropan-2-amine, 1-phenylpropan-1-amine, 1-phenylethane-1,2-diamine, 2-(4-fluorophenyl)ethanamine, 1-(4-fluorophenyl)propan-2-amine, 1-(4-fluorophenyl) propan-1-amine, 1-(4-fluorophenyl) ethane-1,2-diamine, 2-(4-(trifluoromethyl)phenyl)ethanamine, 1-(4-(trifluoromethyl)phenyl)propan-2-amine, 1-(4-(trifluoromethyl)phenyl)propan-1-amine, 3-phenylpropan-1-amine, 4-phenylbutan-2-amine, 1-phenylbutan-2-amine, 1-phenylbutan-1-amine, 3-phenylpropane-1,2-diamine, 3-(4-fluorophenyl)propan-1-amine, 4-(4-fluorophenyl)butan-2-amine, 1-(4-fluorophenyl)butan-1-amine, 4-phenylbutan-1-amine, 5-phenylpentan-2-amine, 1-phenylpentan-3-amine, 1-phenylpentan-1-amine, 4-(4-fluorophenyl)butan-1-amine, 1-(4-fluorophenyl) pentan-3-amine, 1-(4-fluorophenyl) pentan-1-amine, 5-phenylpentan-1-amine, 1-phenylhexan-1-amine, 1-phenylhexan-2-amine, 1-phenylhexan-3-amine, 6-phenylhexan-2-amine, 1-(4-fluorophenyl)hexan-1-amine, 1-(4-fluorophenyl)hexan-3-amine, 6-phenylhexan-1-amine and 1-phenylheptan-1-amine.

3. The perovskite film of claim 1, wherein the perovskite crystal having the 3D/2D core-shell crystal structure has a size of 10 nm to 1 um.

4. A method of manufacturing a perovskite film consisted of a perovskite crystal having 3D/2D core-shell crystal structure comprising:
preparing a mixed solution by adding a phenylalkanamine compound of formula 27 to a perovskite bulk precursor solution (S100); and
forming the perovskite film having the 3D/2D core-shell crystal structure by coating the mixed solution of the perovskite bulk precursor solution and the phenylalkanamine compound on a substrate. 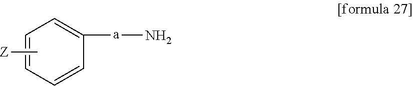
(In formula 27, “a” is unsubstituted linear alkyl or branched alkyl C1 to C10, or amine-substituted linear alkyl or branched alkyl of C1 to C10. “Z” is F or CF₃.)

5. The method of manufacturing the perovskite film of claim 4, wherein the phenylalkanamine compound of the following formula 27 is selected from group consisting of phenylmethanamine, (4-fluorophenyl)methanamine, (4-(trifluoromethyl)phenyl)methanamine, 2-phenylethanamine, 1-phenylpropan-2-amine, 1-phenylpropan-1-amine, 1-phenylethane-1,2-diamine, 2-(4-fluorophenyl)ethanamine, 1-(4-fluorophenyl)propan-2-amine, 1-(4-fluorophenyl) propan-1-amine, 1-(4-fluorophenyl) ethane-1,2-diamine, 2-(4-(trifluoromethyl)phenyl)ethanamine, 1-(4-(trifluoromethyl)phenyl)propan-2-amine, 1-(4-(trifluoromethyl)phenyl)propan-1-amine, 3-phenylpropan-1-amine, 4-phenylbutan-2-amine, 1-phenylbutan-2-amine, 1-phenylbutan-1-amine, 3-phenylpropane-1,2-diamine, 3-(4-fluorophenyl)propan-1-amine, 4-(4-fluorophenyl)butan-2-amine, 1-(4-fluorophenyl)butan-1-amine, 4-phenylbutan-1-amine, 5-phenylpentan-2-amine, 1-phenylpentan-3-amine, 1-phenylpentan-1-amine, 4-(4-fluorophenyl)butan-1-amine, 1-(4-fluorophenyl) pentan-3-amine, 1-(4-fluorophenyl) pentan-1-amine, 5-phenylpentan-1-amine, 1-phenylhexan-1-amine, 1-phenylhexan-2-amine, 1-phenylhexan-3-amine, 6-phenylhexan-2-amine, 1-(4-fluorophenyl)hexan-1-amine, 1-(4-fluorophenyl)hexan-3-amine, 6-phenylhexan-1-amine and 1-phenylheptan-1-amine.

6. The method of manufacturing the perovskite film of claim 4, wherein a solvent of the perovskite bulk precursor solution is dimethylformamide, gamma butyrolactone (gamma), butyrolactone), N-methylpyrrolidone, dimethylsulfoxide or a combination thereof.

7. The method of manufacturing the perovskite film of claim 4, wherein a concentration of the perovskite bulk precursor solution has range of 0.01 M to 1.5 M.

8. The method of manufacturing the perovskite film of claim 4, wherein the phenylalkanamine compound is mixed in a ratio of 0.1 mol. % to 20 mol. % with respect to the perovskite bulk precursor solution in the mixed solution of the perovskite bulk precursor solution and the phenylalkanamine compound.

9. The method of manufacturing the perovskite film of claim 4, wherein the phenylalkanamine compound forms a self-assembled shell by receiving a proton from an organic ammonium ion in the perovskite bulk precursor solution and being changed to a cation.

10. A perovskite light emitting device comprising:
substrate;
a first electrode formed on the substrate;
a light emitting layer positioned on the first electrode; and
a second electrode positioned on the light emitting layer,
wherein the light emitting layer is perovskite film having 3D/2D core-shell crystal structure.

11. The perovskite light emitting device of claim 10, wherein the light emitting layer has thickness of 10 nm to 10 um.

12. The perovskite light emitting device of claim 10, wherein the first electrode or the second electrode has metal, conductive polymer, metallic carbon nanotubes, graphene, reduced graphene oxide, metal nanowires, carbon nanodots, metal nanodots, conductive oxides, or combination thereof.

13. The perovskite light emitting device of claim 10, further comprises a hole injection layer between the first electrode and the light emitting layer,
wherein the hole injection layer has a conductive polymer neutralized to a pH of 4.0 to 10.0 with a work function of 5.8 eV or more by adding a fluorine-based material of formula 26 and a basic material to a conductive polymer. 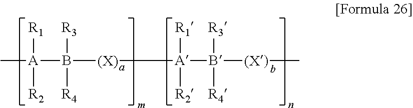
(in formula 26, 0<m≤10,000,000, 0≤n<10,000,000, 0≤a≤20, 0≤b≤20,
A, B, A′ and B′ are each independently selected from the group consisting of C, Si, Ge, Sn, and Pb,
R1, R2, R3, R4, R1′, R2′, R3′ and R4′ are each independently selected from the group consisting of hydrogen, halogen, nitro group, substituted or unsubstituted amino group, cyano group, substituted or unsubstituted C₁-C₃₀ alkyl group, a substituted or unsubstituted C₁-C₃₀ heteroalkyl group, a substituted or unsubstituted C₁-C₃₀ alkoxy group, a substituted or unsubstituted C₁-C₃₀ heteroalkoxy group, a substituted or unsubstituted C₆-C₃₀ aryl group, a substituted or unsubstituted C₆-C₃₀ arylalkyl group, substituted or unsubstituted C₆-C₃₀ aryloxy group, substituted or unsubstituted C₂-C₃₀ heteroaryl group, substituted or unsubstituted C₂-C₃₀ heteroarylalkyl group, substituted or unsubstituted C₂-C₃₀ heteroaryloxy group, substituted or unsubstituted C₅-C₂₀ cycloalkyl group, substituted or unsubstituted C₂-C₃₀ heterocycloalkyl group, substituted or unsubstituted C₁-C₃₀ alkyl ester group, substituted or unsubstituted C₁-C₃₀ heteroalkyl ester group, substituted or unsubstituted C₆-C₃₀ aryl ester group, and substituted or unsubstituted C₂-C₃₀ heteroaryl ester group,
R1, R2, R3, or R4 is an ionic group or includes an ionic group,
X and X′ are each independently selected from the group consisting of a simple bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, substituted or unsubstituted C₆-C₃₀ arylalkylene group, substituted or unsubstituted C₂-C₃₀ heteroarylene group, substituted or unsubstituted C₂-C₃₀ heteroarylalkylene group, substituted or an unsubstituted C₅-C₂₀ cycloalkylene group, a substituted or unsubstituted C₅-C₃₀ heterocycloalkylene group, a substituted or unsubstituted C₆-C₃₀ aryl ester group and a substituted or unsubstituted C₂-C₃₀ heteroaryl ester group,
When n is 0, R1, R2, R3, or R4 is a hydrophobic functional group including a halogen element or a hydrophobic functional group).

14. The perovskite light emitting device of claim 13, wherein the conductive polymer has copolymer of two or more types of compounds, derivative of the compound or blend of two or more compounds among the compound is polythiophene, polyaniline, polypyrrole, polystyrene, polyethylenedioxythiophene, polyacetylene, polyphenylene, polyphenylvinylene and polycarbazole.

15. The perovskite light emitting device of claim 13, wherein the basic material is pyridine compound or amine compound having pKa of 4 to 6 selected from the group consisting of 2-naphthylamine, n-allylaniline), 4-aminobiphenyl, o-toluidine, aniline, quinoline, and N,N,-Diethyl aniline.

16. The perovskite light emitting device of claim 13, wherein the conductive polymer has PEDOT:PSS, PFI or aniline.

17. The perovskite light emitting device of claim 13, further comprises a graphene barrier layer between the first electrode and the hole injection layer in case that the first electrode has indium-tin oxide (ITO), indium-zinc oxide (IZO) or fluorinated-tin oxide (FTO) that is dissociated by acid.

18. The perovskite light emitting device of claim 17, wherein the graphene barrier layer is formed by process,
wherein the process has forming a graphene layer on catalyst metal layer, forming a polymer layer on the graphene layer, forming a polymer layer/graphene layer thin film by removing the catalyst metal layer, transferring the polymer layer/graphene layer thin film on the first electrode and removing the polymer layer.

19. The perovskite light emitting device of claim 17, wherein the graphene barrier layer has thickness of 0.1 nm to 100 nm.

20. The perovskite light emitting device of claim 10, wherein the perovskite light emitting device is light-emitting diode, light-emitting transistor, laser or polarized light-emitting device.
